(19) United States
(12) Patent Application Publication
(10) Pub. No.: US 2025/0127057 A1
(43) Pub. Date: Apr. 17, 2025

(54) LIGHT EMITTING ELEMENT, FUSED POLYCYCLIC COMPOUND FOR THE LIGHT EMITTING ELEMENT, AND DISPLAY DEVICE INCLUDING THE LIGHT EMITTING ELEMENT

(71) Applicant: Samsung Display Co., Ltd., Yongin-si (KR)

(72) Inventors: MUN-KI SIM, Yongin-si (KR); TAEIL KIM, Yongin-si (KR); SUN YOUNG PAK, Yongin-si (KR); MinJae SUNG, Yongin-si (KR); MINJUNG JUNG, Yongin-si (KR); Giwoong HAN, Yongin-si (KR); Seonhyoung HUR, Yongin-si (KR)

(21) Appl. No.: 18/811,371

(22) Filed: Aug. 21, 2024

(30) Foreign Application Priority Data
Sep. 4, 2023 (KR) 10-2023-0116684

(51) Int. Cl. H10K 85/60; H10K 85/40

(52) U.S. Cl. CPC H10K 85/658; H10K 85/40; H10K 85/615; H10K 85/654; H10K 85/656; H10K 85/6572; H10K 85/6574; H10K 85/6576

(57) ABSTRACT

A light emitting element includes a first electrode, a second electrode on the first electrode, and a light emitting layer between the first electrode and the second electrode and including a first compound represented by Formula 1.

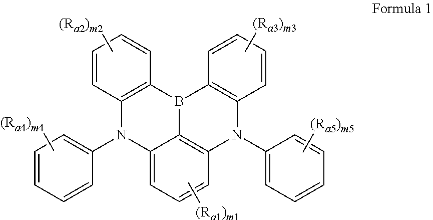

### CROSS-REFERENCE TO RELATED APPLICATION

The present application claims priority to and the benefit of Korean Patent Application No. 10-2023-0116684, filed on Sep. 4, 2023, in the Korean Intellectual Property Office, the entire disclosure of which is incorporated herein by reference.

### BACKGROUND

### 1. Field

One or more embodiments of the present disclosure relate to a light emitting element, a fused polycyclic compound utilized for the light emitting element, and a display device including the light emitting element.

### 2. Description of the Related Art

Recently, as an image display device, an organic electroluminescence display device and/or the like have been actively researched and developed. The organic electroluminescence display device and/or the like is a display device including a self-luminescence light emitting element which realizes display of images by recombining, in a light emitting layer, holes and electrons separately injected from a first electrode and a second electrode to emit light generated from a light emitting material of the light emitting layer.

In applying a light emitting element to a display device, improvements in light efficiency, lifespan, and/or the like are required and desired, and thus the development of a material for a light emitting element capable of stably implementing such improvements is continuously in demand or pursued.

### SUMMARY

One or more aspects of embodiments of the present disclosure are directed toward a light emitting element with improved light emission efficiency and lifespan, and a display device including the light emitting element.

One or more aspects of embodiments of the present disclosure are directed toward a fused polycyclic compound, which is a material for a light emitting element capable of improving light emission efficiency and lifespan of the light emitting element.

Additional aspects will be set forth in part in the description which follows and, in part, will be apparent from the description, or may be learned by practice of the presented embodiments.

According to one or more embodiments of the present disclosure, a light emitting element including a first electrode, a second electrode on the first electrode, and a light emitting layer between the first electrode and the second electrode and including a first compound represented by Formula 1.

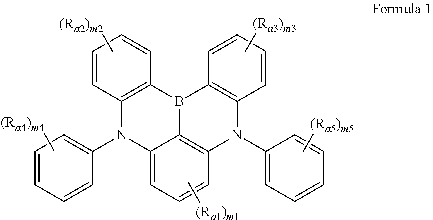

In Formula 1, m1 may be an integer of 0 to 3, m2 and m3 may each independently be an integer of 0 to 4, m4 and m5 may each independently be an integer of 0 to 5, at least one selected from among Rₐ₁ to Rₐ₅ may include a substituted or unsubstituted first carbazole (e.g., a first carbazole substituted or unsubstituted), and at least one selected from among Rₐ₁ to Rₐ₅ may be a group represented by Formula 2, and the rest thereof may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

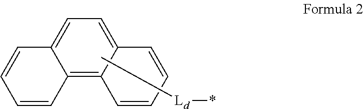

In Formula 2, L_{d} may be a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 30 ring-forming carbon atoms, and when L_{d} does not include the first carbazole, at least one selected from among Rₐ₁ to Rₐ₅ not represented by Formula 2 may include the first carbazole substituted with a substituent other than a phenanthryl group, or Rₐ₂ and Rₐ₃ may each independently be include the first carbazole not substituted or the first carbazole substituted with a substituent other than a phenanthryl group.

In one or more embodiments, the light emitting layer may further include at least one of (e.g., selected from among) a second compound represented by Formula HT-1, a third compound represented by Formula ET-1, and/or a fourth compound represented by Formula D-1.

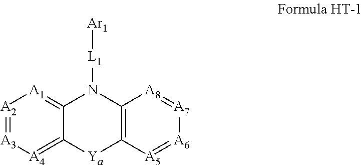

In Formula HT-1, A₁ to A₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Ar₁ may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may form a ring by being bonded to an adjacent group.

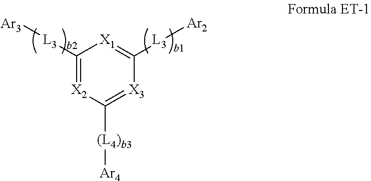

In Formula ET-1, at least one selected from among X₁ to X₃ is N, and the rest thereof may be CR₅₆, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

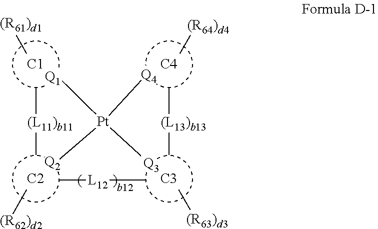

In Formula D-1, Q₁ to Q₄ may each independently be C or N, C1 C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle ring having 2 to 30 ring-forming carbon atoms, L₁₁ to L₁₃ each independently be a direct linkage, *—O—*, *—S—*,

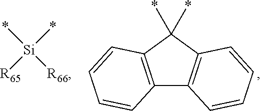

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the first compound represented by Formula 1 may be represented by any one selected from among Formula 1-1 to Formula 1-3.

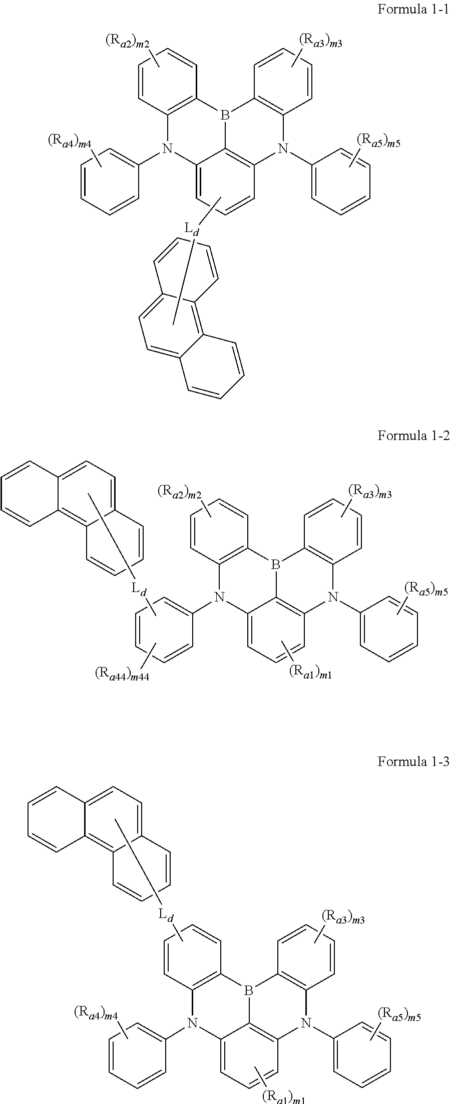

In Formula 1-2, m44 may be an integer of 0 to 4, and Rₐ₄₄ may be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and in Formula 1-1 to Formula 1-3, m1 to m5, Rₐ₁ to Rₐ₅, and L_{d} may each be the same as defined in Formula 1 and Formula 2.

In one or more embodiments, the first compound represented by Formula 1-1 may be represented by Formula 1-1A.

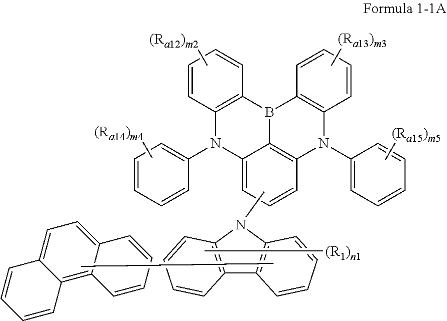

In Formula 1-1A, n1 may be an integer of 0 to 7, R₁ and Rₐ₁₂ to Rₐ₁₅ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and m2 to m5 may each be the same as defined in Formula 1-1.

In one or more embodiments, the first compound represented by Formula 1-2 may be represented by Formula 1-2A.

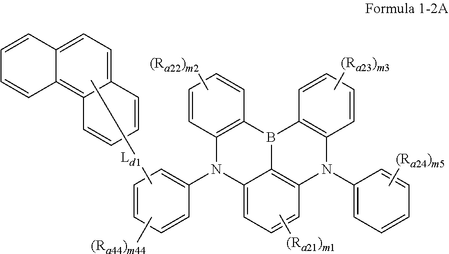

In Formula 1-2A, L_{d1} may be a direct linkage, or a substituted or unsubstituted arylene group having 6 to 30 ring-forming carbon atoms, at least one selected from among Rₐ₂₁ to Rₐ₂₄ may be the first carbazole substituted with a substituent other than a phenanthryl group, and the rest thereof may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or Rₐ₂₂ and Rₐ₂₃ may each independently be the first carbazole not substituted or the first carbazole substituted with a substituent other than a phenanthryl group, and Rₐ₂₁ and Rₐ₂₄ may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and m1 to m3, m5, m44, and Rₐ₄₄ may each be the same as defined in Formula 1-2.

In one or more embodiments, the first compound represented by Formula 1-3 may be represented by Formula 1-3A.

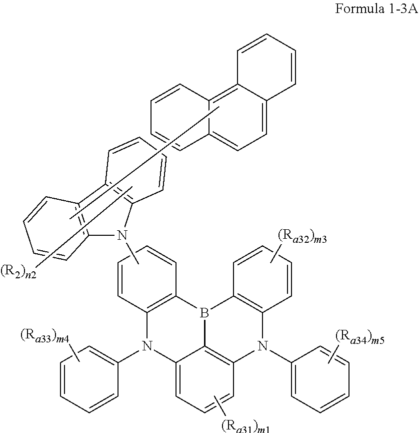

In Formula 1-3A, n2 may be an integer of 0 to 7, and R₂ and Rₐ₃₁ to Rₐ₃₄ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and m1 and m3 to m5 may each be the same as defined in Formula 1-3.

In one or more embodiments, the first compound represented by Formula 1-3A may be represented by Formula 1-3AA.

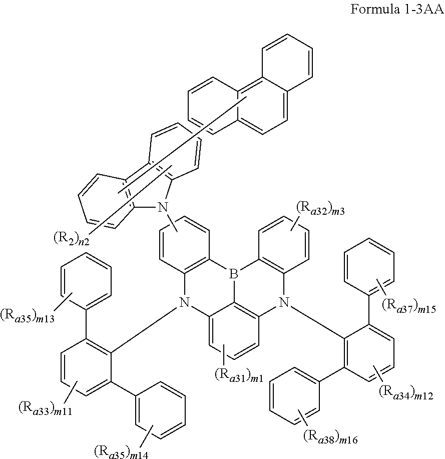

In Formula 1-3AA, m11 and m12 may each independently be an integer of 0 to 3, m13 to m16 may each independently be an integer of 0 to 5, Rₐ₃₅ to Rₐ₃₈ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and m1, m3, n2, R₂, and Rₐ₃₁ to Rₐ₃₄ may each be the same as defined in Formula 1-3A.

In one or more embodiments, the group represented by Formula 2 may be represented by any one selected from among Formula 2-1 to Formula 2-31.

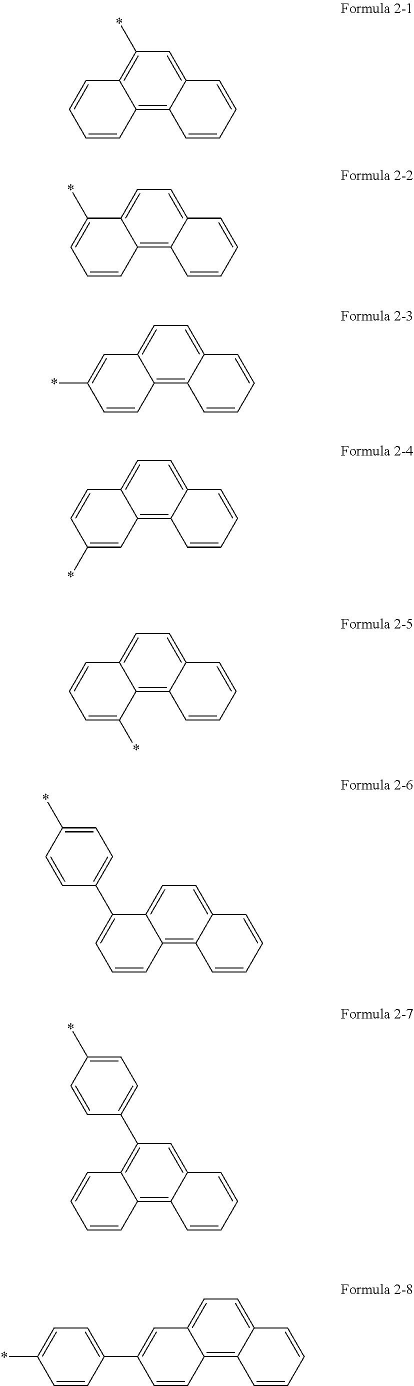

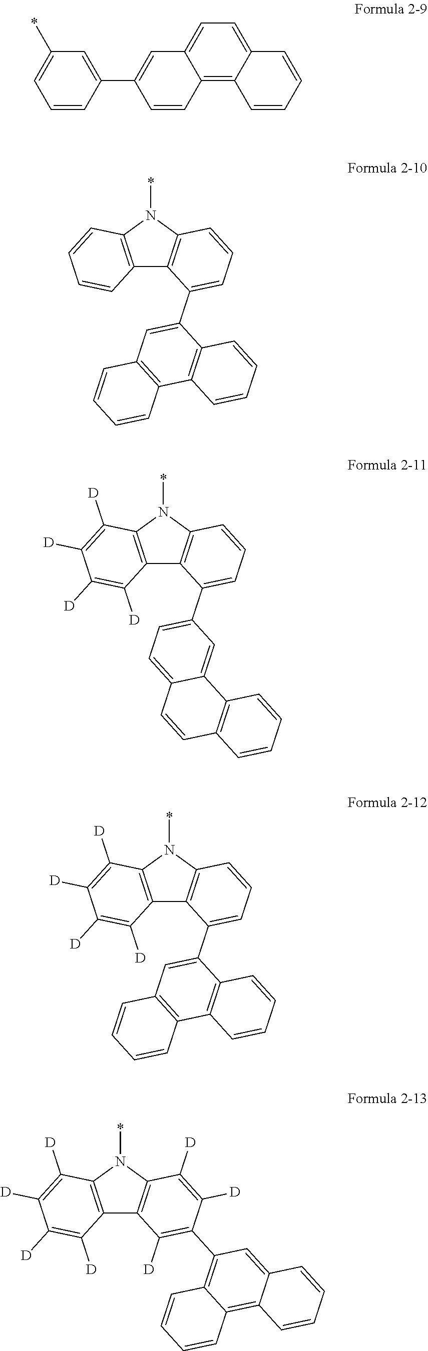 [SMILES: *c1cccc(-c2ccc3c(ccc4ccccc43)c2)c1 ; *n1c2ccccc2c2c(-c3cc4ccccc4c4ccccc34)cccc21 ; *n1c2cccc(-c3ccc4ccc5ccccc5c4c3)c2c2c([2H])c([2H])c([2H])c([2H])c21 ; *n1c2cccc(-c3cc4ccccc4c4ccccc34)c2c2c([2H])c([2H])c([2H])c([2H])c21 ; *n1c2c([2H])c([2H])c([2H])c([2H])c2c2c([2H])c(-c3cc4ccccc4c4ccccc34)c([2H])c([2H])c21]

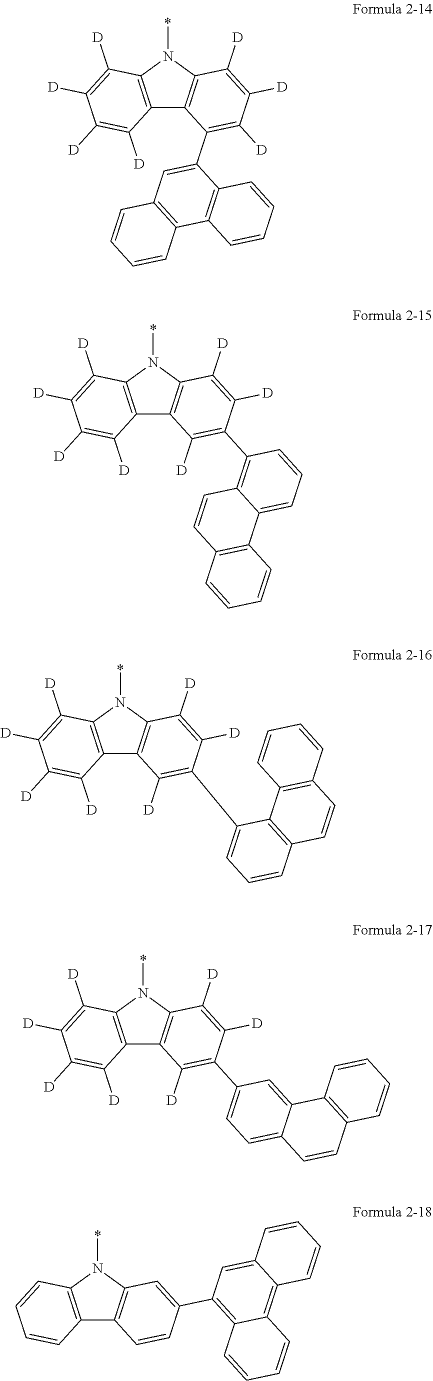 [SMILES: *n1c2c([2H])c([2H])c([2H])c([2H])c2c2c(-c3cc4ccccc4c4ccccc34)c([2H])c([2H])c([2H])c21 ; *n1c2c([2H])c([2H])c([2H])c([2H])c2c2c([2H])c(-c3cccc4c3ccc3ccccc34)c([2H])c([2H])c21 ; *n1c2c([2H])c([2H])c([2H])c([2H])c2c2c([2H])c(-c3cccc4ccc5ccccc5c34)c([2H])c([2H])c21 ; *n1c2c([2H])c([2H])c([2H])c([2H])c2c2c([2H])c(-c3ccc4ccc5ccccc5c4c3)c([2H])c([2H])c21 ; *n1c2ccccc2c2ccc(-c3cc4ccccc4c4ccccc34)cc21]

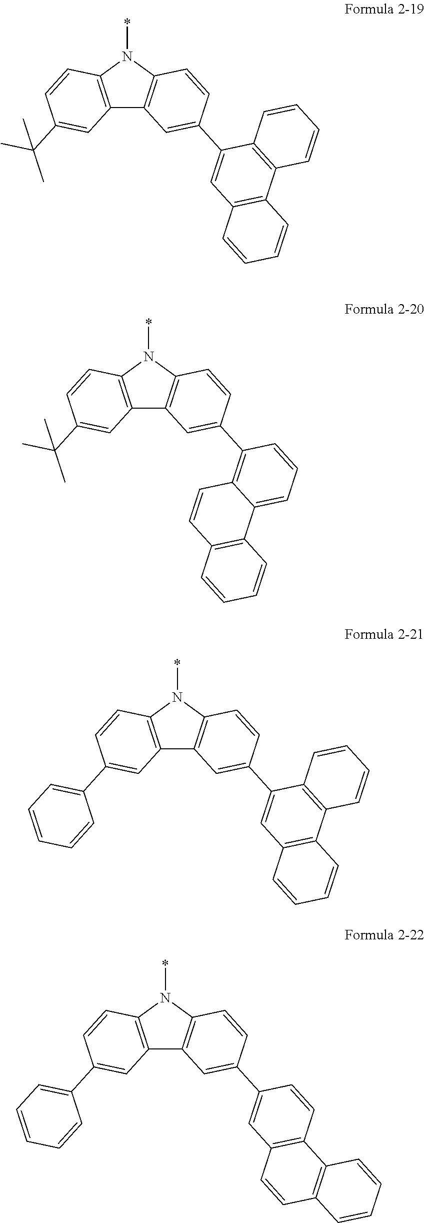 [SMILES: *n1c2ccc(-c3cc4ccccc4c4ccccc34)cc2c2cc(C(C)(C)C)ccc21 ; *n1c2ccc(-c3cccc4c3ccc3ccccc34)cc2c2cc(C(C)(C)C)ccc21 ; *n1c2ccc(-c3ccccc3)cc2c2cc(-c3cc4ccccc4c4ccccc34)ccc21 ; *n1c2ccc(-c3ccccc3)cc2c2cc(-c3ccc4c(ccc5ccccc54)c3)ccc21]

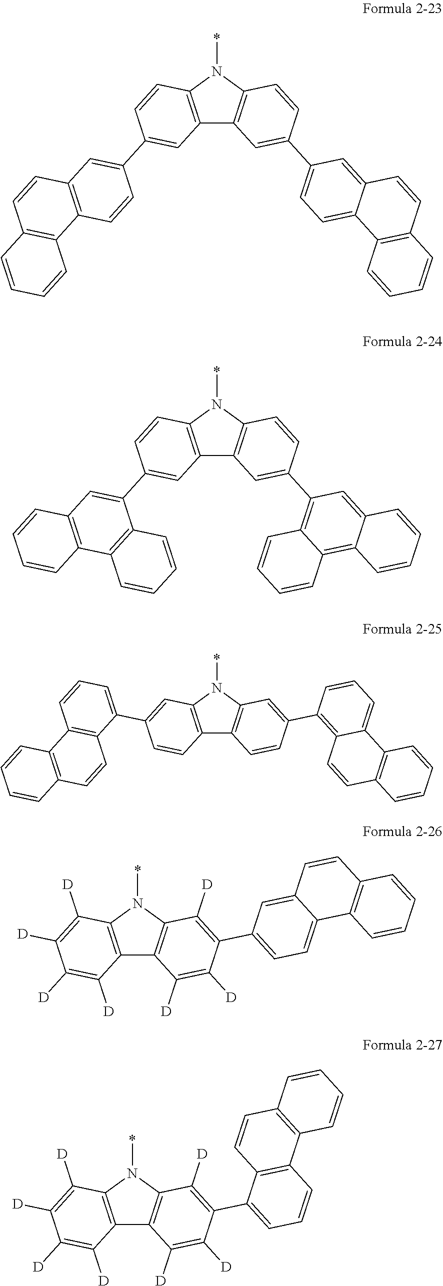 [SMILES: *n1c2ccc(-c3ccc4c(ccc5ccccc54)c3)cc2c2cc(-c3ccc4c(ccc5ccccc54)c3)ccc21 ; *n1c2ccc(-c3cc4ccccc4c4ccccc34)cc2c2cc(-c3cc4ccccc4c4ccccc34)ccc21 ; *n1c2cc(-c3cccc4c3ccc3ccccc34)ccc2c2ccc(-c3cccc4c3ccc3ccccc34)cc21 ; *n1c2c([2H])c([2H])c([2H])c([2H])c2c2c([2H])c([2H])c(-c3ccc4c(ccc5ccccc54)c3)c([2H])c21 ; *n1c2c([2H])c([2H])c([2H])c([2H])c2c2c([2H])c([2H])c(-c3cccc4c3ccc3ccccc34)c([2H])c21]

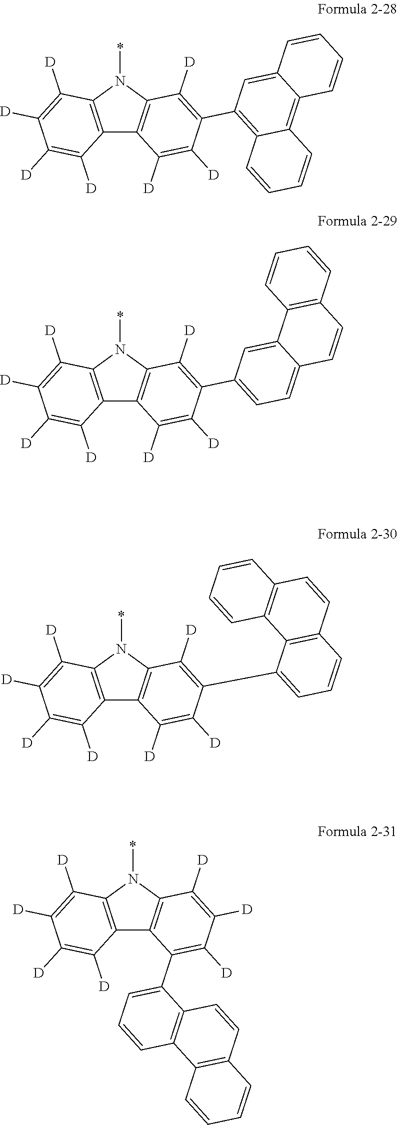 [SMILES: *n1c2c([2H])c([2H])c([2H])c([2H])c2c2c([2H])c([2H])c(-c3cc4ccccc4c4ccccc34)c([2H])c21 ; *n1c2c([2H])c([2H])c([2H])c([2H])c2c2c([2H])c([2H])c(-c3ccc4ccc5ccccc5c4c3)c([2H])c21 ; *n1c2c([2H])c([2H])c([2H])c([2H])c2c2c([2H])c([2H])c(-c3cccc4ccc5ccccc5c34)c([2H])c21 ; *n1c2c([2H])c([2H])c([2H])c([2H])c2c2c(-c3cccc4c3ccc3ccccc34)c([2H])c([2H])c([2H])c21]

In Formula 2-11 to Formula 2-17 and Formula 2-26 to Formula 2-31, D may be a deuterium atom.

In one or more embodiments of the present disclosure, a fused polycyclic compound is represented by Formula 1.

In one or more embodiments of the present disclosure, a display device includes a base layer, a circuit layer on the base layer, and a display element layer on the circuit layer and including a light emitting element, wherein the light emitting element includes a first electrode, a second electrode on the first electrode, and a light emitting layer between the first electrode and the second electrode and including a fused polycyclic compound represented by Formula 1.

In one or more embodiments, the light emitting element may include a first light emitting element configured to emit red light, a second light emitting element configured to emit green light, and a third light emitting element configured to emit blue light, wherein the fused polycyclic compound may be included in the third light emitting element.

In one or more embodiments, the display device may further include a light control layer on the display element layer and including a quantum dot.

### BRIEF DESCRIPTION OF THE DRAWINGS

The accompanying drawings are included to provide a further understanding of the present disclosure, and are incorporated in and constitute a part of this disclosure. The drawings illustrate example embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1 is a plan view showing a display device according to one or more embodiments of the present disclosure;

FIG. 2 is a cross-sectional view showing a portion corresponding to line I-I′ of the display device of FIG. 1;

FIG. 3 is a cross-sectional view schematically showing a light emitting element of one or more embodiments of the present disclosure;

FIG. 4 is a cross-sectional view schematically showing a light emitting element of one or more embodiments of the present disclosure;

FIG. 5 is a cross-sectional view schematically showing a light emitting element of one or more embodiments of the present disclosure;

FIG. 6 is a cross-sectional view schematically showing a light emitting element of one or more embodiments of the present disclosure;

FIG. 7 is a cross-sectional view schematically showing a light emitting element of one or more embodiments of the present disclosure;

FIG. 8 is a view showing the energy levels of Comparative Example Compounds and Example Compounds according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure;

FIG. 11 is a cross-sectional view showing a display device according to one or more embodiments of the present disclosure;

FIG. 12 is a cross-sectional view showing a display device according to one or more embodiments of the present disclosure; and

FIG. 13 is a view showing an interior of a vehicle in which display devices of one or more embodiments of the present disclosure are disposed.

### DETAILED DESCRIPTION

Because the present disclosure may have diverse modified embodiments, specific/example embodiments are illustrated in the drawings and are described in the detailed description of the present disclosure. However, this does not limit the present disclosure to those specific/example embodiments and it should be understood that the present disclosure covers all the modifications, equivalents, and replacements within the idea and technical scope of the present disclosure.

In this disclosure, it will also be understood that when one component (or region, layer, portion) is referred to as being ‘on,’ ‘connected to,’ or ‘coupled to’ another component, it can be directly disposed/connected/coupled on/to the one component, or an intervening third component may also be present. In contrast, “directly on” may refer to that there are no additional layers, films, regions, plates, etc., between a layer, a film, a region, a plate, etc. and the other component. For example, “directly on” may refer to two layers or two members are disposed without utilizing an additional member such as an adhesive member therebetween

Like reference numerals refer to like elements throughout the present disclosure, and duplicative descriptions thereof may not be provided for conciseness. Also, in the drawings, the thickness, ratio, and dimensions of components may be exaggerated for clarity of illustration. The term “and/or” or “or” may include any and all combinations of one or more of the associated components. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

It will be understood that although the terms such as ‘first’ and ‘second’ are utilized herein to describe one or more suitable elements, these elements should not be limited by these terms. These terms are utilized only to distinguish one component from other components. For example, a first element referred to as a first element in an embodiment can be referred to as a second element in another embodiment without departing from the scope of the appended claims. The terms of a singular form may include plural forms unless referred to the contrary. For example, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

Also, “under,” “below,” “above,” “upper,” and/or the like are utilized for explaining relation association of the elements illustrated in the drawings. The terms may be a relative concept and described based on directions expressed in the drawings.

The meaning of ‘include(s)/including’ or ‘comprise(s)/comprising’ or ‘have(has)having’ specifies a property, a fixed number, a process, an operation, an element, a component, or a combination thereof, but does not exclude other properties, fixed numbers, processes, operations, elements, components, or combinations thereof.

Unless otherwise defined, all terms (including technical and scientific terms) utilized herein have the same meaning as commonly understood by a person of ordinary skill in the art to which the present disclosure belongs. In some embodiments, terms such as terms defined in commonly utilized dictionaries should be interpreted as having a meaning consistent with the meaning in the context of the related technology, and unless explicitly defined here, they are interpreted as too ideal or too formal sense.

In the present disclosure, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic or polycyclic. In some embodiments, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the present disclosure, examples of a halogen atom may include a fluorine atom, a chlorine atom, a bromine atom, or an iodine atom.

In the present disclosure, an alkyl group may be linear or branched. The number of carbon atoms in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present disclosure, a cycloalkyl group may refer to a cyclic alkyl group. The number of carbon atoms in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, etc., but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

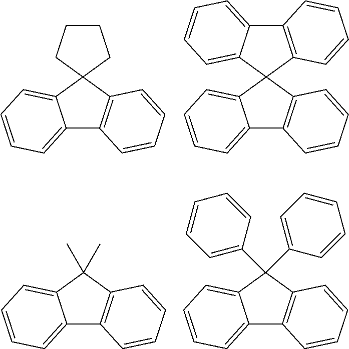

A heterocyclic group utilized herein may refer to any functional group or substituent derived from a ring containing at least one of B, O, N, P, Si, or S as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, a heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 60, 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the present disclosure, a heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present disclosure, the above description of the alkyl group may be applied to an alkylene group except that the alkylene group is a divalent group. The above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments of the present disclosure are not limited thereto.

In the present disclosure, the number of ring-forming carbon atoms in a carbonyl group is not specifically limited, but may be 1 to 40, 1 to 30, or 1 to 20. For example, the carbonyl group may have the following structures, but embodiments of the present disclosure are not limited thereto.

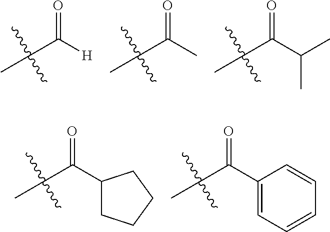

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 30, 1 to 20, or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

A boron group utilized herein may refer to that a boron atom is bonded to the alkyl group or the aryl group defined above. The boron group may include an alkyl boron group and/or an aryl boron group. Examples of the boron group may include a dimethylboron group, a trimethylboron group, a t-butyldimethylboron group, a diphenylboron group, a phenylboron group, etc., but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, etc., but embodiments of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, and an arylamine group may be the same as the examples of the aryl group described above.

In the present disclosure, a direct linkage may refer to a single bond. In the present disclosure

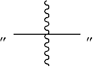

and “—*” refer to a position to be connected.

Hereinafter, embodiments of the present disclosure will be described in more detail with reference to the accompanying drawings.

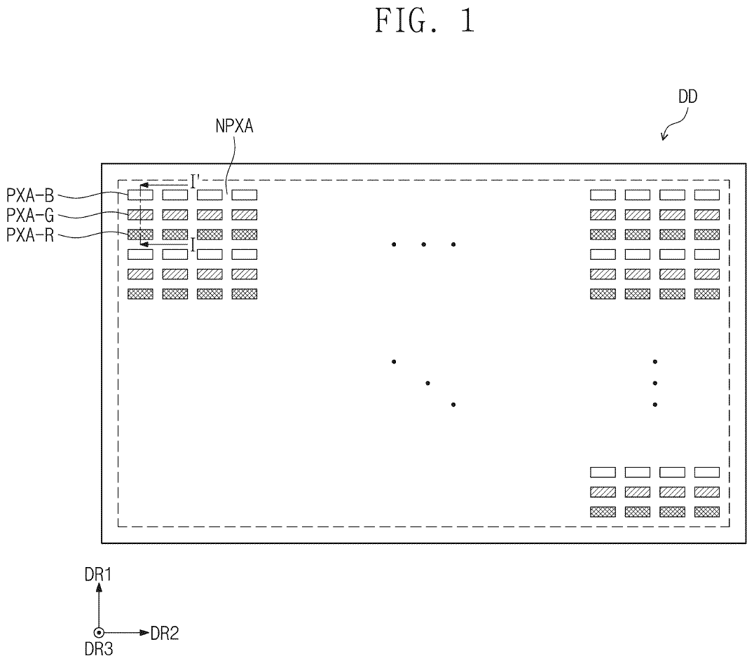

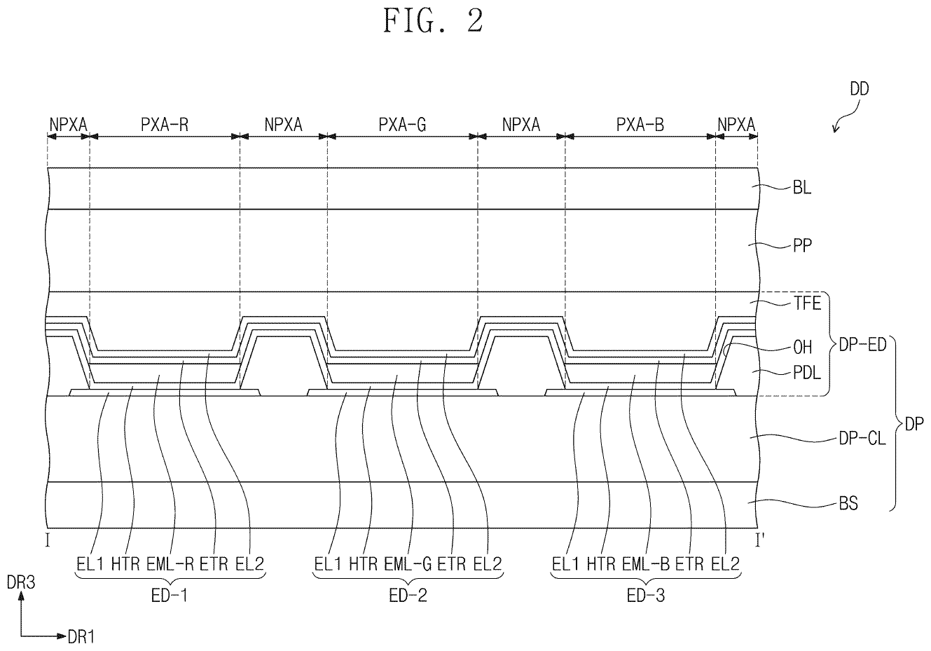

FIG. 1 is a plan view illustrating a display device DD according to one or more embodiments of the present disclosure. FIG. 2 is a cross-sectional view of the display device DD according to one or more embodiments. FIG. 2 is a cross-sectional view illustrating a part taken along line I-I′ of the display device DD of FIG. 1.

The display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP to control reflected light in the display panel DP due to external light. The optical layer PP may include, for example, a polarization layer and/or a color filter layer. In some embodiments, the optical layer PP may not be provided from the display device DD.

A base substrate BL may be disposed or provided on the optical layer PP. The base substrate BL may be a member which provides a base surface on which the optical layer PP disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

The display device DD according to one or more embodiments may further include a filling layer. The filling layer may be disposed between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 disposed between respective portions of the pixel defining film PDL, and an encapsulation layer TFE disposed on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. Each of the transistors may include a control electrode, an input electrode, and an output electrode. For example, in some embodiments, the circuit layer DP-CL may include switching transistor(s) and driving transistor(s) for driving the light emitting elements ED-1, ED-2, and ED-3 of the display element layer DP-ED.

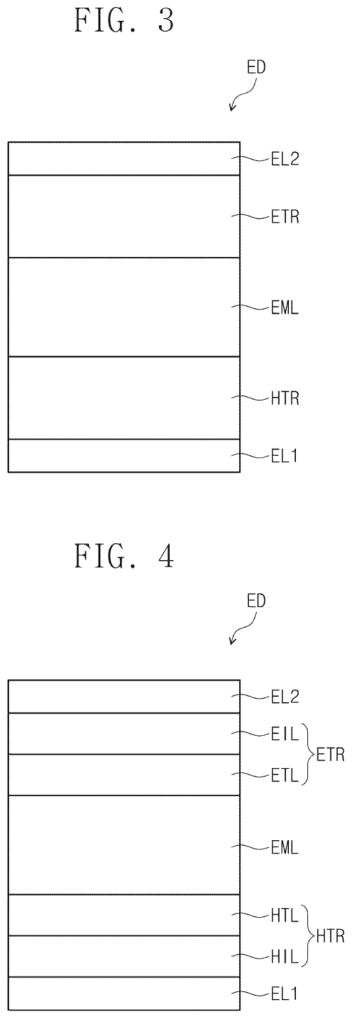

Each of the light emitting elements ED-1, ED-2, and ED-3 may have a structure of one of light emitting elements ED of embodiments according to FIGS. 3 to 7, which will be described later. Each of the light emitting elements ED-1, ED-2, and ED-3 may include a first electrode EL1, a hole transport region HTR, respective light emitting layers EML-R, EML-G, and EML-B, an electron transport region ETR, and a second electrode EL2.

FIG. 2 illustrates an embodiment in which the respective light emitting layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are provided as a common layer in the entire light emitting elements ED-1, ED-2, and ED-3. However, embodiments of the present disclosure are not limited thereto, for example, in one or more embodiments, the hole transport region HTR and the electron transport region ETR may be provided by being patterned inside the openings OH defined in the pixel defining film PDL. For example, in some embodiments, the hole transport region HTR, the respective light emitting layers EML-R, EML-G, and EML-B, and the electron transport region ETR of the light emitting elements ED-1, ED-2, and ED-3 may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers.

The encapsulation layer TFE may include at least one insulation layer. In some embodiments, the encapsulation layer TFE may include at least one inorganic film (hereinafter, an encapsulation-inorganic film). In some embodiments, the encapsulation layer TFE may include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. In some embodiments, the encapsulation-organic film may include an acrylic-based compound, an epoxy-based compound, and/or the like. In some embodiments, the encapsulation-organic film may include a photopolymerizable organic material, but embodiments of the present disclosure are not particularly limited thereto.

The encapsulation layer TFE may be disposed on the second electrode EL2 and may be disposed filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced) from each other on a plane (e.g., in a plan view).

Each of the light emitting regions PXA-R, PXA-G, and PXA-B may be a region divided by the pixel defining film PDL. The non-light emitting areas NPXA may be areas between adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The respective light emitting layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIG. 1 and FIG. 2, three light emitting regions PXA-R, PXA-G, and PXA-B, which emit red light, green light, and blue light, respectively, are exemplarily illustrated. For example, the display device DD of one or more embodiments may include a red light emitting region PXA-R, a green light emitting region PXA-G, a blue light emitting region PXA-B that are separated from each other.

In the display device DD according to one or more embodiments, the plurality of light emitting elements ED-1, ED-2, and ED-3 may be to emit light beams having wavelengths different from each other. For example, in some embodiments, the display device DD may include a first light emitting element ED-1 that emits red light, a second light emitting element ED-2 that emits green light, and a third light emitting element ED-3 that emits blue light. For example, in some embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range or at least one light emitting element may be to emit a light beam in a wavelength range different from the others. For example, in some embodiments, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In some embodiments, the red light emitting region PXA-R, the green light emitting region PXA-G, and the blue light emitting region PXA-B may be alternately arranged in the stated order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. The areas of the light emitting regions PXA-R, PXA-G, and PXA-B may refer to areas when viewed on a plane defined by the first direction axis DR1 and the second direction axis DR2 (e.g., the areas in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a pentile (PENTILE®) arrangement form (for example, an RGBG matrix, an RGBG structure, or an RGBG matrix structure), or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIG. 3 to FIG. 7 are each a cross-sectional view schematically showing a light emitting element according to one or more embodiments of the present disclosure. The light emitting element ED according to one or more embodiments may include a first electrode EL1, a hole transport region HTR, a light emitting layer EML, an electron transport region ETR, and a second electrode EL2 which are sequentially stacked in the stated order.

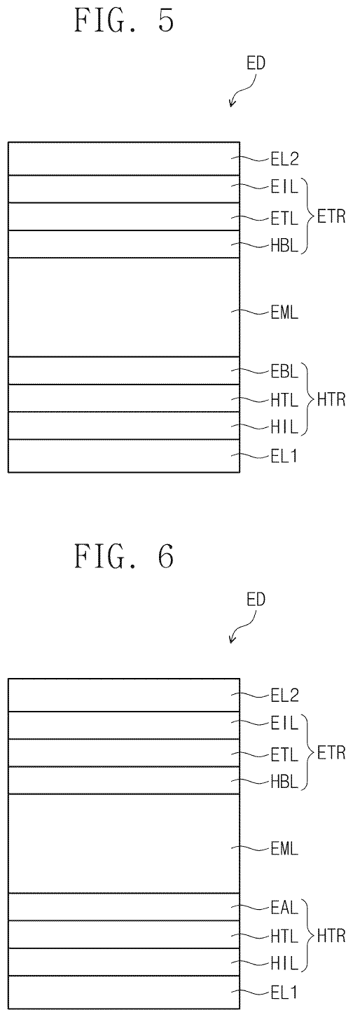

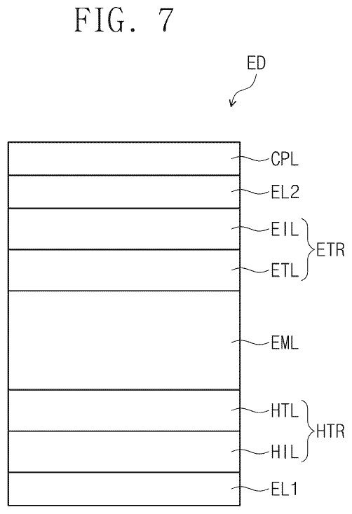

Compared to FIG. 3, FIG. 4 shows a cross-sectional view of a light emitting element ED of one or more embodiments in which the hole transport region HTR includes a hole injection layer HIL and a hole transport layer HTL, and the electron transport region ETR includes an electron injection layer EIL and an electron transport layer ETL. Compared to FIG. 3, FIG. 5 shows a cross-sectional view of a light emitting element ED of one or more embodiments in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. Compared to FIG. 3, FIG. 6 shows a cross-sectional view of a light emitting element ED of one or more embodiments in which the hole transport region HTR includes a hole injection layer HIL, a hole transport layer HTL, and a light emitting auxiliary layer EAL, and the electron transport region ETR includes an electron injection layer EIL, an electron transport layer ETL, and a hole blocking layer HBL. Compared to FIG. 4, FIG. 7 shows a cross-sectional view of a light emitting element ED of one or more embodiments including a capping layer CPL disposed on the second electrode EL2.

The first electrode EL1 has conductivity (e.g., is a conductor or electron conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), any compound being of two or more selected therefrom, any mixture being of two or more selected therefrom, and/or any oxide thereof.

When the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, any compound thereof, or any mixture thereof (e.g., a mixture of Ag and Mg). In some embodiments, the first electrode EL1 may have a multilayer structure including a reflective film or a transflective film formed of one or more of the above-described materials, and a transparent conductive film formed of ITO, IZO, ZnO, ITZO, etc. For example, in some embodiments, the first electrode EL1 may have a three-layer structure of ITO/Ag/ITO, but embodiments of the present disclosure are not limited thereto. The first electrode EL1 may include one of the above-described metal materials, one or more combinations of at least two metal materials of the above-described metal materials, any oxide of the above-described metal materials, and/or the like. A thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a light emitting auxiliary layer EAL, or an electron blocking layer EBL. The light emitting auxiliary layer EAL may be referred to as a buffer layer. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/light emitting auxiliary layer EAL, a hole injection layer HIL/light emitting auxiliary layer EAL, a hole transport layer HTL/light emitting auxiliary layer EAL, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

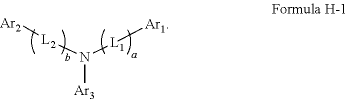

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In one or more embodiments, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ includes an amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

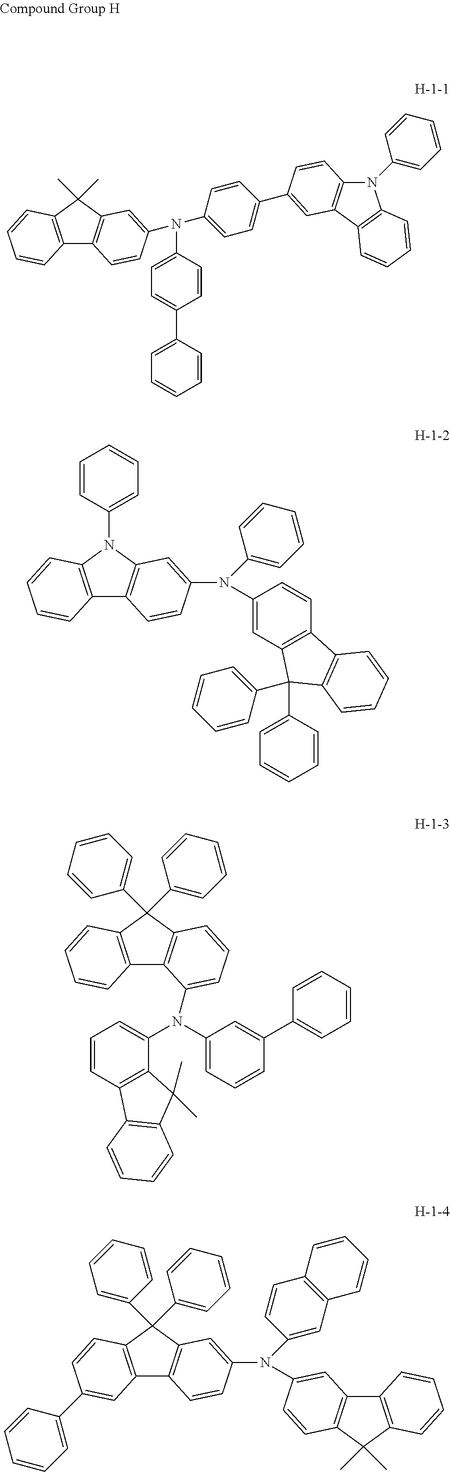 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

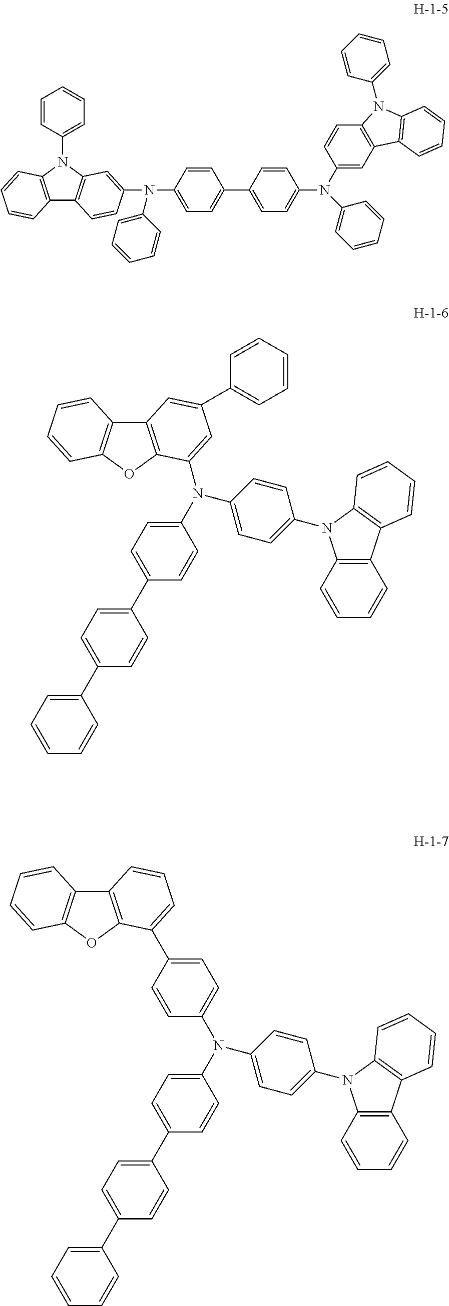 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

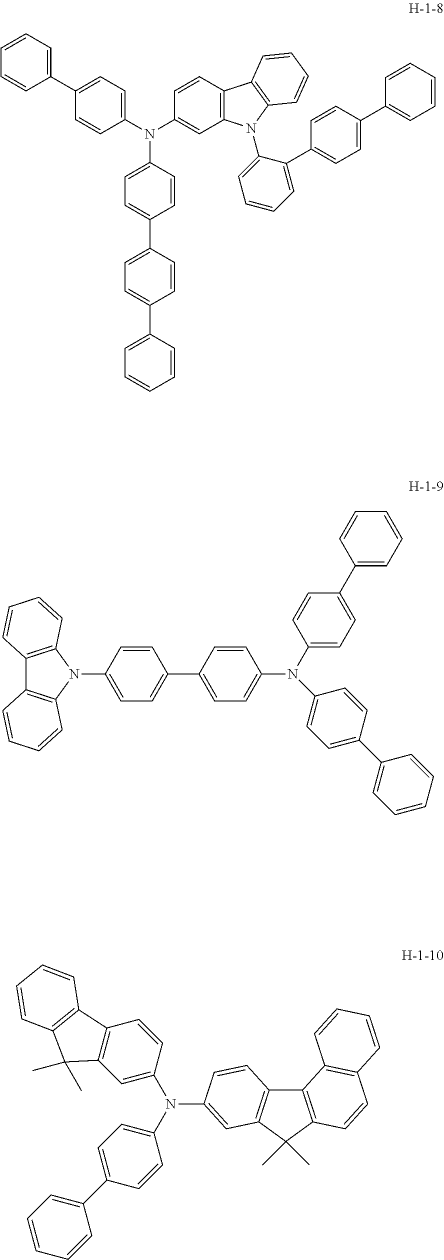 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

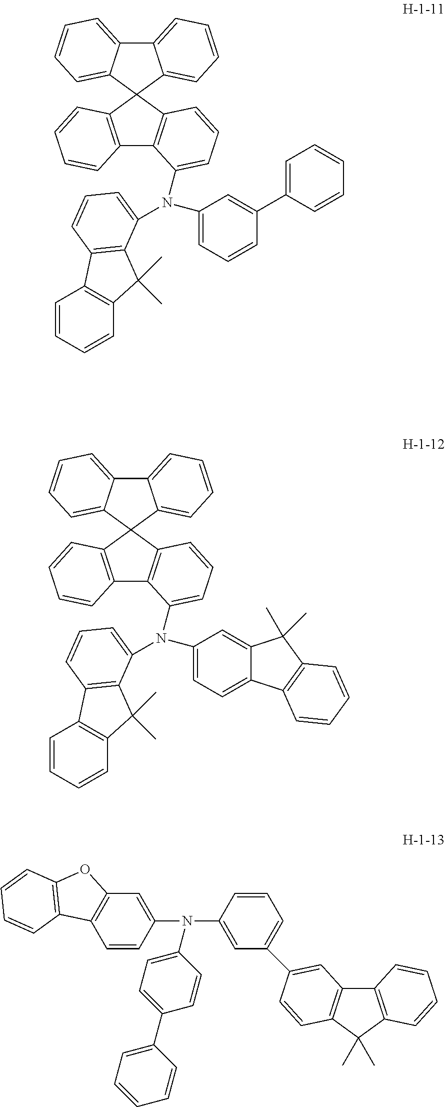 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

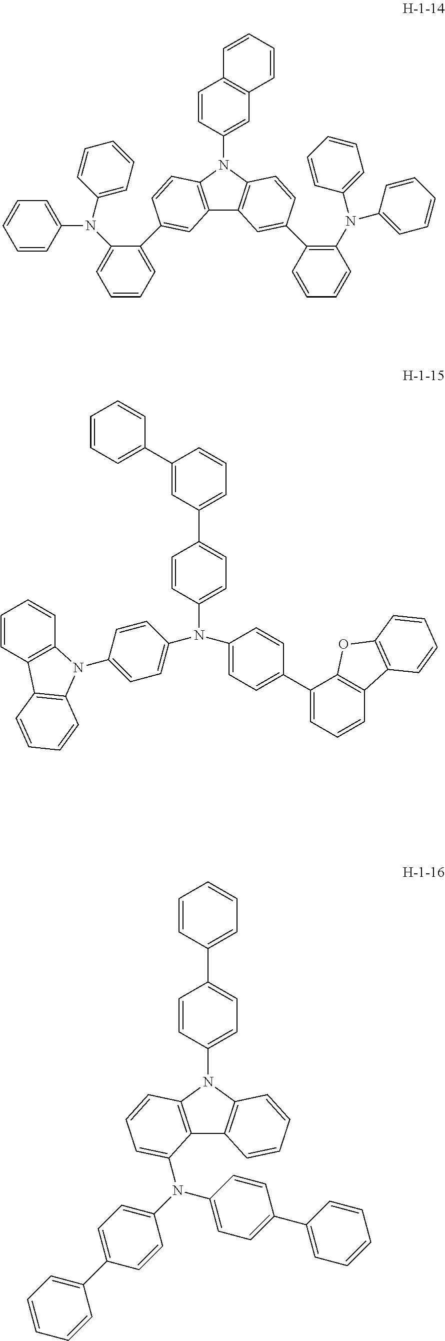 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

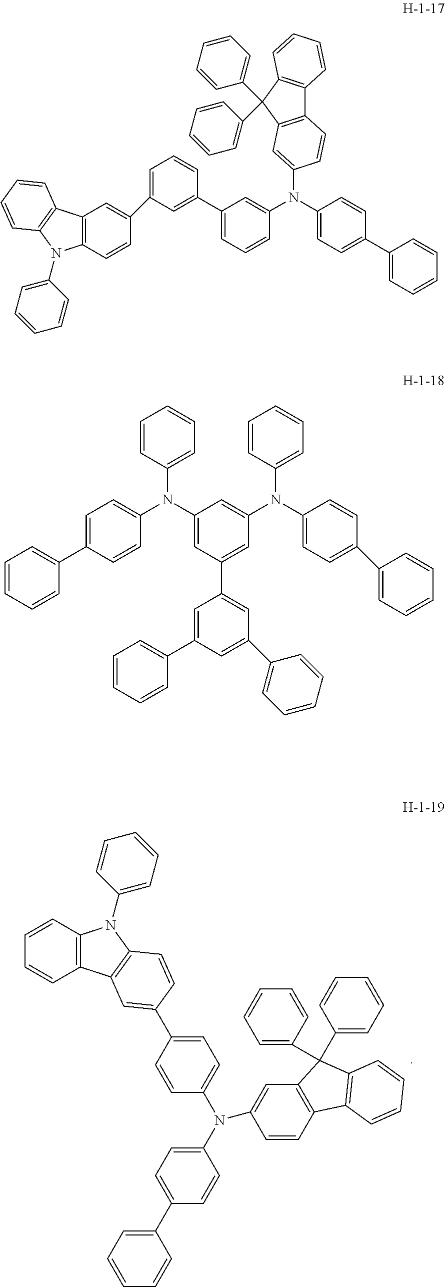 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In some embodiments, the hole transport region HTR may include at least one selected from a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methyl phenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

In one or more embodiments, the hole transport region HTR may include at least one selected from a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include at least one selected from 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include one or more of the above-described compounds of the hole transport region in at least one of a hole injection layer HIL, a hole transport layer HTL, a light emitting auxiliary layer EAL, or an electron blocking layer EBL.

A thickness of the hole transport region HTR may be from about 100 angstrom (Å) to about 10,000 Å, for example, from about 100 Å to about 5,000 Å. When the hole transport region HTR includes a hole injection layer HIL, the hole injection layer HIL may have, for example, a thickness of about 30 Å to about 1,000 Å. When the hole transport region HTR includes a hole transport layer HTL, the hole transport layer HTL may have a thickness of about 250 Å to about 1,000 Å. For example, when the hole transport region HTR includes an electron blocking layer EBL, the electron blocking layer EBL may have a thickness of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

In one or more embodiments, the hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in some embodiments, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F₄-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the light emitting auxiliary layer EAL and the electron blocking layer EBL, in addition to the hole injection layer HIL and the hole transport layer HTL. The light emitting auxiliary layer EAL may increase light emission efficiency by compensating for a resonance distance according to the wavelength of light emitted from the light emitting layer EML, and controlling hole charge balance. In some embodiments, the light emitting auxiliary layer EAL may also serve to prevent or reduce electron injection into the hole transport region HTR. As for materials included in the light emitting auxiliary layer EAL, materials which may be included in the hole transport region HTR may be utilized. The electron blocking layer EBL is a layer serving to prevent or reduce electron injection from the electron transport region ETR to the hole transport region HTR.

In one or more embodiments, the light emitting layer EML may include a first compound of one or more embodiments of the present disclosure. In one or more embodiments, the light emitting layer EML may further include at least one selected from among second to fourth compounds. The second compound may include a three-ring fused ring containing a nitrogen atom as a ring-forming atom. The third compound may include a hexagonal (e.g., 6-membered) ring group containing at least one nitrogen atom as a ring-forming atom. The fourth compound may include an organometallic complex. The second to fourth compounds will be discussed in more detail later.

In the present disclosure, the first compound may be referred to as a fused polycyclic compound of one or more embodiments. The fused polycyclic compound of one or more embodiments may include, as a central structure (e.g., a core structure), a 5-ring fused ring system containing two nitrogen atoms and one boron atom as ring-forming atoms. In one or more embodiments, the fused polycyclic compound of one or more embodiments may include a phenanthrene moiety and a carbazole moiety bonded directly or indirectly to the central structure. The fused polycyclic compound of one or more embodiments including the phenanthrene moiety may have energy levels of the higher-order triplet state (Tn state) that are close to each other, so that Reverse Inter System Crossing (RISC) may be accelerated. In one or more embodiments, the fused polycyclic compound of one or more embodiments including the carbazole moiety facilitates the matching of a host material and a Highest Occupied Molecular Orbital (HOMO) energy level of the fused polycyclic compound, which may contribute to improving the efficiency and lifespan of the light emitting element ED. In one or more embodiments, the light emitting element ED including a fused polycyclic compound of the present disclosure may exhibit low-driving voltage, high-efficiency, and long-lifespan properties.

The light emitting element ED of one or more embodiments may include the fused polycyclic compound of one or more embodiments. The fused polycyclic compound of one or more embodiments may be represented by Formula 1.

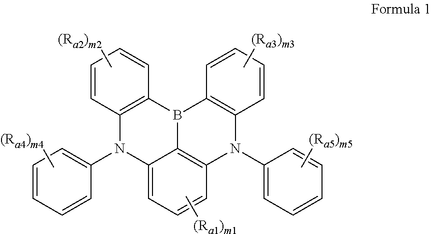

In Formula 1, m1 may be an integer of 0 to 3. m2 and m3 may each independently be an integer of 0 to 4, and m4 and m5 may each independently be an integer of 0 to 5.

When m1 is an integer of 2 or greater, a plurality of Rₐ₁'s may all be the same or at least one thereof may be different from the rest thereof. When m1 is 0, it may be the same as when m1 is 3 and three Rₐ₁'s are each hydrogen atom. When m2 is an integer of 2 or greater, a plurality of Rₐ₂'s may all be the same or at least one thereof may be different from the rest thereof. When m2 is 0, it may be the same as when m2 is 4 and four Rₐ₂'s are each hydrogen atom. When m3 is an integer of 2 or greater, a plurality of Rₐ₃'s may all be the same or at least one thereof may be different from the rest thereof. When m3 is 0, it may be the same as when m3 is 4 and four Rₐ₃'s are each hydrogen atom.

When m4 is an integer of 2 or greater, a plurality of Rₐ₄'s may all be the same or at least one thereof may be different from the rest thereof. When m4 is 0, it may be the same as when m4 is 5 and five Rₐ₄'s are each hydrogen atom. When m5 is an integer of 2 or greater, a plurality of R^{a5}'s may all be the same or at least one thereof may be different from the rest thereof. When m5 is 0, it may be the same as when m5 is 5 and five R^{a5}'s are each hydrogen atom.

In Formula 1, at least one selected from among Rₐ₁ to R^{a5} may be a group represented by Formula 2. In Formula 1, at least one selected from among Rₐ₁ to R^{a5} may include a substituted or unsubstituted first carbazole. For example, in one or more embodiments, any one selected from among Rₐ₁ to R^{a5} may be a group represented by Formula 2, and may include the substituted or unsubstituted first carbazole. For example, in some embodiments, in Rₐ₁ to R^{a5}, a group represented by Formula 2 and a group including the substituted or unsubstituted first carbazole may be the same as each other. In contrast, in some embodiments, any one selected from among Rₐ₁ to R^{a5} may be a group represented by Formula 2, and at least one selected from among the rest of Rₐ₁ to R^{a5} not represented by Formula 2 may include the substituted or unsubstituted first carbazole. For example, in Rₐ₁ to R^{a5}, a group represented by Formula 2 and a group including the substituted or unsubstituted first carbazole may be different from each other.

The rest of Rₐ₁ to Ra₅ not represented by Formula 2 may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, when m5 is an integer of 2 or greater, two or more R^{a5}'s selected from among a plurality of R^{a5}'s may each independently be represented by Formula 2. The same descriptions as those of m5 and R^{a5} may be applied to m1 to m4, and Rₐ₁ to Rₐ₄.

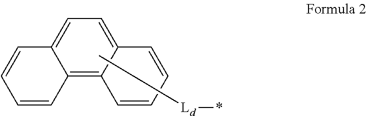

In Formula 2, L_{d} may be a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 30 ring-forming carbon atoms. For example, in one or more embodiments, L_{d} may be a direct linkage, a substituted or unsubstituted phenylene group, or a substituted or unsubstituted divalent carbazole group.

When L_{d} does not include the first carbazole, at least one selected from among Rₐ₁ to R^{a5} not represented by Formula 2 may include a first carbazole substituted with a substituent other than a phenanthryl group, or Rₐ₂ and R^{a3} may each independently include a first carbazole not substituted or a first carbazole group substituted with a substituent other than a phenanthryl group.

The fused polycyclic compound of one or more embodiments represented by Formula 1 may satisfy any one selected from among cases A1 to A3. Case A1 is defined that in Formula 2, L_{d} includes a substituted or unsubstituted divalent first carbazole. Case A2 is defined that in Formula 2, when L_{d} does not include a substituted or unsubstituted first carbazole, at least one selected from among the rest of Rₐ₁ to R^{a5} not represented by Formula 2 includes a first carbazole substituted with a substituent other than a phenanthryl group. Case A3 is defined that in Formula 2, when L_{d} does not include a substituted or unsubstituted first carbazole, Rₐ₂ and Rₐ₃ each independently include a first carbazole not substituted, or include a first carbazole substituted with a substituent other than a phenanthryl group. For example, in one or more embodiments, in Formulas 1 and 2, L_{d} and at least one selected from among Rai to R^{a5} may include a carbazole group (or a divalent carbazole group).

In one or more embodiments, in Formulas 1 and 2, L_{d} and at least one selected from among Rₐ₁ to R^{a5} may be a substituted or unsubstituted carbazole group (or a divalent carbazole group), or may include a carbazole group as a substituent. In Formula 1, at least one selected from among Rₐ₁ to R^{a5} may be a phenanthryl group not substituted, or may be a group including a phenanthryl group as a substituent. When L_{d} of Formula 2 is a divalent carbazole group, the fused polycyclic compound of one or more embodiments may include a carbazole group substituted with a phenanthryl group. When L_{d} of Formula 2 is not a divalent carbazole group, the fused polycyclic compound of one or more embodiments may include a carbazole group substituted with a substituent other than a phenanthryl group and a phenanthryl group not substituted. In some embodiments, when L_{d} of Formula 2 is not a divalent carbazole group, the fused polycyclic compound of one or more embodiments may include a carbazole group not substituted and a phenanthryl group not substituted.

The fused polycyclic compound of one or more embodiments includes, as a central structure (e.g., a core structure), a 5-ring fused ring system containing two nitrogen atoms and one boron atom as ring-forming atoms, and a phenanthrene moiety and a carbazole moiety may be bonded directly or indirectly to the central structure. The fused polycyclic compound of one or more embodiments may include at least one carbazole moiety and at least one phenanthryl moiety. For example, in some embodiments, the fused polycyclic compound of one or more embodiments may include a carbazole group substituted with a phenanthryl group, and the carbazole group substituted with a phenanthryl group may be directly bonded to the central structure. In some embodiments, the fused polycyclic compound of one or more embodiments may include a phenanthryl group and a carbazole group not substituted with a phenanthryl group. The carbazole group not substituted with a phenanthryl group may be one substituted with a substituent other than the phenanthryl group or one not substituted. Each of the phenanthryl group and the carbazole group not substituted with a phenanthryl group may be directly or indirectly bonded to the central structure.

The group represented by Formula 2 may be represented by any one selected from among Formula 2-1 to Formula 2-31. In Formula 2-11 to Formula 2-17 and Formula 2-26 to Formula 2-31, D is a deuterium atom.

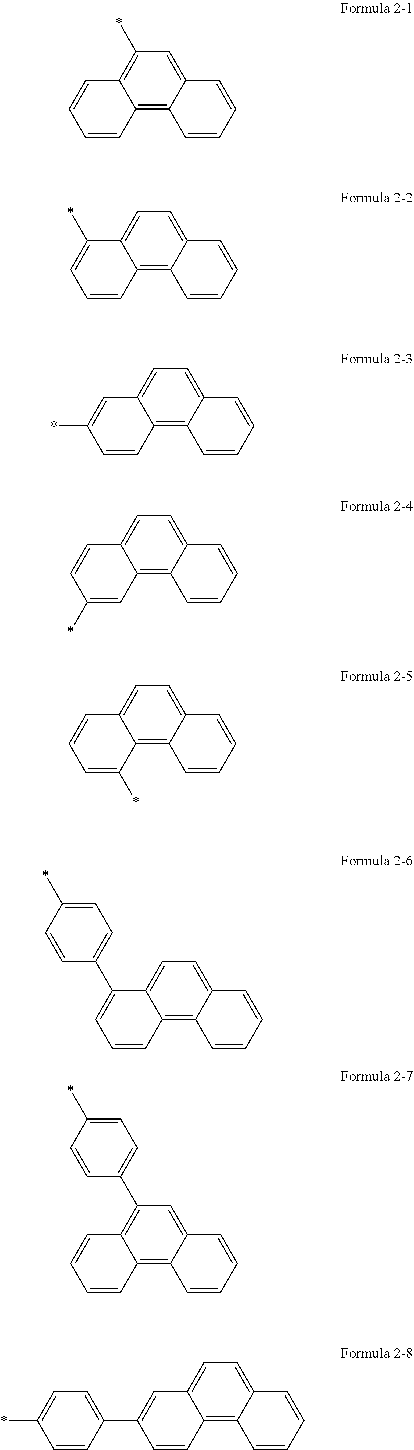

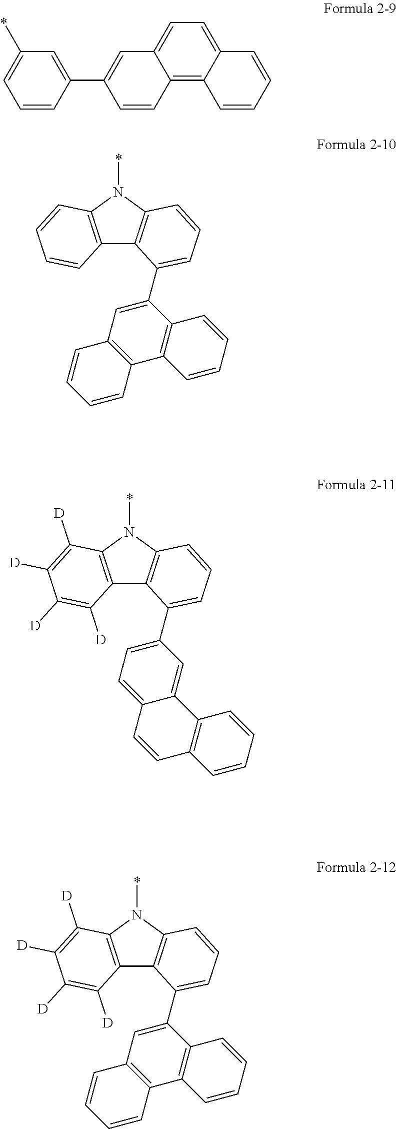 [SMILES: *c1cccc(-c2ccc3c(ccc4ccccc43)c2)c1 ; *n1c2ccccc2c2c(-c3cc4ccccc4c4ccccc34)cccc21 ; *n1c2cccc(-c3ccc4ccc5ccccc5c4c3)c2c2c([2H])c([2H])c([2H])c([2H])c21 ; *n1c2cccc(-c3cc4ccccc4c4ccccc34)c2c2c([2H])c([2H])c([2H])c([2H])c21]

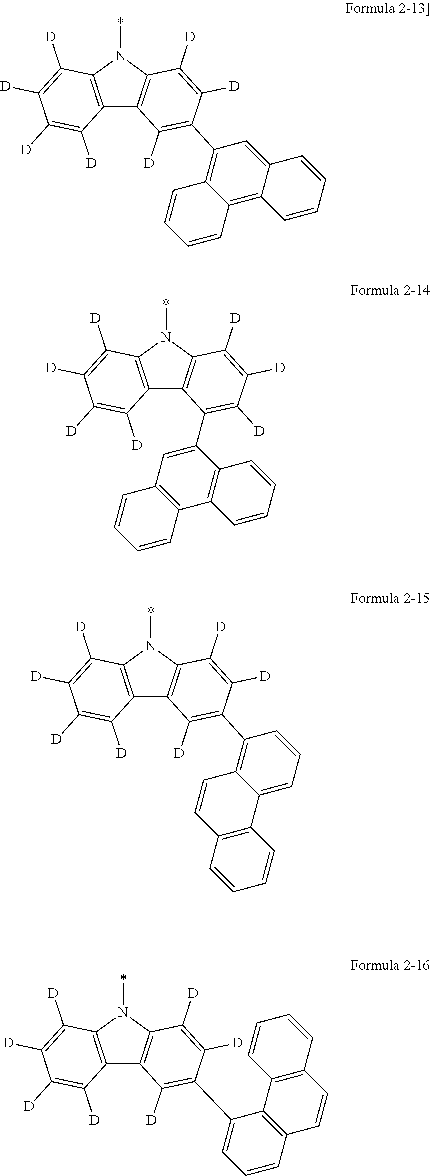 [SMILES: *n1c2c([2H])c([2H])c([2H])c([2H])c2c2c([2H])c(-c3cc4ccccc4c4ccccc34)c([2H])c([2H])c21 ; *n1c2c([2H])c([2H])c([2H])c([2H])c2c2c(-c3cc4ccccc4c4ccccc34)c([2H])c([2H])c([2H])c21 ; *n1c2c([2H])c([2H])c([2H])c([2H])c2c2c([2H])c(-c3cccc4c3ccc3ccccc34)c([2H])c([2H])c21 ; *n1c2c([2H])c([2H])c([2H])c([2H])c2c2c([2H])c(-c3cccc4ccc5ccccc5c34)c([2H])c([2H])c21]

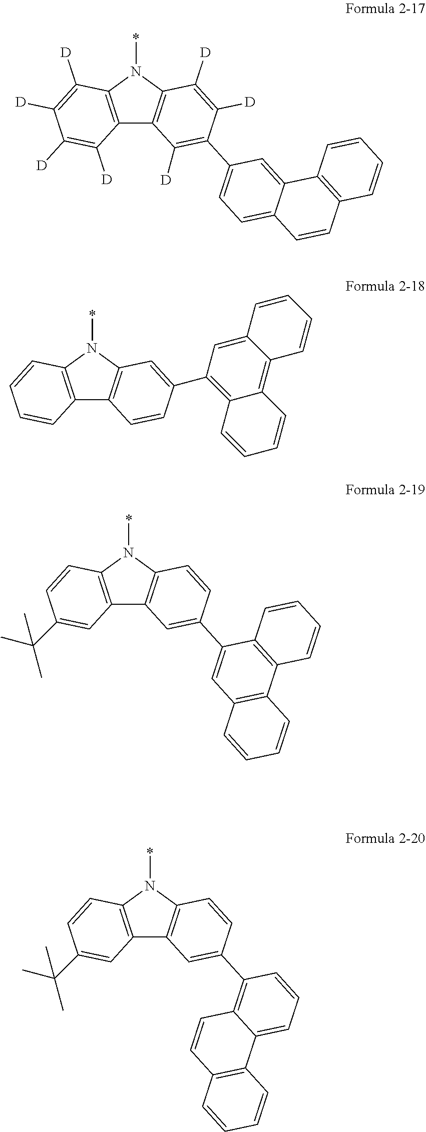 [SMILES: *n1c2c([2H])c([2H])c([2H])c([2H])c2c2c([2H])c(-c3ccc4ccc5ccccc5c4c3)c([2H])c([2H])c21 ; *n1c2ccccc2c2ccc(-c3cc4ccccc4c4ccccc34)cc21 ; *n1c2ccc(-c3cc4ccccc4c4ccccc34)cc2c2cc(C(C)(C)C)ccc21 ; *n1c2ccc(-c3cccc4c3ccc3ccccc34)cc2c2cc(C(C)(C)C)ccc21]

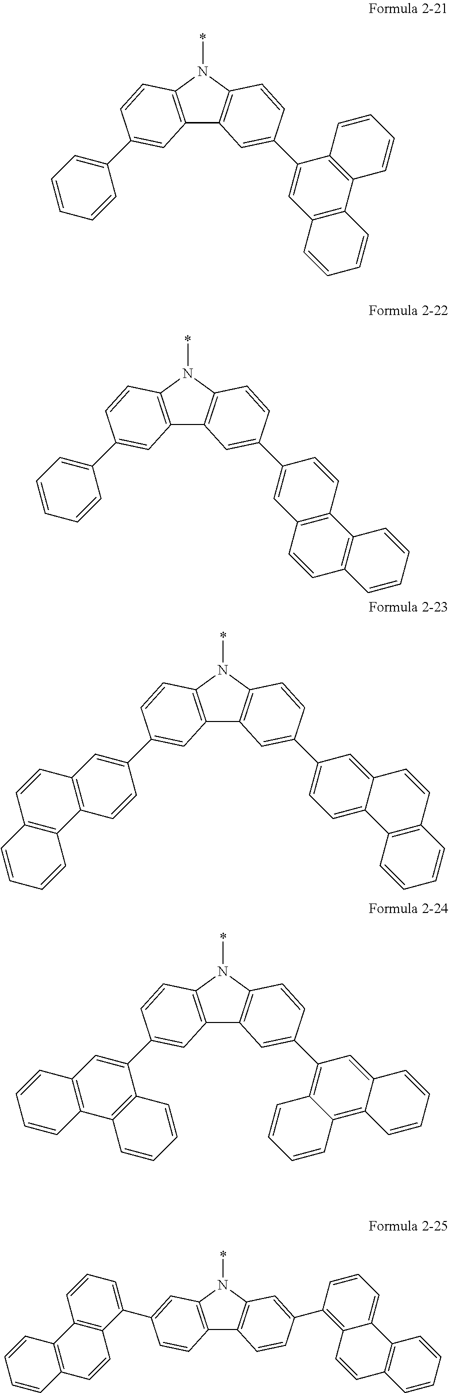 [SMILES: *n1c2ccc(-c3ccccc3)cc2c2cc(-c3cc4ccccc4c4ccccc34)ccc21 ; *n1c2ccc(-c3ccccc3)cc2c2cc(-c3ccc4c(ccc5ccccc54)c3)ccc21 ; *n1c2ccc(-c3ccc4c(ccc5ccccc54)c3)cc2c2cc(-c3ccc4c(ccc5ccccc54)c3)ccc21 ; *n1c2ccc(-c3cc4ccccc4c4ccccc34)cc2c2cc(-c3cc4ccccc4c4ccccc34)ccc21 ; *n1c2cc(-c3cccc4c3ccc3ccccc34)ccc2c2ccc(-c3cccc4c3ccc3ccccc34)cc21]

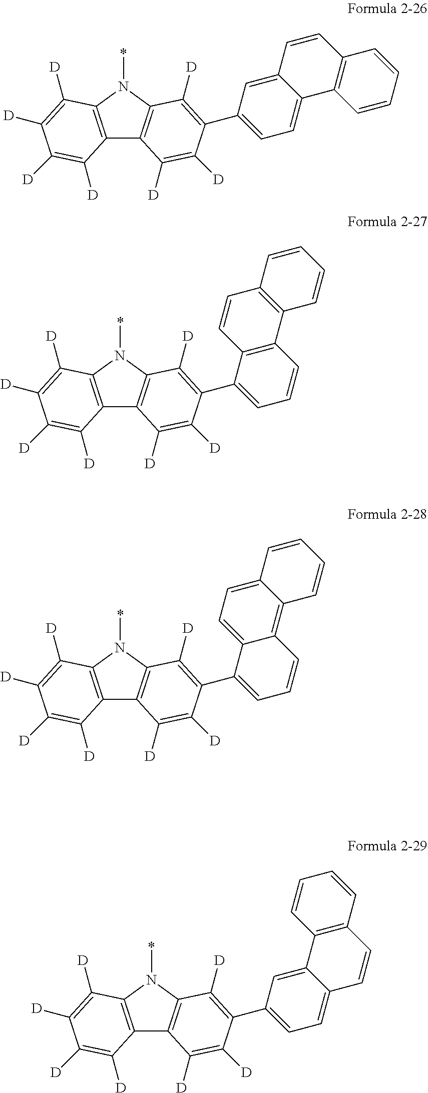 [SMILES: *n1c2c([2H])c([2H])c([2H])c([2H])c2c2c([2H])c([2H])c(-c3ccc4c(ccc5ccccc54)c3)c([2H])c21 ; *n1c2c([2H])c([2H])c([2H])c([2H])c2c2c([2H])c([2H])c(-c3cccc4c3ccc3ccccc34)c([2H])c21 ; *n1c2c([2H])c([2H])c([2H])c([2H])c2c2c([2H])c([2H])c(-c3cccc4c3ccc3ccccc34)c([2H])c21 ; *n1c2c([2H])c([2H])c([2H])c([2H])c2c2c([2H])c([2H])c(-c3ccc4ccc5ccccc5c4c3)c([2H])c21]

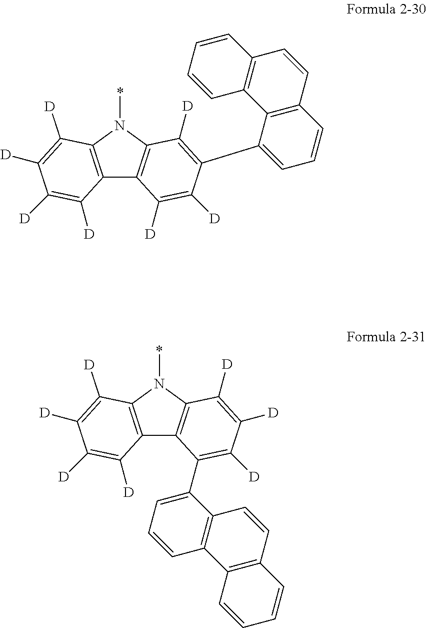 [SMILES: *n1c2c([2H])c([2H])c([2H])c([2H])c2c2c([2H])c([2H])c(-c3cccc4ccc5ccccc5c34)c([2H])c21 ; *n1c2c([2H])c([2H])c([2H])c([2H])c2c2c(-c3cccc4c3ccc3ccccc34)c([2H])c([2H])c([2H])c21]

In one or more embodiments, the fused polycyclic compound represented by Formula 1 may be represented by any one selected from among Formula 1-1 to Formula 1-3. Formula 1-1 may represent a case (e.g., embodiments) in which m1 is 1 in Formula 1 and Rₐ₁ is a group represented by Formula 2. Formula 1-2 may represent a case (e.g., embodiments) in which m4 is an integer of 1 or greater in Formula 1, and Rₐ₄ is a group represented by Formula 2. Formula 1-3 may represent a case (e.g., embodiments) in which m2 is 1 in Formula 1, and Rₐ₂ is a group represented by Formula 2.

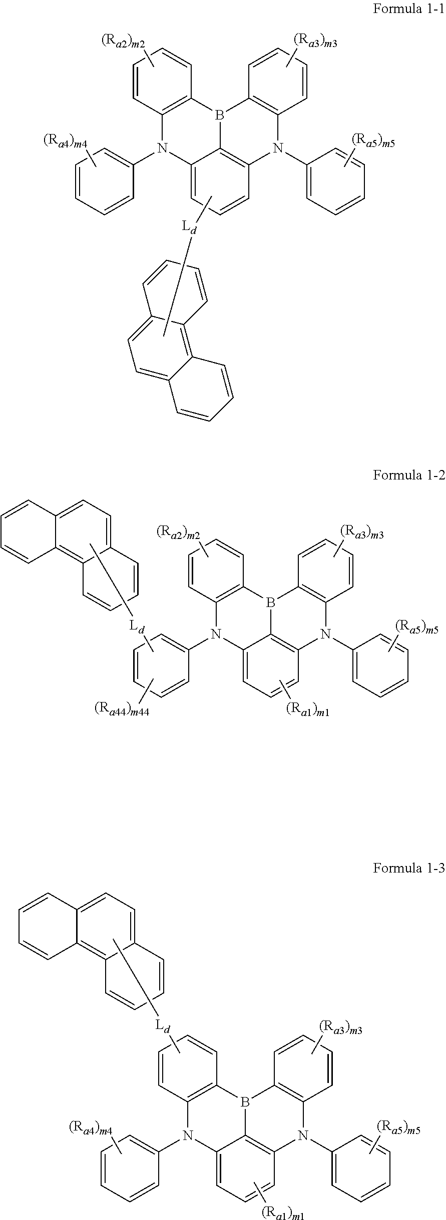

In Formula 1-1 to Formula 1-3, the same contents as those described with reference to Formula 1 and Formula 2 may be applied to m1 to m5, Rₐ₁ to R^{a5}, and L_{d}.

In Formula 1-2, m44 may be an integer of 0 to 4. When m44 is an integer of 2 or greater, a plurality of Rₐ₄₄'s may all be the same or at least one thereof may be different from the rest thereof. When m44 is 0, it may be the same as when m44 is 4 and four Rₐ₄₄'s are each hydrogen atom. Rₐ₄₄ may be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Rₐ₄₄ may be a hydrogen atom, a substituted or unsubstituted phenyl group, or a substituted or unsubstituted phenanthryl group.

In one or more embodiments, the fused polycyclic compound represented by Formula 1-1 may be represented by Formula 1-1A. Formula 1-1A may represent a case (e.g., embodiments) in which L_{d} is a substituted or unsubstituted divalent carbazole group in Formula 1-1.

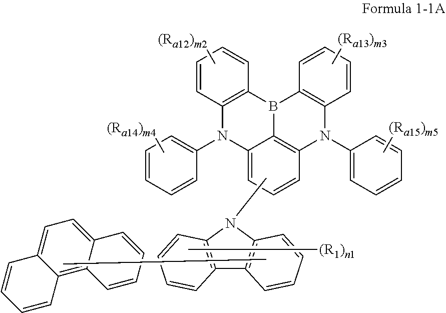

In Formula 1-1A, the same contents as those described with reference to Formula 1-1 may be applied to m2 to m5. n1 may be an integer of 0 to 7. When n1 is an integer of 2 or greater, a plurality of R₁'s may all be the same or at least one thereof may be different from the rest thereof. When n1 is 0, it may be the same as when n1 is 7 and seven R₁'s are each hydrogen atom. R₁ and Rₐ₁₂ to Rₐ₁₅ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

For example, in one or more embodiments, the fused polycyclic compound represented by Formula 1-1A may be represented by Formula 1-1AA. Formula 1-1AA may specify and show the bonding position of the divalent carbazole group in Formula 1-1A.

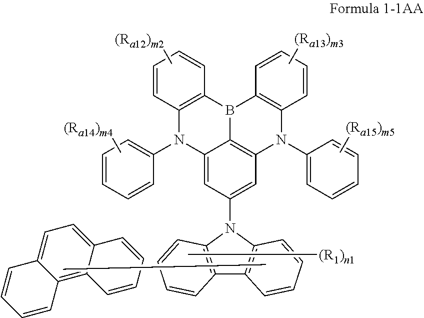

In Formula 1-1AA, the same contents as those described with reference to Formula 1-1A may be applied to m2 to m5, n1, R₁, and Rₐ₁₂ to Rₐ₁₅.

In one or more embodiments, the fused polycyclic compound represented by Formula 1-2 may be represented by Formula 1-2A. Formula 1-2A may represent a case (e.g., embodiments) in which L_{d} is a direct linkage or an arylene group in Formula 1-2. In some embodiments, Formula 1-2A may represent a case (e.g., embodiments) in which in Formula 2, L_{d} is not a substituted or unsubstituted divalent carbazole group, and at least one selected from among the rest of Rₐ₁ to R^{a5} of Formula 1 not represented by Formula 2 is a substituted carbazole group, or Rₐ₂ and Rₐ₃ may each independently be a substituted or unsubstituted carbazole group.

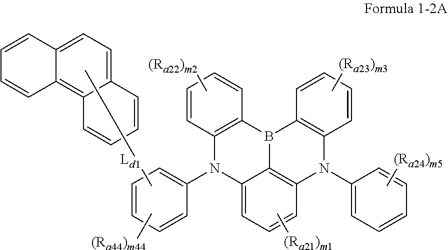

In Formula 1-2A, the same contents as those described with reference to Formula 1-2 may be applied to m1 to m3, m5, m44, and Rₐ₄₄.

In Formula 1-2A, L_{d1} may be a direct linkage or a substituted or unsubstituted arylene group having 6 to 30 ring-forming carbon atoms. In Formula 1-2A, Rₐ₂₁ to Rₐ₂₄ may be defined as Case B1 or Case B2. Rₐ₂₁ to Rₐ₂₄ may satisfy Case B1, or may satisfy Case B2. Case B1 may correspond to Case A2 described with reference to Formula 1. Case B2 may correspond to Case A3 described with reference to Formula 1.

Case B1 may be defined that at least one selected from among Rₐ₂₁ to Rₐ₂₄ is a first carbazole substituted with a substituent other than a phenanthryl group, and the rest thereof may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, when it is Case B1, Rₐ₂₂ and Rₐ₂₃ may each independently be a first carbazole substituted with a substituent other than a phenanthryl group, Rₐ₂₁ may be a substituted or unsubstituted t-butyl group, a substituted or unsubstituted phenyl group, a substituted or unsubstituted carbazole group, a substituted or unsubstituted dibenzofuran group, or a substituted or unsubstituted dibenzothiophene group, and Rₐ₂₄ may be a hydrogen atom, a substituted or unsubstituted t-butyl group, a substituted or unsubstituted phenyl group, a substituted or unsubstituted biphenyl group, or a substituted or unsubstituted phenanthryl group.

Case B2 may be defined that Rₐ₂₂ and Rₐ₂₃ may each independently be a first carbazole not substituted or a first carbazole substituted with a substituent other than a phenanthryl group, and Rₐ₂₁ and Rₐ₂₄ may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, when it is Case B2, Rₐ₂₂ and Rₐ₂₃ may be first carbazoles not substituted, and Rₐ₂₁ and Rₐ₂₄ may each independently be a substituted or unsubstituted t-butyl group or a substituted or unsubstituted phenyl group.

For example, in one or more embodiments, the fused polycyclic compound represented by Formulas 1-2A may be represented by any one selected from among Formula 1-2AA to Formula 1-2AD. Formula 1-2AA and Formula 1-2AB may represent a case (e.g., embodiments) in which L_{d1} is a direct linkage in Formula 1-2A. Formula 1-2AC and Formula 1-2AD may represent a case (e.g., embodiments) in which L_{d1} is a substituted or unsubstituted phenylene group in Formula 1-2A.

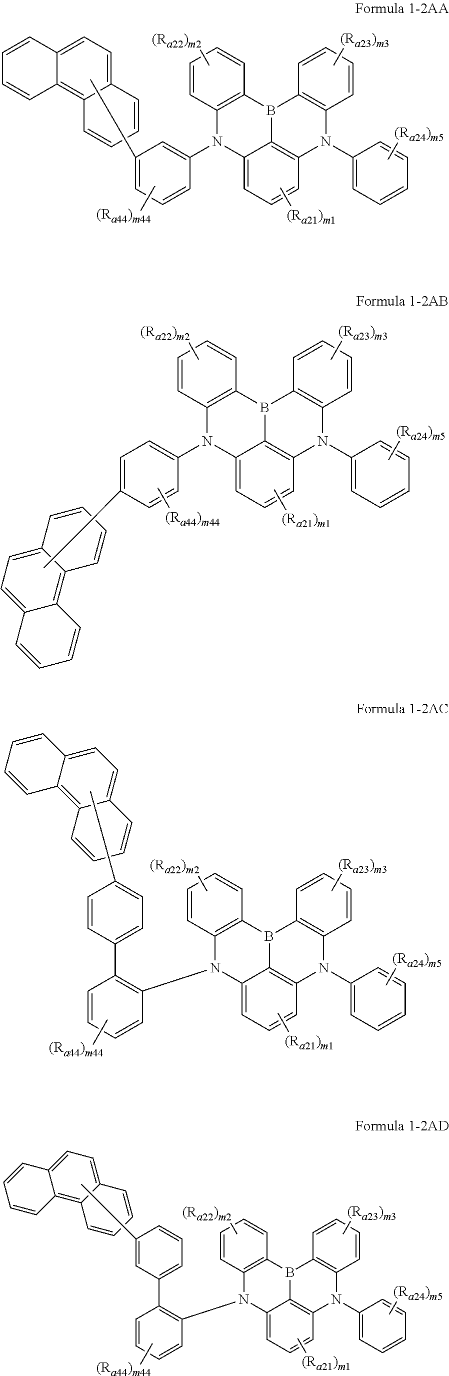

In Formula 1-2AA to Formula 1-2AD, the same contents as those described with reference to Formula 1-2A may be applied to m1 to m3, m5, m44, Rₐ₂₁ to Rₐ₂₄, and Rₐ₄₄.

In one or more embodiments, the fused polycyclic compound represented by Formula 1-3 may be represented by Formula 1-3A. Formula 1-3A may represent a case (e.g., embodiments) in which L_{d} is a substituted or unsubstituted divalent carbazole group in Formula 1-3.

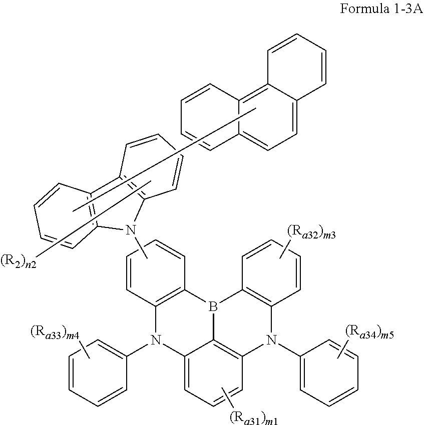

In Formula 1-3A, the same contents as those described with reference to Formula 1-3 may be applied to m1 and m3 to m5.

In Formula 1-3A, n2 may be an integer of 0 to 7. When n2 is an integer of 2 or greater, a plurality of R₂'s may all be the same or at least one thereof may be different from the rest thereof. When n2 is 0, it may be the same as when n2 is 7 and seven R 2's are each hydrogen atom. R₂ and Rₐ₃₁ to Rₐ₃₄ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the fused polycyclic compound represented by Formula 1-3A may be represented by Formula 1-3AA. Formula 1-3AA may represent a case (e.g., embodiments) in which in Formula 1-3A, m4 and m5 are each independently an integer of 2 or greater, and two Rₐ₃₃'s and two Rₐ₃₄'s are phenyl groups.

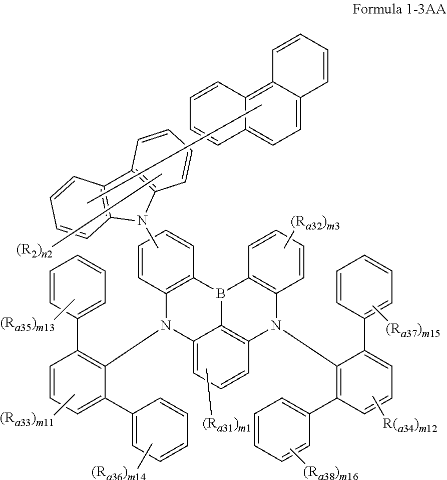

In Formula 1-3AA, the same contents as those described with reference to Formula 1-3A may be applied to m1, m3, n2, R₂, and Rₐ₃₁ to Rₐ₃₄.

m11 and m12 may each independently be an integer of 0 to 3. When m11 is an integer of 2 or greater, a plurality of Rₐ₃₃'s may all be the same or at least one thereof may be different from the rest thereof. When m11 is 0, it may be the same as when m11 is 3 and three Rₐ₃₃'s are each hydrogen atom. When m12 is an integer of 2 or greater, a plurality of Rₐ₃₄'s may all be the same or at least one thereof may be different from the rest thereof. When m12 is 0, it may be the same as when m12 is 3 and five Rₐ₃₄'s are each hydrogen atom.

m13 to m16 may each independently be an integer of 0 to 5. When m13 is an integer of 2 or greater, a plurality of Rₐ₃₅'s may all be the same or at least one thereof may be different from the rest thereof. When m13 is 0, it may be the same as when m13 is 5 and five Rₐ₃₅'s are each hydrogen atom. When m14 is an integer of 2 or greater, a plurality of Rₐ₃₆'s may all be the same or at least one thereof may be different from the rest thereof. When m14 is 0, it may be the same as when m14 is 5 and five Rₐ₃₆'s are each hydrogen atom. When m15 is an integer of 2 or greater, a plurality of Rₐ₃₇'s may all be the same or at least one thereof may be different from the rest thereof. When m15 is 0, it may be the same as when m15 is 5 and five Rₐ₃₇'s are each hydrogen atom. When m16 is an integer of 2 or greater, a plurality of Rₐ₃₈'s may all be the same or at least one thereof may be different from the rest thereof. When m16 is 0, it may be the same as when m16 is 5 and five Rₐ₃₈'s are each hydrogen atom.

Rₐ₃₅ to Rₐ₃₈ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Rₐ₃₅ to Rₐ₃₈ may each independently be a hydrogen atom, a substituted or unsubstituted t-butyl group, or a substituted or unsubstituted phenyl group.

In one or more embodiments, the fused polycyclic compound represented by Formula 1 may be any one selected from among compounds of Compound Group 1.

The fused polycyclic compound of one or more embodiments may be any one selected from among the compounds of Compound Group 1. The light emitting element ED of one or more embodiments may include at least one selected from among the compounds of Compound Group 1. In Compound Group 1, D is a deuterium atom.

### Compound Group 1

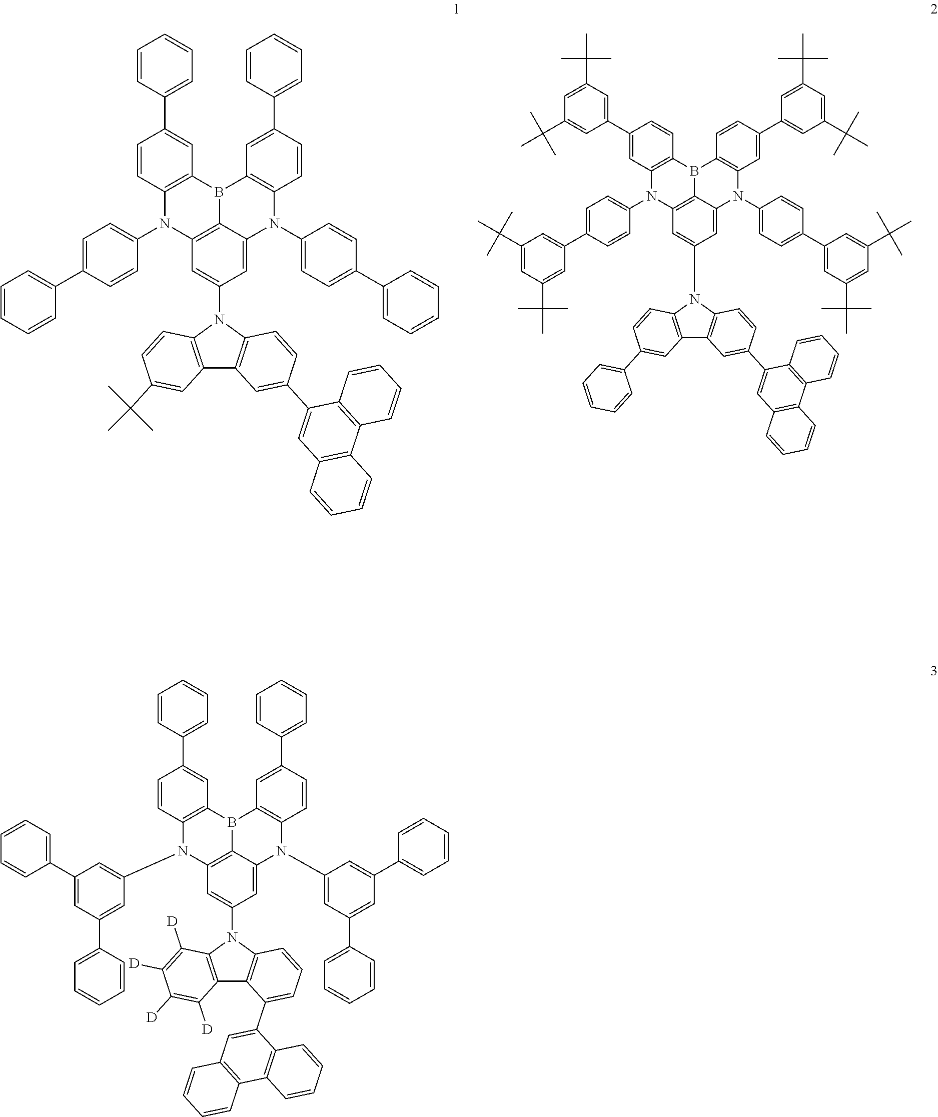

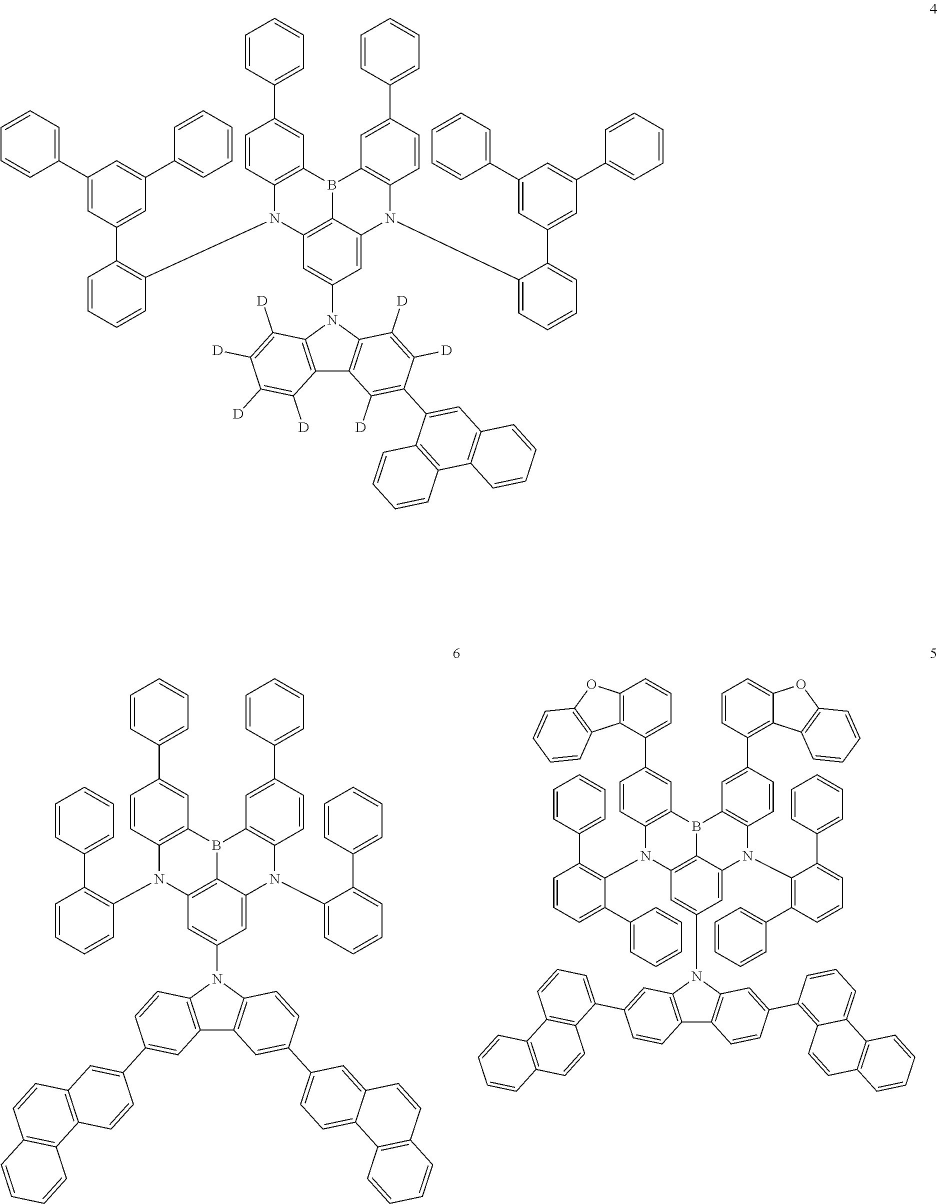

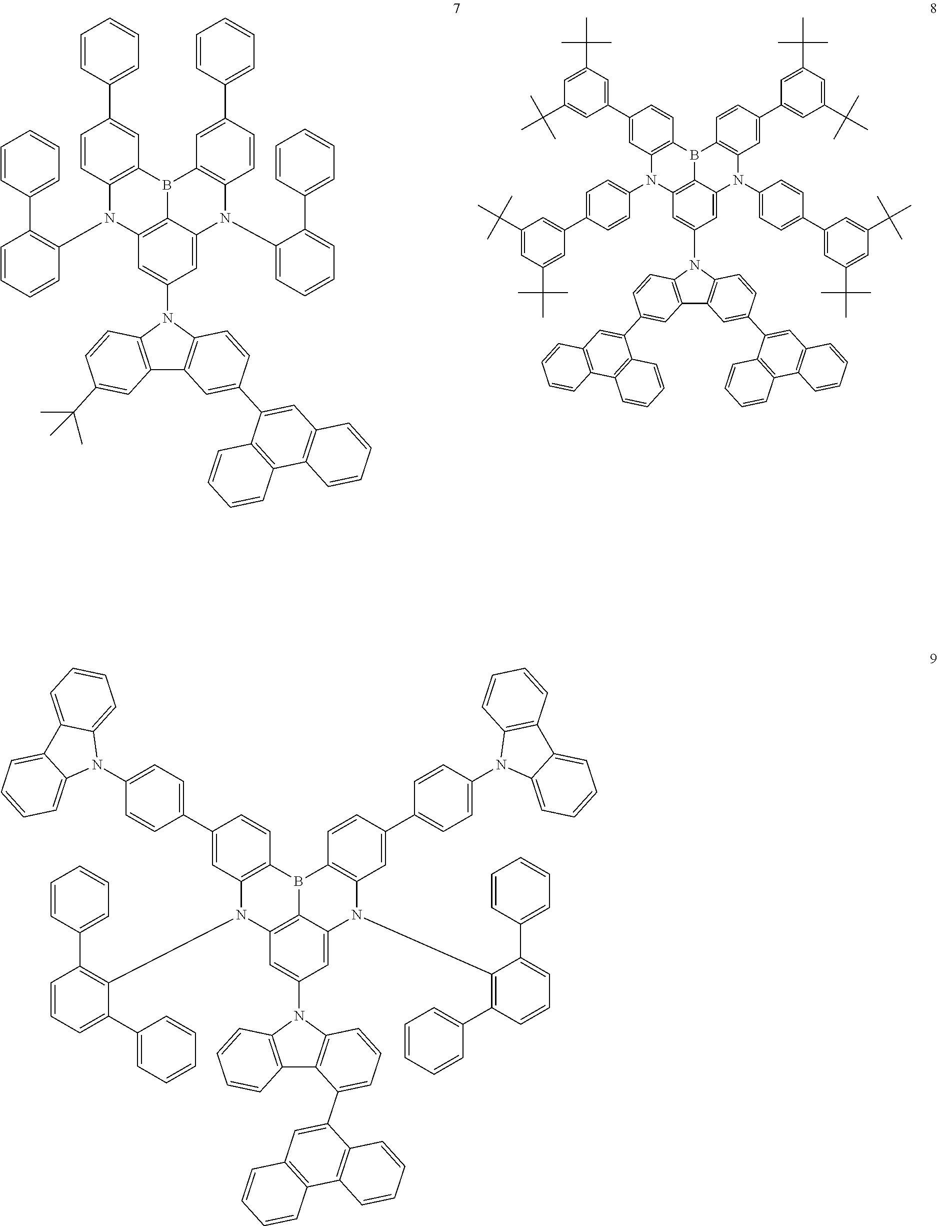

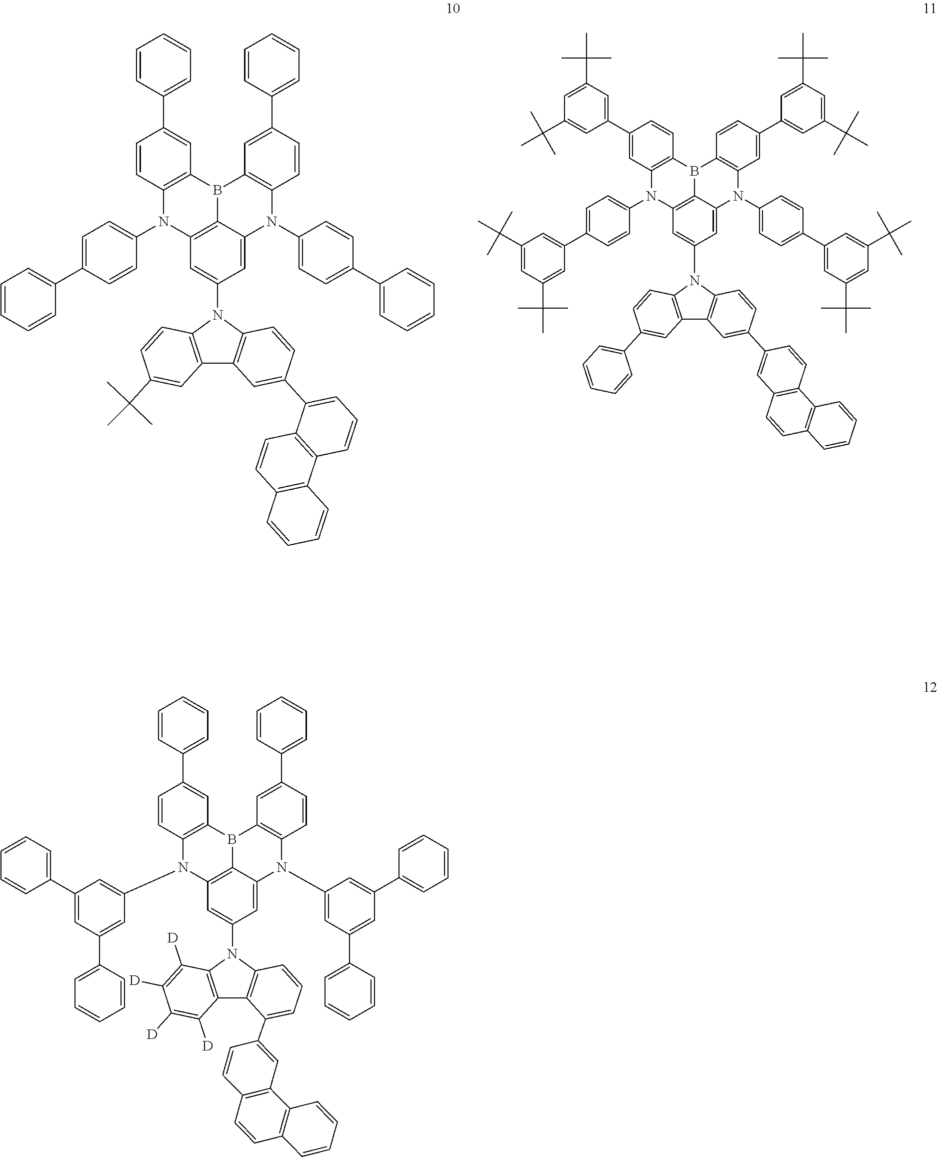

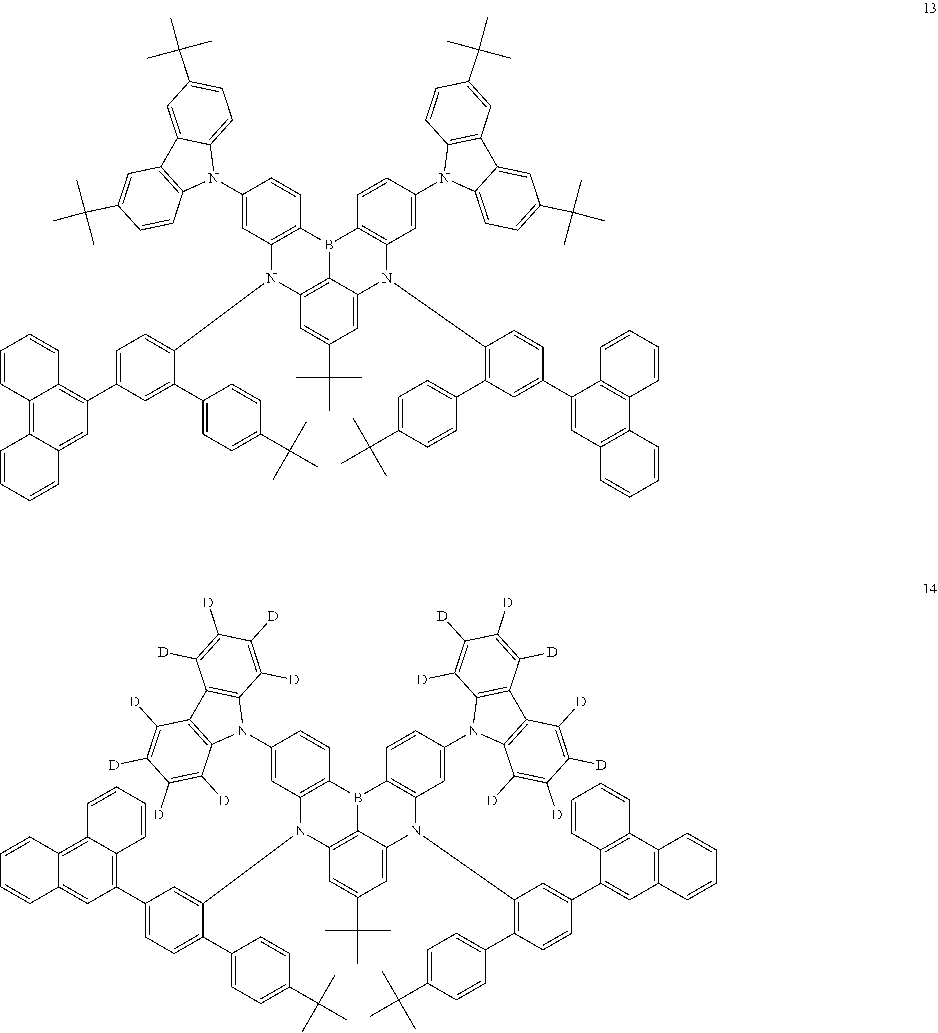

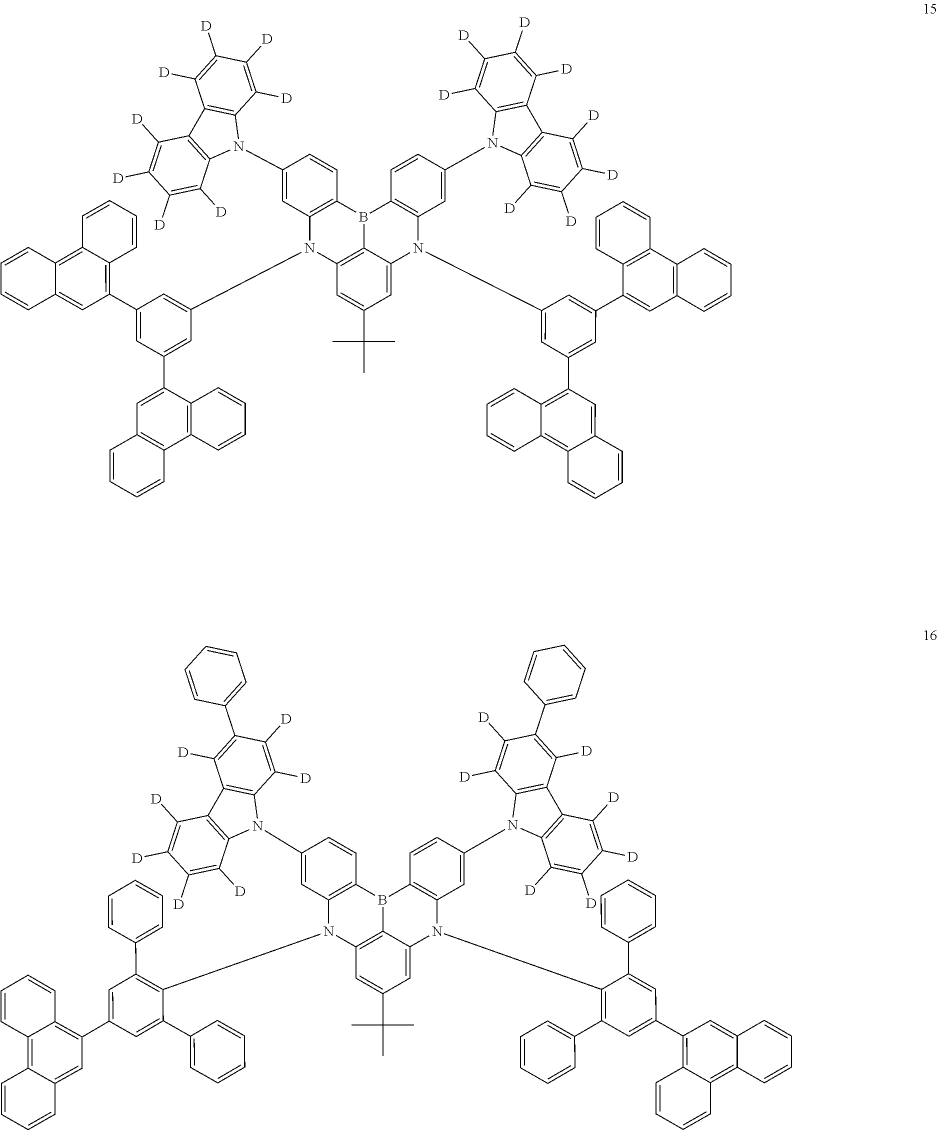

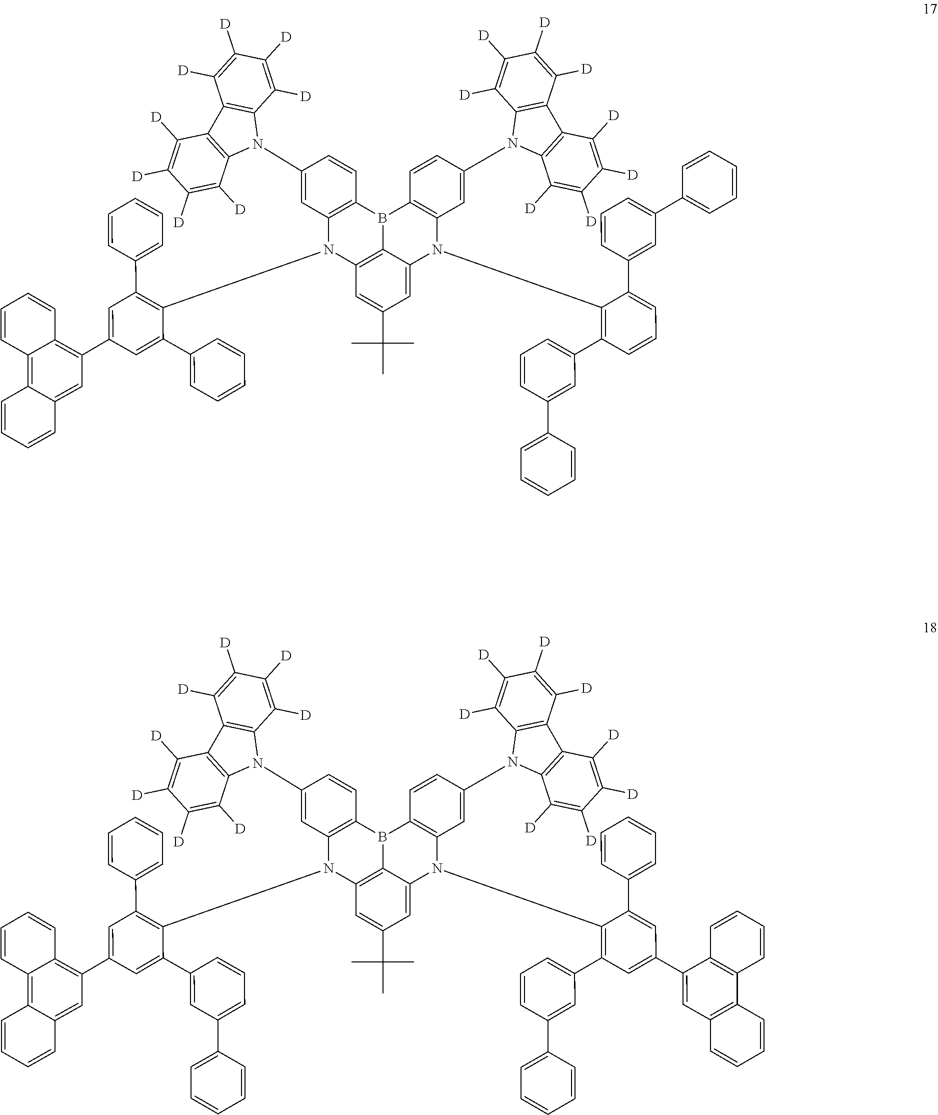

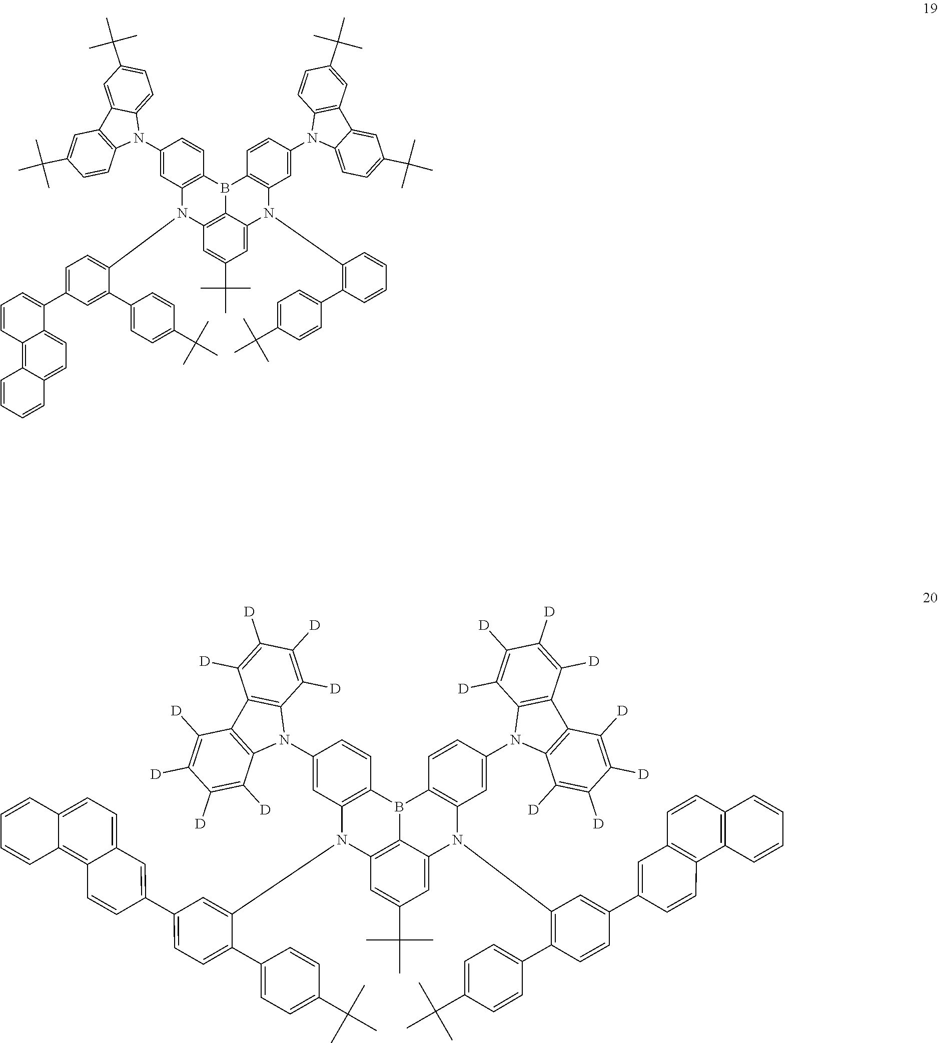 [SMILES: CC(C)(C)c1ccc(-c2ccccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5cccc6c5ccc5ccccc56)cc4-c4ccc(C(C)(C)C)cc4)c4cc(C(C)(C)C)cc2c43)cc1 ; [2H]c1c([2H])c([2H])c2c(c1[2H])c1c([2H])c([2H])c([2H])c([2H])c1n2-c1ccc2c(c1)N(c1cc(-c3ccc4c(ccc5ccccc54)c3)ccc1-c1ccc(C(C)(C)C)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1cc(-c2ccc3c(ccc4ccccc43)c2)ccc1-c1ccc(C(C)(C)C)cc1]

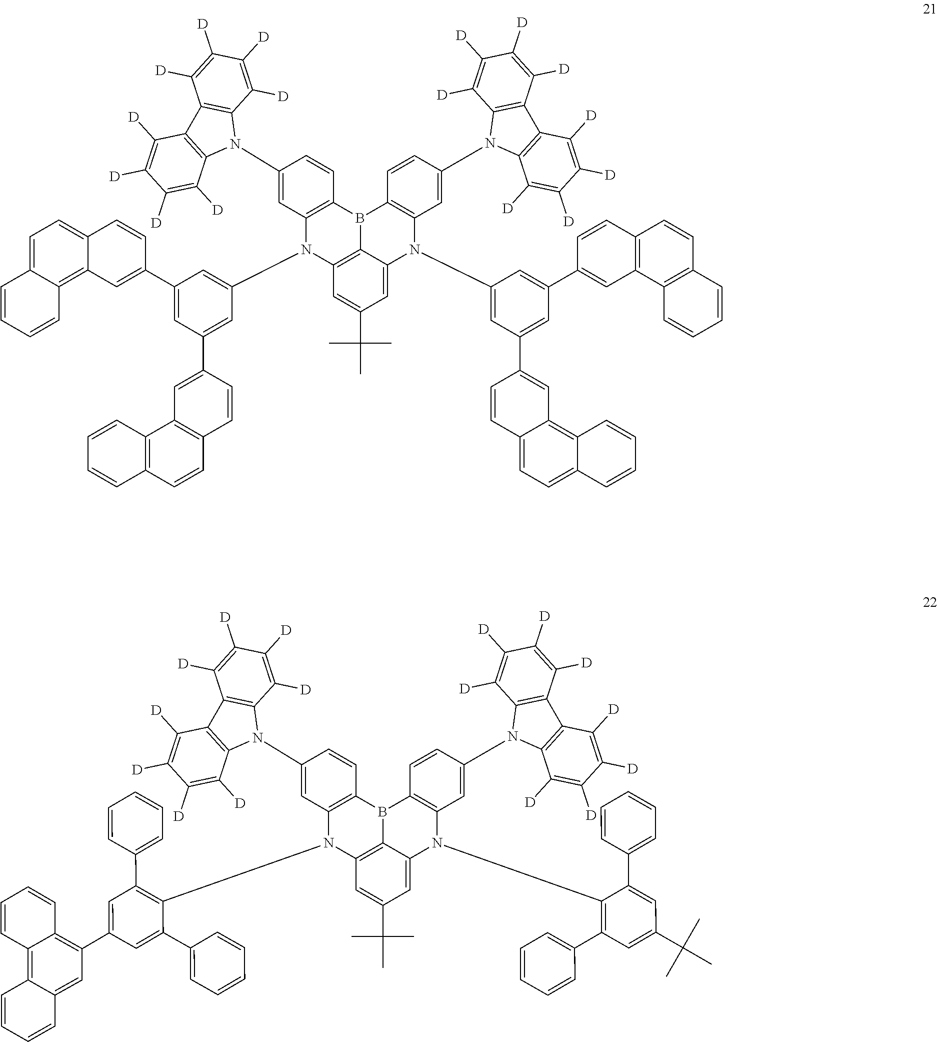

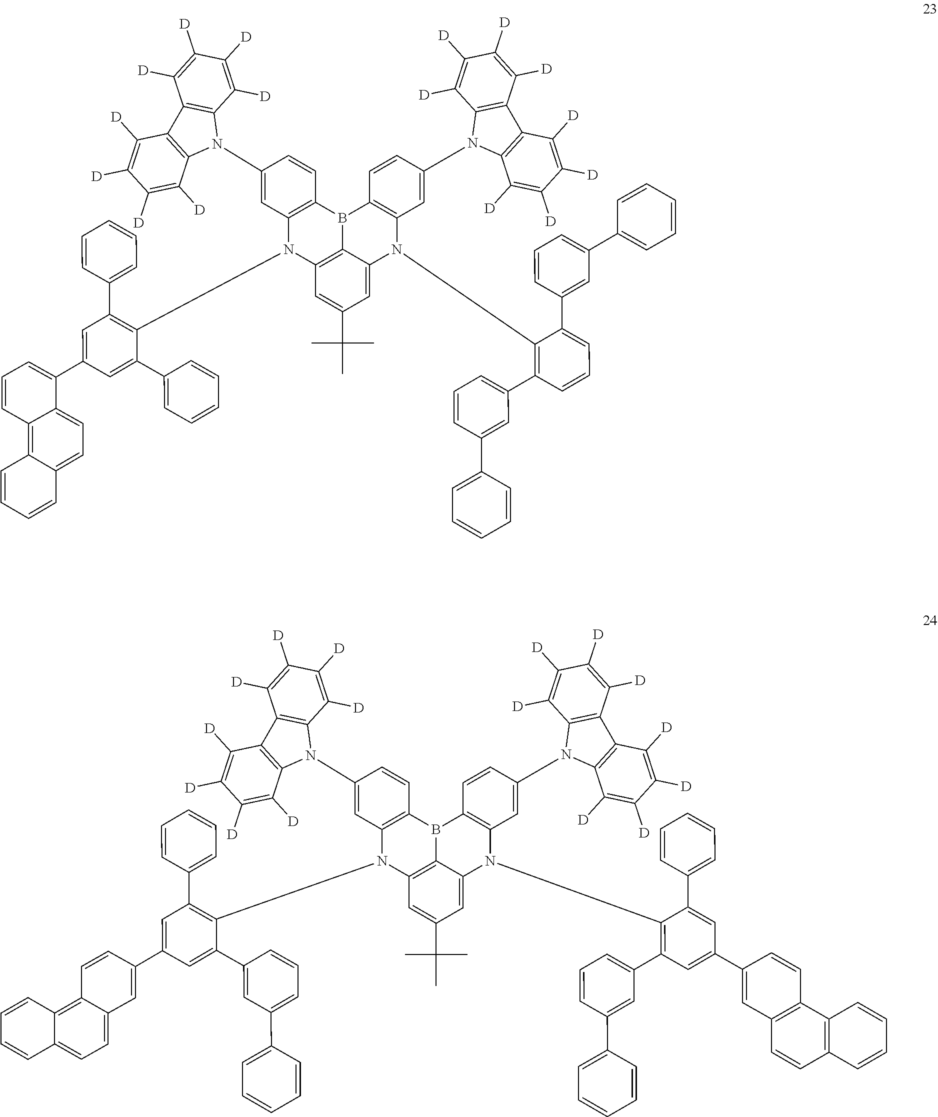

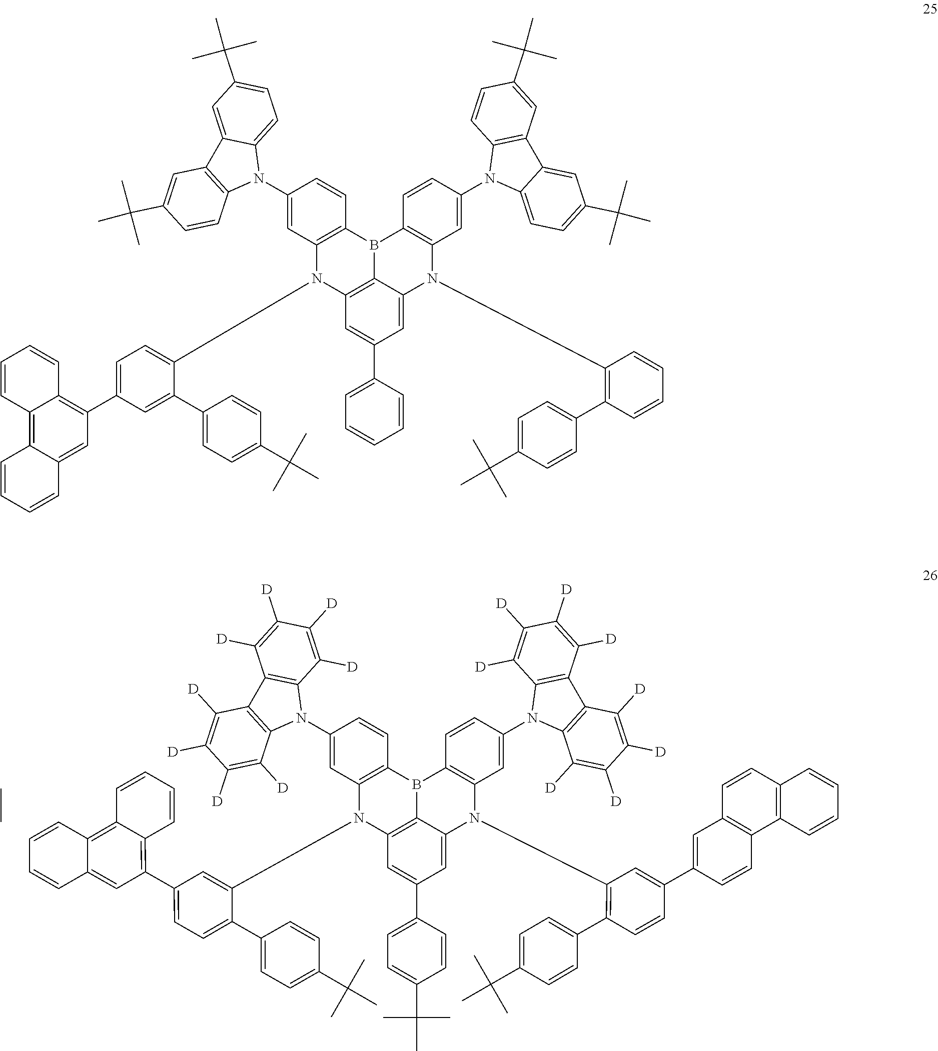

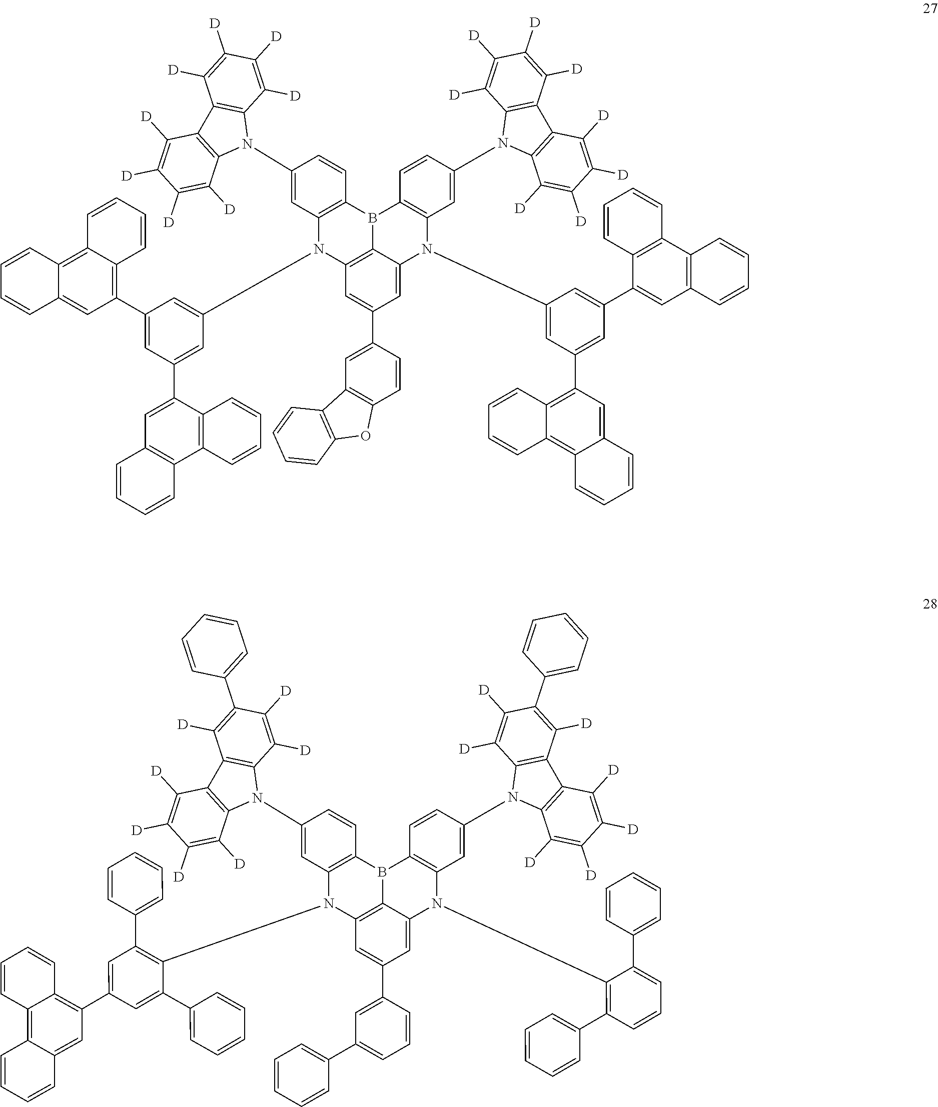

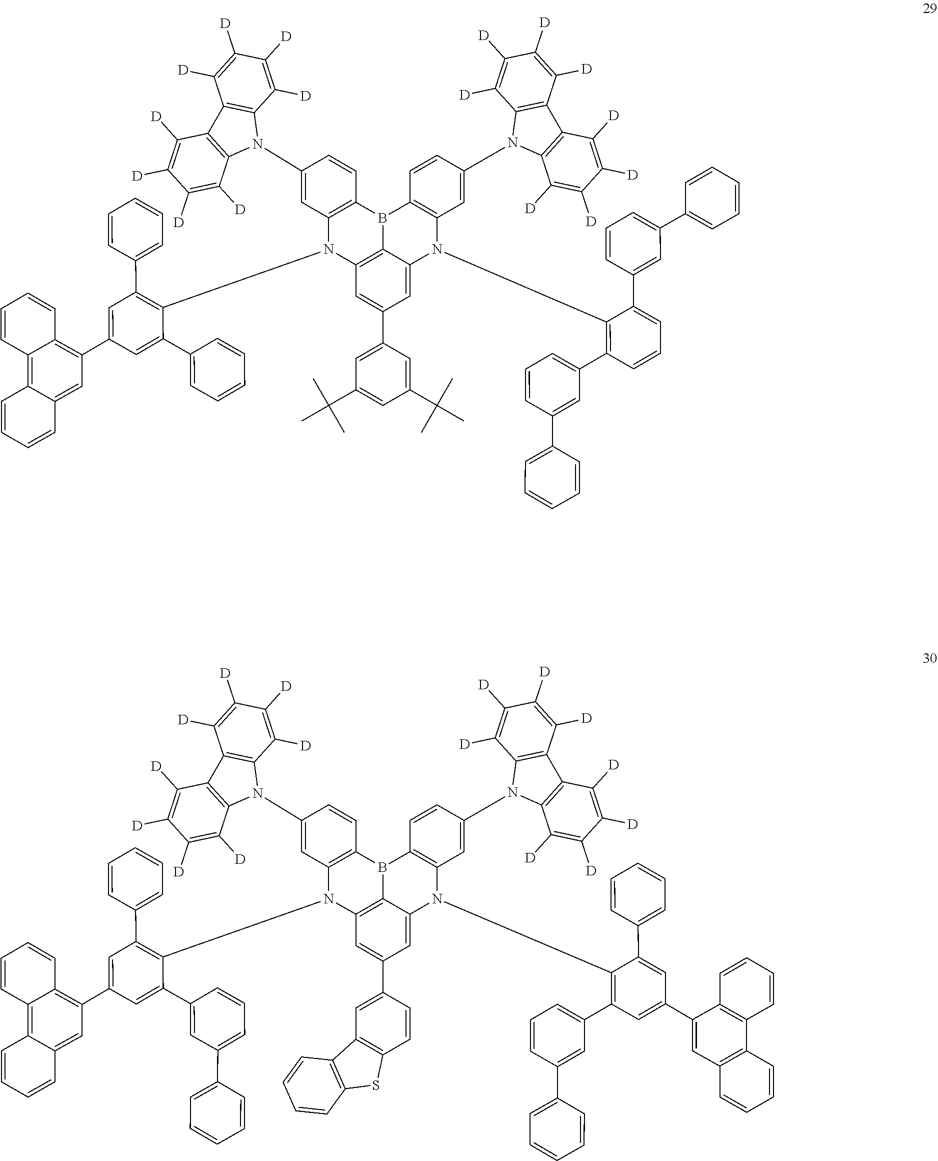

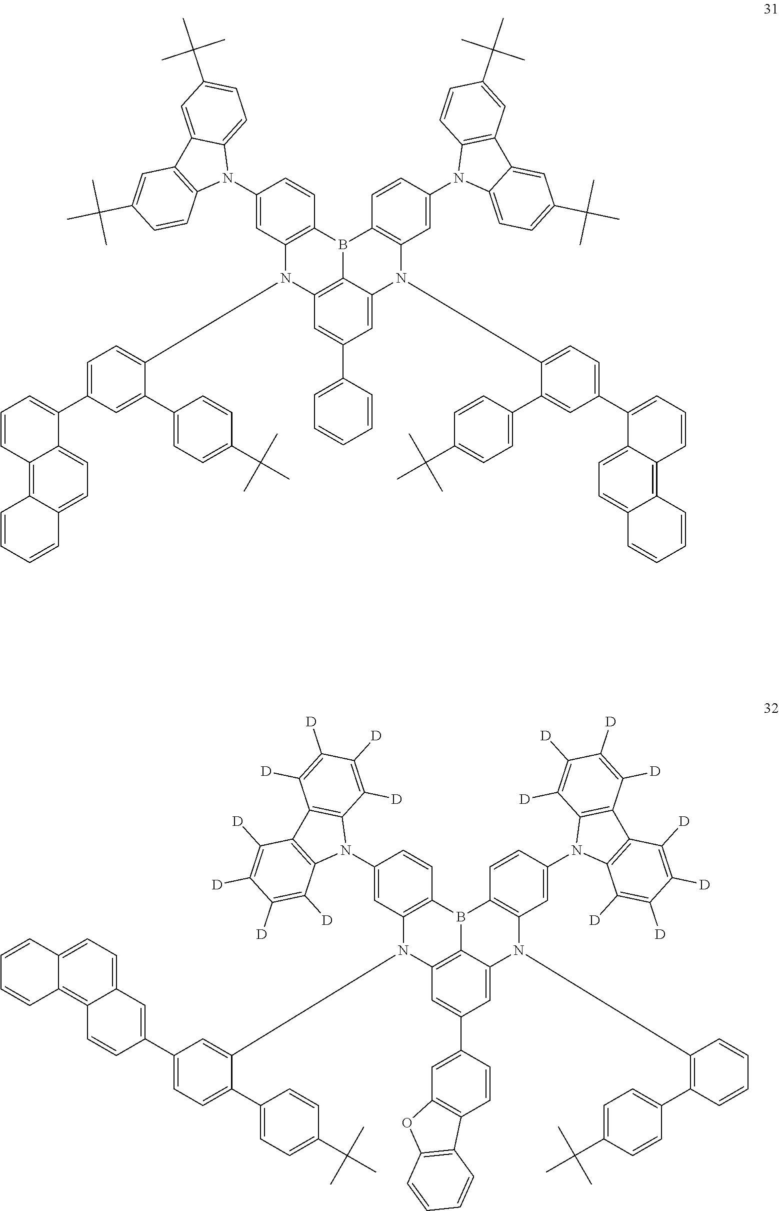

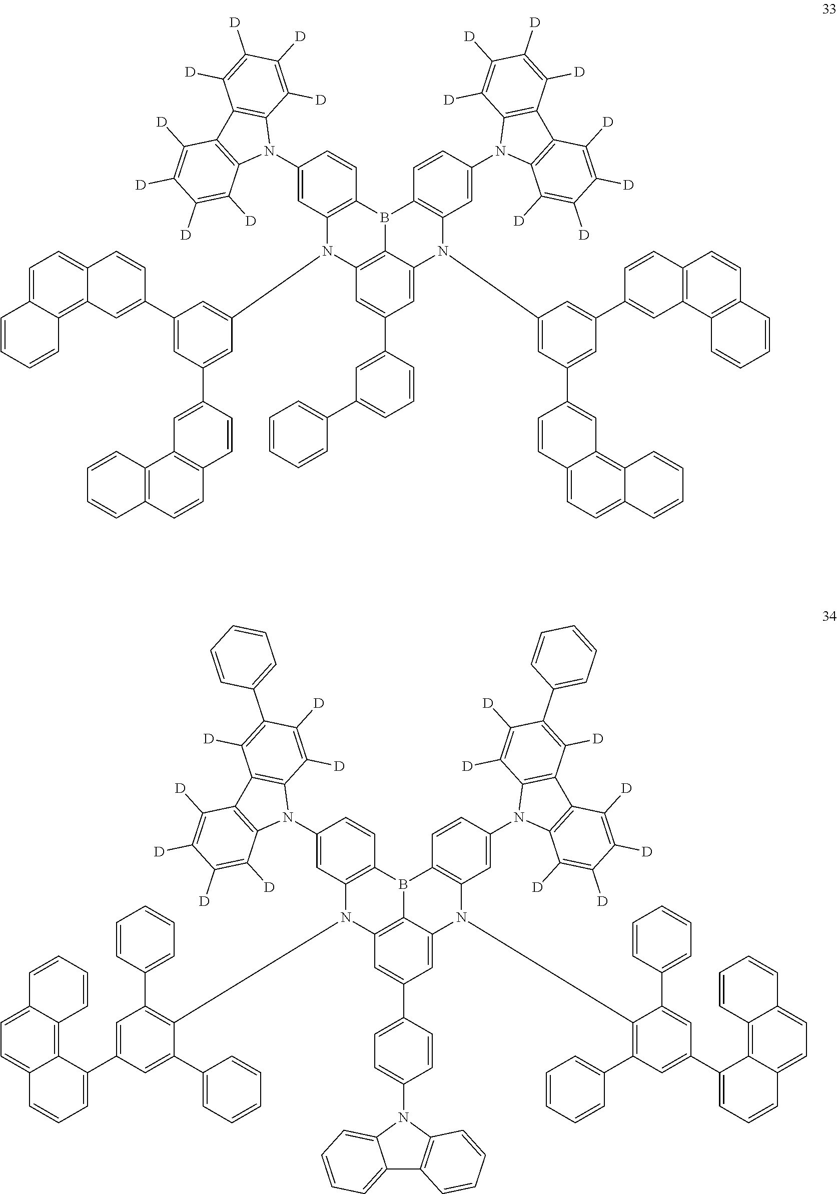

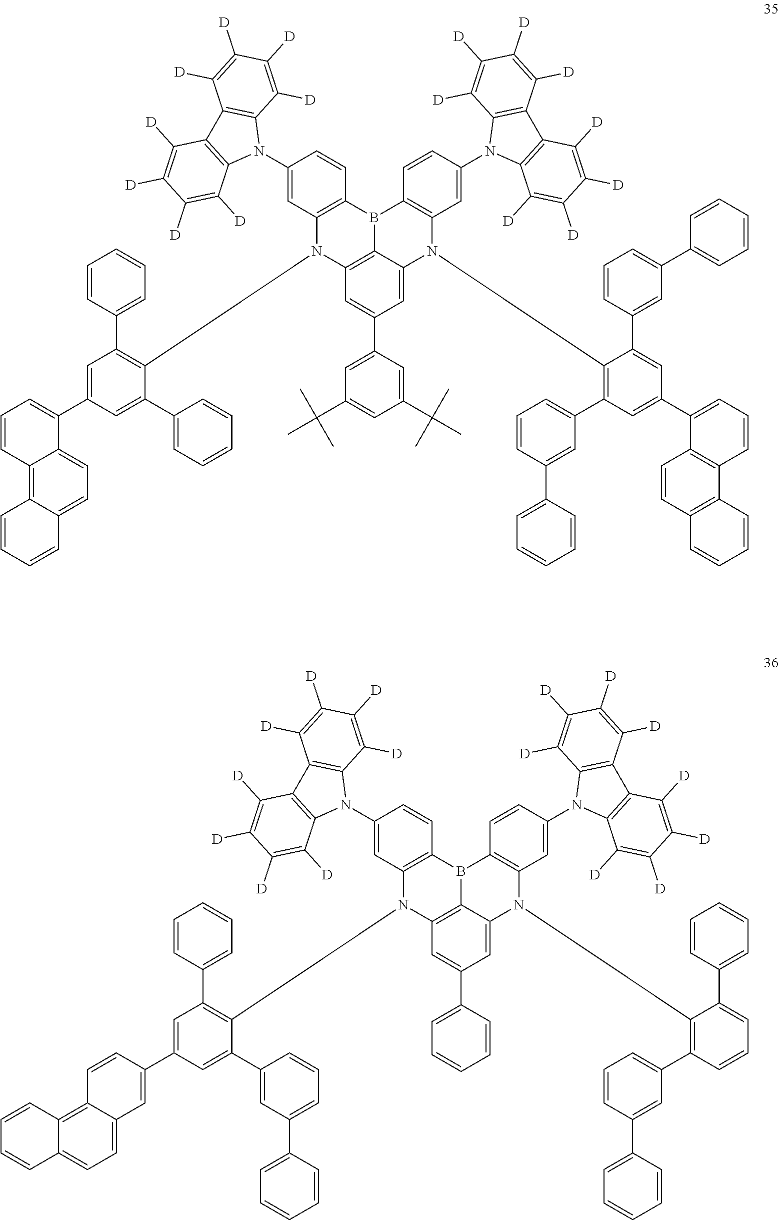

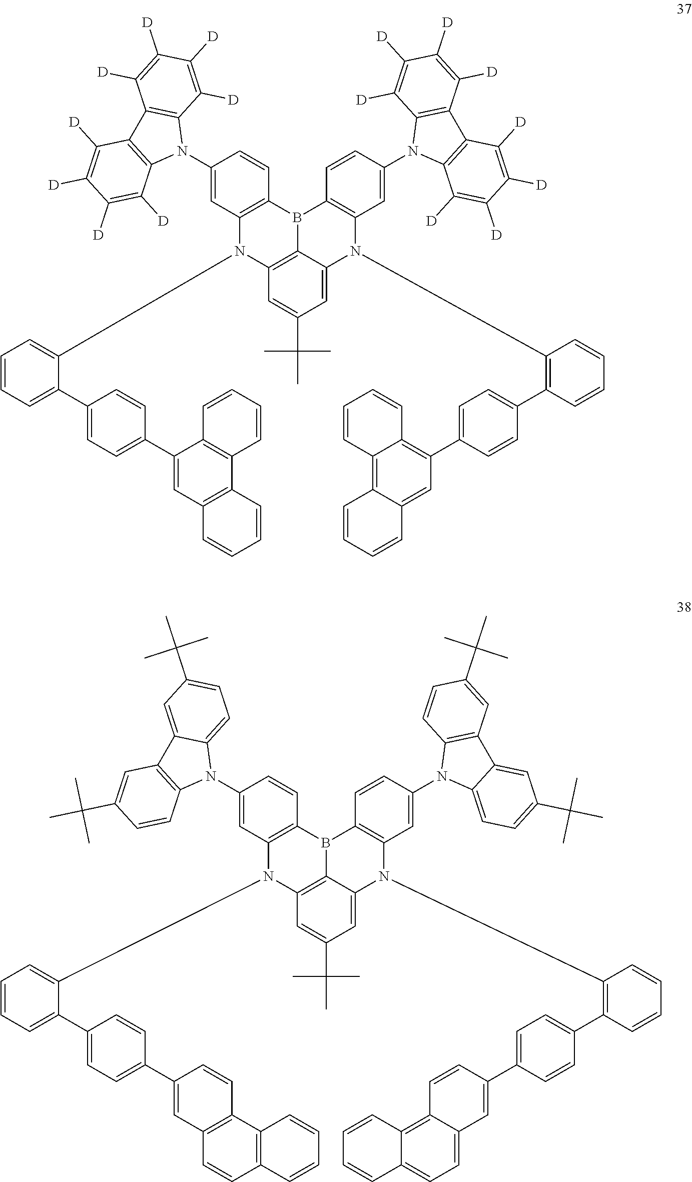 [SMILES: [2H]c1c([2H])c([2H])c2c(c1[2H])c1c([2H])c([2H])c([2H])c([2H])c1n2-c1ccc2c(c1)N(c1ccccc1-c1ccc(-c3cc4ccccc4c4ccccc34)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1ccccc1-c1ccc(-c2cc3ccccc3c3ccccc23)cc1 ; CC(C)(C)c1cc2c3c(c1)N(c1ccccc1-c1ccc(-c4ccc5c(ccc6ccccc65)c4)cc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1ccccc1-c1ccc(-c2ccc3c(ccc4ccccc43)c2)cc1]

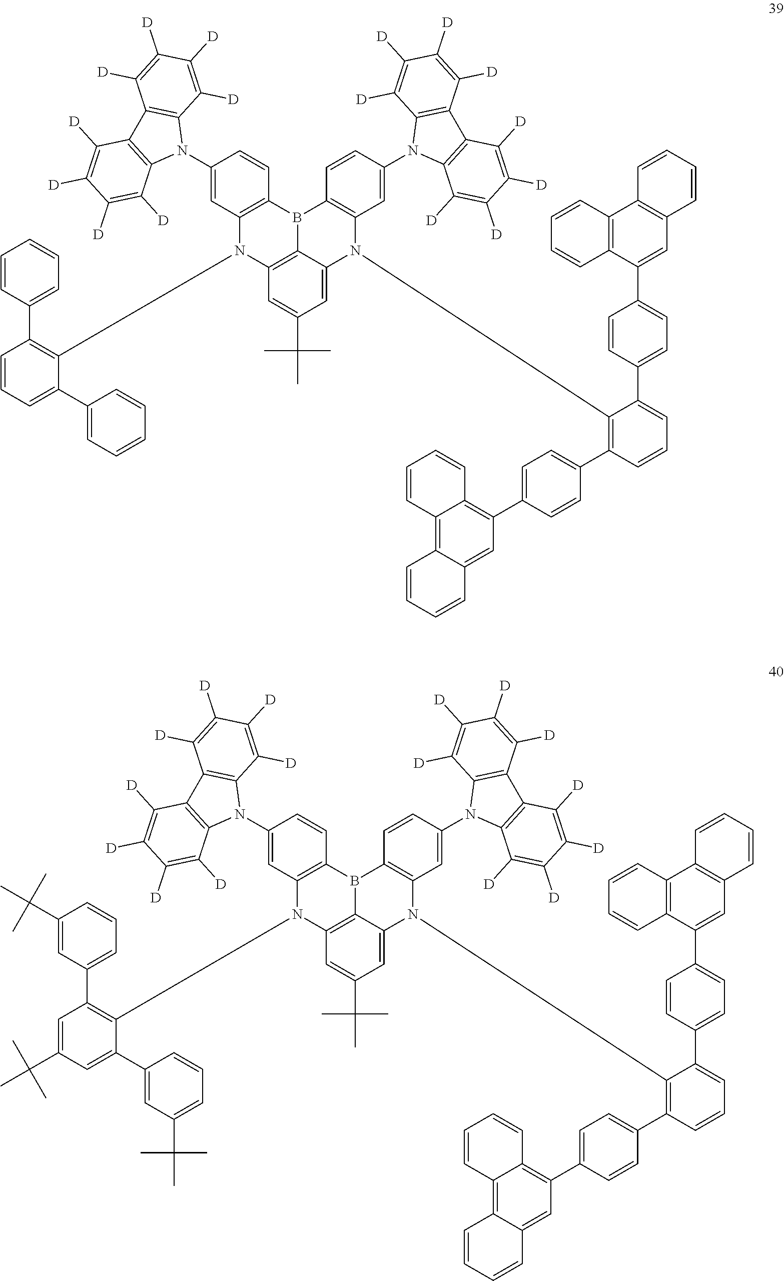

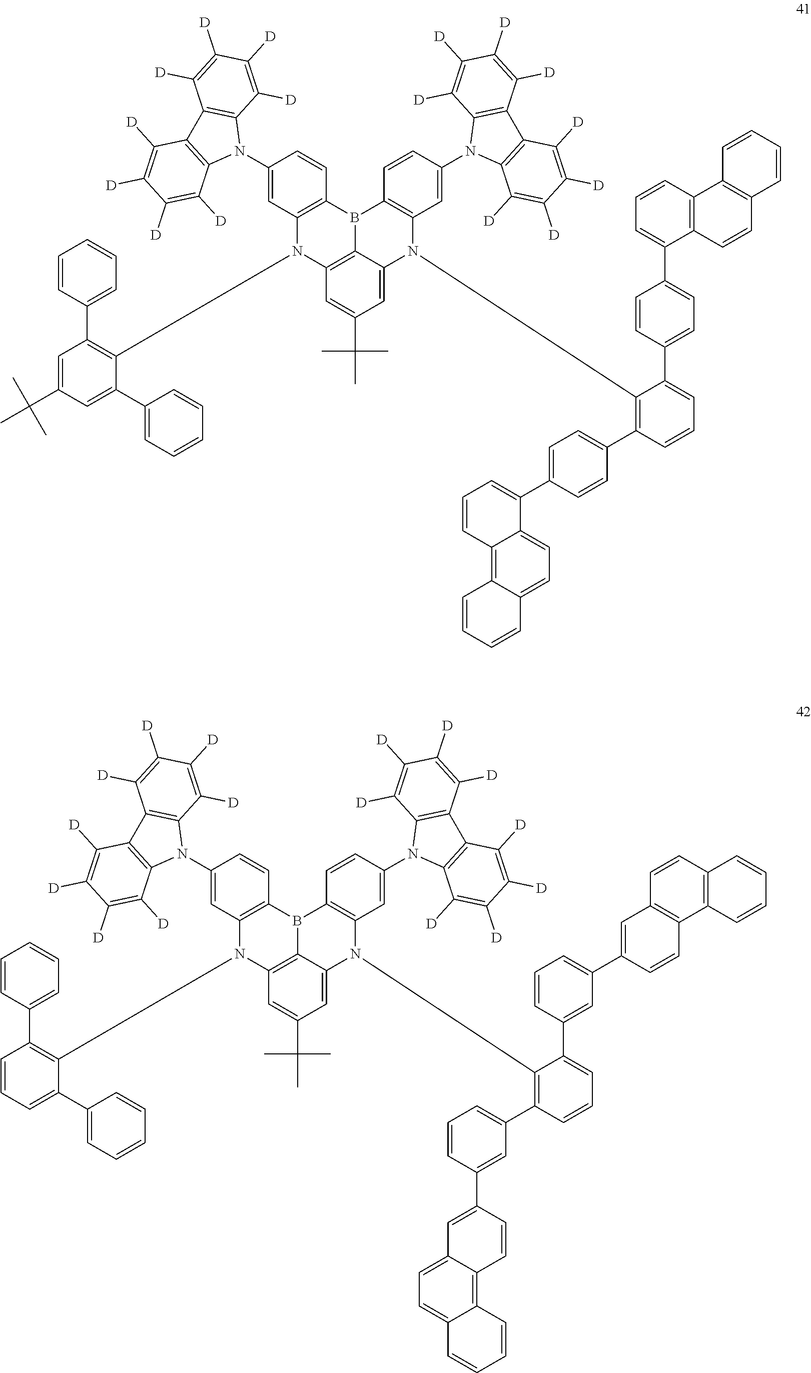

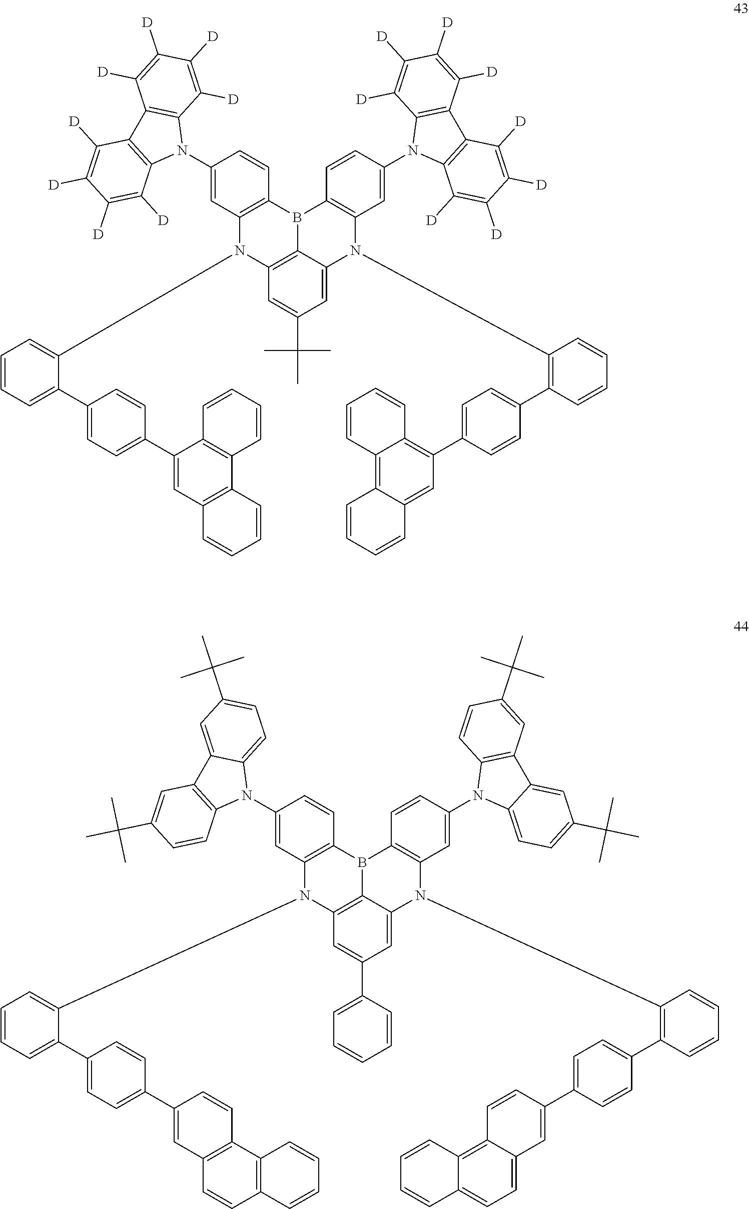 [SMILES: [2H]c1c([2H])c([2H])c2c(c1[2H])c1c([2H])c([2H])c([2H])c([2H])c1n2-c1ccc2c(c1)N(c1ccccc1-c1ccc(-c3cc4ccccc4c4ccccc34)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1ccccc1-c1ccc(-c2cc3ccccc3c3ccccc23)cc1 ; CC(C)(C)c1ccc2c(c1)c1cc(C(C)(C)C)ccc1n2-c1ccc2c(c1)N(c1ccccc1-c1ccc(-c3ccc4c(ccc5ccccc54)c3)cc1)c1cc(-c3ccccc3)cc3c1B2c1ccc(-n2c4ccc(C(C)(C)C)cc4c4cc(C(C)(C)C)ccc42)cc1N3c1ccccc1-c1ccc(-c2ccc3c(ccc4ccccc43)c2)cc1]

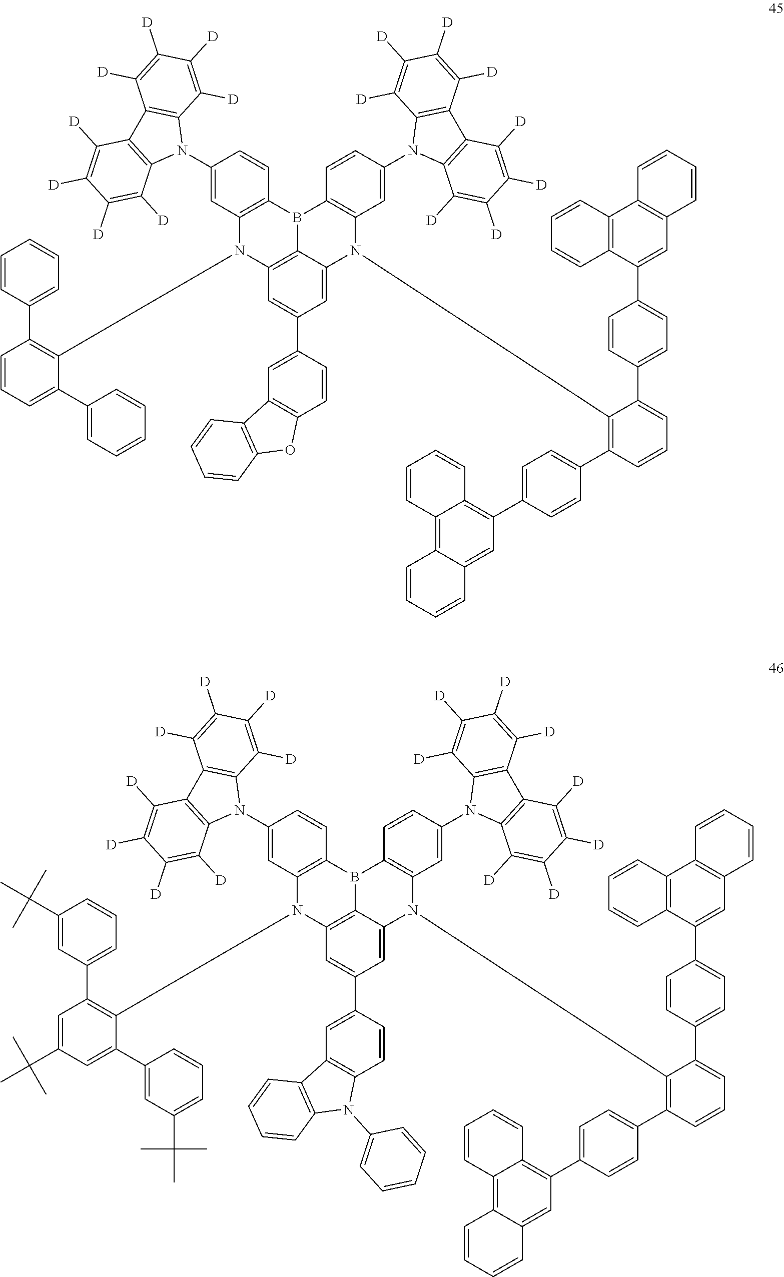

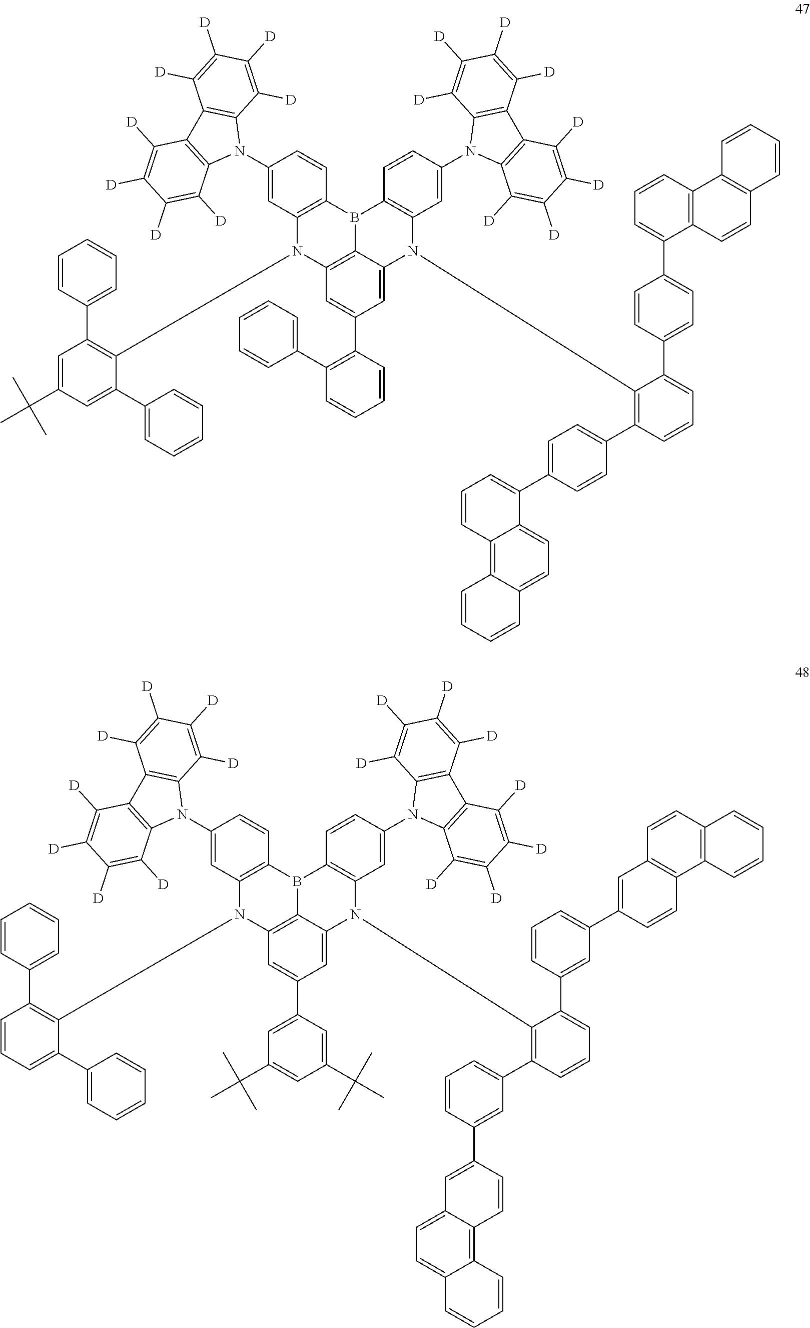

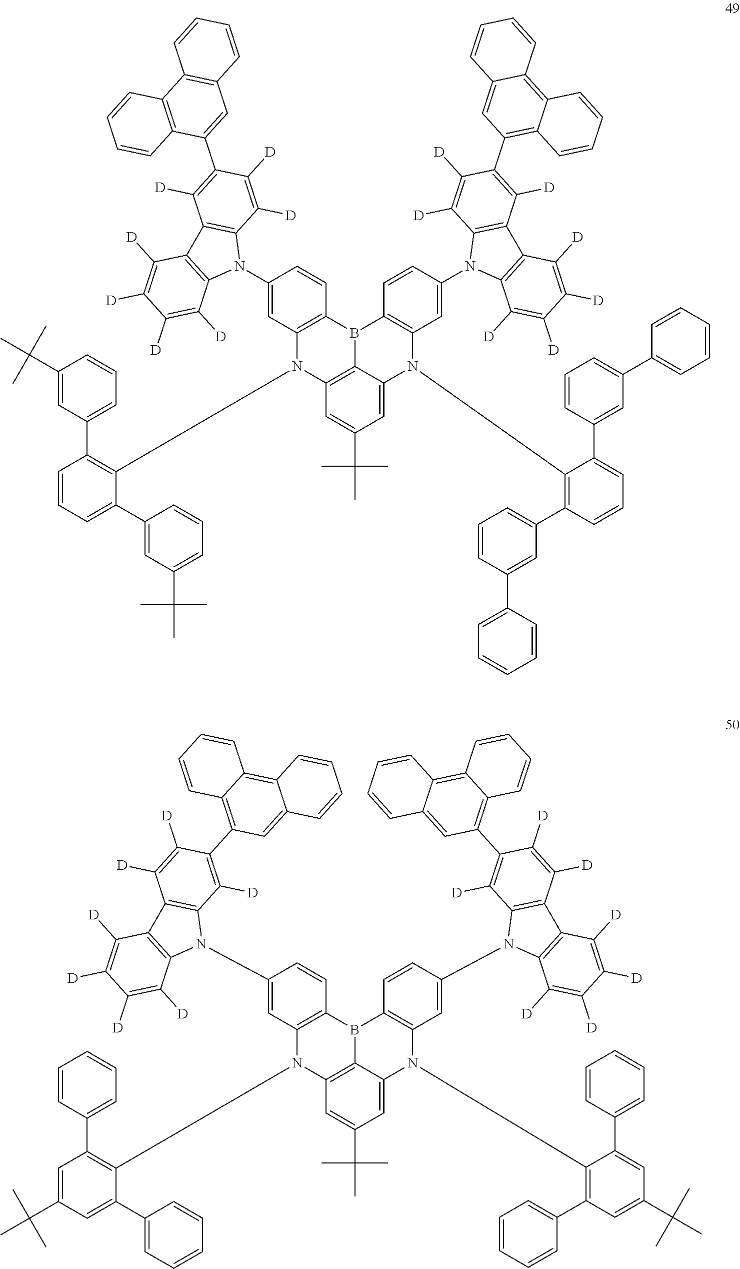

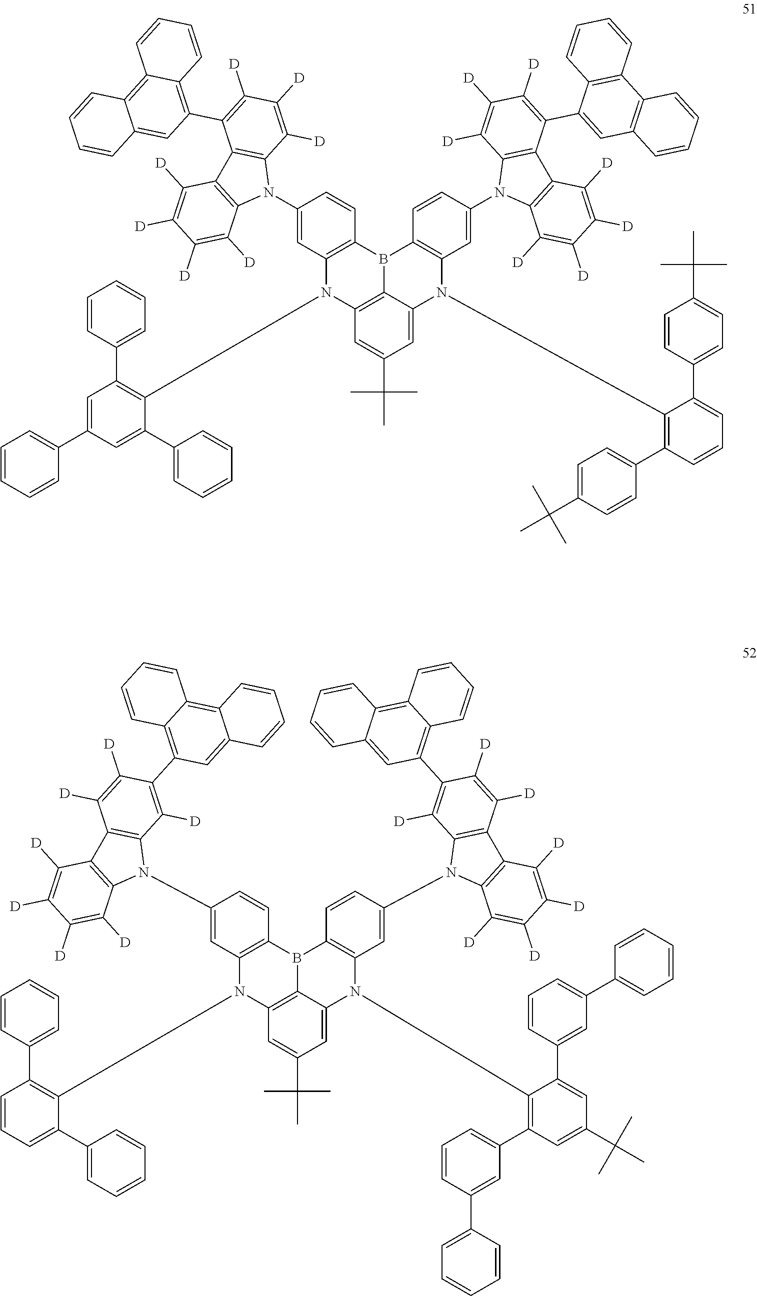

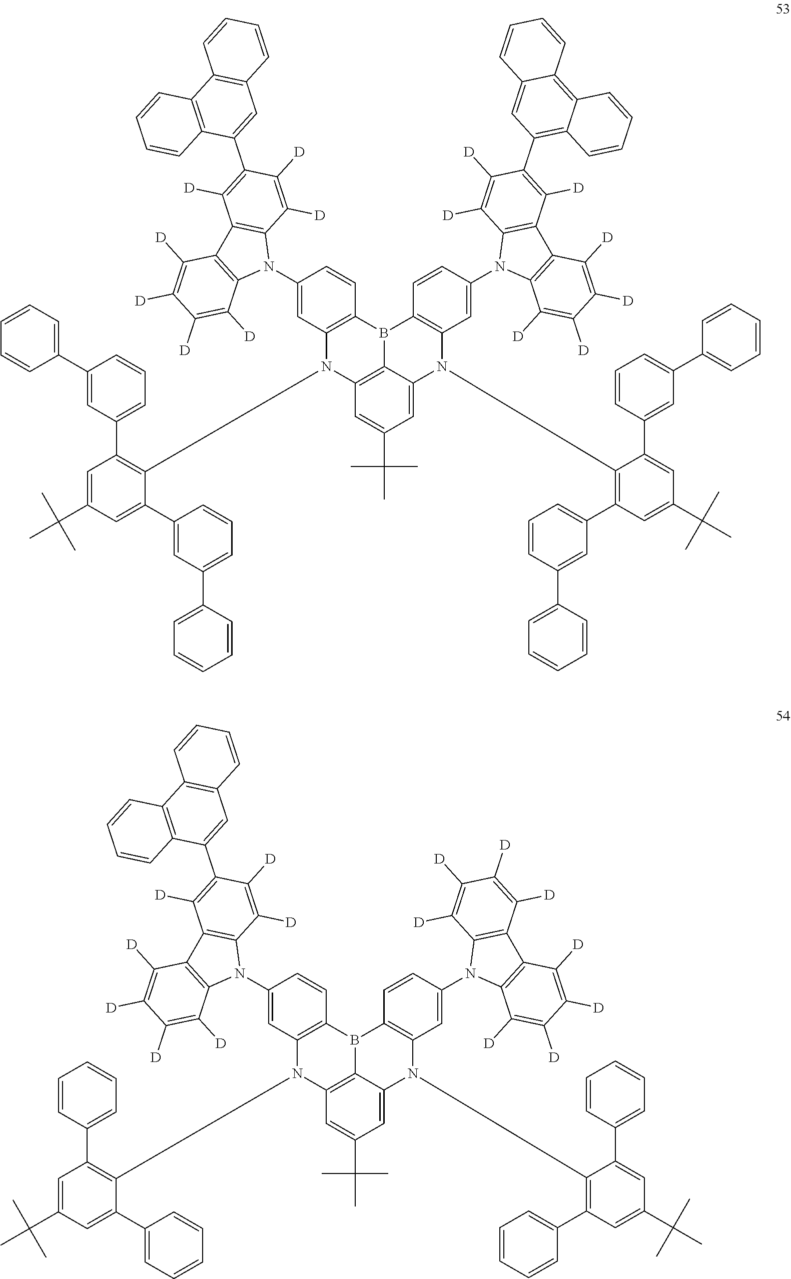

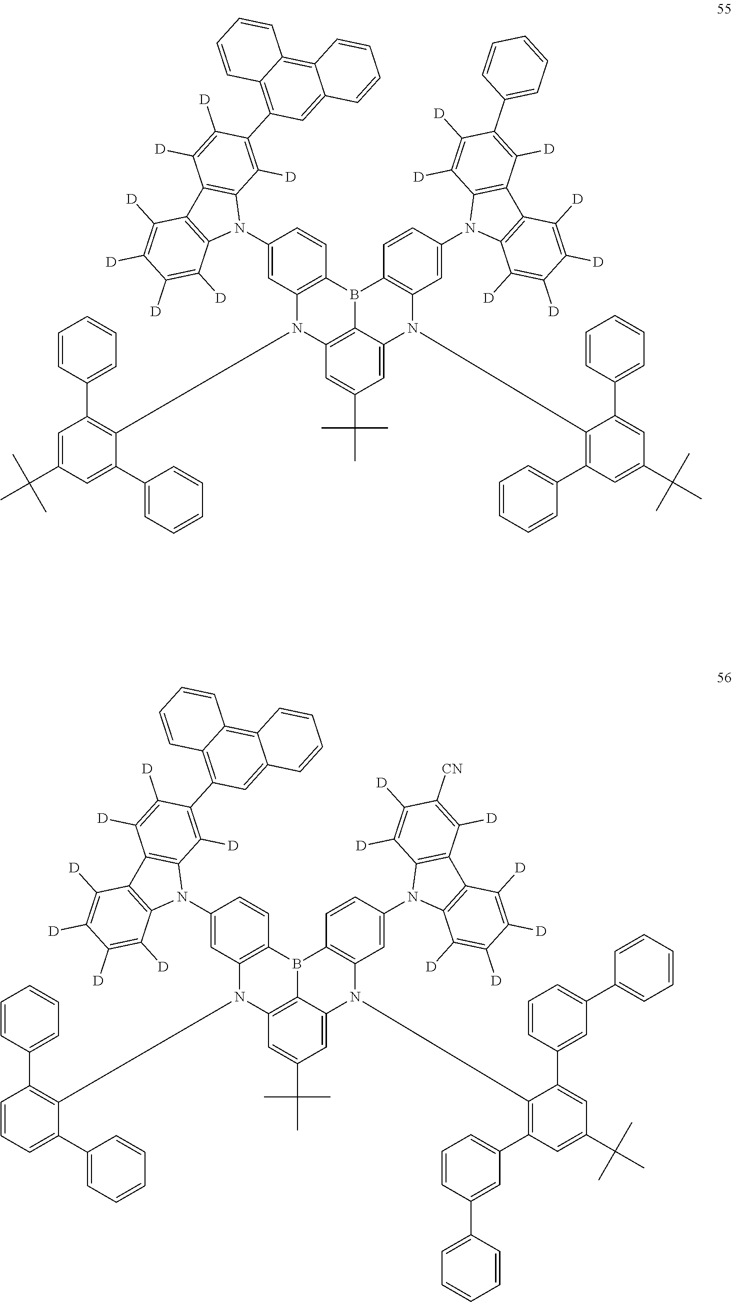

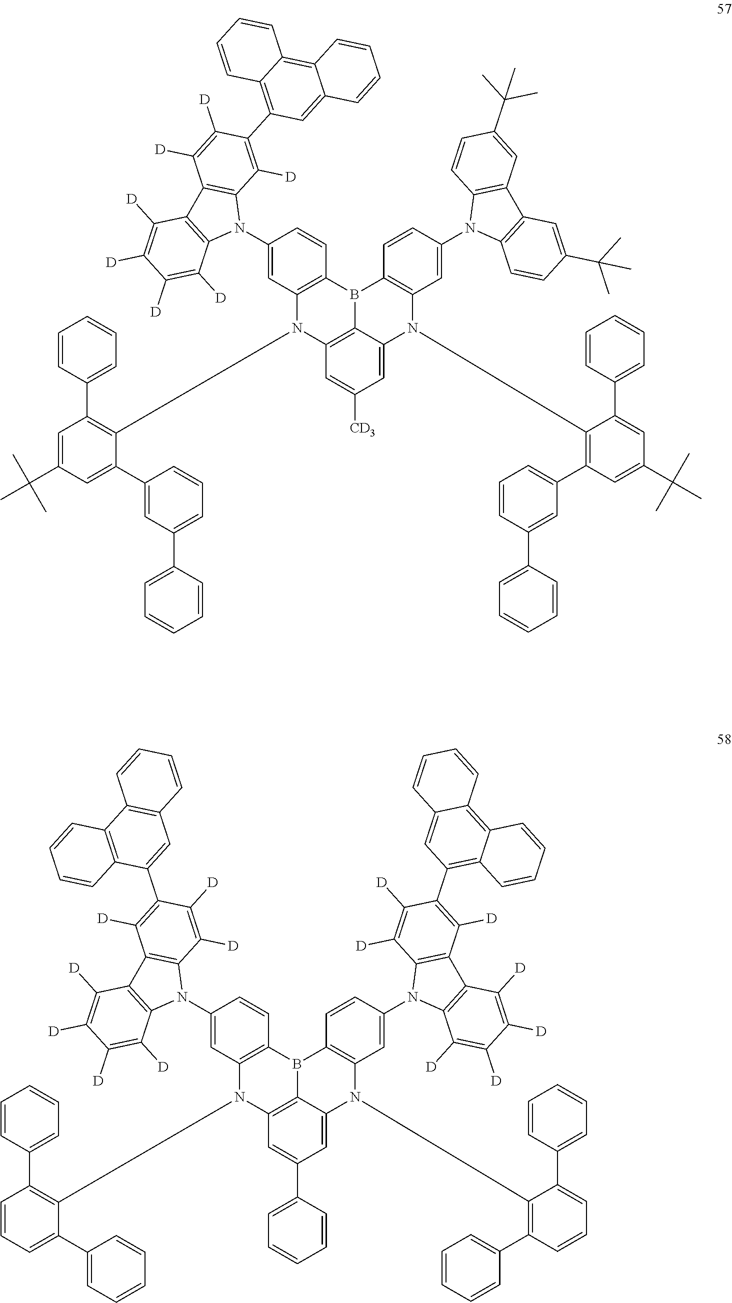

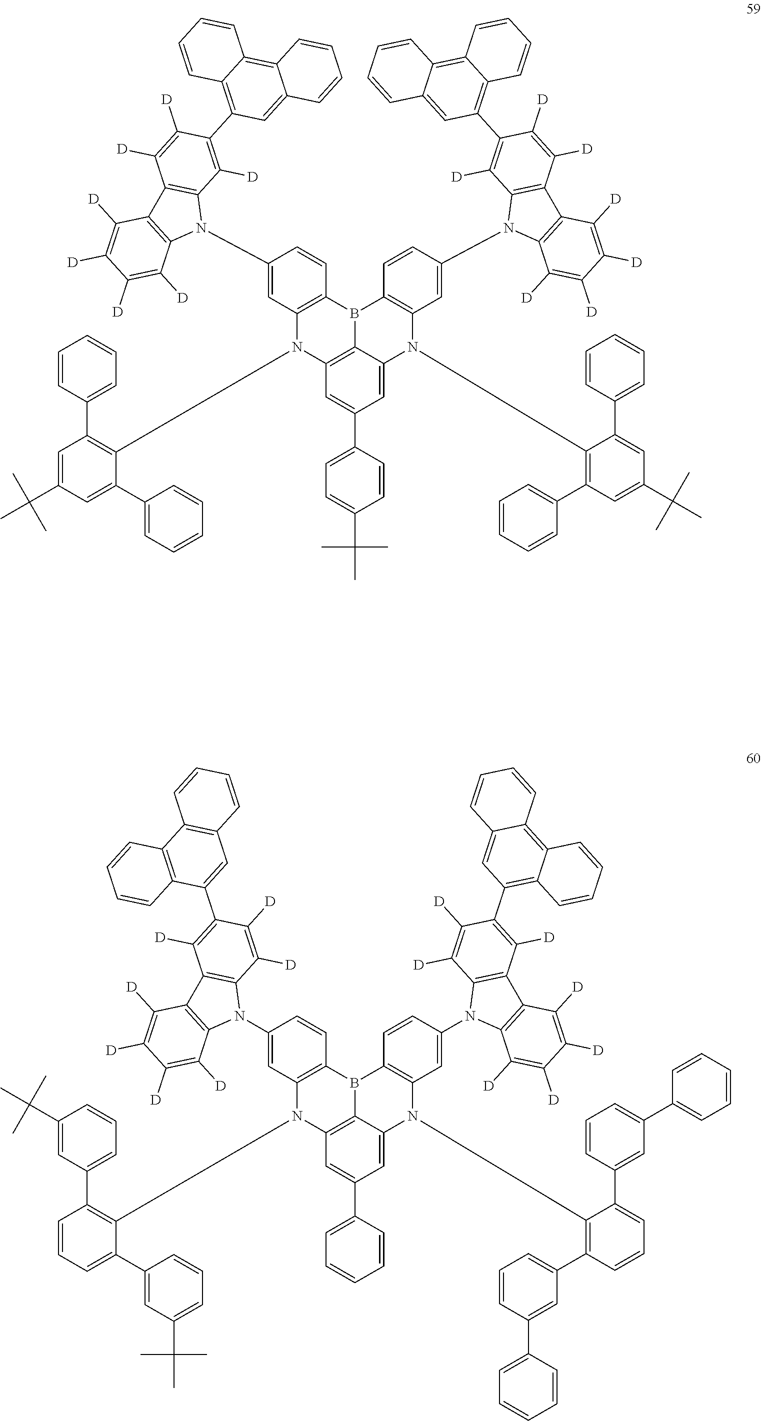

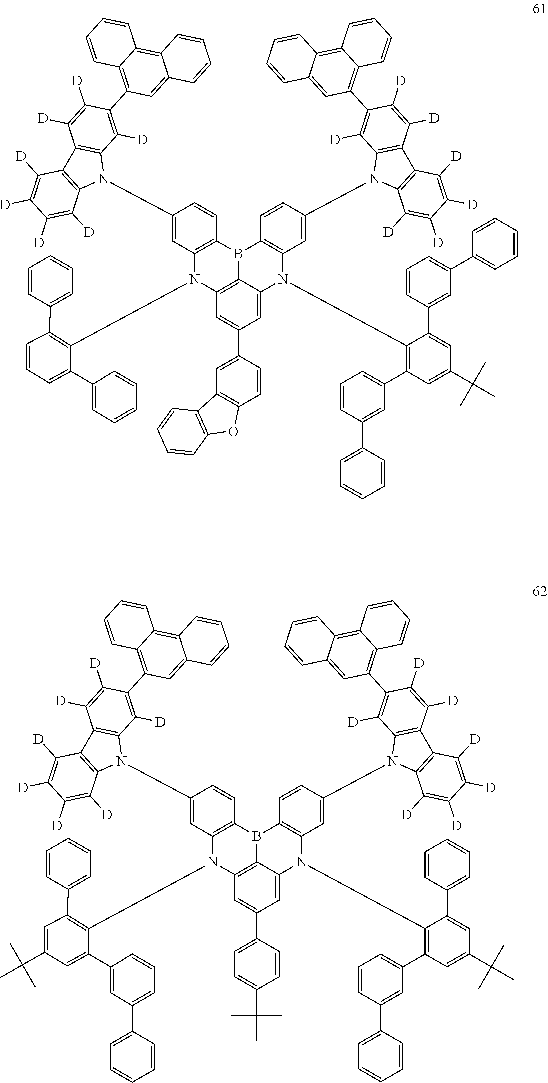

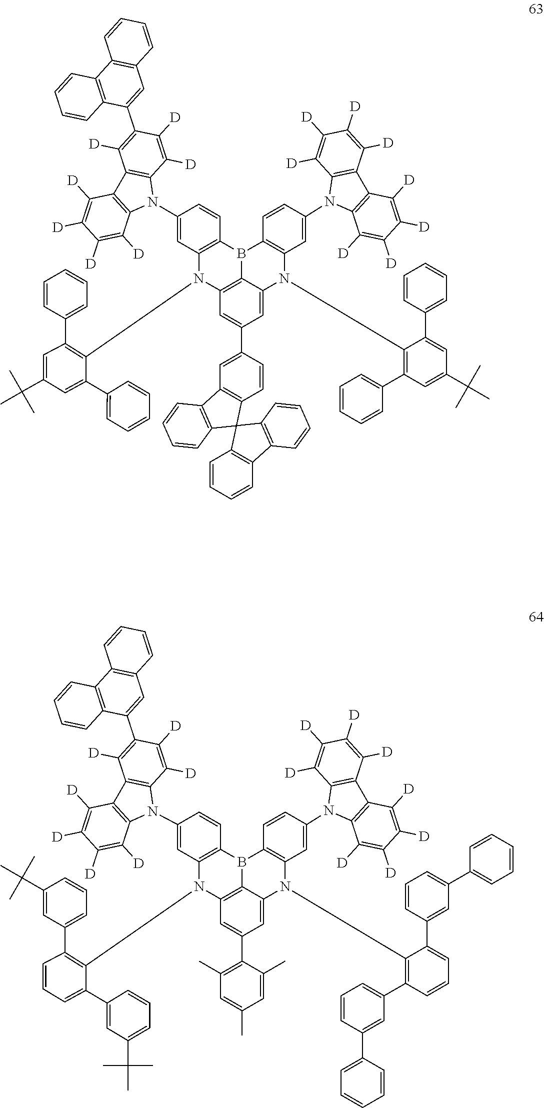

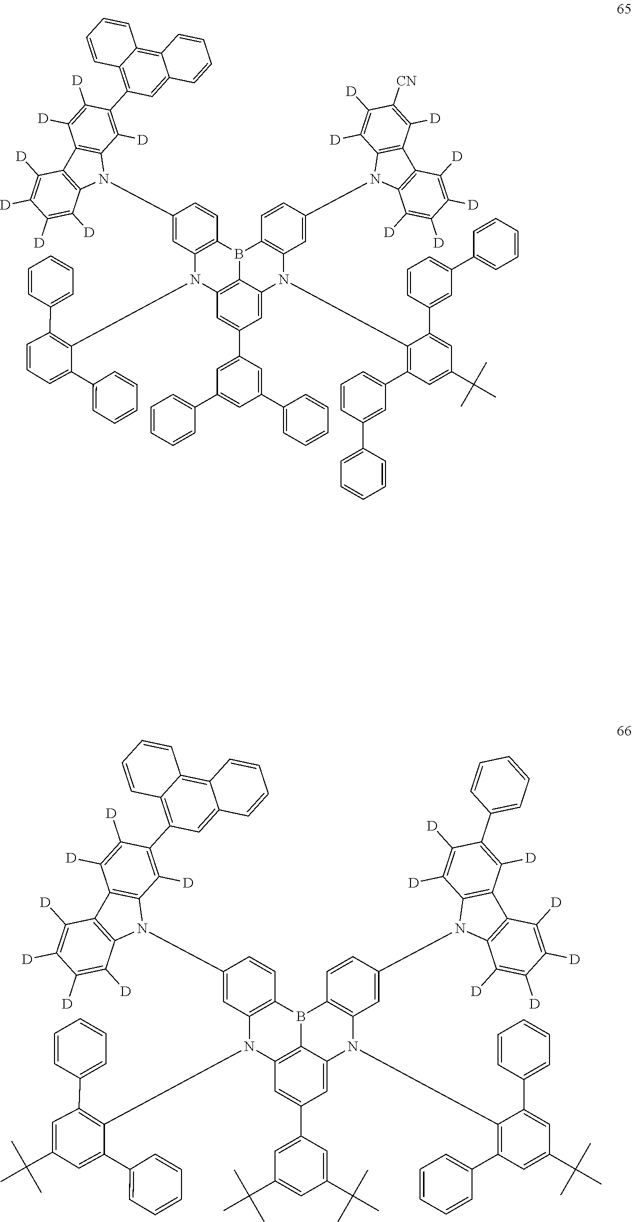

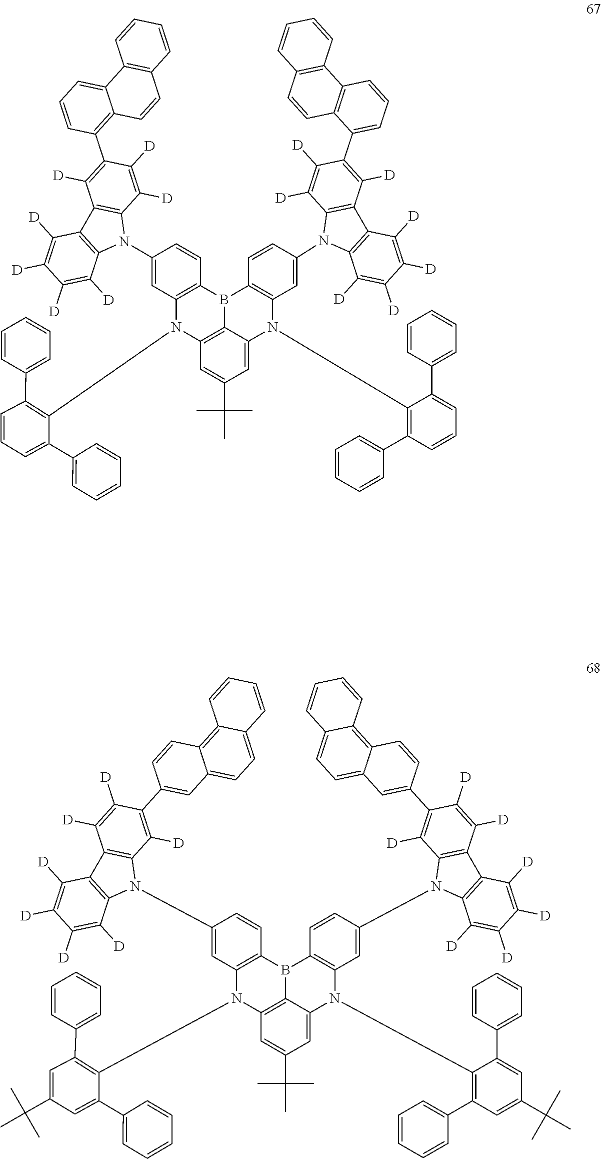

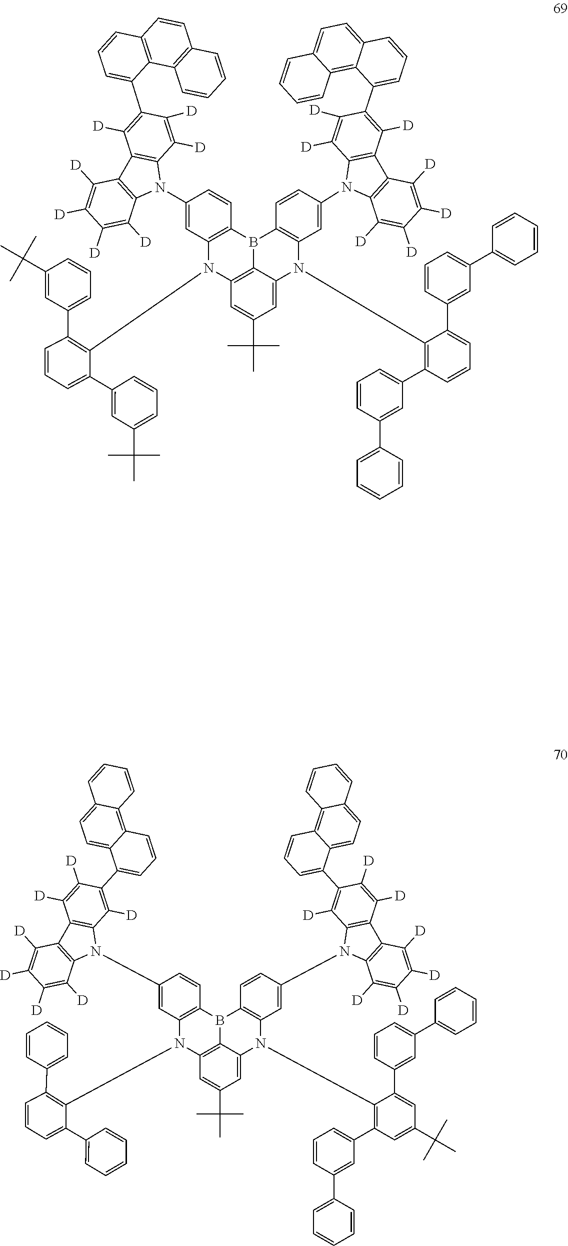

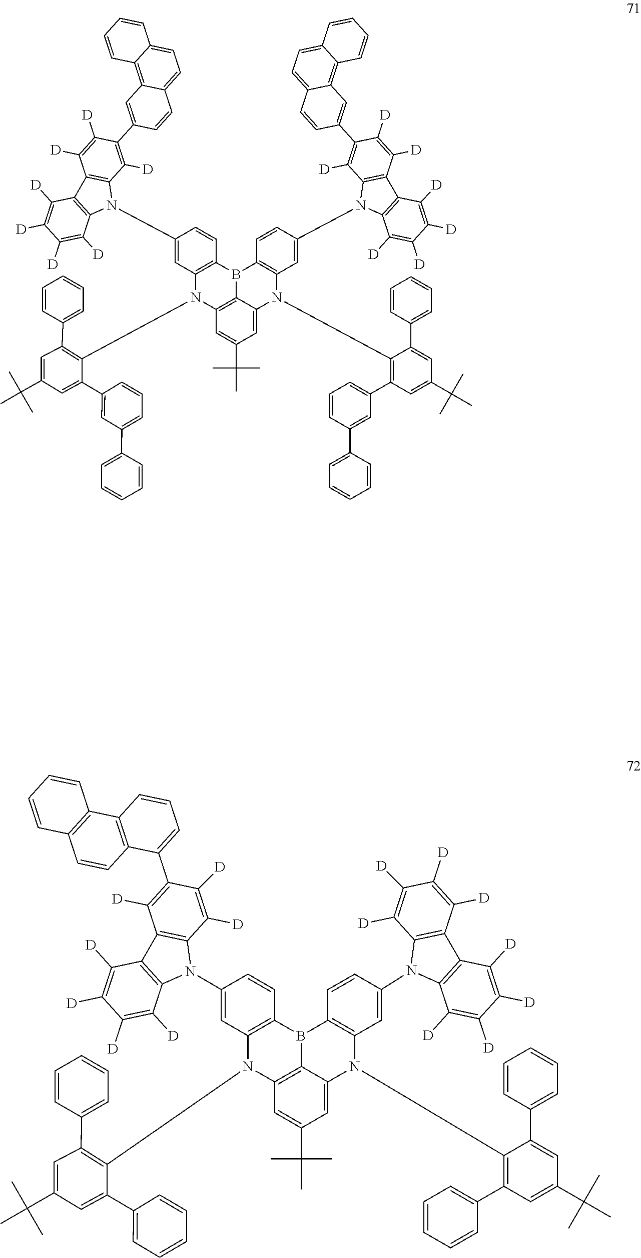

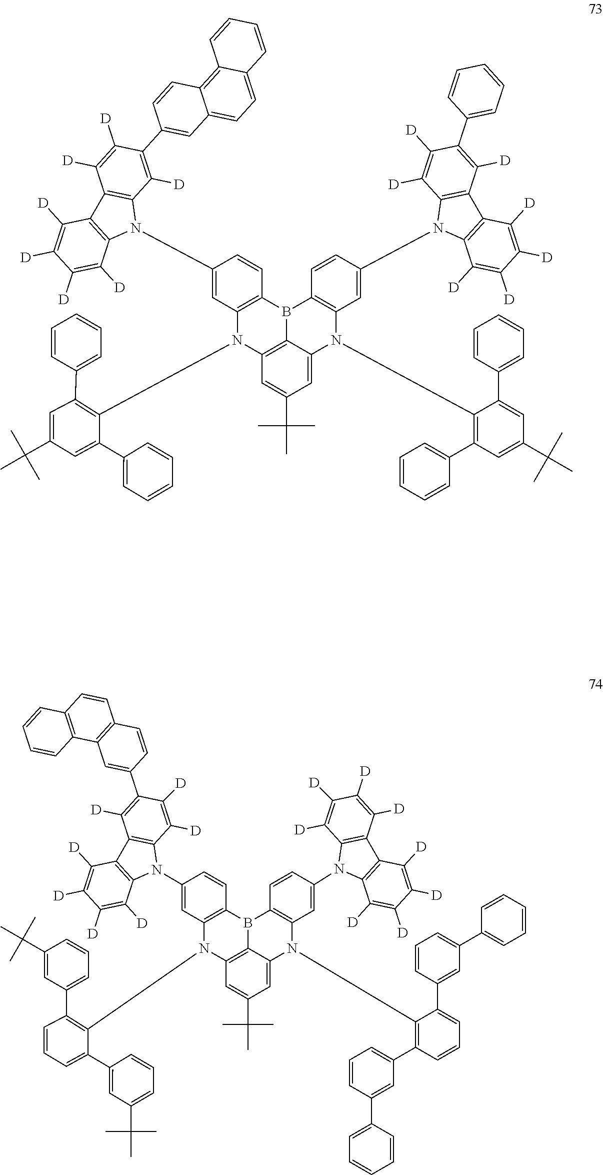

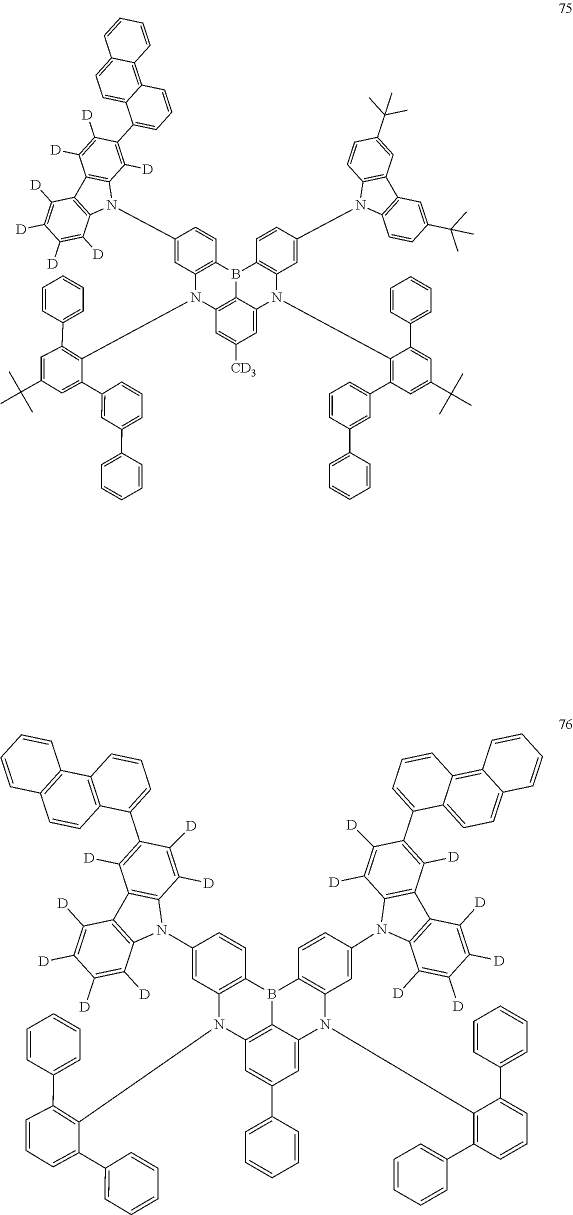

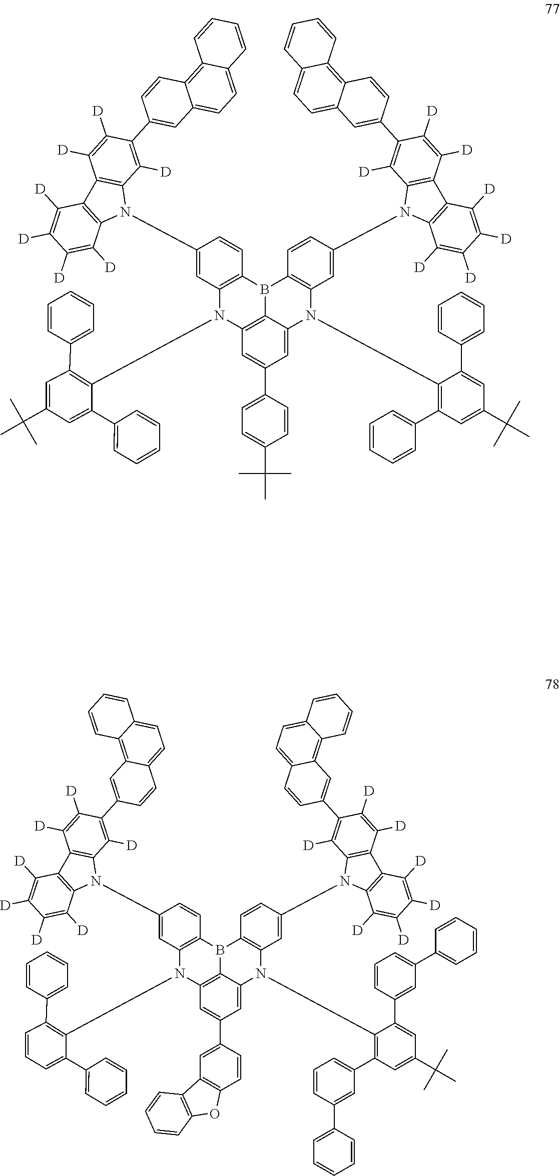

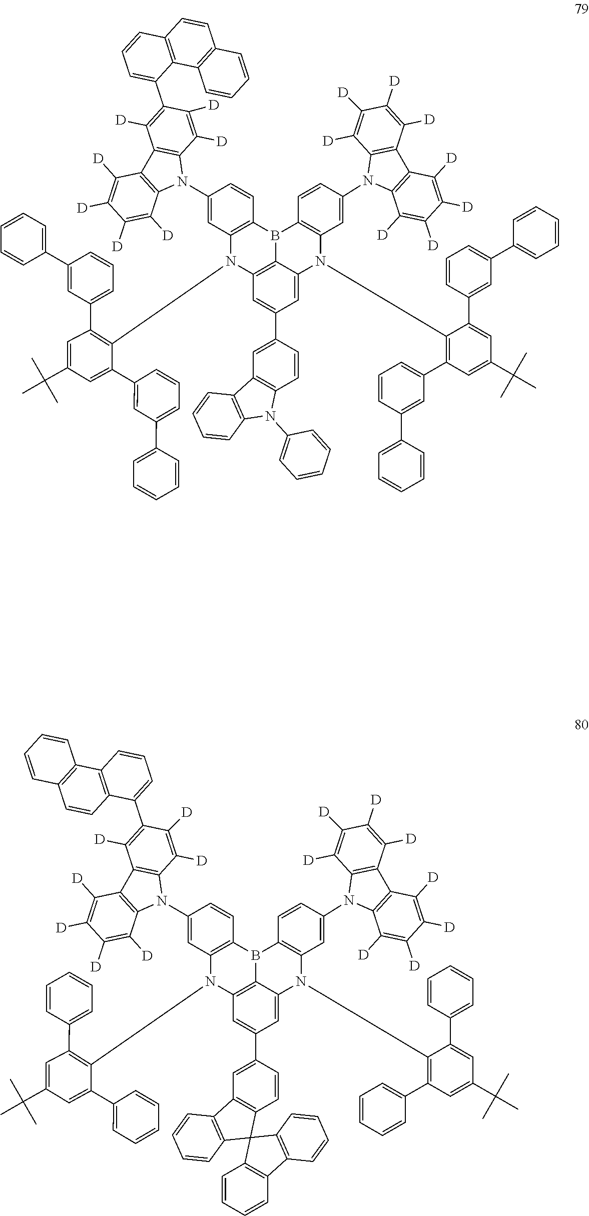

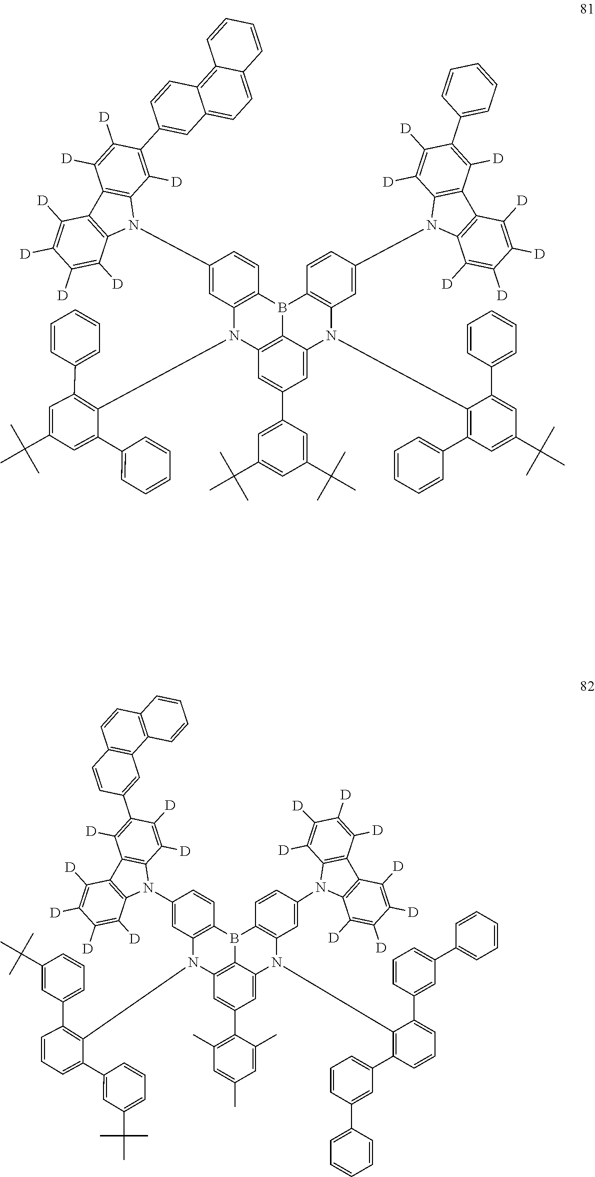

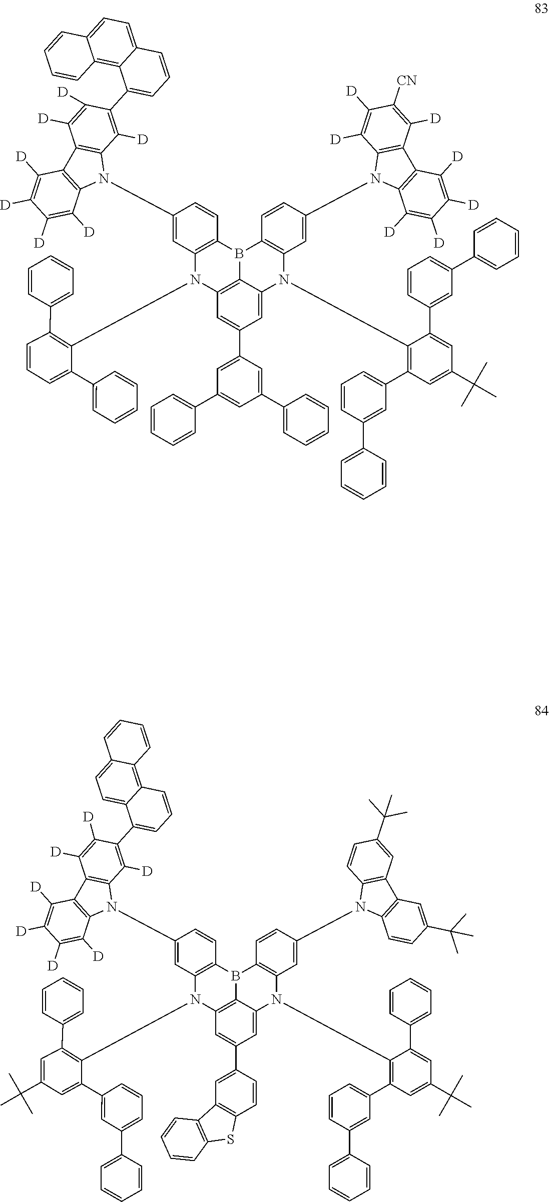

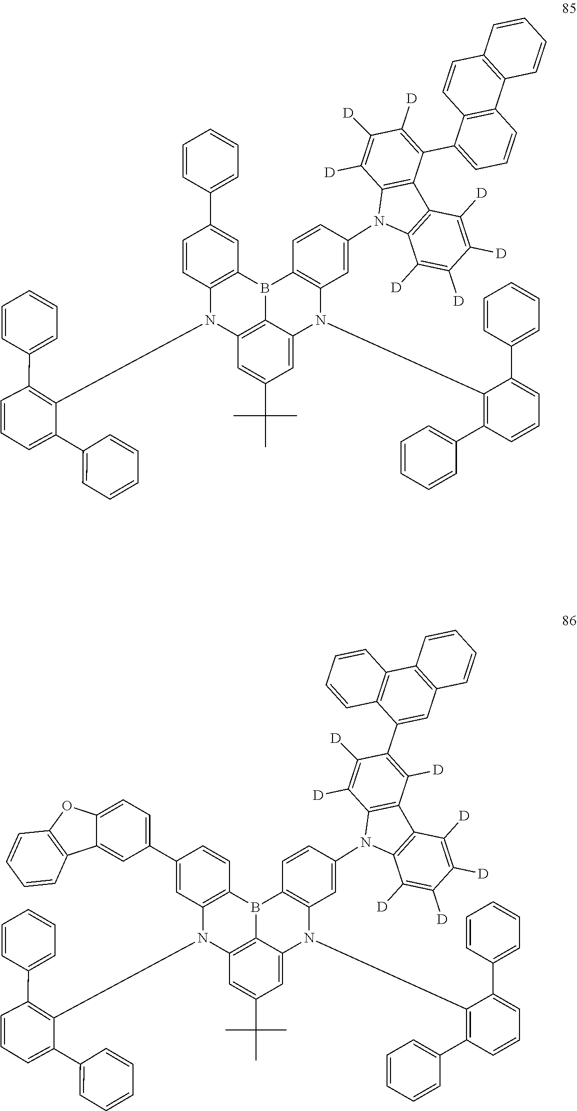 [SMILES: [2H]c1c([2H])c([2H])c2c(c1[2H])c1c(-c3cccc4c3ccc3ccccc34)c([2H])c([2H])c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1ccccc1 ; [2H]c1c([2H])c([2H])c2c(c1[2H])c1c([2H])c(-c3cc4ccccc4c4ccccc34)c([2H])c([2H])c1n2-c1ccc2c(c1)N(c1c(-c3ccccc3)cccc1-c1ccccc1)c1cc(C(C)(C)C)cc3c1B2c1ccc(-c2ccc4oc5ccccc5c4c2)cc1N3c1c(-c2ccccc2)cccc1-c1ccccc1]

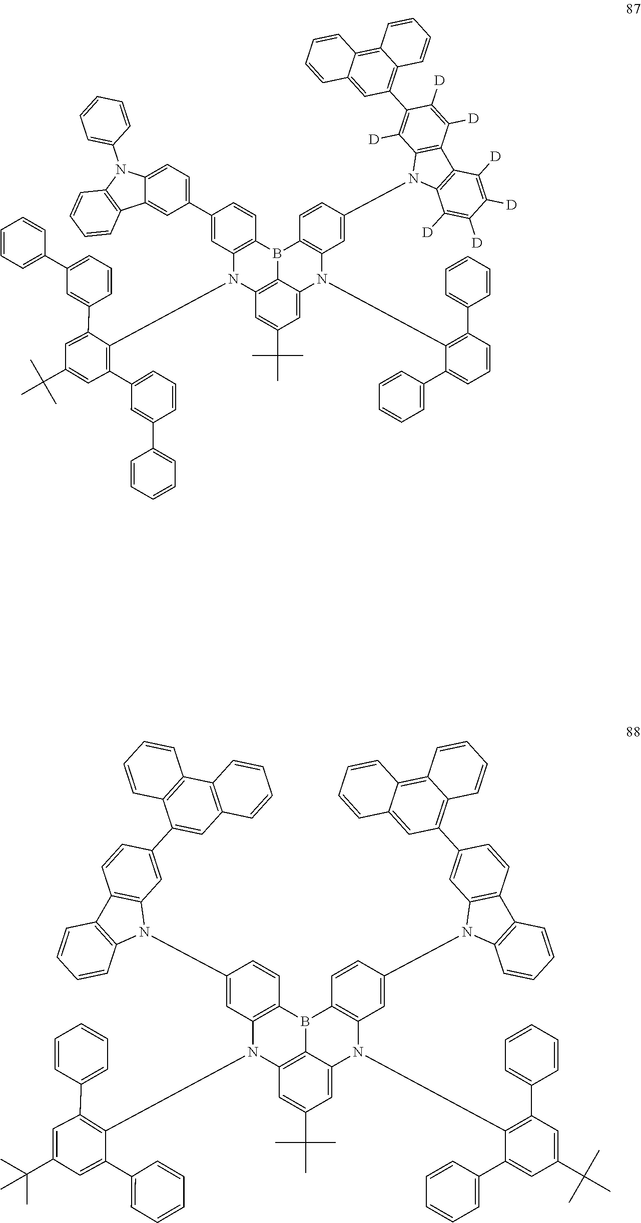 [SMILES: [2H]c1c([2H])c([2H])c2c(c1[2H])c1c([2H])c([2H])c(-c3cc4ccccc4c4ccccc34)c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2cccc(-c3ccccc3)c2)cc(C(C)(C)C)cc1-c1cccc(-c2ccccc2)c1 ; CC(C)(C)c1cc(-c2ccccc2)c(N2c3cc(-n4c5ccccc5c5ccc(-c6cc7ccccc7c7ccccc67)cc54)ccc3B3c4ccc(-n5c6ccccc6c6ccc(-c7cc8ccccc8c8ccccc78)cc65)cc4N(c4c(-c5ccccc5)cc(C(C)(C)C)cc4-c4ccccc4)c4cc(C(C)(C)C)cc2c43)c(-c2ccccc2)c1]

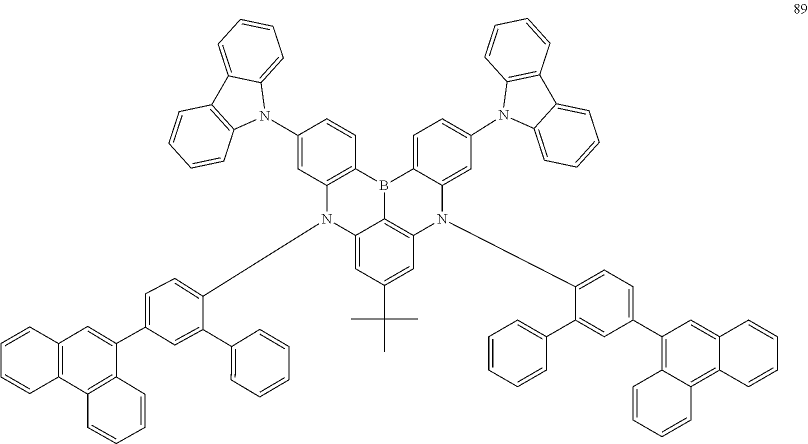 [SMILES: CC(C)(C)c1cc2c3c(c1)N(c1ccc(-c4cc5ccccc5c5ccccc45)cc1-c1ccccc1)c1cc(-n4c5ccccc5c5ccccc54)ccc1B3c1ccc(-n3c4ccccc4c4ccccc43)cc1N2c1ccc(-c2cc3ccccc3c3ccccc23)cc1-c1ccccc1]

The fused polycyclic compound of one or more embodiments may be to emit blue light. For example, the fused polycyclic compound of one or more embodiments may be a light emitting material having a light emmission center wavelength in a wavelength region of about 430 nm to about 490 nm. For example, the fused polycyclic compound of one or more embodiments may be a light emitting material having a light emission center wavelength in a wavelength region of about 450 nm to about 470 nm. The light emitting element ED including the fused polycyclic compound of one or more embodiments may be to emit blue light. For example, in some embodiments, the third light emitting element ED-3 (see FIG. 2) which emits blue light may include the fused polycyclic compound of one or more embodiments.

In one or more embodiments, the light emitting layer EML may include the fused polycyclic compound of one or more embodiments as a dopant. The fused polycyclic compound of one or more embodiments may be a Thermally Activated Delayed Fluorescence (TADF) material. The fused polycyclic compound of one or more embodiments may be a Thermally Activated Delayed Fluorescence material of a multiple resonance (MR) type or kind. The fused polycyclic compound of one or more embodiments may be to emit light by converting a triplet exciton into a singlet exciton by a Reverse Inter System Crossing (RISC) mechanism.

The fused polycyclic compound of one or more embodiments includes, as a central structure, a 5-ring fused ring system containing two nitrogen atoms and one boron atom as ring-forming atoms, and may include a phenanthryl moiety and a carbazole moiety bonded to the central structure. The light emitting element ED including the fused polycyclic compound of one or more embodiments which includes a phenanthryl moiety and a carbazole moiety may exhibit low-driving voltage, high-efficiency, and long-lifespan properties.

The energy level of a T1 state of the phenanthryl moiety and the energy level of an S1 state of the fused polycyclic compound are quasi-degenerated states, and the fused polycyclic compound of one or more embodiments may exhibit desirable properties that facilitate RISC. In one or more embodiments, the fused polycyclic compound of one or more embodiments including the phenanthryl moiety may have energy levels of higher-order triplet states (Tn states) that are close to each other, so that RISC may be accelerated. The energy level of the higher-order triplet state (Tn state) may move to the energy level of the S1 state or to an energy level lower than the energy level of the S1 state, and thus, may become close to each other. When the energy levels of the triplet states are close to each other, a triplet exciton lifetime (Tau) may be reduced by promoting spin-vibronic coupling (SVC) in a RISC process. In addition, when the energy levels of the triplet states are close to each other, the movement/transition between triplet states is facilitated, and the RISC in which an exciton in the T1 state is changed to be in the S1 state via a T2 state or a T3 state may be accelerated.

The fused polycyclic compound including the carbazole moiety may exhibit properties that facilitate the matching of a host material and a Highest Occupied Molecular Orbital (HOMO) energy level of the fused polycyclic compound. A host material having a wide band gap and a high T1 low energy level is essential for a light emitting element which emits thermally activated delayed fluorescence and blue light while utilizing a triplet exciton, and such a host material mostly includes a carbazole group. The host material including a carbazole group has a relatively deeper HOMO energy level, and when a dopant material has a shallower HOMO energy level than that of the host material, a trap assistant recombination (TAR) phenomenon, in which an emitter (e.g., dopant) traps a hole and directly performs charge recombination to generate an exciton, is promoted. Such a process increases the triplet exciton concentration and causes the degradation in efficiency and lifespan of a light emitting element. A triplet exciton of a high concentration stays in an excited state for a long period of time, and thus, causes the decomposition of a compound, and generates a hot exciton through triplet-triplet annihilation (TTA), thereby destroying surrounding compounds, which results in degrading the lifespan of a light emitting element. In contrast, the fused polycyclic compound including the carbazole moiety facilitates the matching of a host material and a HOMO energy level of the fused polycyclic compound, which may contribute to improving the efficiency and lifespan of the light emitting element ED.

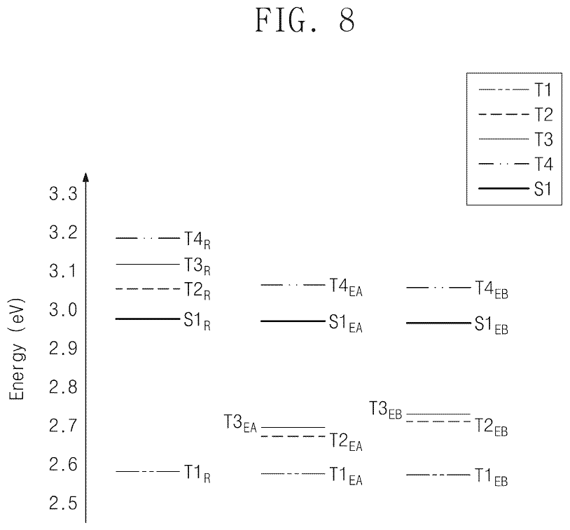

FIG. 8 shows energy levels of S1, and T1 to T4 states in Comparative Example Compounds and in the fused polycyclic compound of one or more embodiments. S1_{R}, T1_{R}, T2_{R}, T3_{R}, and T4_{R} represent energy levels of Comparative Example Compound CX1. S1_{R} represents the energy level of an S1 state of Comparative Example Compound CX1. T1_{R}, T2_{R}, T3_{R}, and T4_{R} respectively represent the energy levels of T1, T2, T3, and T4 states of Comparative Example Compound CX1.

S1_{EA}, T1_{EA}, T2_{EA}, T3_{EA}, and T4_{EA} represent energy levels of Compound 88. S1EA represents the energy level of an S1 state of Compound 88. T1_{EA}, T2_{EA}, T3_{EA}, and T4_{EA} respectively represent the energy levels of T1, T2, T3, and T4 states of Compound 88.

S1_{EB}, T1_{EB}, T2_{EB}, T3_{EB}, and T4_{EB} represent energy levels of Compound 89. S1_{EB} represents the energy level of an S1 state of Compound 89. T1_{EB}, T2_{EB}, T3_{EB}, and T4_{EB} respectively represent the energy levels of T1, T2, T3, and T4 states of Compound 89. Compounds 88 and 89 are the fused polycyclic compounds of one or more embodiments presented in Compound Group 1 described above.

### Comparative Example Compound CX1, Compound 88, and Compound 89

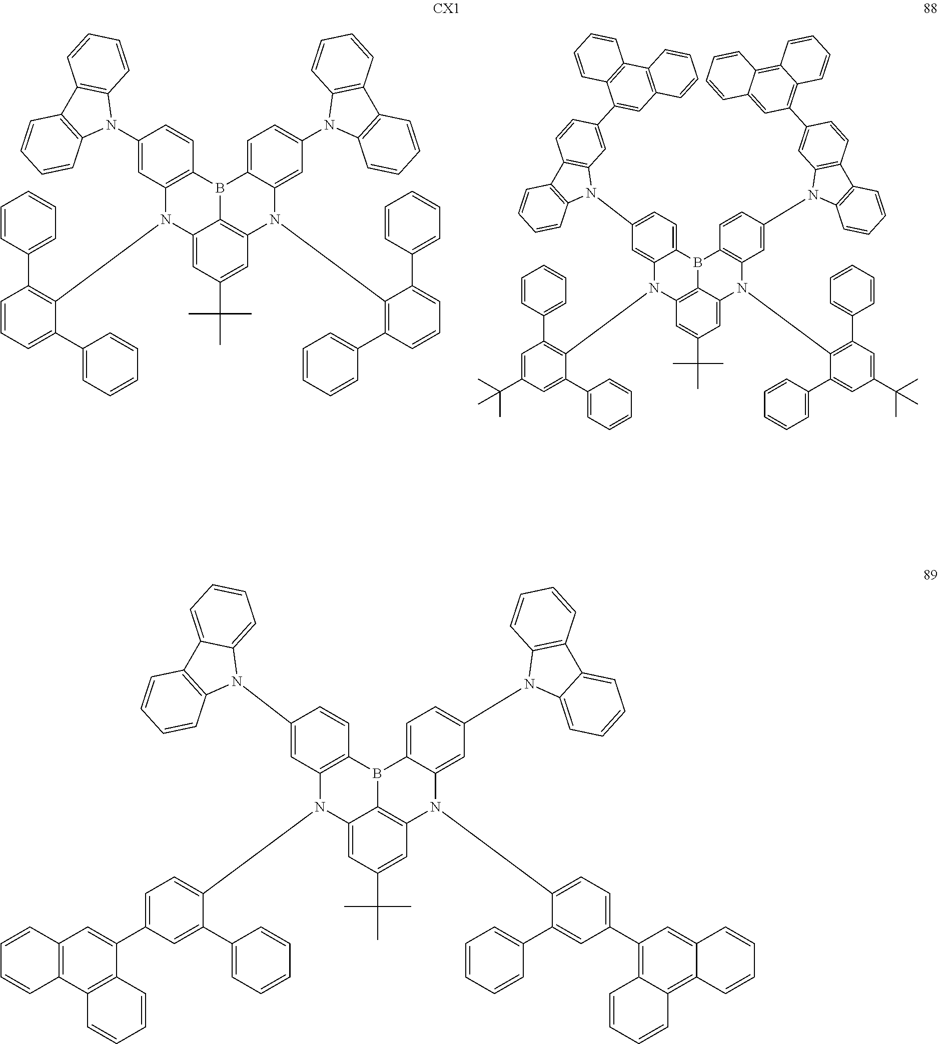

Referring to FIG. 8, it can be seen that in Compound 88, the T2 and T3 state energy levels T2_{EA} and T3_{EA} are close to the T1 state energy level T1_{EA}. It can be seen that in Compound 89, the T2 and T3 state energy levels T2_{EB} and T3_{EB} are close to the T1 state energy level T1_{EB}. In addition, it can be seen that compared to the T4 state energy level T4R of Comparative Example Compound CX1, the T4 state energy levels T4_{EA} and T4_{EB} of Compounds 88 and 89, respectively, are close to the S1 state energy levels S1_{EA} and S1_{EB} thereof. Compounds 88 and 89 are the fused polycyclic compounds of one or more embodiments, which include a phenanthryl moiety. Unlike Compounds 88 and 89, Comparative Example Compound CX1 does not include a phenanthryl moiety. Therefore, it can be confirmed that the fused polycyclic compound of one or more embodiments including a phenanthryl moiety has energy levels of the higher-order triplet states that are close to each other, and RISC will be accelerated.

Table 1 shows the evaluation of properties of Comparative Example Compound CX1, Compound 88, and Compound 89, and is the computation/simulation result. In Table 1, HOMO represents a HOMO energy level, and LUMO represents a Lowest Unoccupied Molecular Orbital (LUMO) energy level. S1 (nm) represents a light emission wavelength in the lowest singlet state, and T1 (nm) represents a light emission wavelength in the lowest triplet state. F1 represents an oscillator strength f, and T2-T1 represents an absolute value of a difference in energy level between the T2 state and the T1 state. ΔE_{ST} represents an absolute value of a difference in energy level between the S1 state and the T1 state.

TABLE 1

| | HOMO | LUMO | S1(nm) | F1 | T1(nm) | T2-T1 | ΔE_{ST} |
|---|---|---|---|---|---|---|---|
| Compar- | −5.18 | −1.64 | 417 | 0.313 | 480.1 | 0.469 | 0.391 |
| ative | | | | | | | |
| Example | | | | | | | |
| Compound | | | | | | | |
| CX1 | | | | | | | |
| Compound | −5.24 | −1.7 | 417.6 | 0.246 | 480.4 | 0.095 | 0.388 |
| 88 | | | | | | | |
| Compound | −5.26 | −1.73 | 418.2 | 0.349 | 481.8 | 0.138 | 0.391 |
| 89 | | | | | | | |

Referring to Table 1, it can be seen that Comparative Example Compound CX1, Compound 88, and Compound 89 exhibit similar levels of S1 (nm), T1 (nm), and ΔE_{ST}. As described above, unlike Compounds 88 and 89, Comparative Example Compound CX1 does not include a phenanthryl moiety. Accordingly, it can be seen that the phenanthryl moiety does not affect S1 and T1.

Compared to Comparative Example Compound CX1, Compounds 88 and 89 show deeper HOMO energy levels, which may prevent or reduce an increase in T1 exciton concentration caused by the TAR phenomenon. Compounds 88 and 89 are the fused polycyclic compounds of one or more embodiments, which include a phenanthryl moiety. Therefore, it can be seen that the fused polycyclic compound of one or more embodiments including a phenanthryl moiety will contribute to improving the lifespan of the light emitting element ED.

In one or more embodiments, the light emitting layer EML includes the fused polycyclic compound of one or more embodiments, and may further include at least one selected from among the second to fourth compounds. In some embodiments, the light emitting layer EML may include the second compound represented by Formula HT-1. For example, the second compound may be utilized as a hole transporting host material of the light emitting layer EML.

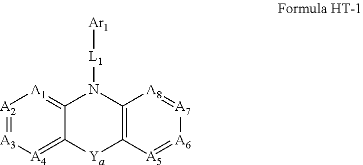

In Formula HT-1, A₁ to A₈ may each independently be N or CR₅₁. For example, in some embodiments, all of A₁ to A₈ may be CR₅₁. In some embodiments, any one selected from among A₁ to A₈ may be N, and the rest may be CRs1.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in some embodiments, L₁ may be a direct linkage, a substituted or unsubstituted phenylene group, a substituted or unsubstituted divalent biphenyl group, a substituted or unsubstituted divalent carbazole group, etc., but embodiments of the present disclosure are not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

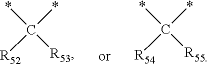

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, in some embodiments, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments of the present disclosure are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, one or more of R₅₁ to R₅₅ may be bonded to an adjacent group to form a ring. For example, in some embodiments, R₅₁ to R₅₅ may each independently be a hydrogen atom or a deuterium atom. In some embodiments, R₅₁ to R₅₅ may each independently be an unsubstituted methyl group or an unsubstituted phenyl group.

In one or more embodiments, the second compound represented by Formula HT-1 may be any one selected from among compounds represented by Compound Group 2. The light emitting layer EML may include at least one selected from among the compounds represented in Compound Group 2 as a hole transporting host material.

### Compound Group 2

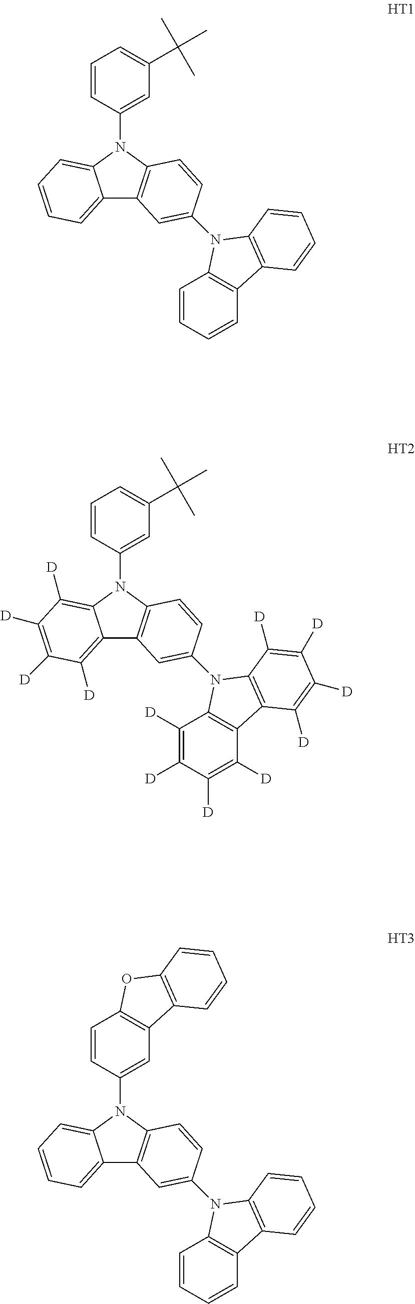 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

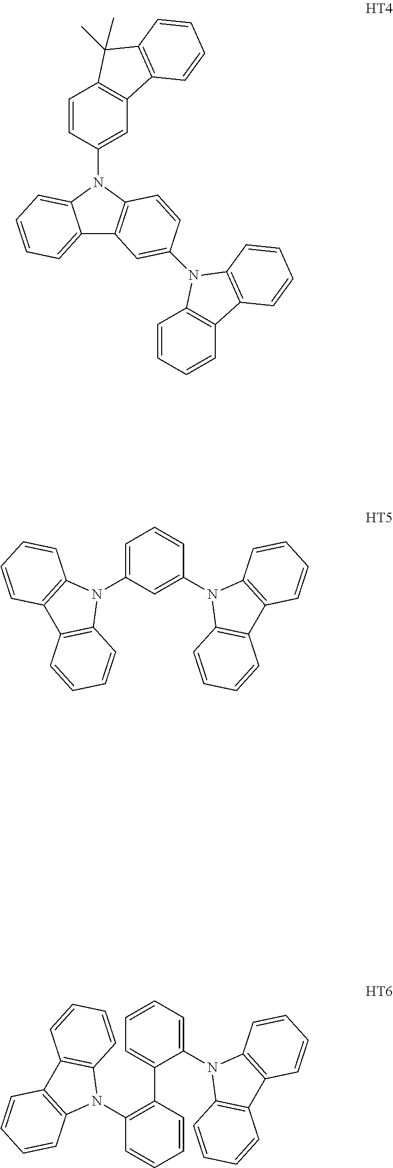 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1]

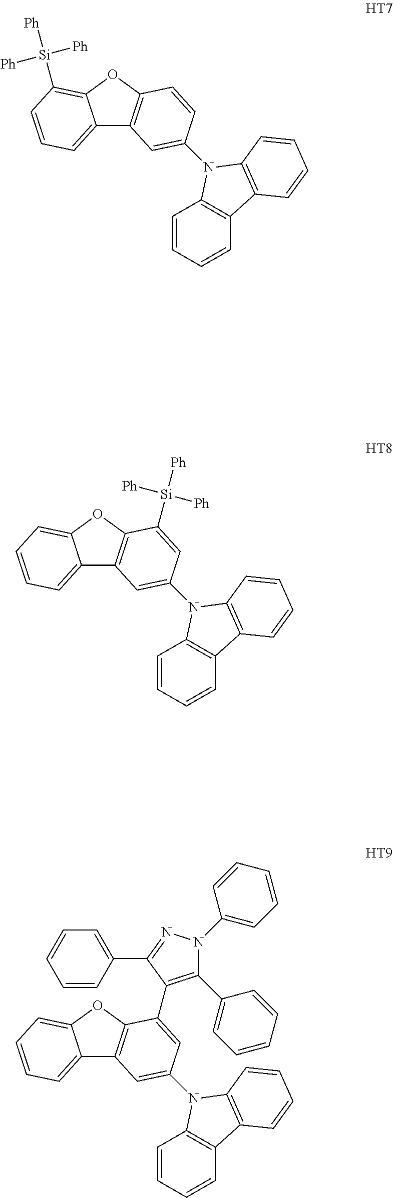 [SMILES: c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

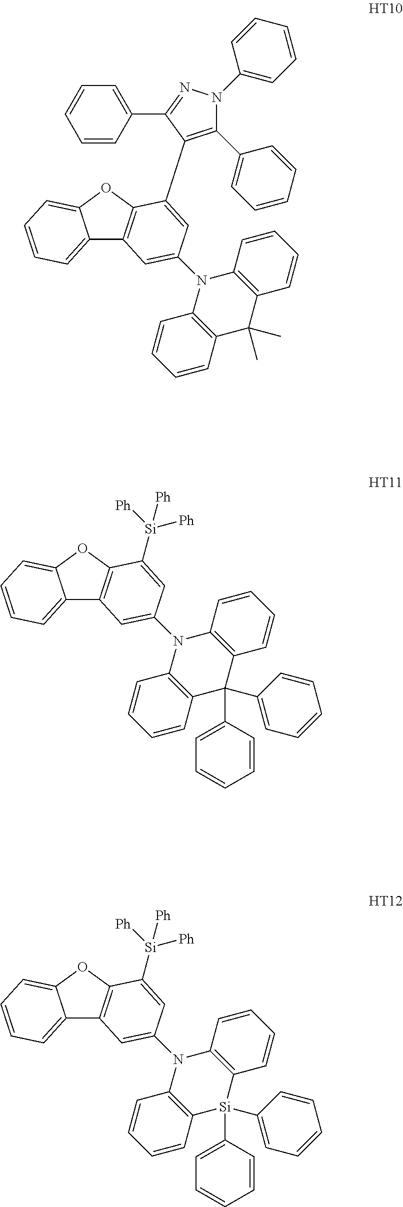 [SMILES: CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

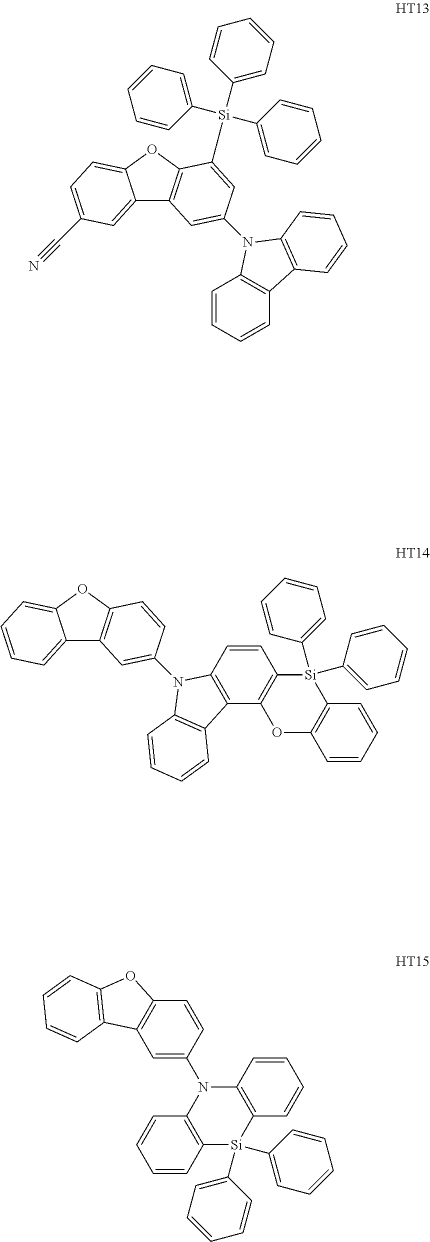 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

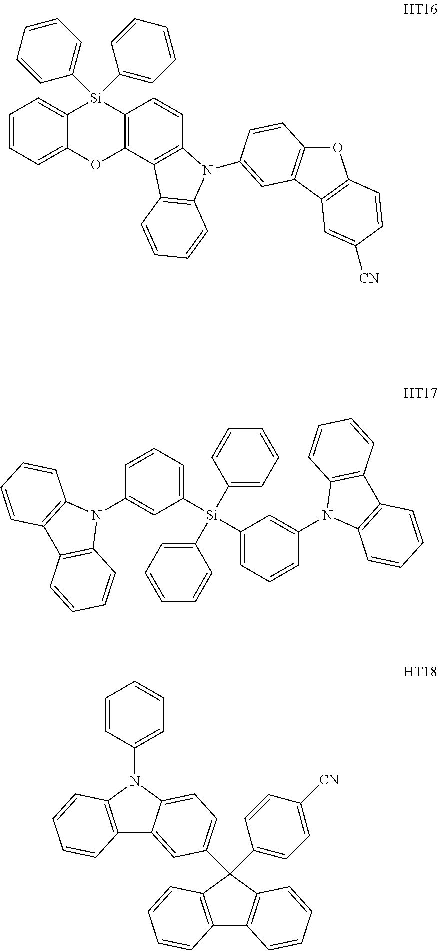 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

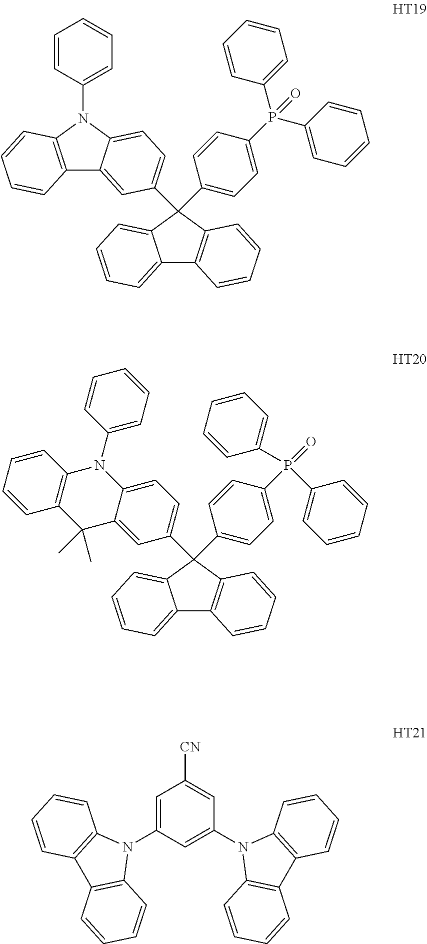 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

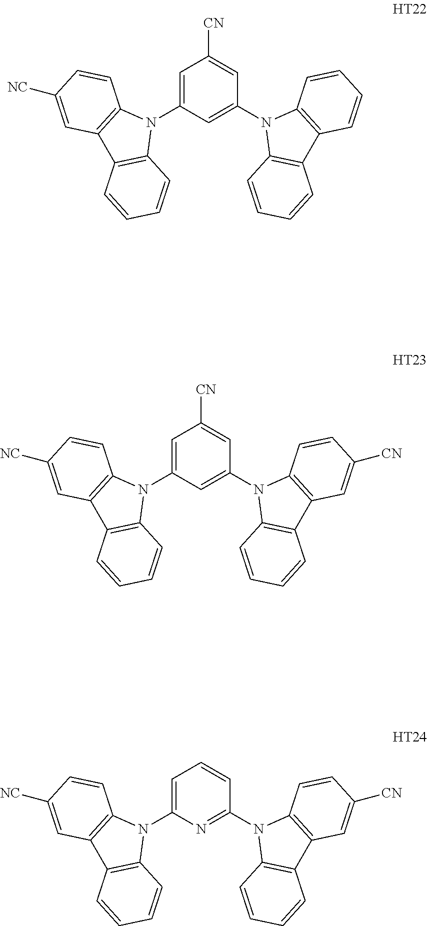 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

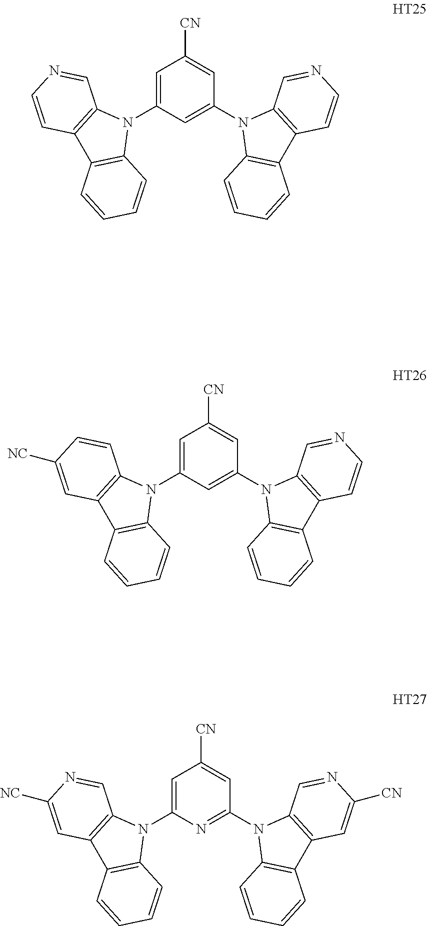 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)nc(-n2c3ccccc3c3cc(C#N)ncc32)c1]

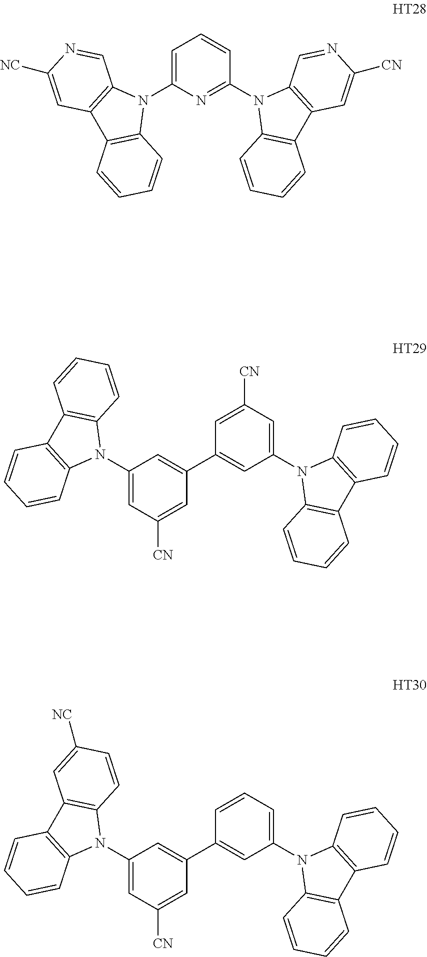 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

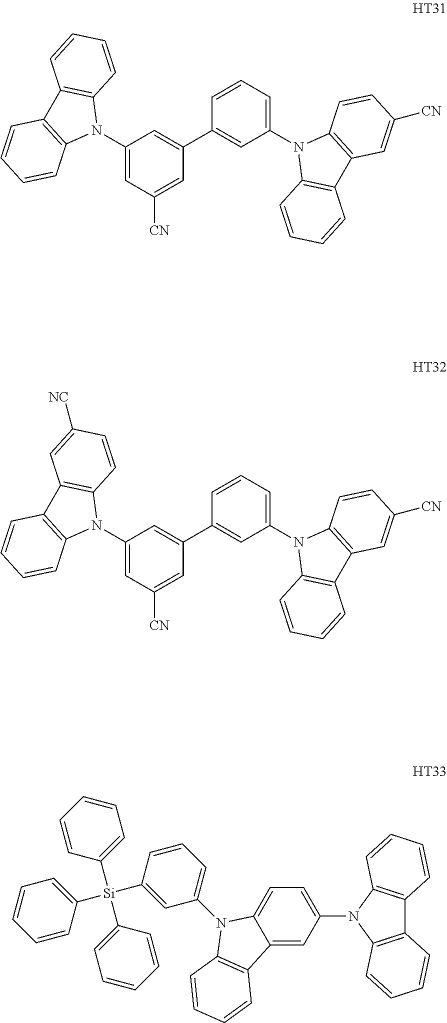 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

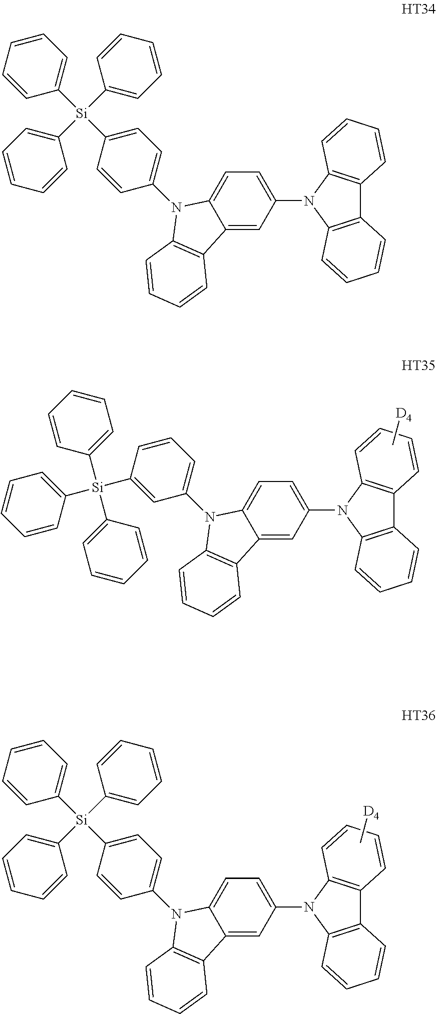

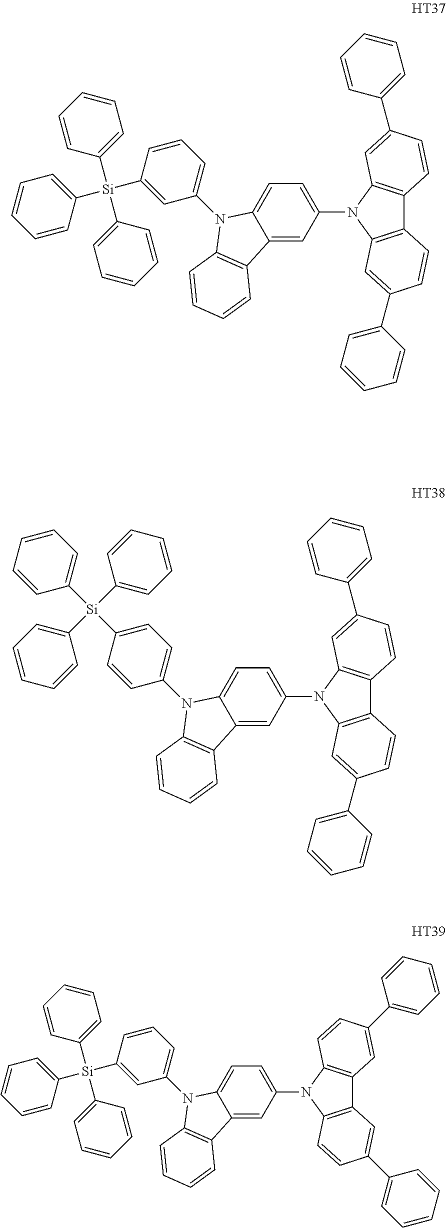 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

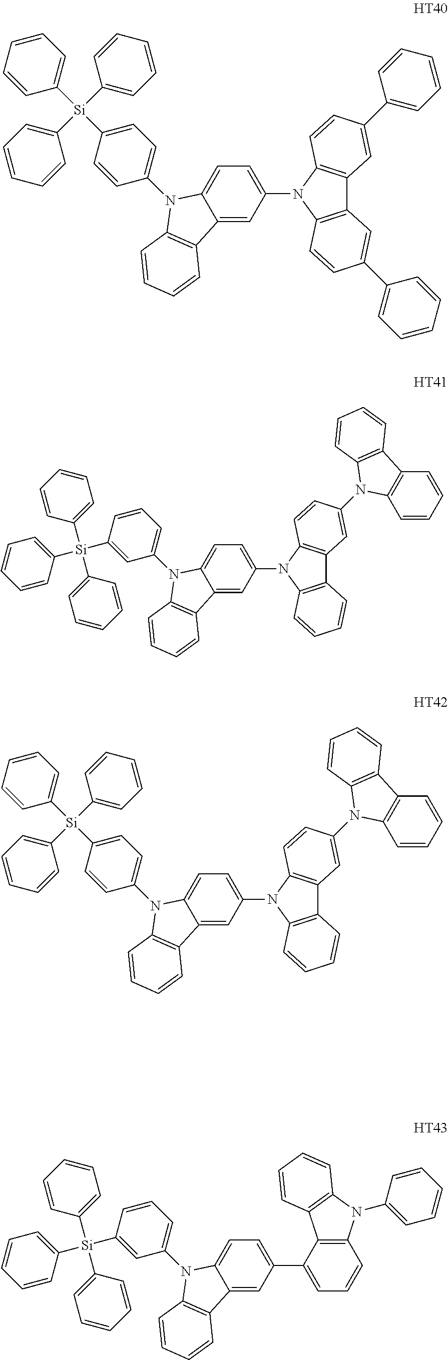 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1]

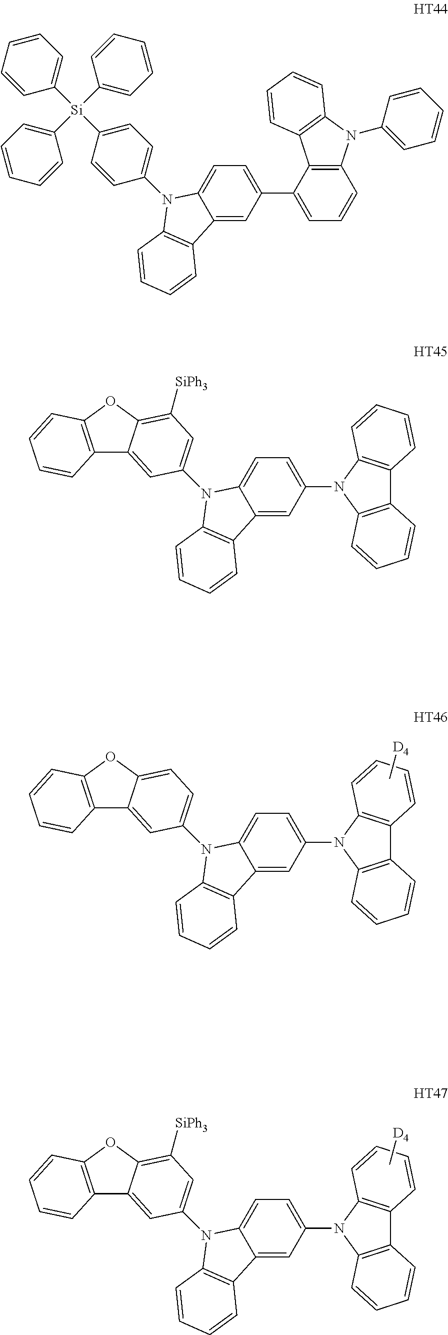

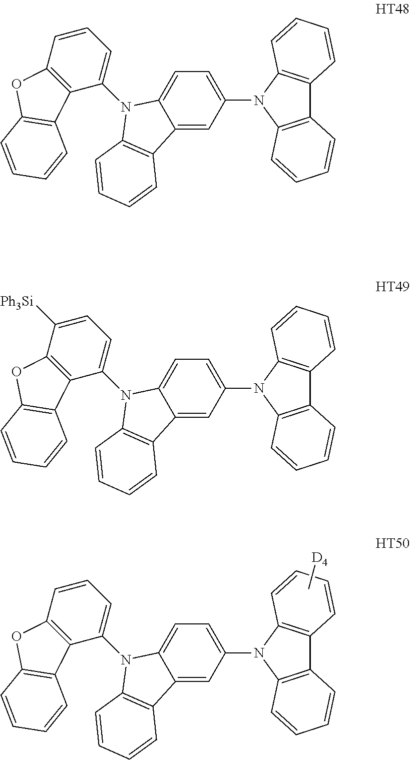

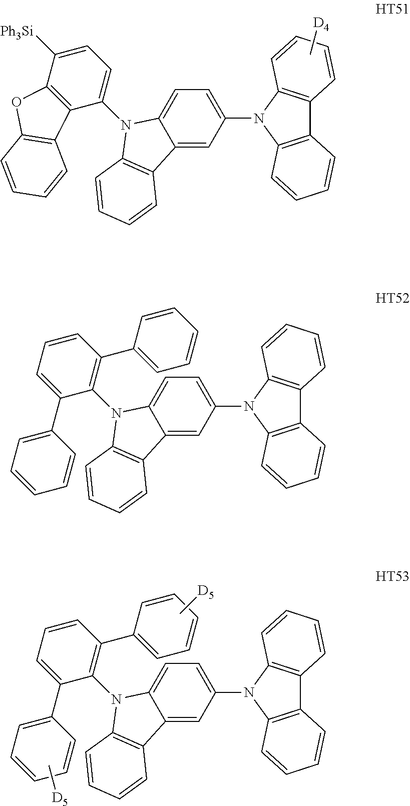

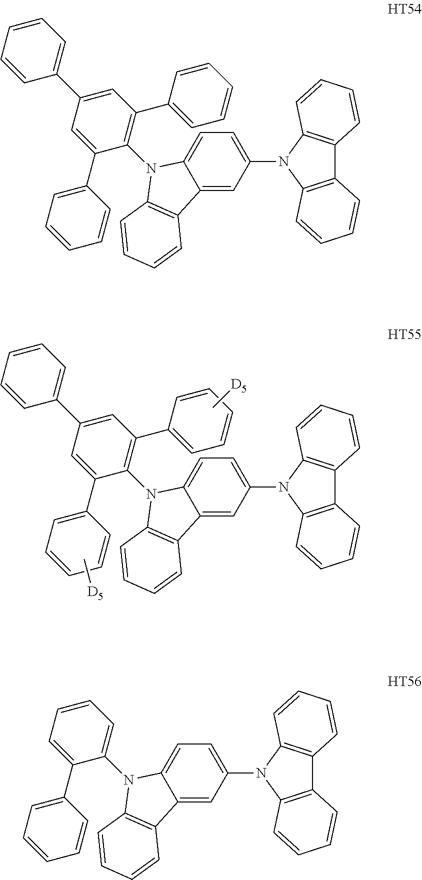

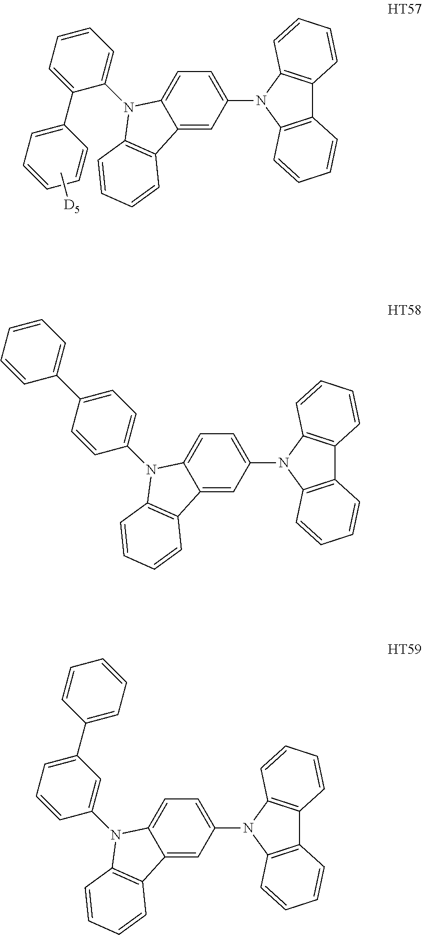

In embodiment compounds presented in Compound Group 2, “D” may refer to a deuterium atom, and “Ph” may refer to a substituted or unsubstituted phenyl group. For example, in some embodiments, in embodiment compounds presented in Compound Group 2, “Ph” may refer to an unsubstituted phenyl group.

In one or more embodiments, the light emitting layer EML may include the third compound represented by Formula ET-1. For example, the third compound may be utilized as an electron transporting host material for the light emitting layer EML.

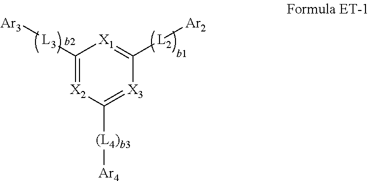

In Formula ET-1, at least one selected from among X₁ to X₃ may be N, and the rest may be CR₅₆. For example, in some embodiments, any one (e.g., only one) selected from among X₁ to X₃ may be N, and the rest may each independently be CR₅₆. In these embodiments, the third compound represented by Formula ET-1 may include a pyridine moiety. In some embodiments, two selected from among X₁ to X₃ may be N, and the rest may be CR₅₆. In these embodiments, the third compound represented by Formula ET-1 may include a pyrimidine moiety. In some embodiments, X₁ to X₃ may all be N. In these embodiments, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂'s to L₄'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light emitting element ED of one or more embodiments may include any one selected from among the compounds in Compound Group 3.

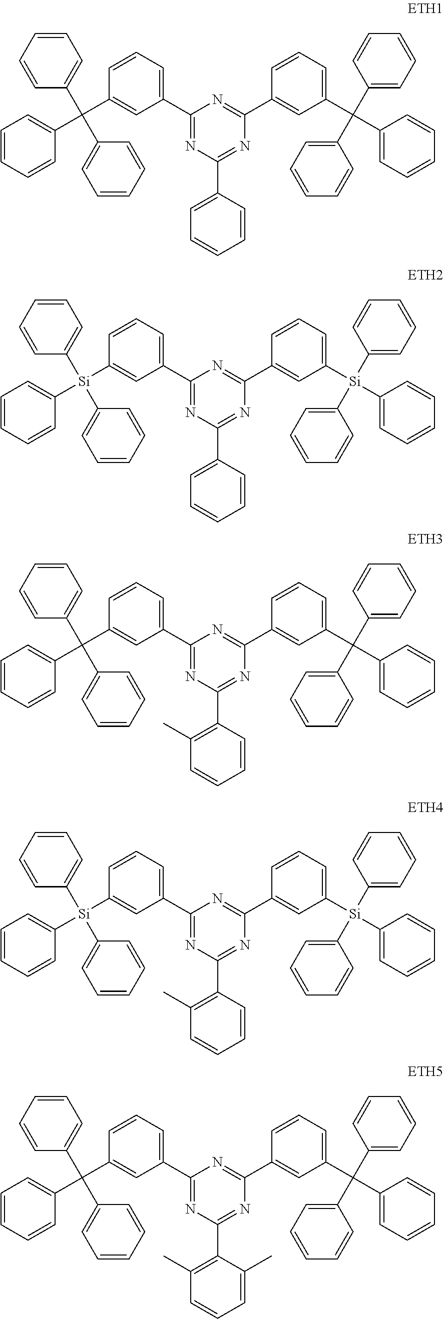

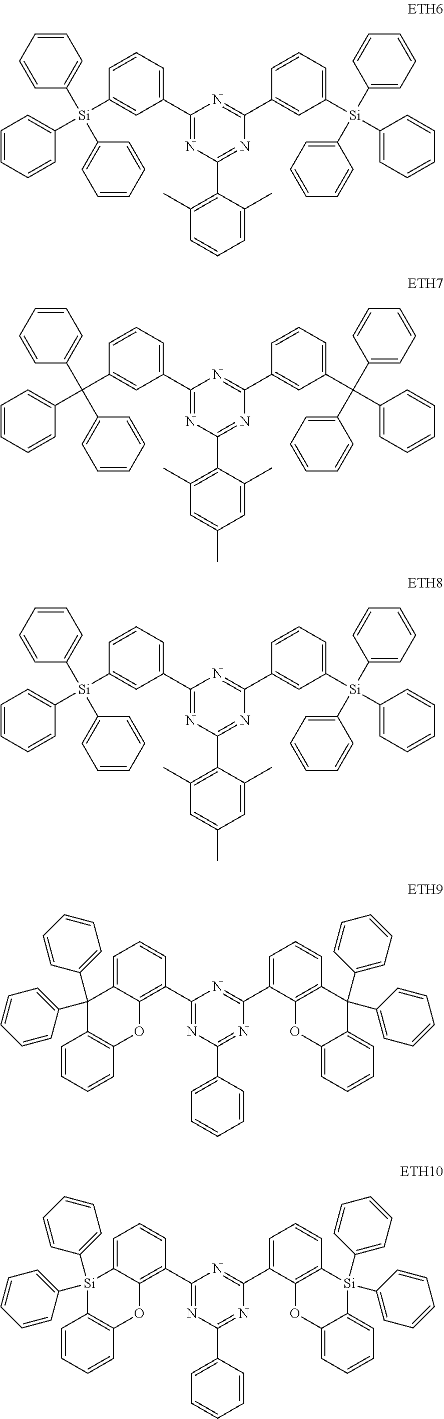

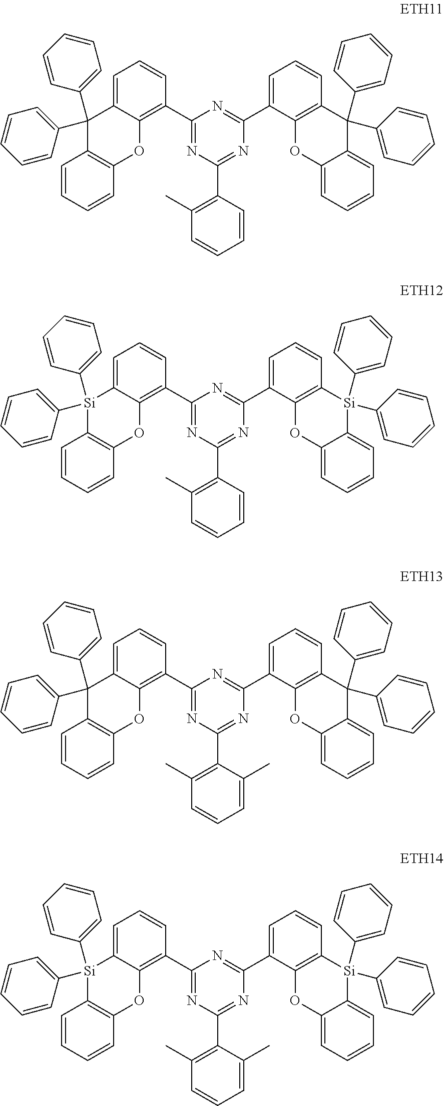 [SMILES: Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

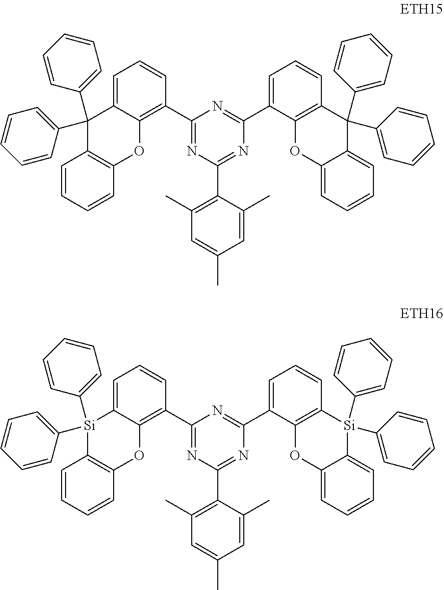 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

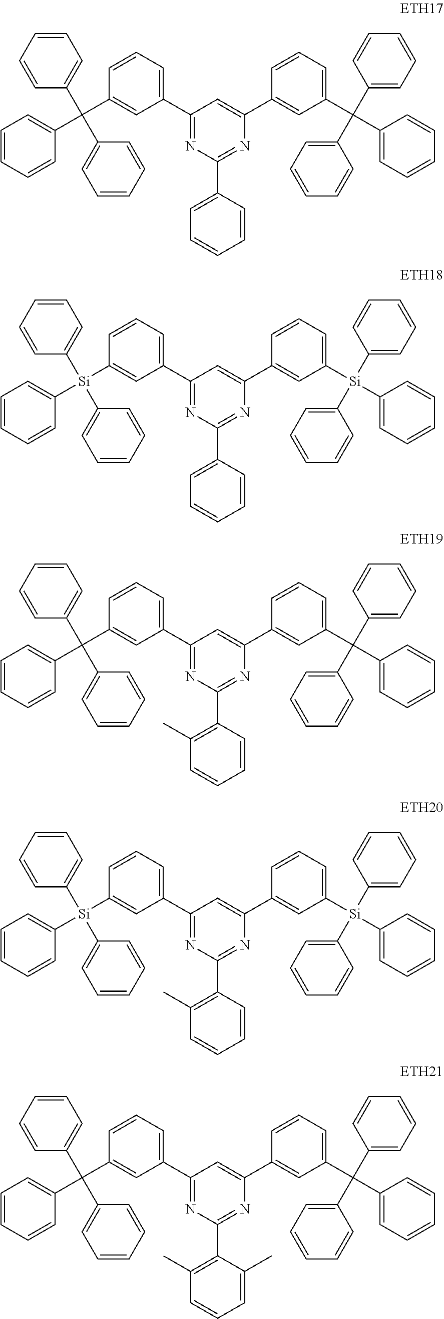

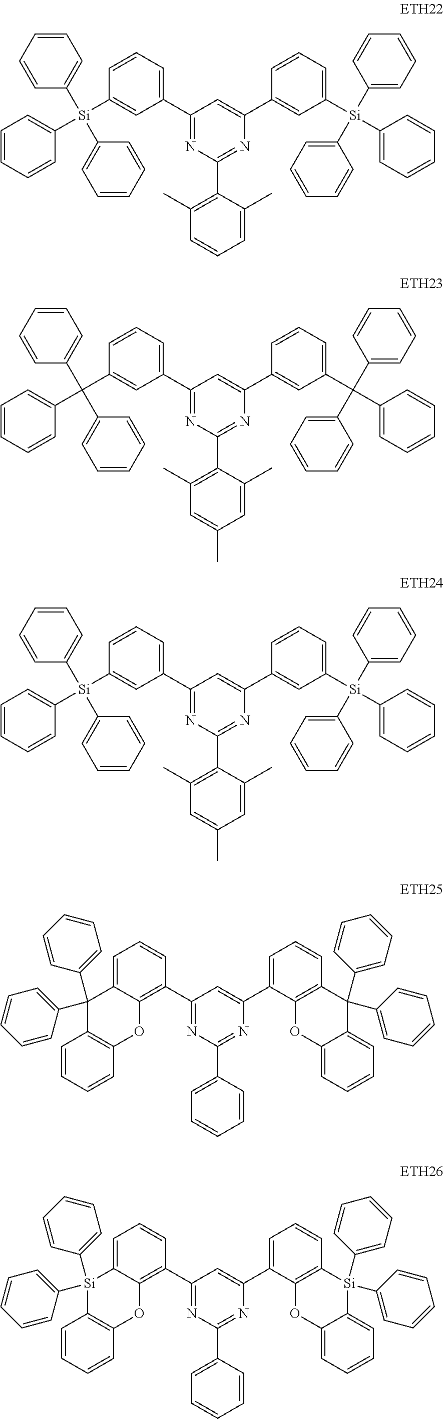

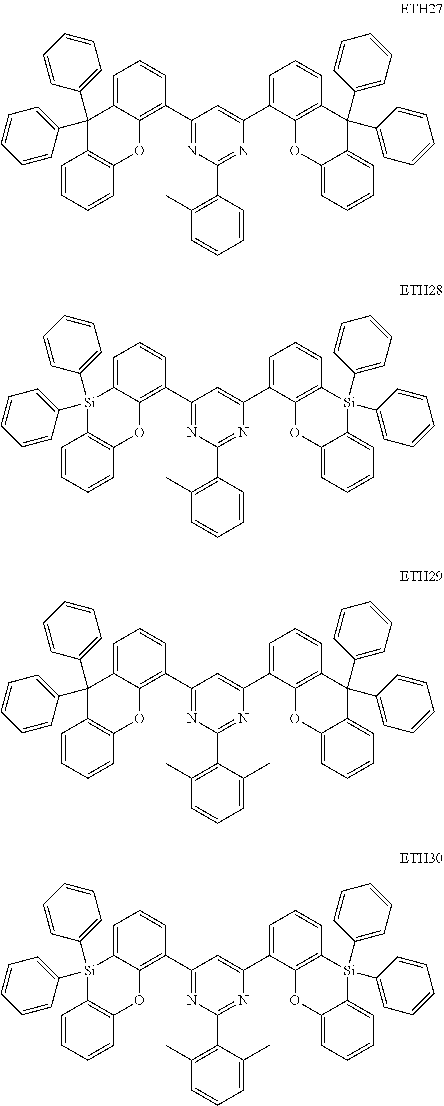 [SMILES: Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

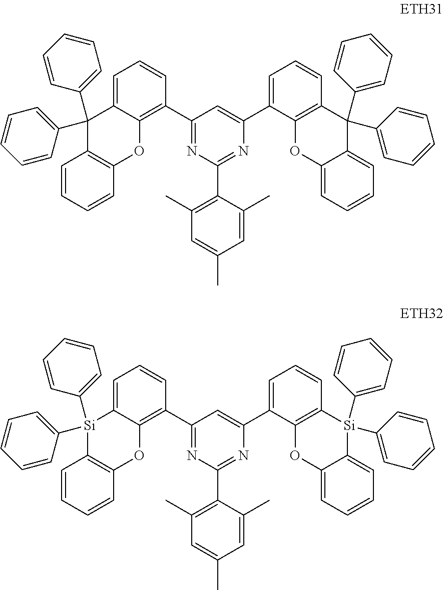 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

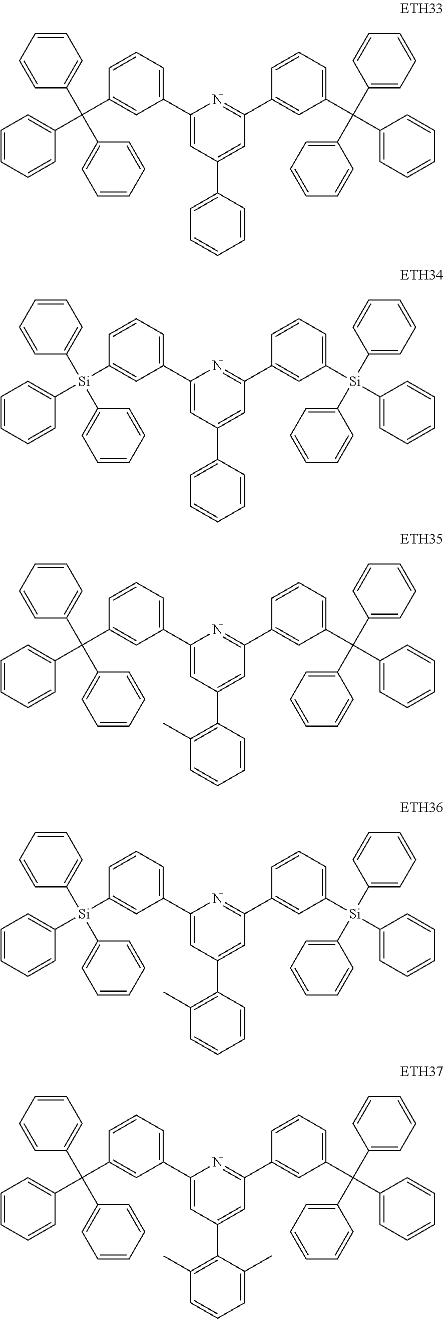

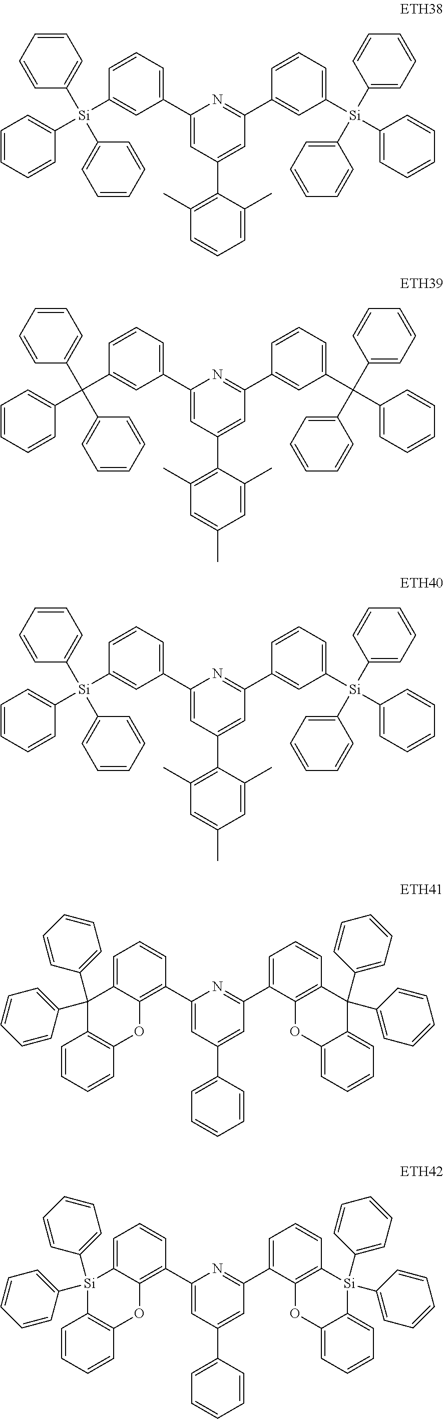

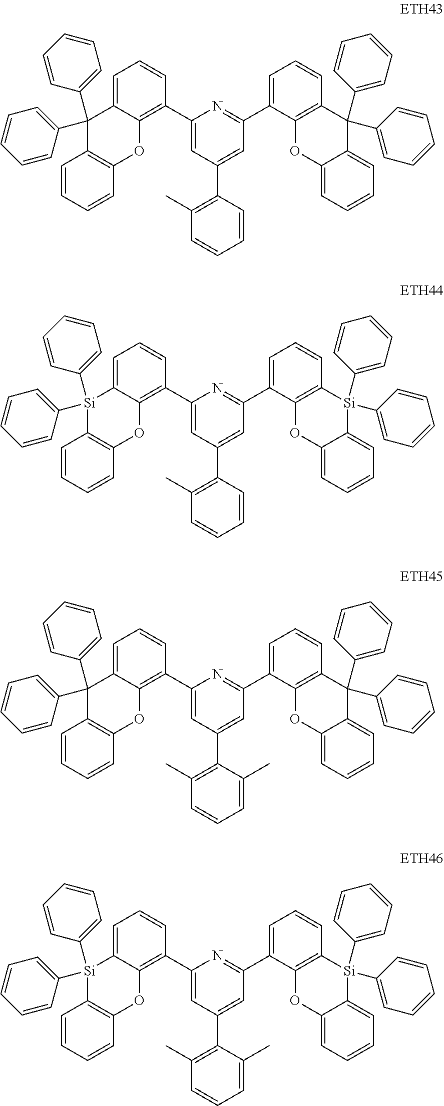 [SMILES: Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

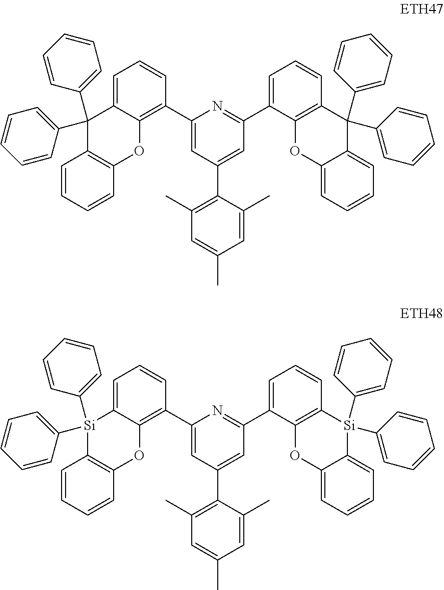 [SMILES: Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

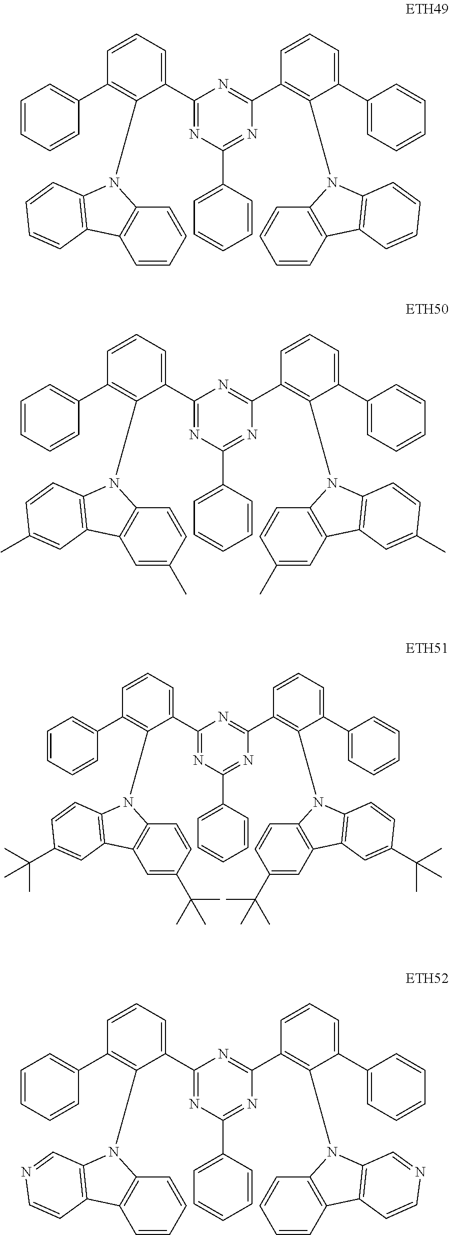

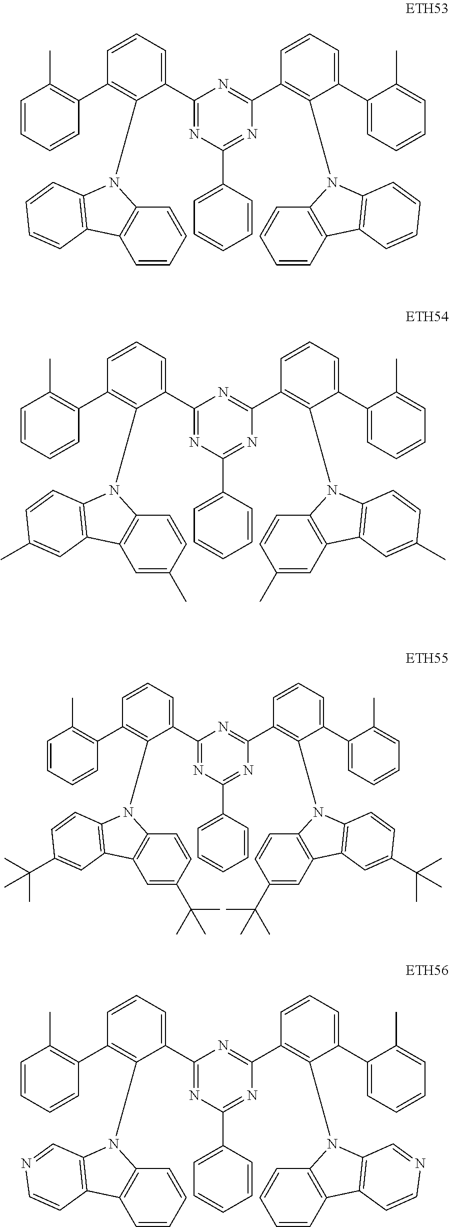

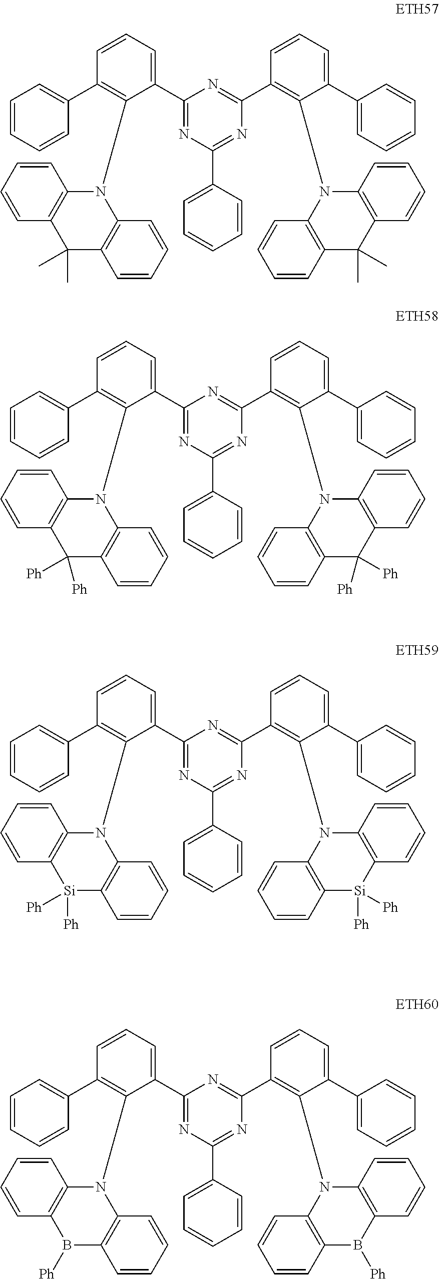

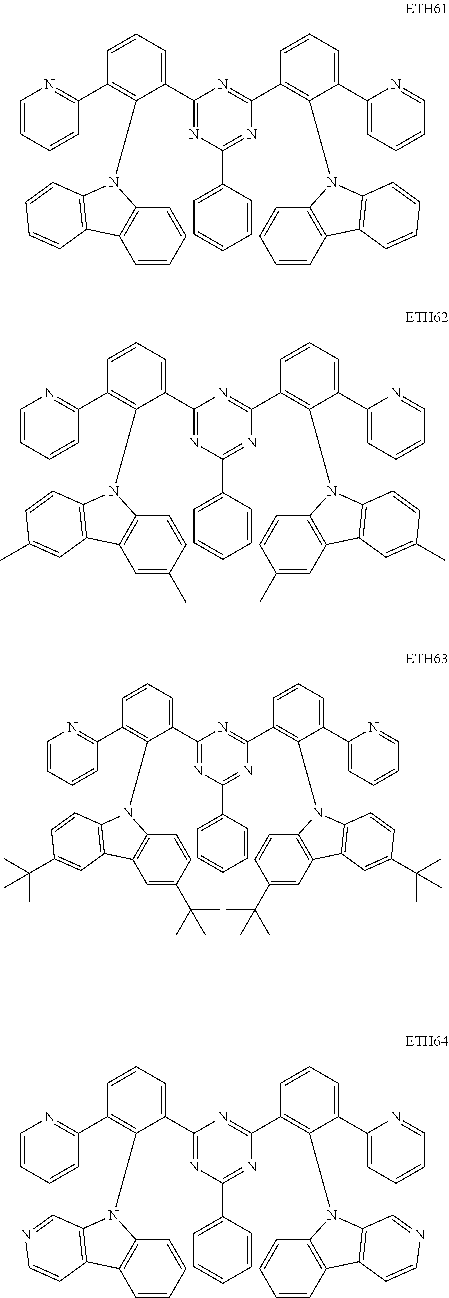

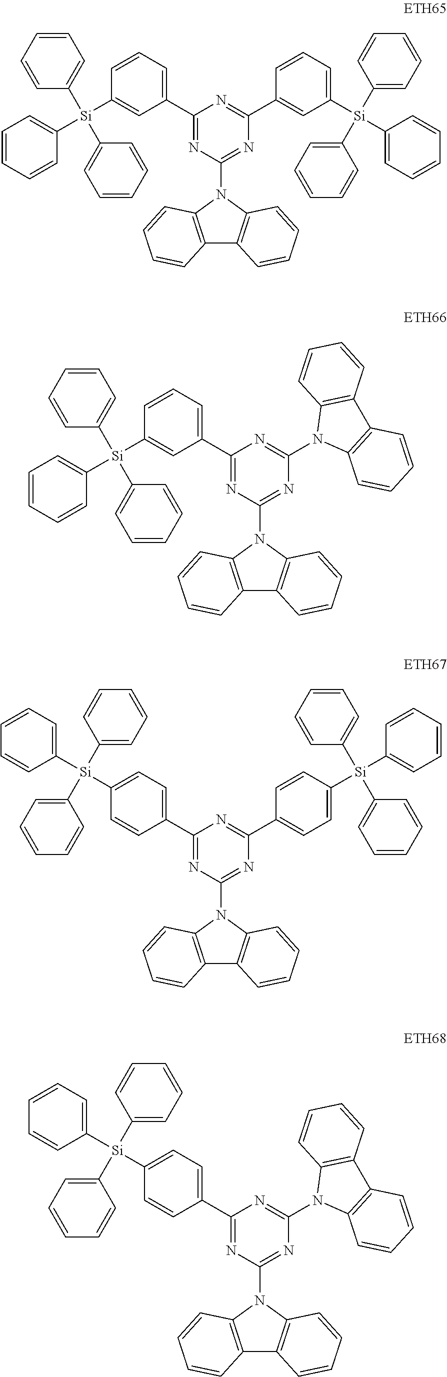 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

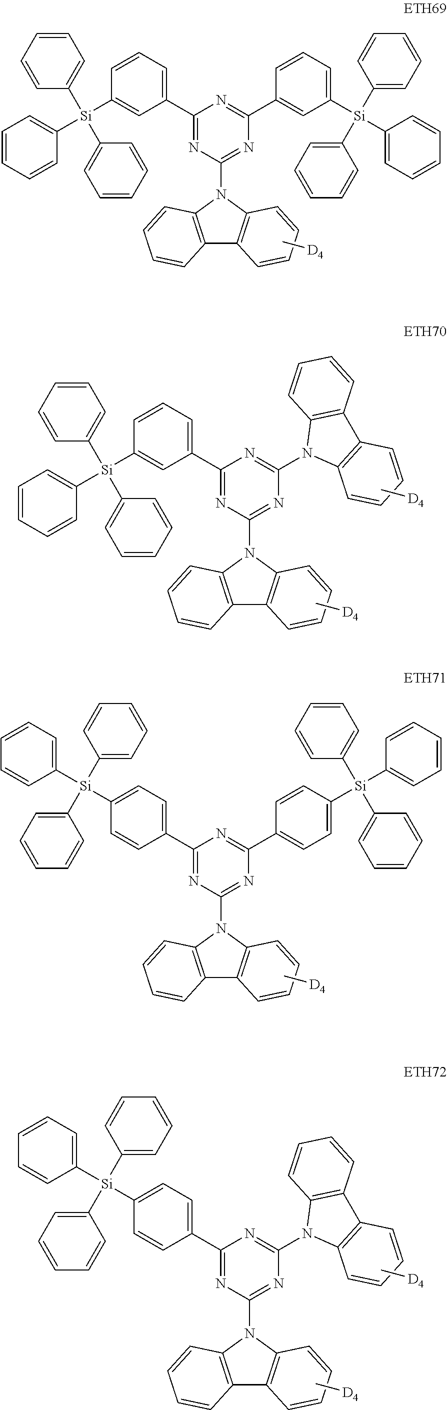

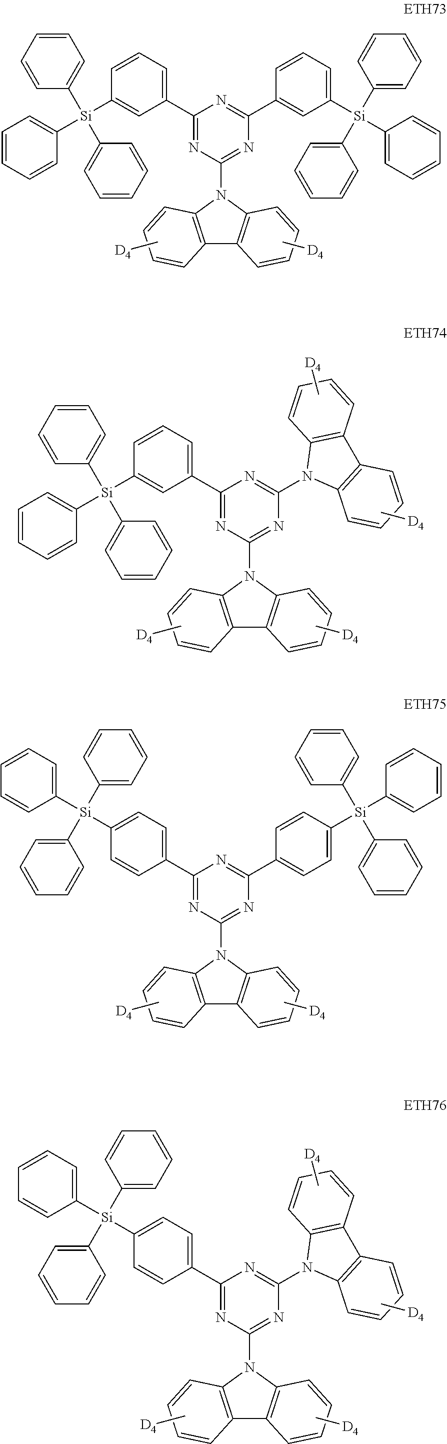

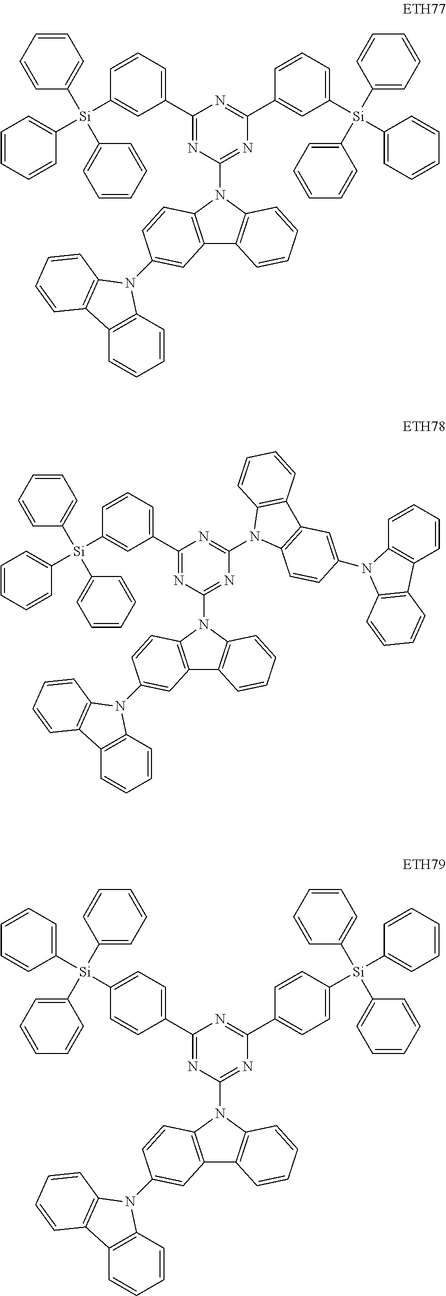 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

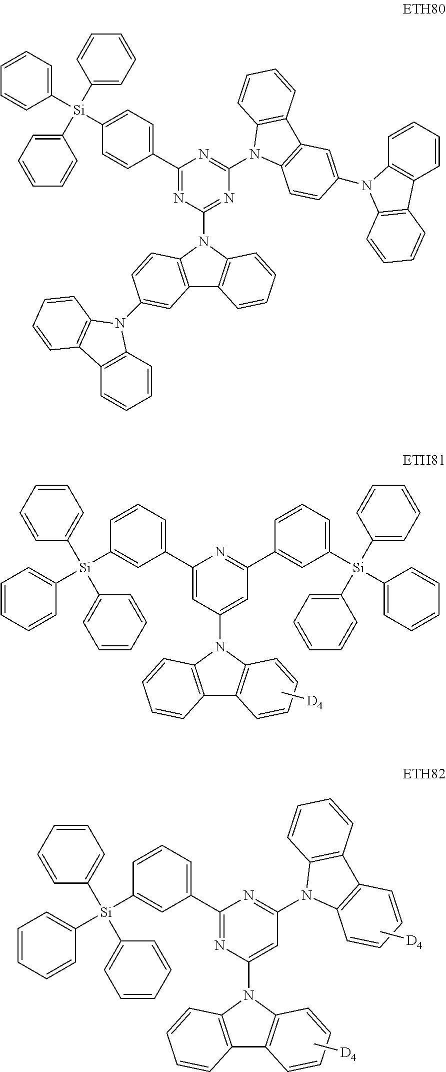

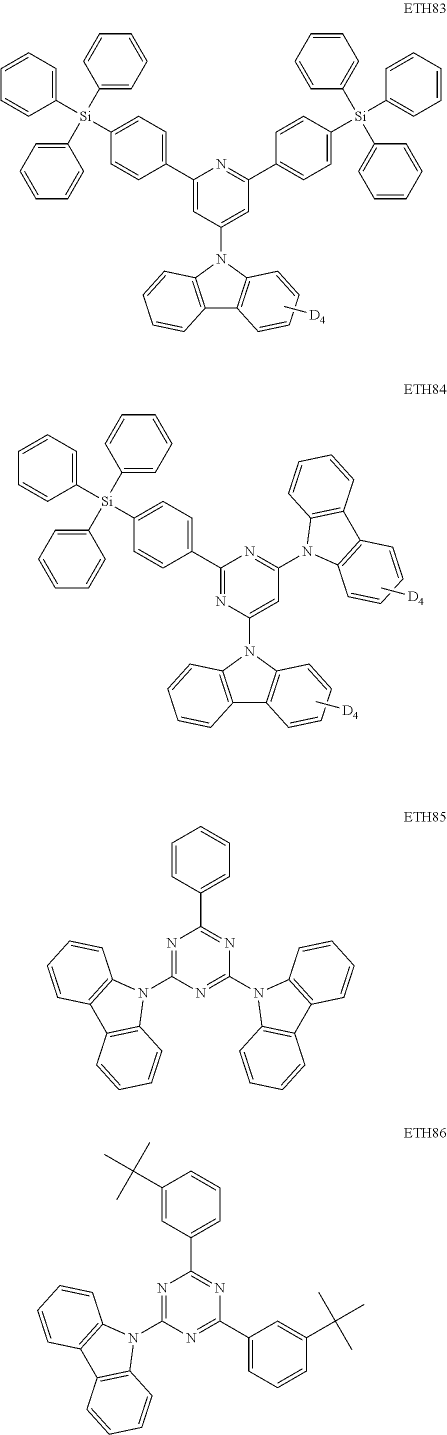

In the embodiment compounds presented in Compound Group 3, “D” refers to a deuterium atom and “Ph” refers to an unsubstituted phenyl group.

In one or more embodiments, the light emitting layer EML may include the second compound and the third compound, and the second compound and the third compound may form an exciplex. In the light emitting layer EML, an exciplex may be formed by the hole transporting host and the electron transporting host. In this case, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, an absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the light emitting layer EML may include a fourth compound in addition to the first compound to the third compound as described above. The fourth compound may be utilized as a phosphorescent sensitizer of the light emitting layer EML. The energy may be transferred from the fourth compound to the first compound, thereby emitting light.

For example, in one or more embodiments, the light emitting layer EML may include, as the fourth compound, an organometallic complex containing platinum (Pt) as a central metal atom and ligands linked to the central metal atom. The light emitting layer EML in the light emitting element ED of one or more embodiments may include, as the fourth compound, a compound represented by Formula D-1:

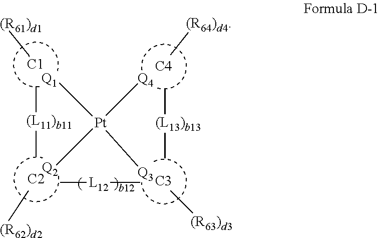

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle ring having 2 to 30 ring-forming carbon atoms.

In Formula D-1, L₁₁ to L₁₃ may each independently be a direct linkage, *—O—*, *—S—*,

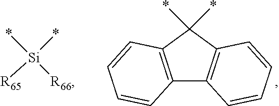

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “—*” refers to a part linked to C1 to C4.

In Formula D-1, b11 to b13 may each independently be 0 or 1. When b11 is 0, C1 and C2 may not be linked to each other. When b12 is 0, C2 and C3 may not be linked to each other. When b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, one or more of R₆₁ to R₆₆ may be bonded to an adjacent group to form a ring. In some embodiments, R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R₆₄. The embodiment in which each of d1 to d4 is 4 and R₆₁'s to R₆₄′ are each hydrogen atom may be the same as the embodiment in which each of d1 to d4 is 0. When each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle ring, represented by any one selected from among C-1 to C-4:

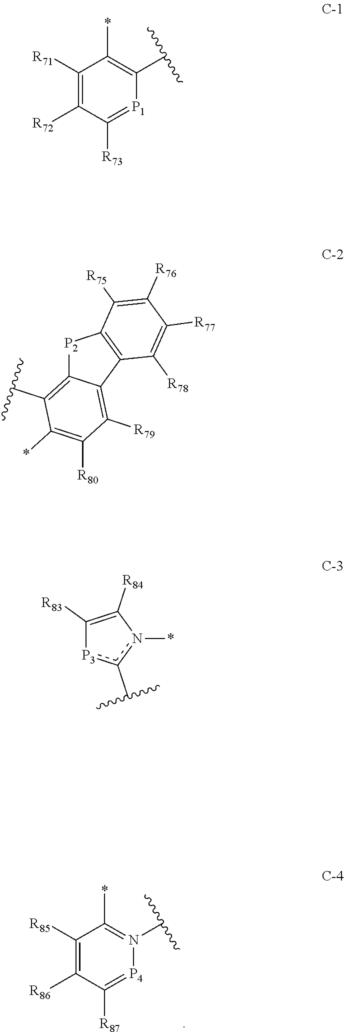

In C-1 to C-4, P₁ may be C—* or CR₇₄, P₂ may be N—* or NR₈₁, P₃ may be N—* or NR₈₂, and P₄ may be C−* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In some embodiments, in C-1 to C-4,

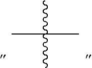

corresponds to a part linked to Pt that is a central metal atom, and “—*” corresponds to a part linked to a neighboring cyclic group (C1 to C4) or a linker (L₁₁ to L₁₃).

The light emitting layer EML of one or more embodiments may include the first compound, which is a fused polycyclic compound of the present disclosure, and at least one selected from among the second to fourth compounds. For example, in one or more embodiments, the light emitting layer EML may include the first compound, the second compound, and the third compound. In the light emitting layer EML, the second compound and the third compound may form an exciplex, and energy may be transferred from the exciplex to the first compound, thereby emitting light.

In one or more embodiments, the light emitting layer EML may include the first compound, the second compound, the third compound, and the fourth compound. In the light emitting layer EML, the second compound and the third compound may form an exciplex, and energy may be transferred from the exciplex to the fourth compound and the first compound, thereby emitting light. In some embodiments, the fourth compound may be a sensitizer. The fourth compound included in the light emitting layer EML in the light emitting element ED of one or more embodiments may serve as a sensitizer to deliver energy from the host to the first compound that is a light emitting dopant. For example, in some embodiments, the fourth compound serving as an auxiliary dopant accelerates energy delivery to the first compound that is a light emitting dopant, thereby increasing the emission ratio of the first compound. Accordingly, the light emitting layer EML of one or more embodiments may improve luminous efficiency. In some embodiments, when the energy transfer to the first compound is increased, an exciton formed in the light emitting layer EML is not accumulated in the light emitting layer EML but emits light rapidly, and thus deterioration of the device may be reduced. As a result, the service life of the light emitting element ED of one or more embodiments may increase.

The light emitting element ED of one or more embodiments may include all of the first compound, the second compound, the third compound, and the fourth compound, and the light emitting layer EML may include the combination of two host materials and two dopant materials. In the light emitting element ED of one or more embodiments, the light emitting layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be at least one selected from among compounds represented in Compound Group 4. In some embodiments, the light emitting layer EML may include at least one selected from among the compounds represented in Compound Group 4 as a sensitizer material.

### Compound Group 4

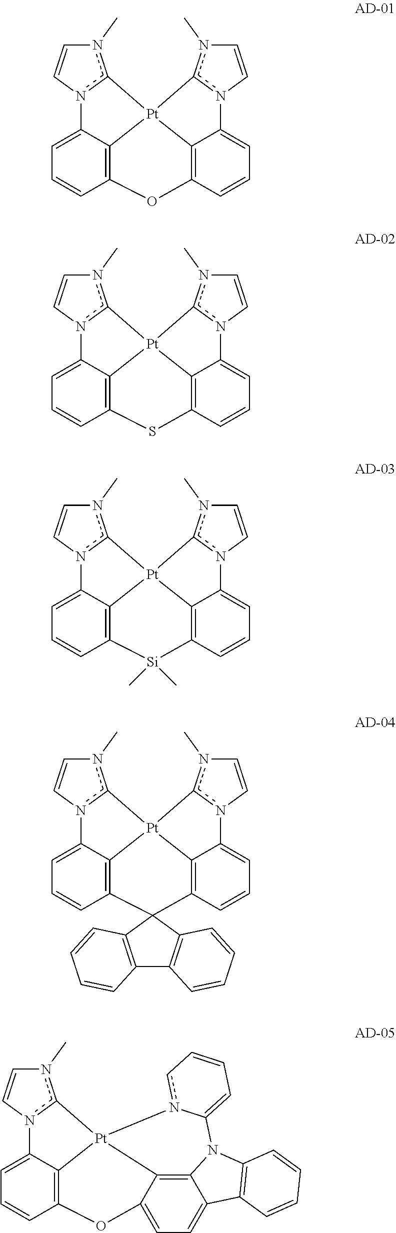

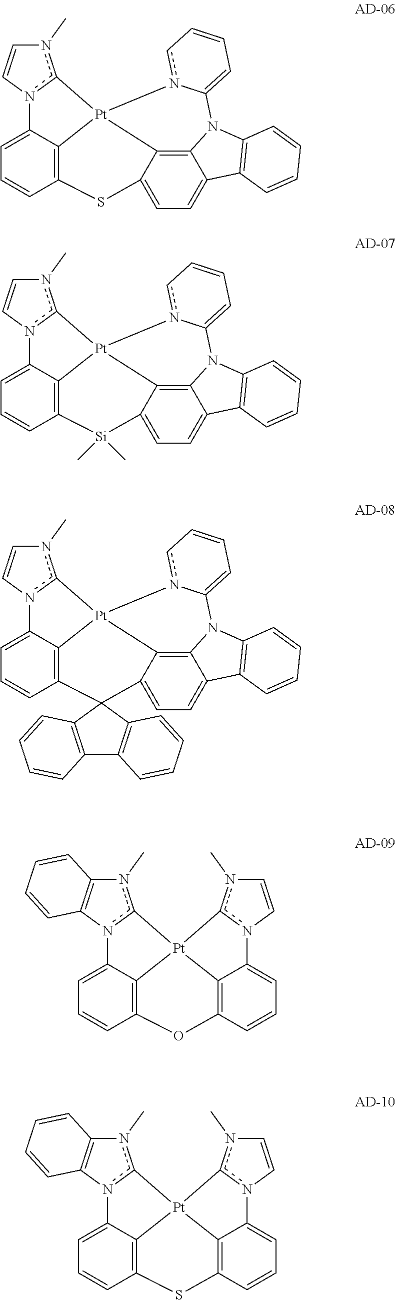

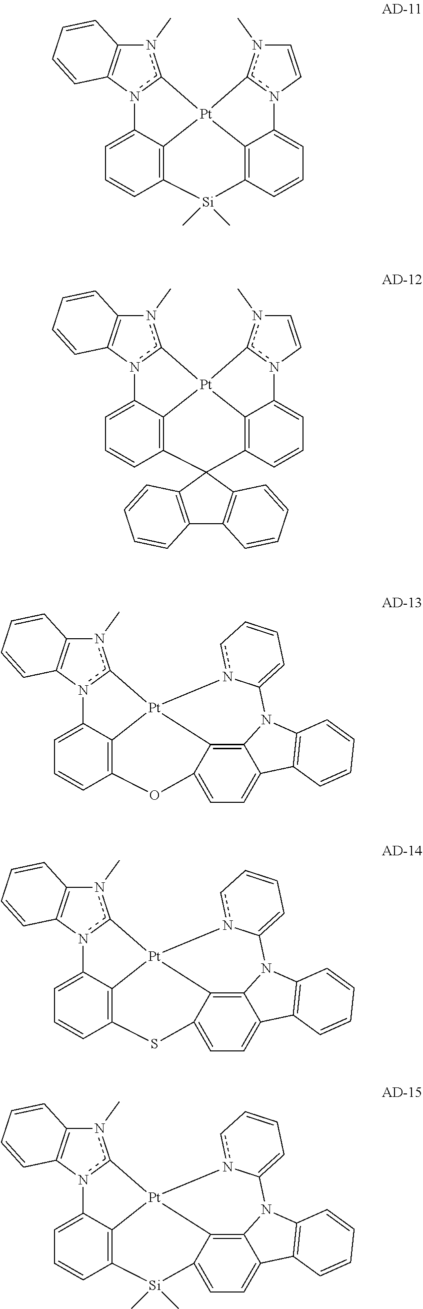

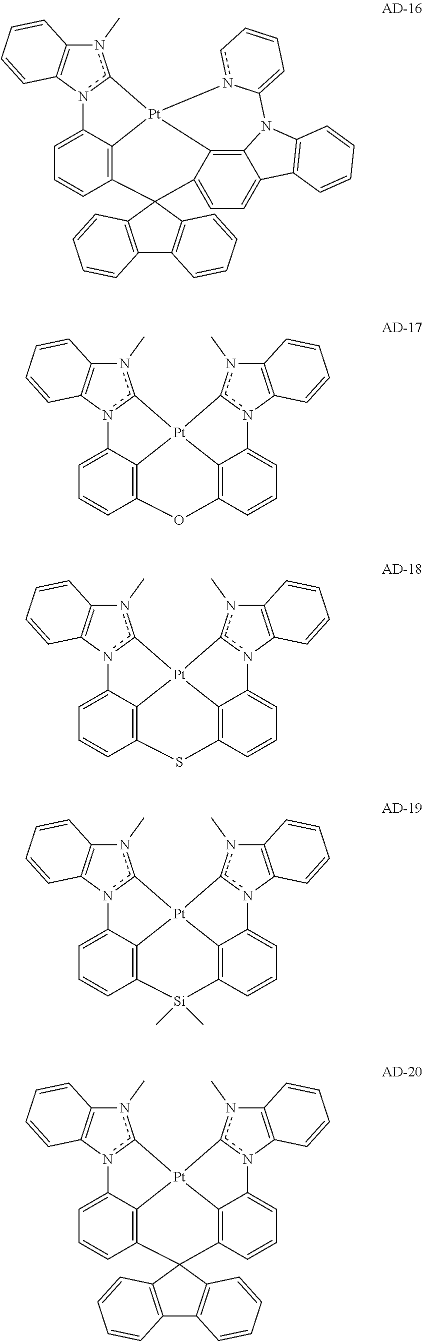

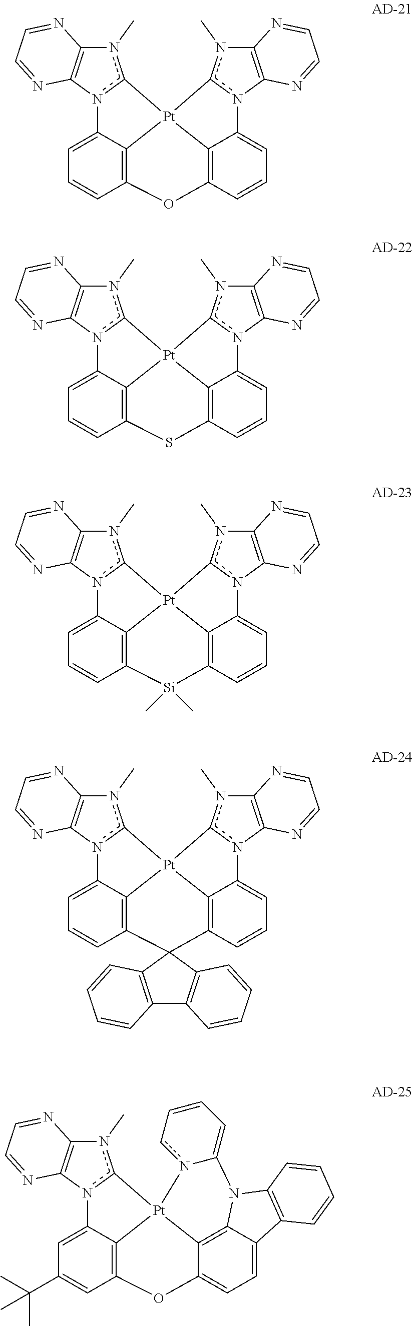

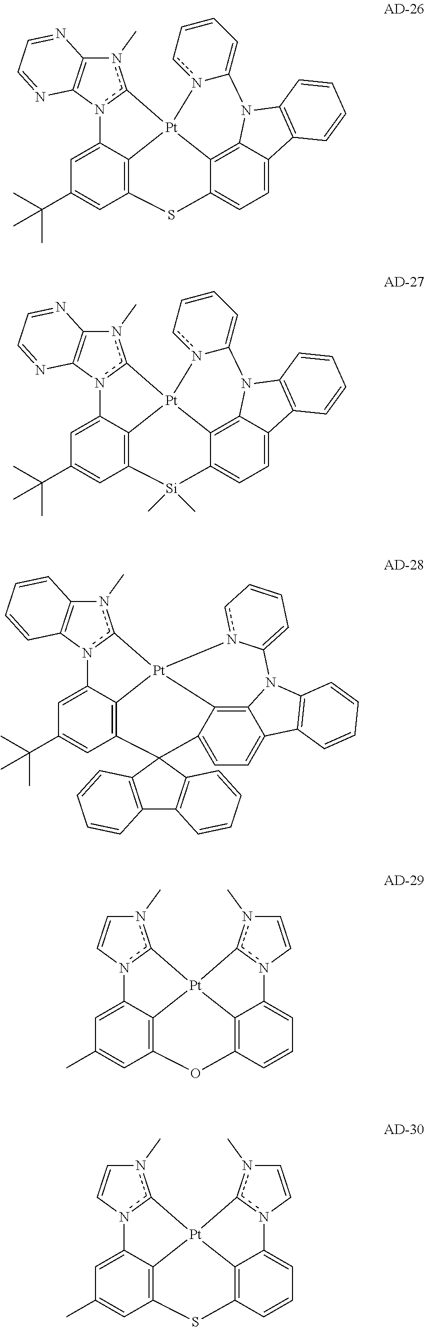

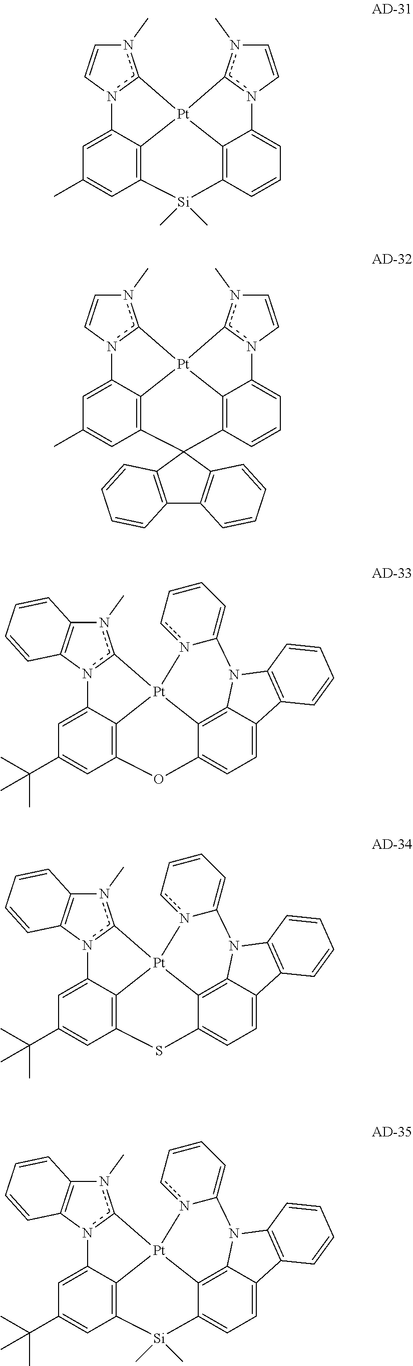

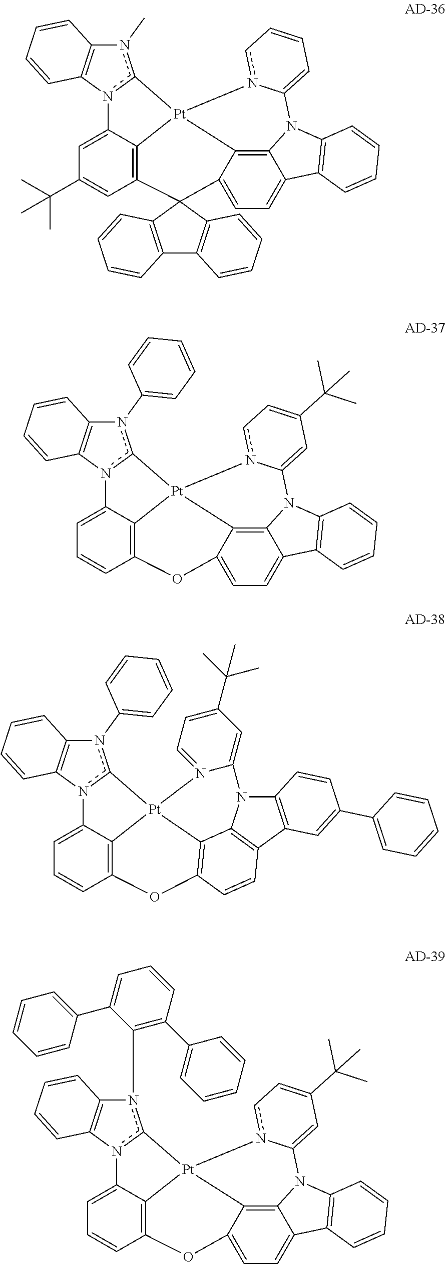

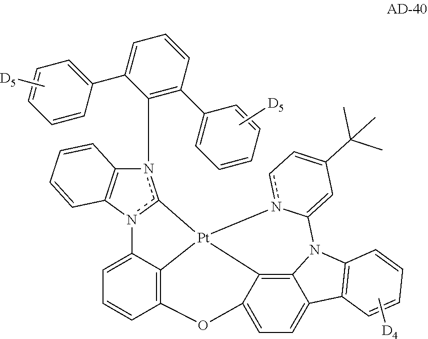

In the embodiment compounds presented in Compound Group 4, “D” refers to a deuterium atom.

When the light emitting layer EML in the light emitting element ED of one or more embodiments includes all of the first compound, the second compound, and the third compound, with respect to the total weight of the first compound, the second compound, and the third compound, A content (e.g., amount) of the first compound may be about 0.1 wt % to about 5 wt %. However, embodiments of the present disclosure are not limited thereto. When the content (e.g., amount) of the first compound satisfy the above-described proportion, the energy transfer from the second compound and the third compound to the first compound may increase, and thus the luminous efficiency and device service life may increase.

The contents (e.g., a total amount) of the second compound and the third compound in the light emitting layer EML may be the rest excluding the weight of the first compound. For example, the contents of the second compound and the third compound in the light emitting layer EML may be about 65 wt % to about 95 wt % with respect to the total weight of the first compound, the second compound, and the third compound.

In the total weight of the second compound and the third compound, a weight ratio of the second compound to the third compound may be about 3:7 to about 7:3.

When the contents of the second compound and the third compound satisfy the above-described ratio, a charge balance characteristic in the light emitting layer EML are improved, and thus the luminous efficiency and device service life may increase. When the contents of the second compound and the third compound deviate from the above-described ratio range, a charge balance in the light emitting layer EML is broken, and thus the luminous efficiency may be reduced and the device may be easily deteriorated.

When the light emitting layer EML includes the fourth compound, a content (e.g., amount) of the fourth compound in the light emitting layer EML may be about 10 wt % to about 30 wt % with respect to the total weight of the first compound, the second compound, the third compound, and the fourth compound. However, embodiments of the present disclosure are not limited thereto. When the content (e.g., amount) of the fourth compound satisfies the above-described content (e.g., amount), the energy transfer from the host to the first compound which is a light emitting dopant may be increased, a luminous ratio may be improved, and thus the luminous efficiency of the light emitting layer EML may be improved. When the first compound, the second compound, the third compound, and the fourth compound included in the light emitting layer EML satisfy the above-described content (e.g., amount) ratio range, excellent or suitable luminous efficiency and long service life of the light emitting element may be achieved.

The light emitting layer EML may be provided on the hole transport region HTR. The light emitting layer EML may have a thickness of, for example, about 100 Å to about 1,000 Å or about 100 Å to about 300 Å. The light emitting layer EML may have a single layer formed of a single material, a single layer formed of a plurality of different materials, or a multilayer structure having a plurality of layers formed of a plurality of different materials.

In the light emitting element ED of one or more embodiments, the light emitting layer EML may further include at least one of an anthracene derivative, a pyrene derivative, a fluoranthene derivative, a chrysene derivative, a dehydrobenzanthracene derivative, or a triphenylene derivative. For example, in some embodiments, the light emitting layer EML may include an anthracene derivative and/or a pyrene derivative.

In each light emitting element ED of embodiments illustrated in FIGS. 3 to 7, the light emitting layer EML may further include a suitable host and dopant besides the above-described host and dopant. For example, in some embodiments, the light emitting layer EML may include a compound represented by Formula E-1. The compound represented by Formula E-1 may be utilized as a fluorescent host material.

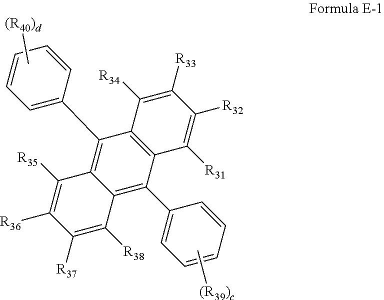

In Formula 1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, one or more selected from among R₃₁ to R₄₀ may each independently be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among Compound E1 to Compound E19:

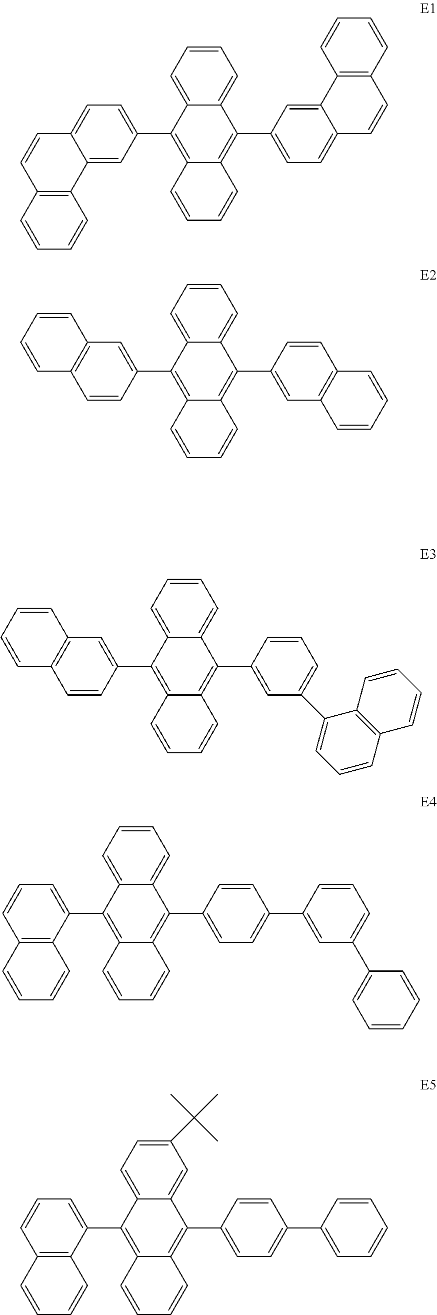

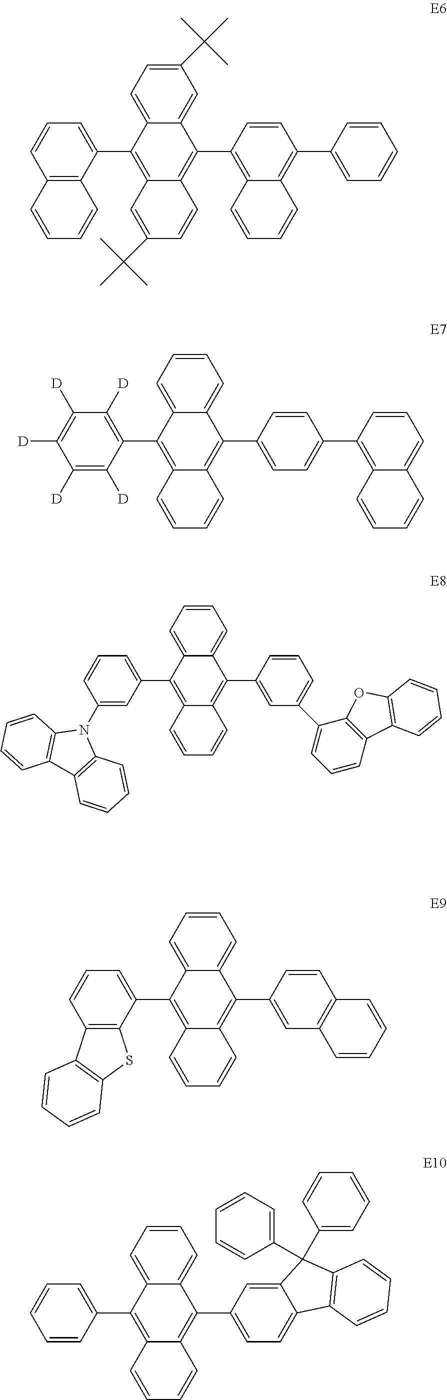

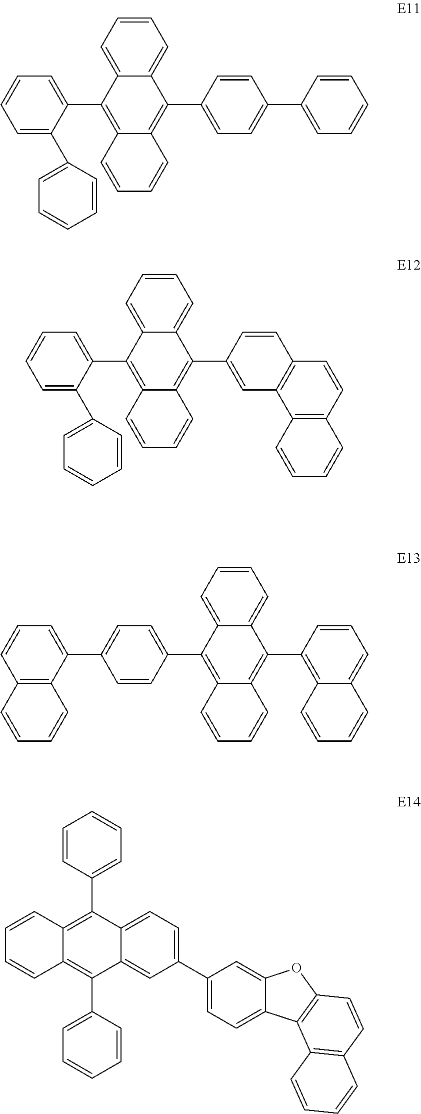

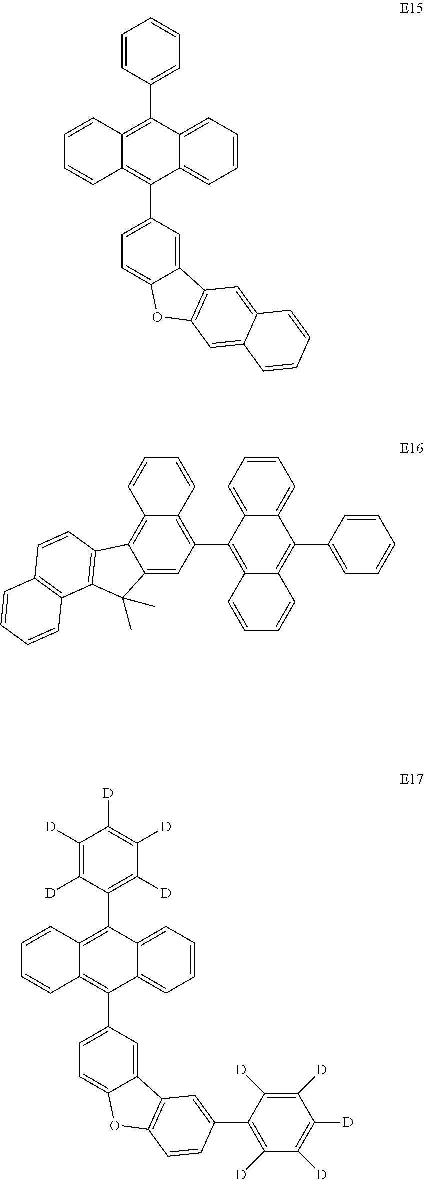

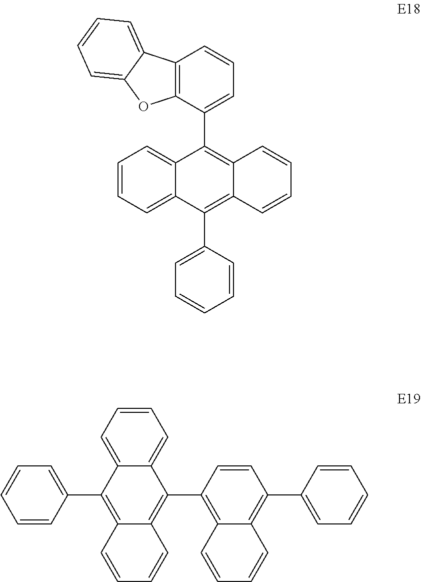

In one or more embodiments, the light emitting layer EML may include a compound represented by Formula E-2a or Formula E-2b. The compound represented by Formula E-2a or Formula E-2b may be utilized as a phosphorescent host material.

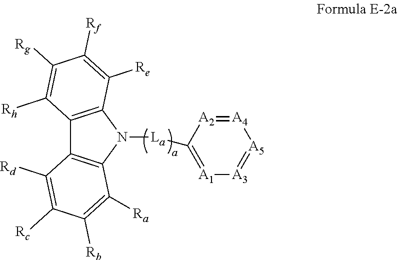

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, one or more selected from among Rₐ to Rᵢ may each independently be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest may be CRᵢ.

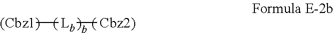

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. Meanwhile, b may be an integer of 0 to 10, and when b is an integer of 2 or more, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are mere examples, and the compound represented by Formula E-2a or Formula E-2b is not limited to those represented in Compound Group E-2.

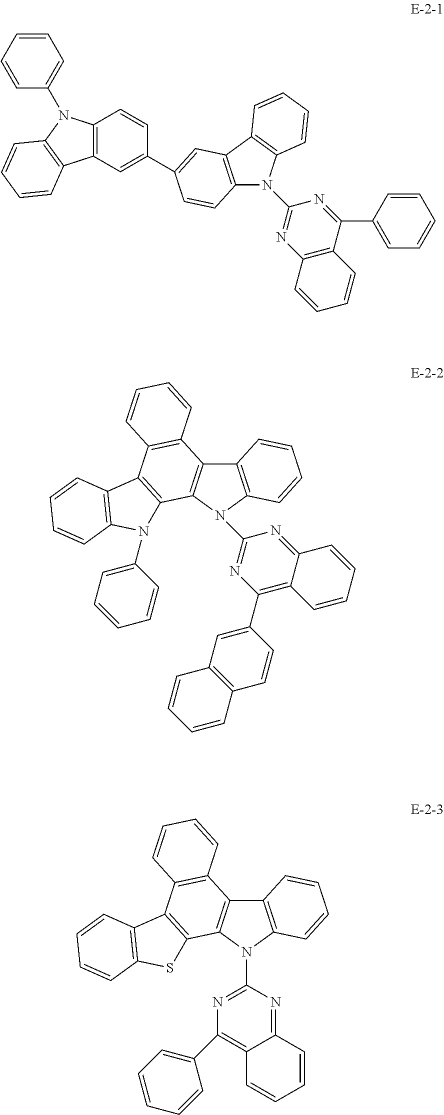 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

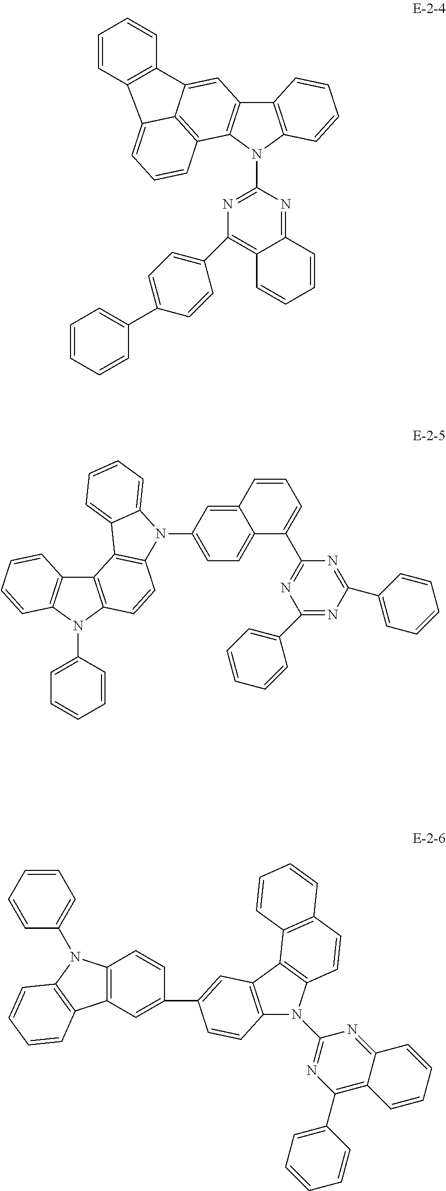 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

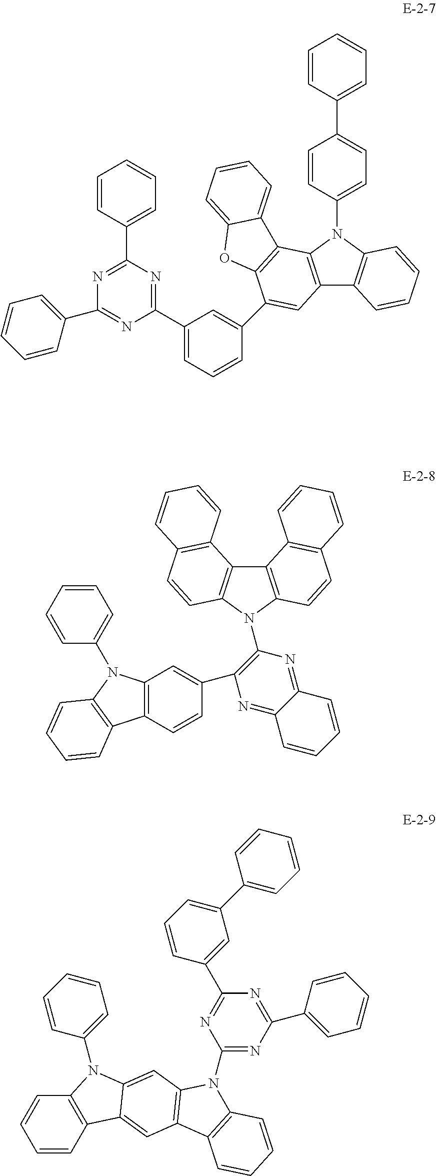 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

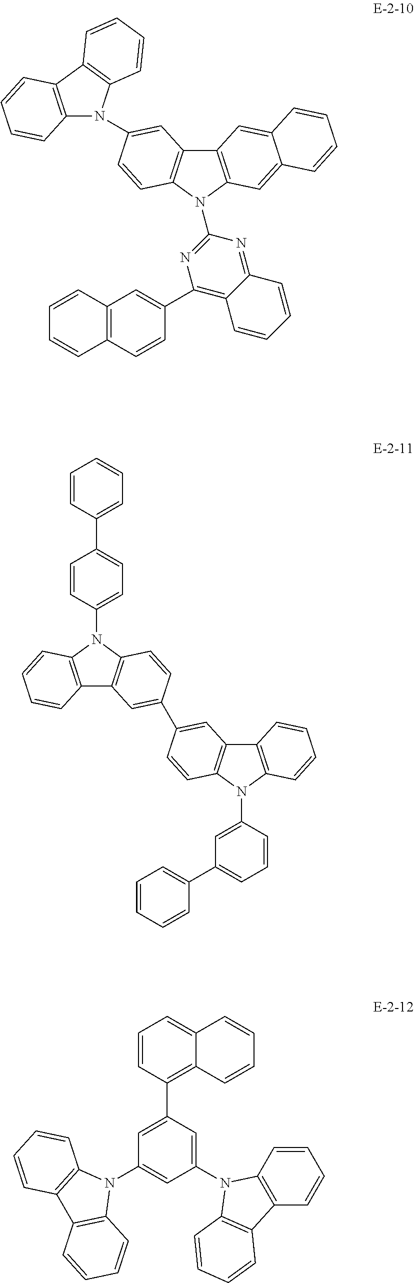 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

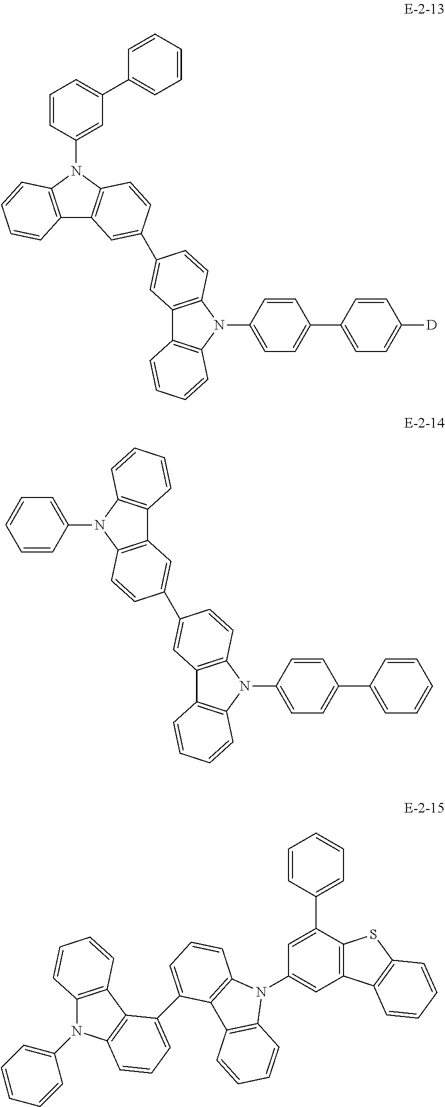 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

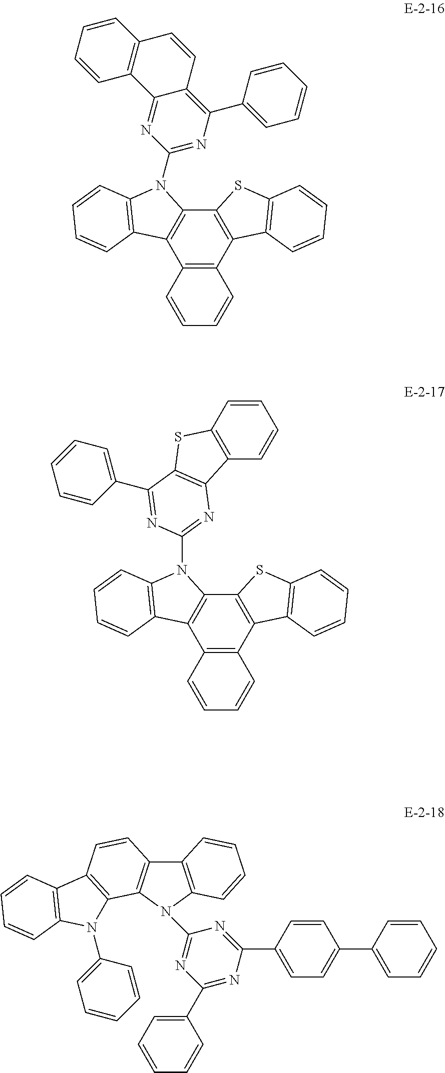 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

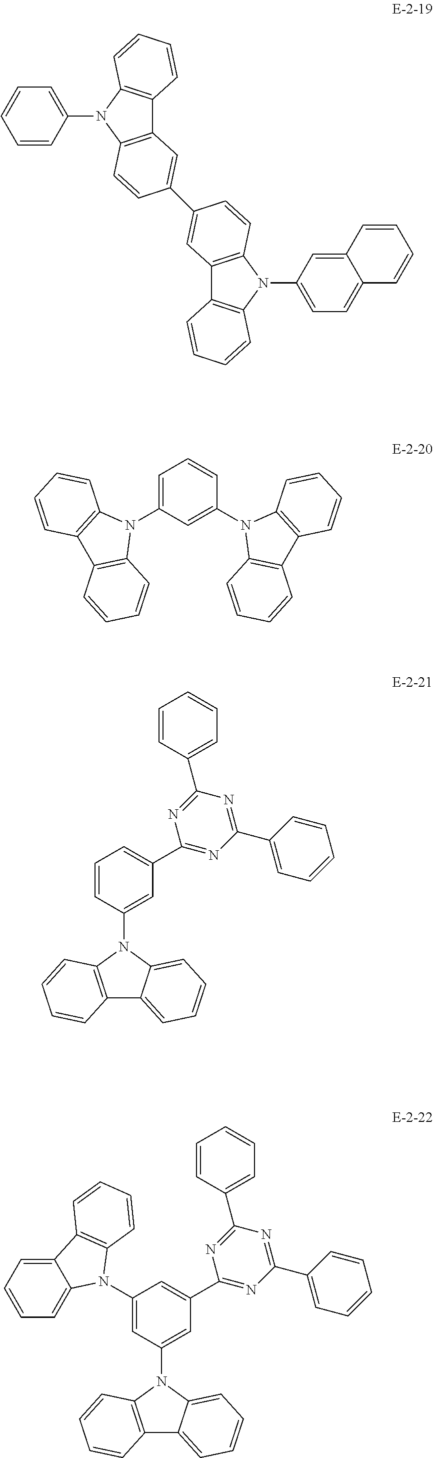 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

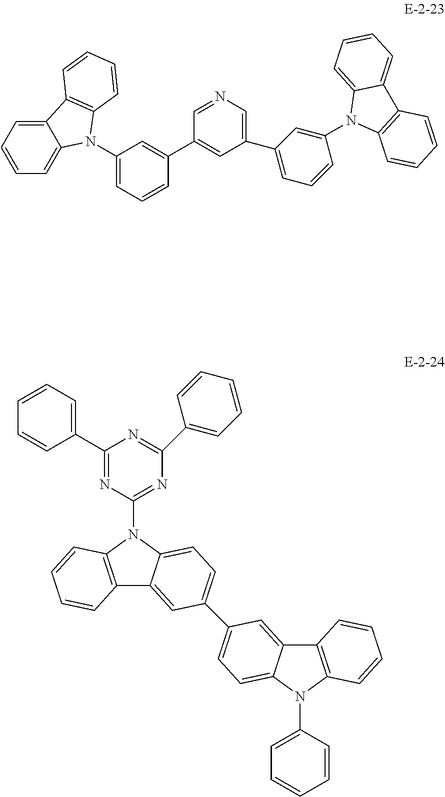 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the light emitting layer EML may further include a material suitable in the art as a host material. For example, the light emitting layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto, for example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

In one or more embodiments, the light emitting layer EML may include a compound represented by Formula M-a. The compound represented by Formula M-a may be utilized as a phosphorescent dopant material.

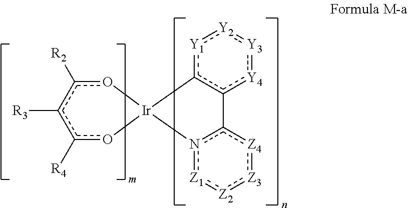

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25.

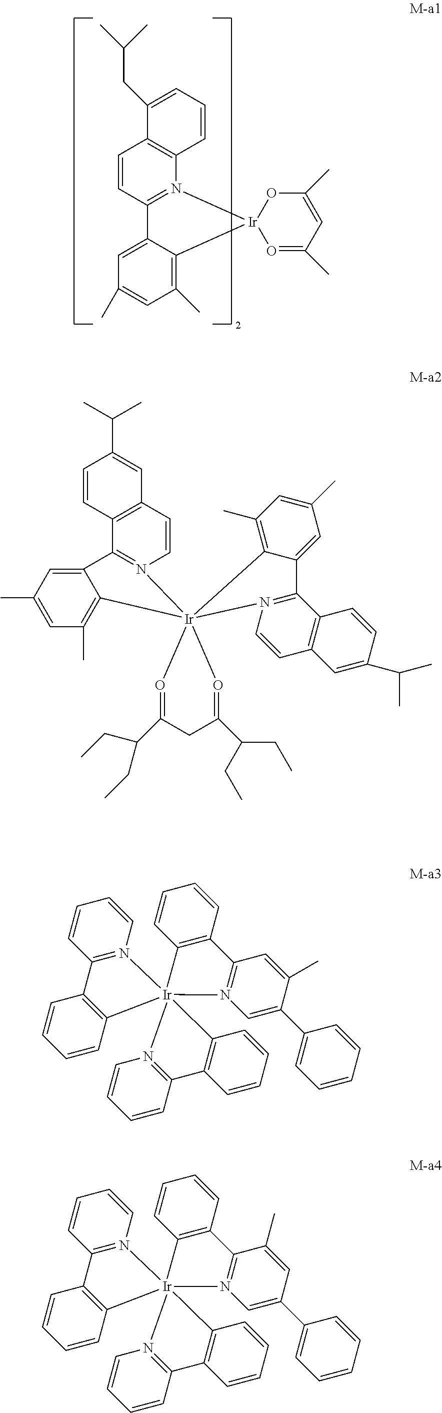

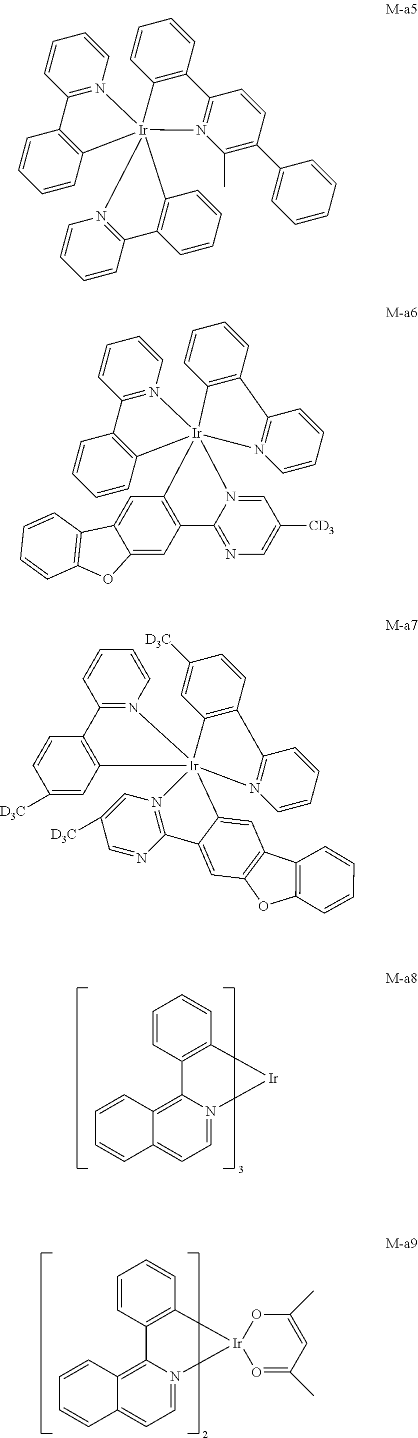

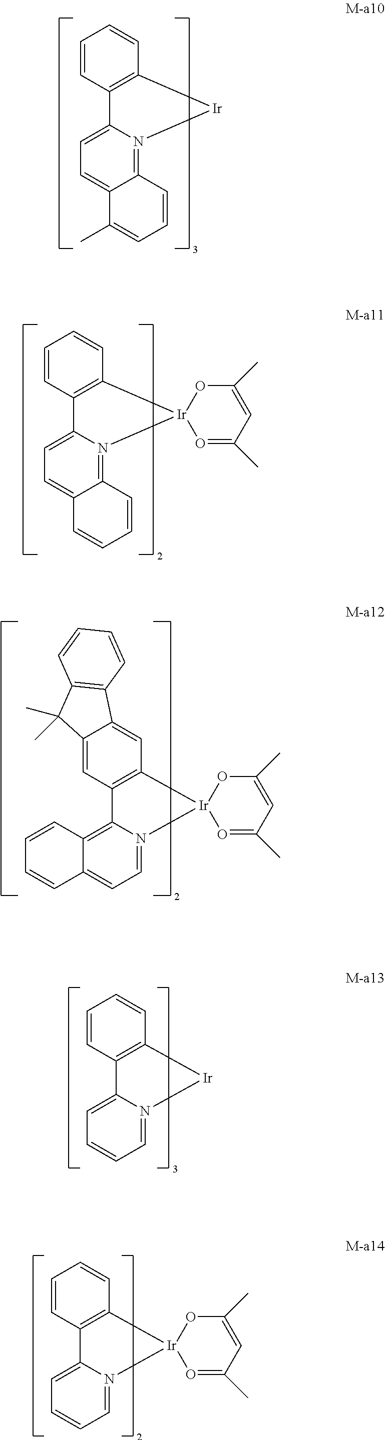

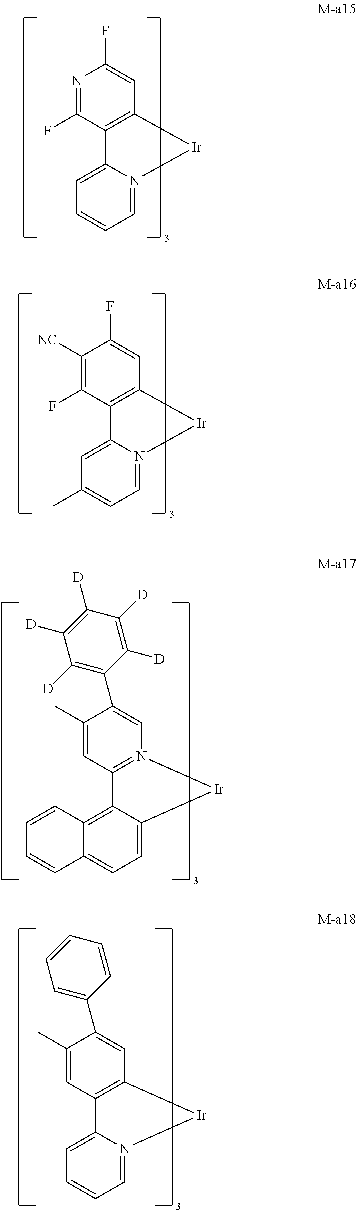

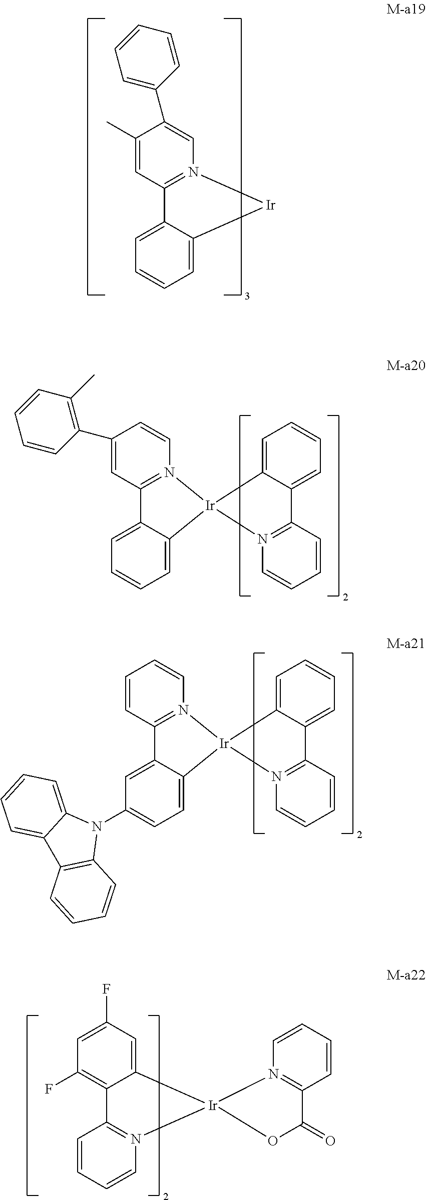

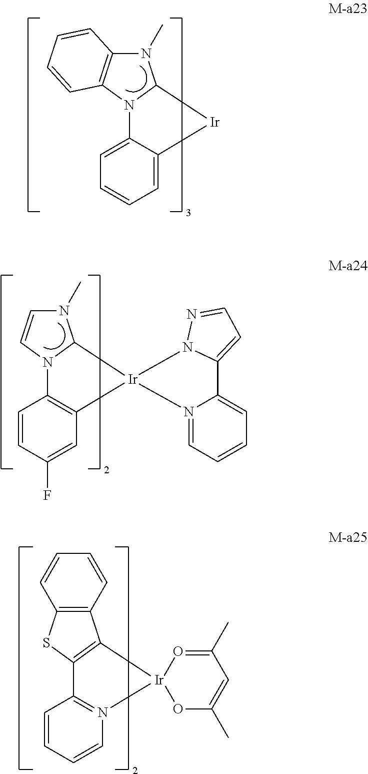

In one or more embodiments, the light emitting layer EML may further include a compound represented by any one selected from among Formula F-a to Formula F-c. The compound represented by Formula F-a to Formula F-c may be utilized as a fluorescence dopant material.

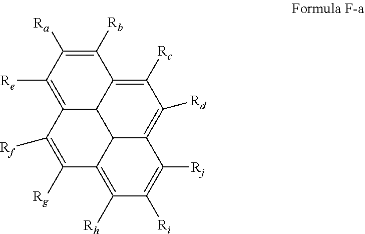

In Formula F-a, two selected from among Rₐ to Rⱼ may each independently be substituted with *—NAr₁Ar₂. The others, which are not substituted with *—NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

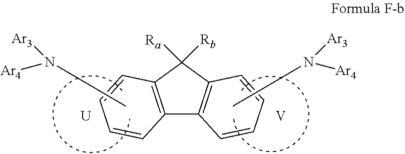

In Formula F-b above, Ra and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In some embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

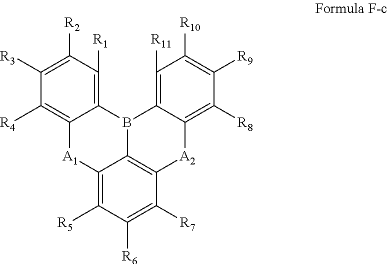

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In some embodiments, in Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

In one or more embodiments, the light emitting layer EML may further include, as a suitable dopant material, one or more selected from among styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

In one or more embodiments, the light emitting layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2′)picolinate) (Flrpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, embodiments of the present disclosure are not limited thereto.

In one or more embodiments, the light emitting layer EML may include a quantum dot material. In one or more embodiments, the quantum dot material may have a core/shell structure. A core of a quantum dot may be selected from a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

In some embodiments, the Group II-VI compound may further include a Group I metal and/or a Group IV element. The Group I-II-VI compound may be selected from CuSnS and/or CuZnS, and the Group II-IV-VI compound may be selected from ZnSnS and/or the like. The Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group II-IV-V compound may be selected from a ternary compound selected from the group consisting of ZnSnP, ZnSnP₂, ZnSnAs₂, ZnGeP₂, ZnGeAs₂, CdSnP₂, CdGeP₂, and a mixture thereof.

The Group III-VI compound may include a binary compound such as GaS, Ga₂S₃, GaSe, Ga₂Se₃, GaTe, InTe, InS, InSe, In₂S₃, In₂Se₃, and/or the like, a ternary compound such as InGaS₃, InGaSe₃, and/or the like, or any combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, and a mixture thereof, and/or a quaternary compound such as AgInGaS₂, CuInGaS₂, and/or the like.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group Ill-V compound may further include a Group II metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a multi-element compound, such as the binary compound, the ternary compound, and the quaternary compound, may be present in a particle at a substantially uniform concentration or non-substantially uniform concentration. For example, the above formula represents types (kinds) of elements included in a compound, and the ratio of elements in the compound may vary. For example, AgInGaS₂ may represent AgInₓGa₁₋ₓS₂ (wherein x is a real number of 0 and 1).

In some embodiments, the quantum dot may have a single structure in which the concentration of each element included in the corresponding quantum dot is substantially uniform or a dual structure of a core-shell. For example, a material included in the core and a material included in the shell may be different from each other.

A shell of the quantum dot may serve as a protective layer for preventing or reducing the chemical deformation of the core to maintain semiconductor properties, and/or a charging layer to impart electrophoresis properties to the quantum dot. The shell may be a single layer or multiple layers. An interface between a core and a shell may have a concentration gradient in which the concentration of an element present in the shell decreases toward the center.

In some embodiments, a quantum dot may have the aforementioned core-shell structure including a core having a nano-crystal and a shell around (e.g., surrounding) the core. An example of the shell of the quantum dot may be a metal or non-metal oxide, a semiconductor compound, or a combination thereof.

For example, the metal or non-metal oxide suitable as a shell may be a binary compound such as SiO₂, Al₂O₃, TiO₂, ZnO, MnO, Mn₂O₃, Mn³O₄, CuO, FeO, Fe₂O₃, Fe₃O₄, CoO, Co₃O₄, NiO, and/or the like, and/or a ternary compound such as MgAl₂O₄, CoFe₂O₄, NiFe₂O₄, CoMn₂O₄, and/or the like, but embodiments of the present disclosure are not limited thereto.

The semiconductor compound suitable as a shell may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like as an example, but embodiments of the present disclosure are not limited thereto.

Each element included in a multi-element compound such as the binary compound or the ternary compound may be present in (e.g., be in a form of) a particle at a substantially uniform concentration or non-substantially uniform concentration. For example, the above formula represents types (kinds) of elements included in a compound, and the ratio of elements in the compound may vary.

A quantum dot may have a full width of half maximum (FWHM) of a light emission spectrum of about 45 nanometer (nm) or less, about 40 nm or less, or about 30 nm or less, and color purity or color reproducibility of the quantum dot may be improved within the above range. In some embodiments, light emitted through such a quantum dot is emitted in all directions, so that a wide viewing angle may be achieved.

Although the form/shape of a quantum dot is not particularly limited as long as it is a form/shape utilized in the art, a quantum dot in the form of, more specifically, spherical nanoparticles, pyramidal nanoparticles, multi-arm nanoparticles, or cubic nanoparticles, nanotubes, nanowires, nanofibers, nanoplate particles, and/or the like may be utilized.

Because an energy band gap of the quantum dot may be adjusted by adjusting the size of the quantum dot or adjusting an element ratio in a quantum dot compound, it may obtain light of one or more suitable wavelength bands from a quantum-dot light emitting layer. Therefore, a light emitting element which emits light of one or more suitable wavelengths may be implemented by utilizing quantum dots as described above (e.g., utilizing quantum dots of different sizes from each other and/or having different element ratios in a quantum dot compound). For example, the adjustment of the size of the quantum dot and/or the element ratio in the quantum dot compound may enable quantum dots to emit red, green, and/or blue light. In some embodiments, the quantum dots may be configured to emit white light by combining light of one or more suitable colors.

In each of the light emitting elements ED of embodiments illustrated in FIGS. 3 to 7, the electron transport region ETR may be provided on the light emitting layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order (e.g., in the stated order) from the light emitting layer EML, but embodiments of the present disclosure are not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2:

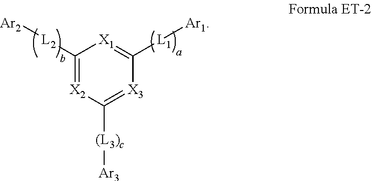

In Formula ET-2, at least one selected from among X₁ to X₃ may be N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each independently an integer of 2 or more, L₁'s to L₃'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, for example, the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), or a mixture thereof.

In one or more embodiments, the electron transport region ETR may include at least one selected from among Compound ET1 to Compound ET36:

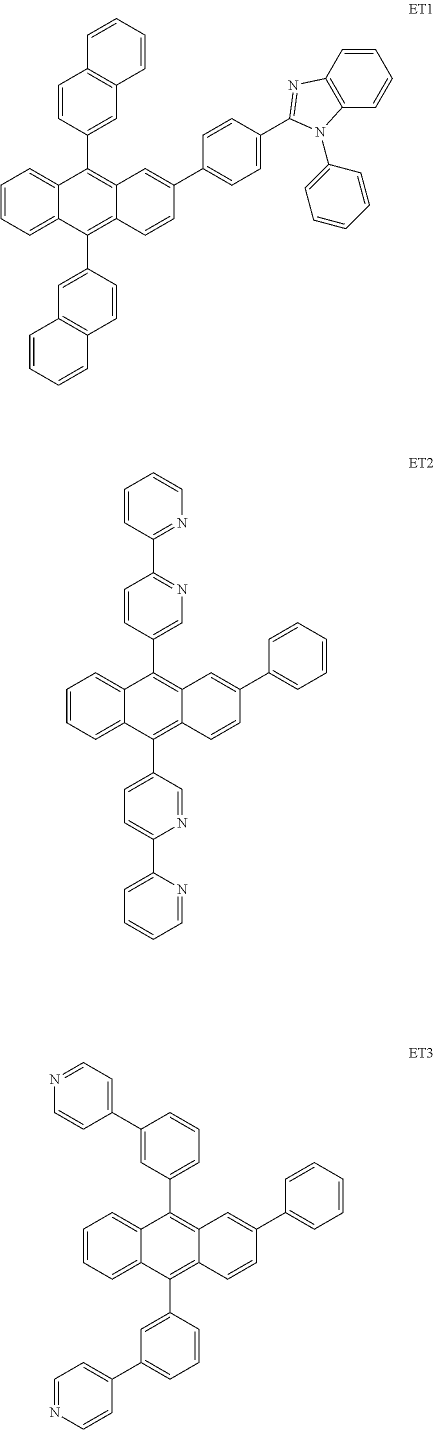 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

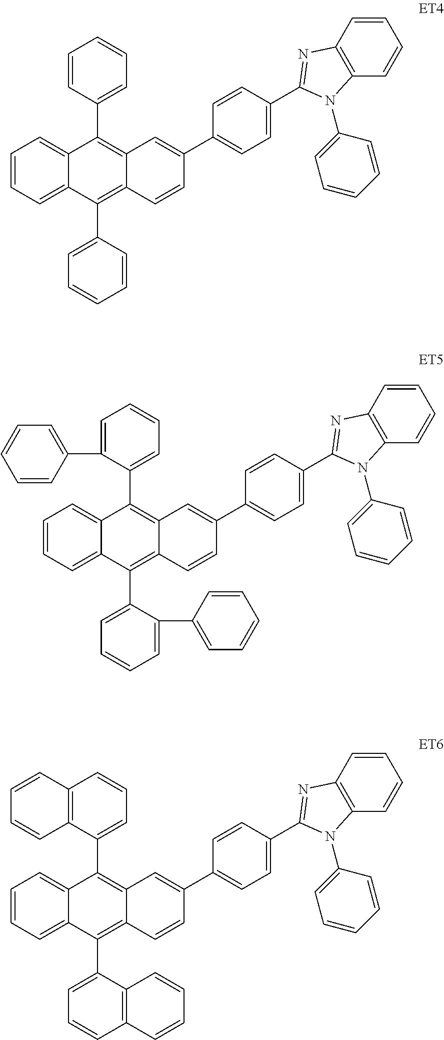 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

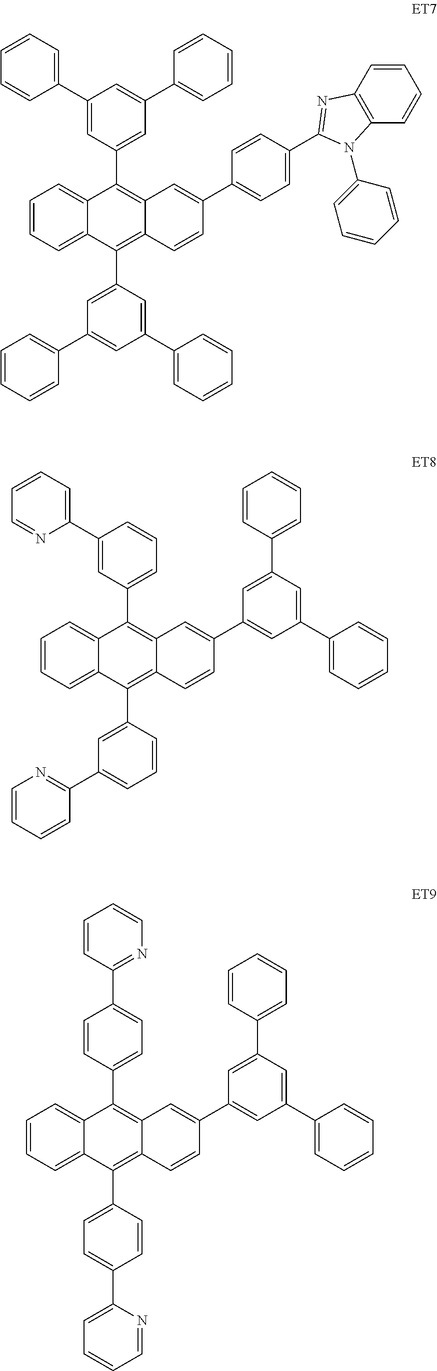 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

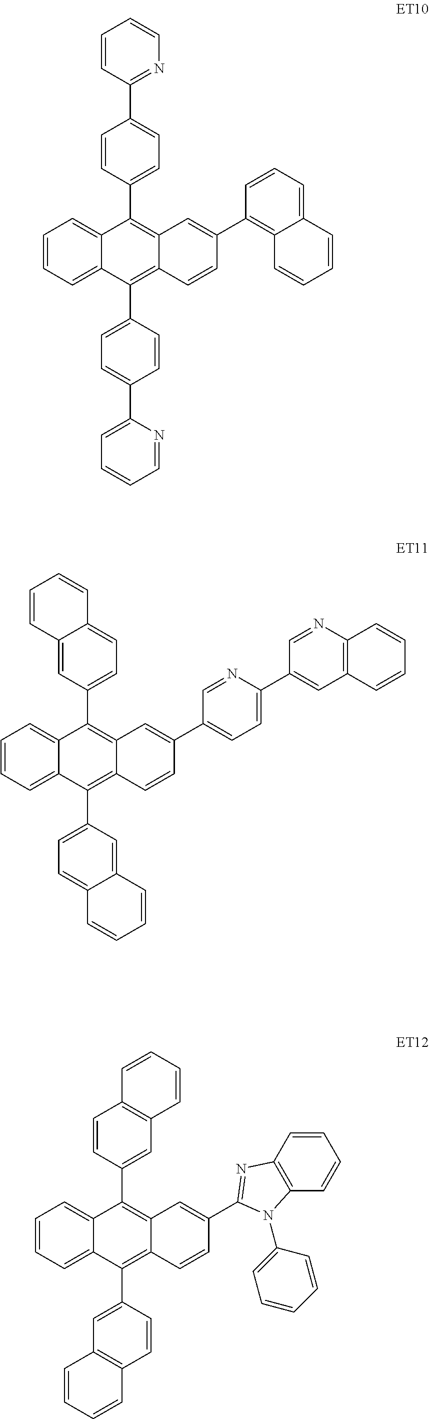 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

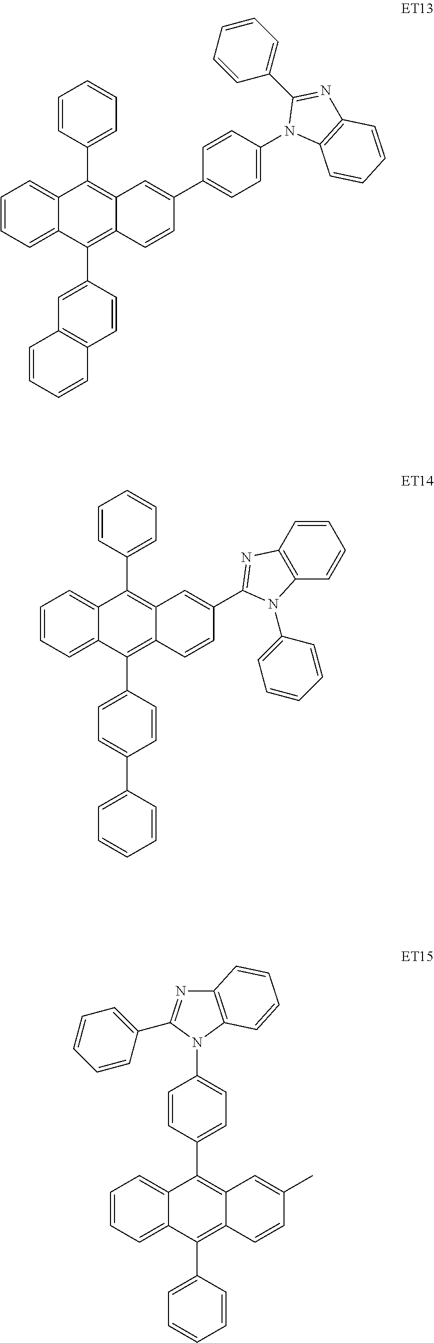 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

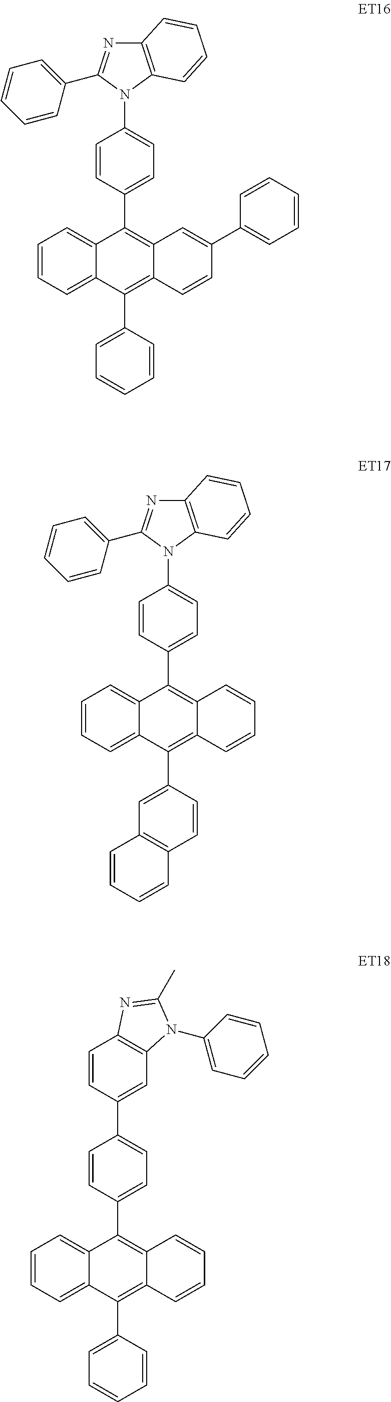 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

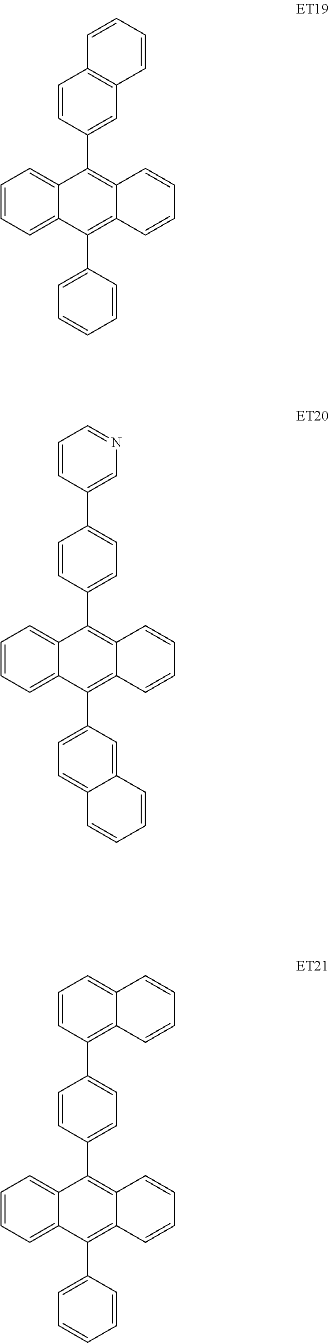

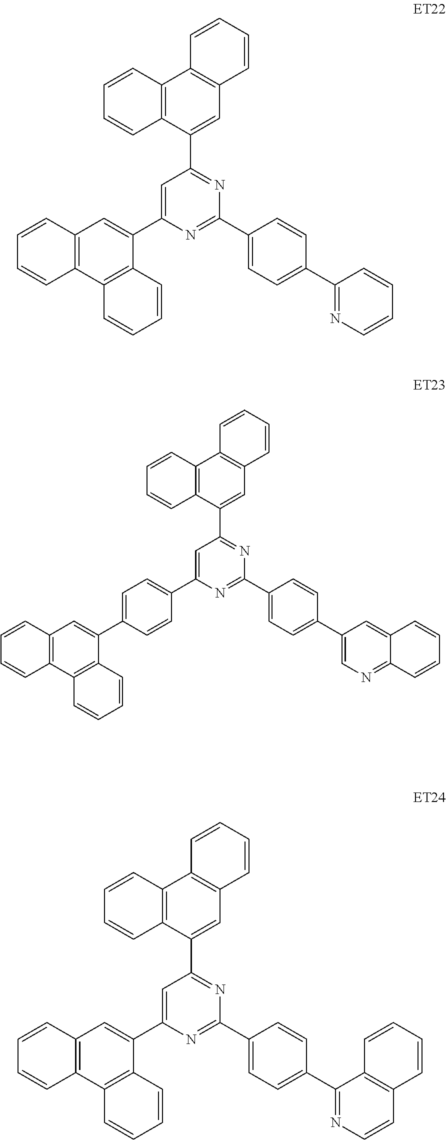 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

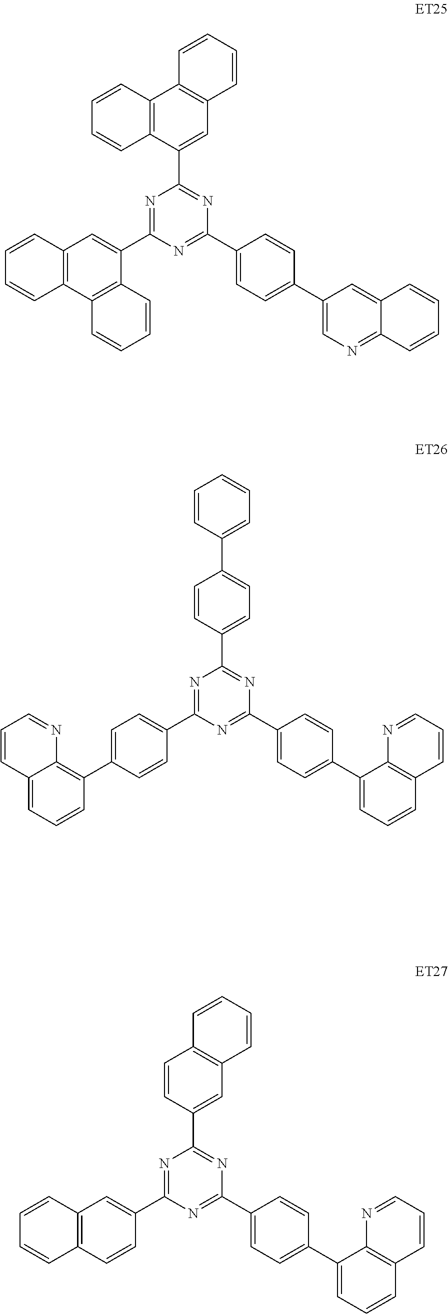 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

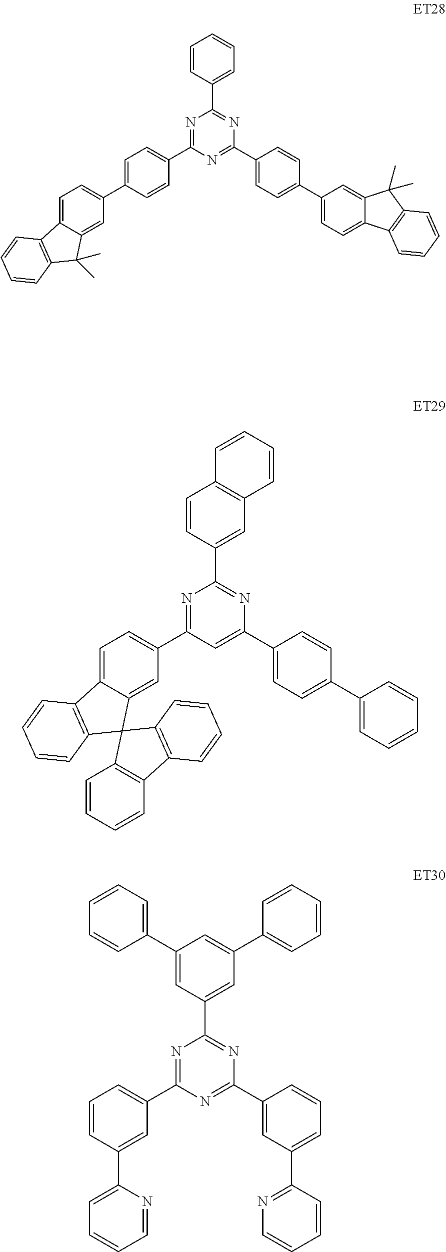 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

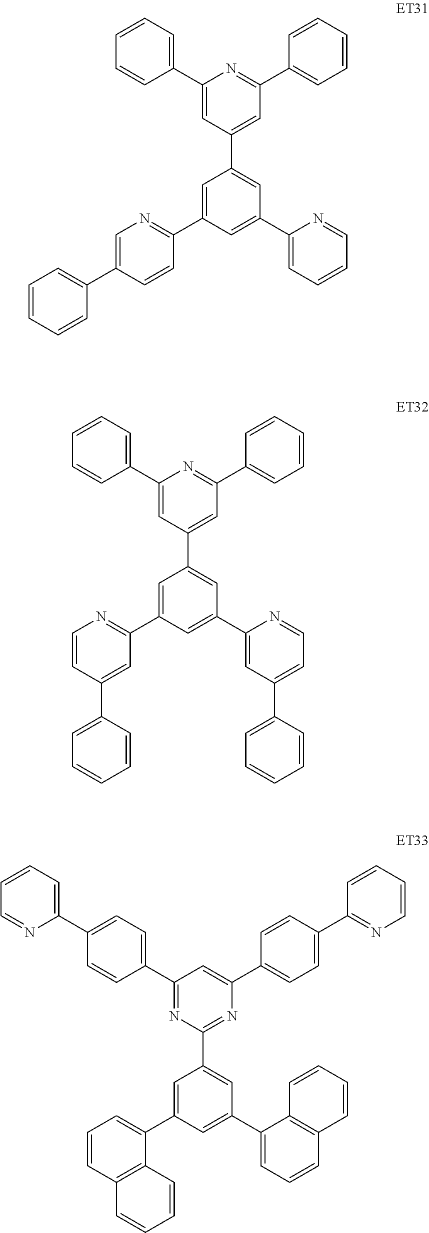 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

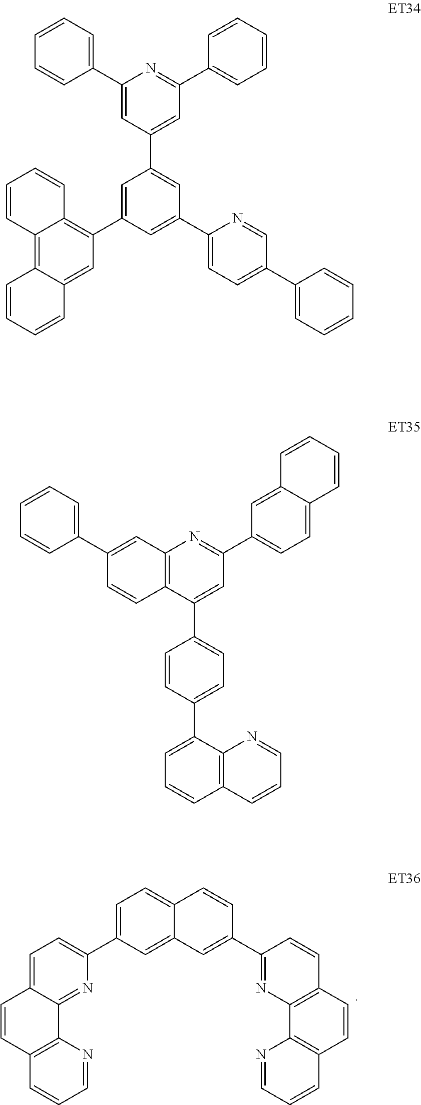 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and/or KI, a lanthanide metal such as Yb, or a co-deposited material of the metal halide and the lanthanide metal. For example, in some embodiments, the electron transport region ETR may include KI:Yb, RbI:Yb, LiF:Yb, etc., as a co-deposited material. In some embodiments, the electron transport region ETR may be formed utilizing a metal oxide such as Li₂O and/or BaO, or 8-hydroxyl-lithium quinolate (Liq), etc., but embodiments of the present disclosure are not limited thereto. In some embodiments, the electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments of the present disclosure are not limited thereto.

The electron transport region ETR may include one or more of (e.g., selected from among) the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes an electron injection layer EIL, the electron injection layer EIL may have a thickness of about 1 Å to about 100 Å, for example, about 3 Å to about 90 Å. When the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, any compound thereof, or any mixture thereof (e.g., AgMg, AgYb, or MgYb). In some embodiments, the second electrode EL2 may have a multilayer structure including a reflective film or a transflective film formed of one or more of the above-described materials and a transparent conductive film formed of ITO, IZO, ZnO, ITZO, etc. For example, the second electrode EL2 may include one of the above-described metal materials, one or more combinations of at least two metal materials selected from the above-described metal materials, one or more oxides of the above-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting element ED. The capping layer CPL may include a multilayer or a single layer.

In one or more embodiments, the capping layer CPL may be an organic layer or an inorganic layer. For example, in some embodiments, when the capping layer CPL contains an inorganic material, the inorganic material may include an alkali metal compound (e.g., LiF), an alkaline earth metal compound (e.g., MgF₂), SiON, SiNₓ, SiO_{y}, etc.

For example, in some embodiments, when the capping layer CPL includes an organic material, the organic material may include one or more of (e.g., at least one selected from among) α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., and/or an epoxy resin, and/or acrylate such as methacrylate. However, embodiments of the present disclosure are not limited thereto, for example, in some embodiments, the capping layer CPL may include at least one selected from among Compounds P1 to P5:

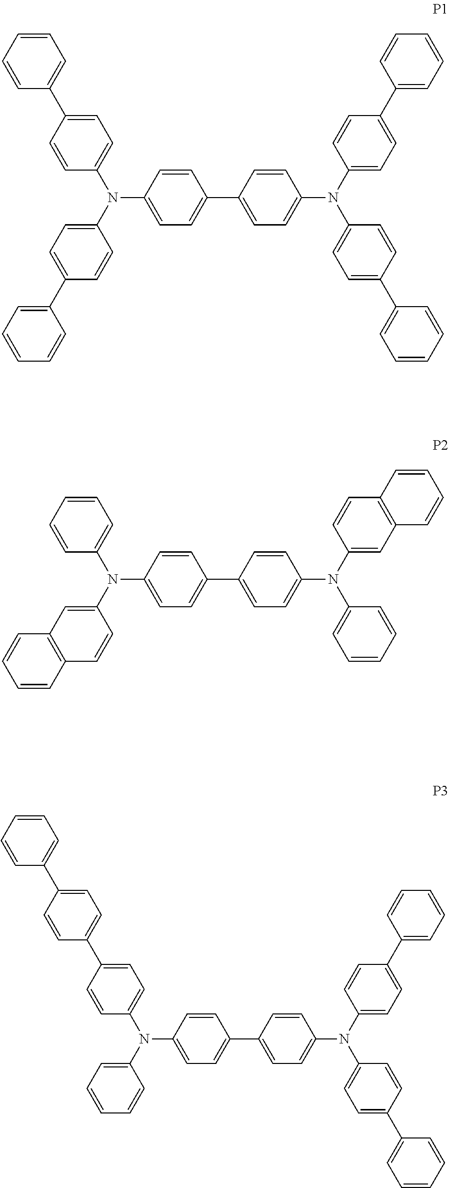 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

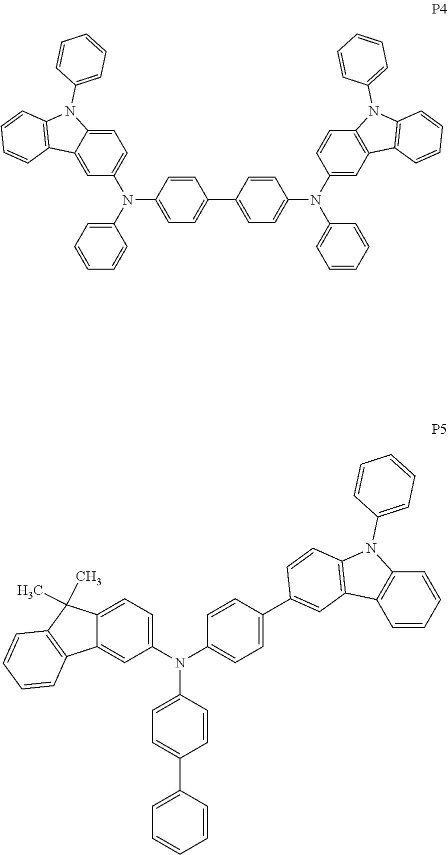 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, in some embodiments, the refractive index of the capping layer CPL may be about 1.6 or more with respect to light in a wavelength range of about 550 nm to about 660 nm.

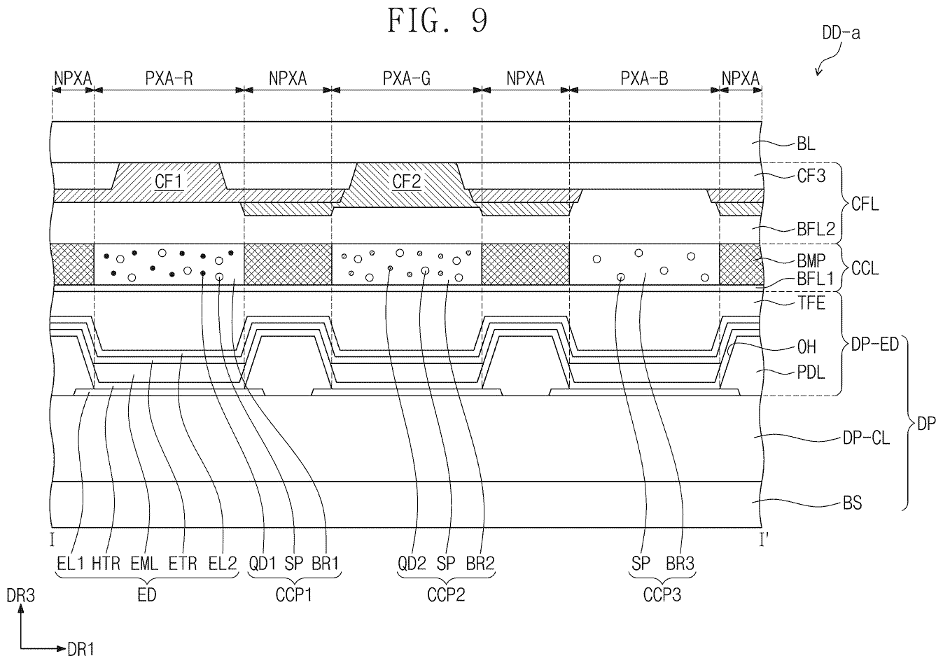

FIG. 9 to FIG. 12 are each a cross-sectional view of a display device according to one or more embodiments of the present disclosure. Hereinafter, in a description of a display device of one or more embodiments to be provided with reference to FIG. 9 to FIG. 12, the same contents as those described above with reference to FIG. 1 to FIG. 8 will not be repeated for conciseness. Instead, the description will mainly focus on differences.

Referring to FIG. 9, a display device DD-a according to one or more embodiments may include a display panel DP including a display element layer DP-ED, a light control layer CCL disposed on the display panel DP, and a color filter layer CFL. In one or more embodiments illustrated in FIG. 9, the display panel DP may include a base layer BS, a circuit layer DP-CL provided on the base layer BS, and the display element layer DP-ED, wherein the display element layer DP-ED may include a light emitting element ED.

The light emitting element ED may include a first electrode EL1, a hole transport region HTR on the first electrode EL1, a light emitting layer EML on the hole transport region HTR, an electron transport region ETR on the light emitting layer EML, and a second electrode EL2 on the electron transport region ETR. The light emitting element ED illustrated in FIG. 9 may include the fused polycyclic compound of one or more embodiments. The light emitting element ED including the fused polycyclic compound of one or more embodiments may exhibit low-driving voltage, high-efficiency, and long-lifespan properties. In one or more embodiments, the structure of any light emitting element described above with reference to FIG. 3 to FIG. 7 may be equally applied to the structure of the light emitting element ED illustrated in FIG. 9.

Referring to FIG. 9, the light emitting layer EML may be disposed in an opening OH defined in a pixel defining film PDL. For example, the light emitting layer EML which is divided by the pixel defining film PDL and provided corresponding to each of light emitting regions PXA-R, PXA-G, and PXA-B, may be to emit light in substantially the same wavelength range. In the display device DD-a of one or more embodiments, the light emitting layer EML may be to emit blue light. In some embodiments, the light emitting layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing a quantum dot or a layer containing a phosphor.

The light control layer CCL may include a plurality of light control parts CCP1, CCP2, and CCP3. The light control parts CCP1, CCP2, and CCP3 may be spaced apart from each other.

Referring to FIG. 9, divided patterns BMP may be disposed between the light control parts CCP1, CCP2 and CCP3 which are spaced apart from each other, but embodiments of the present disclosure are not limited thereto. FIG. 9 illustrates that the divided patterns BMP do not overlap the light control parts CCP1, CCP2, and CCP3, but, in some embodiments, at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, in some embodiments, the first quantum dot QD1 may be a red quantum dot to emit red light, and the second quantum dot QD2 may be a green quantum dot to emit green light. The same as described above regarding quantum dots may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. In one or more embodiments, the scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may each independently be acrylic-based resins, urethane-based resins, silicone-based resins, epoxy-based resins, etc. The base resins BR1, BR2, and BR3 may be transparent resins. In one or more embodiments, the first base resin BR1, the second base resin BR2, and the third base resin BR3 may be the same as or different from each other.

In one or more embodiments, the light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, a barrier layer BFL2 may be provided between the light control parts CCP1, CCP2, and CCP3 and the color filter layer CFL.

The barrier layers BFL1 and BFL2 may each include at least one inorganic layer. For example, in some embodiments, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may each be formed of a single layer or a plurality of layers.

In the display device DD-a of one or more embodiments, the color filter layer CFL may be disposed on the light control layer CCL. For example, in some embodiments, the color filter layer CFL may be directly disposed on the light control layer CCL. In these embodiments, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, in some embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. In some embodiments, the first filter CF1 may include a red pigment and/or dye, the second filter CF2 may include a green pigment and/or dye, and the third filter CF3 may include a blue pigment and/or dye.

In some embodiments, the third filter CF3 may not include (e.g., may exclude) any pigment and/or dye. The third filter CF3 may include a polymeric photosensitive resin and may not include (e.g., may exclude) any pigment and/or dye. The third filter CF3 may be transparent. The third filter CF3 may be formed of a transparent photosensitive resin.

Furthermore, in some embodiments, the first filter CF1 and the second filter CF2 may each be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material and/or an inorganic light shielding material containing a black pigment and/or dye. The light shielding part may prevent or reduce light leakage, and may separate boundaries between the adjacent filters CF1, CF2, and CF3. In some embodiments, the light shielding part may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface on which the color filter layer CFL, the light control layer CCL, and/or the like are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

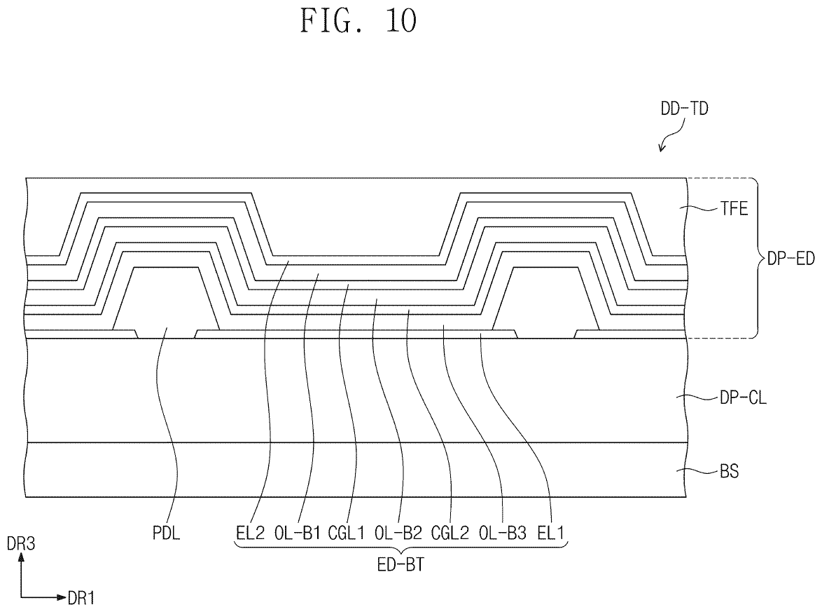

FIG. 10 is a cross-sectional view showing a portion of a display device according to one or more embodiments of the present disclosure. In a display device DD-TD of one or more embodiments, a light emitting element ED-BT may include a plurality of light emitting structures OL-B1, OL-B2, and OL-B3. The light emitting element ED-BT may include the fused polycyclic compound of one or more embodiments. The light emitting element ED-BT including the fused polycyclic compound of one or more embodiments may exhibit low-driving voltage, high-efficiency, and long-lifespan properties.

The light emitting element ED-BT may include a first electrode EL1 and a second electrode EL2 which face each other, and the plurality of light emitting structures OL-B1, OL-B2, and OL-B3 sequentially stacked in a thickness direction between the first electrode EL1 and the second electrode EL2. The light emitting structures OL-B1, OL-B2, and OL-B3 each may include a light emitting layer EML (referring to FIG. 9) and a hole transport region HTR and an electron transport region ETR disposed with the light emitting layer EML (FIG. 9) located therebetween.

For example, the light emitting element ED-BT included in the display device DD-TD of one or more embodiments may be a light emitting element having a tandem structure and including a plurality of light emitting layers.

In one or more embodiments illustrated in FIG. 10, all light beams respectively emitted from the light emitting structures OL-B1, OL-B2, and OL-B3 may be blue light. However, embodiments of the present disclosure are not limited thereto, for example, in some embodiments, the light beams respectively emitted from the light emitting structures OL-B1, OL-B2, and OL-B3 may have wavelength ranges different from each other. For example, in one or more embodiments, the light emitting element ED-BT including the plurality of light emitting structures OL-B1, OL-B2, and OL-B3, which emit light beams having wavelength ranges different from each other, may be to emit white light (e.g., combined white light).

Charge generation layers CGL1 and CGL2 may be respectively disposed between two of the neighboring light emitting structures OL-B1, OL-B2, and OL-B3. The charge generation layers CGL1 and CGL2 may include a p-type or kind charge (e.g., P-charge) generation layer and/or an n-type or kind charge (N-charge) generation layer.

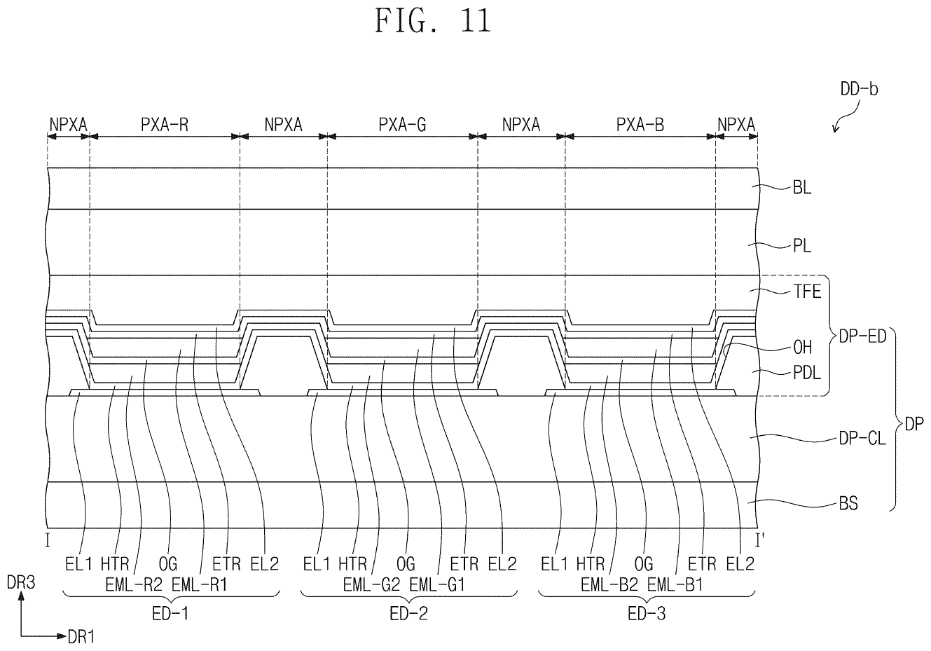

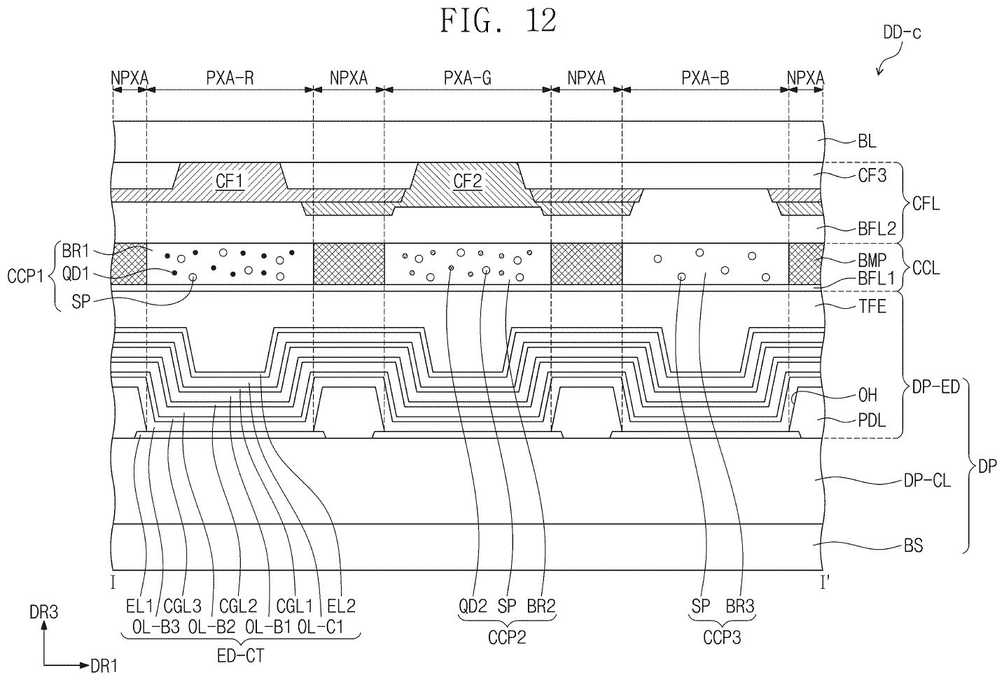

Referring to FIG. 11, a display device DD-b according to one or more embodiments may include light emitting elements ED-1, ED-2, and ED-3 in each of which two light emitting layers are stacked. The display device DD-b illustrated in FIG. 11 differs from the display device DD illustrated in FIG. 2 in that first to third light emitting elements ED-1, ED-2, and ED-3 each include two light emitting layers stacked in a thickness direction. The two light emitting layers in each of the first to third light emitting elements ED-1, ED-2, and ED-3 may be to emit light of the same wavelength region. At least one selected from among the first to third light emitting elements ED-1, ED-2, and ED-3 may include the fused polycyclic compound of one or more embodiments. The light emitting element (at least one selected from among ED-1, ED-2, and ED-3) including the fused polycyclic compound of one or more embodiments may exhibit low-driving voltage, high-efficiency, and long-lifespan properties.

The first light emitting element ED-1 may include a first red light emitting layer EML-R₁ and a second red light emitting layer EML-R₂. The second light emitting element ED-2 may include a first green light emitting layer EML-G1 and a second green light emitting layer EML-G2. In addition, the third light emitting element ED-3 may include a first blue light emitting layer EML-B1 and a second blue light emitting layer EML-B2. An emission auxiliary part OG may be disposed between the first red light emitting layer EML-R₁ and the second red light emitting layer EML-R₂, between the first green light emitting layer EML-G1 and the second green light emitting layer EML-G2, and between the first blue light emitting layer EML-B1 and the second blue light emitting layer EML-B2.

The emission auxiliary part OG may include a single layer or a multilayer. The emission auxiliary part OG may include a charge generation layer. In one or more embodiments, the emission auxiliary part OG may include an electron transport region, a charge generation layer, and a hole transport region that are sequentially stacked. The emission auxiliary part OG may be provided as a common layer in all of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red light emitting layer EML-R₁, the first green light emitting layer EML-G1, and the first blue light emitting layer EML-B1 may each be disposed between the emission auxiliary part OG and the electron transport region ETR. The second red light emitting layer EML-R₂, the second green light emitting layer EML-G2, and the second blue light emitting layer EML-B2 may each be disposed between the hole transport region HTR and the emission auxiliary part OG.

For example, in one or more embodiments, the first light emitting element ED-1 may include a first electrode EL1, a hole transport region HTR, a second red light emitting layer EML-R₂, an emission auxiliary part OG, a first red light emitting layer EML-R₁, an electron transport region ETR, and a second electrode EL2 that are sequentially stacked. The second light emitting element ED-2 may include a first electrode EL1, the hole transport region HTR, a second green light emitting layer EML-G2, the emission auxiliary part OG, a first green light emitting layer EML-G1, the electron transport region ETR, and the second electrode EL2 that are sequentially stacked. The third light emitting element ED-3 may include a first electrode EL1, the hole transport region HTR, a second blue light emitting layer EML-B2, the emission auxiliary part OG, a first blue light emitting layer EML-B1, the electron transport region ETR, and the second electrode EL2 that are sequentially stacked.

In some embodiments, an optical auxiliary layer PL may be disposed on the display element layer DP-ED. The optical auxiliary layer PL may include a polarizing layer. The optical auxiliary layer PL may be disposed on a display panel DP and control reflected light at the display panel DP due to external light. In some embodiments, the optical auxiliary layer PL in the display device may not be provided.

Unlike FIG. 10 and FIG. 11, a display device DD-c of FIG. 12 is illustrated as including four light emitting structures OL-B1, OL-B2, OL-B3, and OL-C1. A light emitting element ED-CT may include a first electrode EL1 and a second electrode EL2 facing each other, and first to fourth light emitting structures OL-B1, OL-B2, OL-B3, and OL-C1 stacked in a thickness direction between the first electrode EL1 and the second electrode EL2. The light emitting element ED-CT may include the fused polycyclic compound of one or more embodiments. The light emitting element ED-CT including the fused polycyclic compound of one or more embodiments may exhibit low-driving voltage, high-efficiency, and long-lifespan properties.

Charge generation layers CGL1, CGL2, and CGL3 may be disposed between adjacent first to fourth light emitting structures OL-B1, OL-B2, OL-B3, and OL-C1. The charge generation layers CGL1, CGL2, and CGL3 disposed between adjacent light emitting structures OL-B1, OL-B2, OL-B3, and OL-C1 may include a p-type or kind charge (e.g., P-charge) generation layer and/or an n-type or kind charge (e.g., N-charge) generation layer.

Among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light beams in different wavelength regions.

In one or more embodiments, an electronic apparatus may include a display device including a plurality of light emitting elements and a control part which controls the display device. The electronic apparatus of one or more embodiments may be a device that is activated according to an electrical signal. The electronic apparatus may include display devices of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

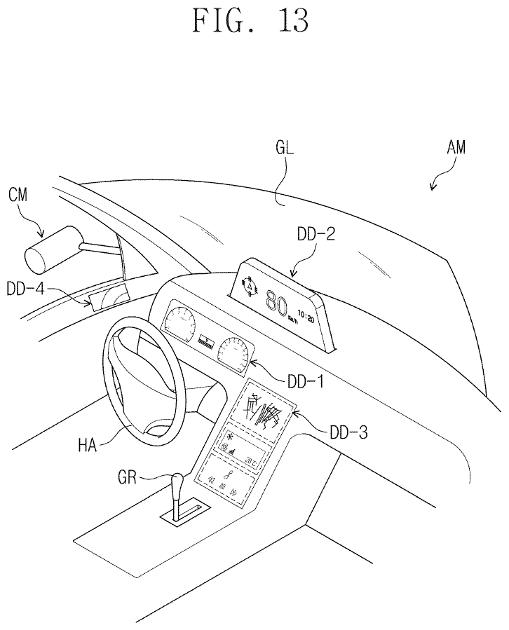

FIG. 13 is a view illustrating a vehicle AM in which first to fourth display devices DD-1, DD-2, DD-3, and DD-4 are disposed. At least one selected from among the first to fourth display devices DD-1, DD-2, DD-3, and DD-4 may include substantially the same configuration as the display devices DD, DD-TD, DD-a, DD-b, and/or DD-c as described with reference to FIGS. 1, and 2, and 9 to 12.

FIG. 13 illustrates a vehicle AM, but this is a mere example, and the first to fourth display devices DD-1, DD-2, DD-3, and DD-4 may be disposed in another transportation apparatuses such as bicycles, motorcycles, trains, ships, and/or airplanes. In some embodiments, at least one selected from among the first to fourth display devices DD-1, DD-2, DD-3, and DD-4 including substantially the same configuration as the display devices DD, DD-TD, DD-a, DD-b, and/or DD-c may be employed in a personal computer, a laptop computer, a personal digital terminal, a game console, a portable electronic device, a television, a monitor, an outdoor billboard, and/or the like. These are merely provided as embodiments, and the display device may be employed in other electronic apparatuses unless departing from the spirit of present disclosure.

In one or more embodiments, at least one selected from among the first to fourth display devices DD-1, DD-2, DD-3, and DD-4 may include one of the light emitting elements ED described with reference to FIG. 3 to FIG. 7. At least one selected from among the first to fourth display devices DD-1, DD-2, DD-3, and DD-4 may include the fused polycyclic compound of one or more embodiments. The display device (at least one selected from among DD-1, DD-2, DD-3, and DD-4) including the fused polycyclic compound of one or more embodiments may exhibit low-driving voltage, high-efficiency, and long-lifespan properties.

Referring to FIG. 13, the vehicle AM may include a steering wheel HA and a gear GR for driving the vehicle AM. In addition, the vehicle AM may include a front window GL disposed so as to face a driver.

The first display device DD-1 may be disposed in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, etc. The first scale and the second scale may be indicated as digital images.

The second display device DD-2 may be disposed in a second region facing a driver seat and overlapping the front window GL. The driver seat may be a seat in which the steering wheel HA faces. For example, the second display device DD-2 may be a head up display (HUD) which displays second information of the vehicle AM. The second display device DD-2 may be optically transparent. The second information may include digital numbers which indicate a driving speed, and may further include information such as the current time. In some embodiments, the second information of the second display device DD-2 may be projected to the front window GL and displayed on the front window GL.

The third display device DD-3 may be disposed in a third region adjacent to the gear GR. For example, the third display device DD-3 may be disposed between the driver seat and a passenger seat and may be a center information display (CID) for the vehicle to display third information. The passenger seat may be a seat spaced from the driver seat with the gear GR disposed therebetween. The third information may include information about traffic (e.g., navigation information), playing music or radio or a video (or an image), temperatures inside the vehicle AM, etc.

The fourth display device DD-4 may be spaced from the steering wheel HA and the gear GR and may be disposed in a fourth region adjacent to a side of the vehicle AM. For example, the fourth display device DD-4 may be a digital side-view mirror which displays fourth information. The fourth display device DD-4 may display an image outside the vehicle AM taken by a camera module CM disposed outside the vehicle AM. The fourth information may include an image outside the vehicle AM.

The above-described first to fourth information are mere examples, and the first to fourth display devices DD-1, DD-2, DD-3, and DD-4 may further display information about the inside and outside of the vehicle AM. The first to fourth information may include different information from each other. However, embodiments of the present disclosure are not limited thereto, and a portion of the first to fourth information may include the same information.

Hereinafter, referring to Examples and Comparative Examples, a fused polycyclic compound according to one or more embodiments of the present disclosure and a light emitting element of one or more embodiments will be described in more detail. In addition, Examples shown herein are for illustrative purposes, only to facilitate the understanding of the present disclosure, and thus, the scope of the present disclosure is not limited thereto.

### EXAMPLES

### 1. Synthesis of Fused Polycyclic Compounds of Embodiment

A method for synthesizing a fused polycyclic compound according to one or more embodiments will be described in more detail with reference to a method for synthesizing Fused Polycyclic Compounds 11, 22, 39, 52, and 85. In addition, the method for synthesizing the fused polycyclic compounds to be described herein is only an example, and the method for synthesizing a fused polycyclic compound according to embodiments of the present disclosure is not limited to Examples.

### (1) Synthesis of Fused Polycyclic Compound 11

Fused Polycyclic Compound 11 according to one or more embodiments may be synthesized by, for example, steps of Reaction Formula 1.

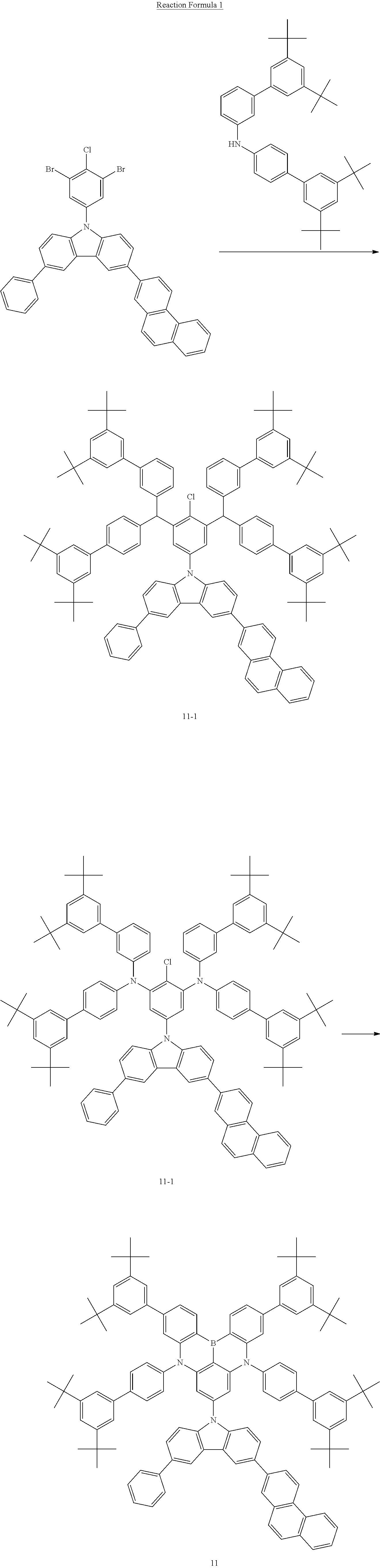

### Synthesis of Intermediate 11-1

9-(3,5-dibromo-4-chlorophenyl)-3-(phenanthren-2-yl)-6-phenyl-9H-carbazole (1 eq), 3′,5′-di-tert-butyl-N-(3′,5′-di-tert-butyl-[1,1′-biphenyl]-4-yl)-[1,1′-biphenyl]-3-amine (2 eq), Tris(dibenzylideneacetone)dipalladium(0) (0.05 eq), Tri-tert-butyl phosphine (0.1 eq), and Sodium tert-butoxide (3 eq) were dissolved in toluene, and then stirred at 100 degrees Celsius for 8 hours. The reaction solution was cooled, washed three times with ethyl acetate and water, and then separated to obtain an organic layer. The obtained organic layer was dried over MgSO₄ and then dried under reduced pressure. Intermediate 11-1 was obtained by purification by column chromatography utilizing methylene chloride (MC) and n-Hexane as an eluent. (Yield: 54%)

### Synthesis of Compound 11

Intermediate 11-1 (1 eq) was dissolved in t-butyl benzene in a flask, and then cooled to minus 78 degrees Celsius in a nitrogen atmosphere. After t-BuLi (2 eq) was slowly injected to the reactant solution, the mixture was stirred for 30 minutes by raising the temperature to room temperature, and then stirred at 90 degrees Celsius for 2 hours. The reactor temperature decreased to minus 78 degrees Celsius, and then BBr₃ (2 eq) was slowly injected thereto. After the completion of injection, the mixture was stirred at room temperature for 1 hour. After performing cooling to 0 degrees Celsius and injecting triethylamine (6 eq), the temperature was raised to 140 degrees Celsius, and stirring was performed for 12 hours. After the cooling, triethylamine was slowly dropped into the flask to terminate the reaction, and then ethyl alcohol was added to the reaction solution to perform precipitation and filtering to obtain solids. The obtained solids were purified by column chromatography to obtain Compound 11. (Yield: 23%)

### (2) Synthesis of Fused Polycyclic Compound 22

Fused Polycyclic Compound 22 according to one or more embodiments may be synthesized by, for example, steps of Reaction Formula 2.

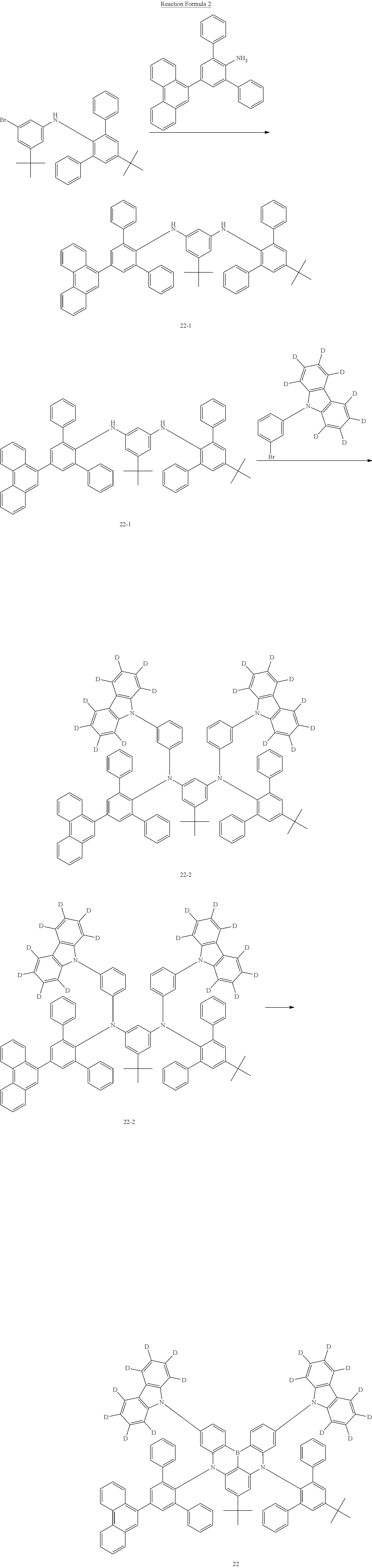

### Synthesis of Intermediate 22-1

N-(3-bromo-5-(tert-butyl)phenyl)-5′-(tert-butyl)-[1,1′:3′,1″-terphenyl]-2′-amine (1 eq), 5′-(phenanthren-9-yl)-[1,1′:3′,1″-terphenyl]-2′-amine (1.2 eq), Tris(dibenzylideneacetone)dipalladium(0) (0.15 eq), Tri-tert-butyl phosphine (0.3 eq), and Sodium tert-butoxide (3 eq) were dissolved in toluene, and then stirred at 110 degrees Celsius for 24 hours. The reaction solution was cooled, washed three times with ethyl acetate and water, and then separated to obtain an organic layer. The obtained organic layer was dried over MgSO₄ and then dried under reduced pressure. Intermediate 22-1 was obtained by purification by column chromatography utilizing MC and n-Hexane as an eluent. (Yield: 73%)

### Synthesis of Intermediate 22-2

Intermediate 22-1 (1 eq), 9-(3-bromophenyl)-9H-carbazole-1,2,3,4,5,6,7,8-d8 (4 eq), Tris(dibenzylideneacetone)dipalladium(0) (0.2 eq), Tri-tert-butyl phosphine (0.4 eq), and Sodium tert-butoxide (5 eq) were dissolved in o-xylene, and then stirred at 150 degrees Celsius for 60 hours. The reaction solution was cooled, washed three times with ethyl acetate and water, and then separated to obtain an organic layer. The obtained organic layer was dried over MgSO₄ and then dried under reduced pressure. Intermediate 22-2 was obtained by purification by column chromatography utilizing MC and n-Hexane as an eluent. (Yield: 32%)

### Synthesis of Compound 22

Intermediate 22-2 (1 eq) was dissolved in ortho dichlorobenzene in a flask, cooled to 0 degrees Celsius, and BBr₃ (4 eq) was slowly injected thereto in a nitrogen atmosphere. After the completion of the injection, the temperature was raised to 140 degrees Celsius and stirring was performed for 24 hours. After the cooling, triethylamine was slowly dropped into the flask to terminate the reaction, and then ethyl alcohol was added to the reaction solution to perform precipitation and filtering to obtain solids. The obtained solids were purified by column chromatography utilizing MC and n-Hexane as an eluent, and then recrystallized utilizing toluene and acetone to obtain Compound 22. (Yield: 5%)

### (3) Synthesis of Fused Polycyclic Compound 39

Fused Polycyclic Compound 39 according to one or more embodiments may be synthesized by, for example, steps of Reaction Formula 3.

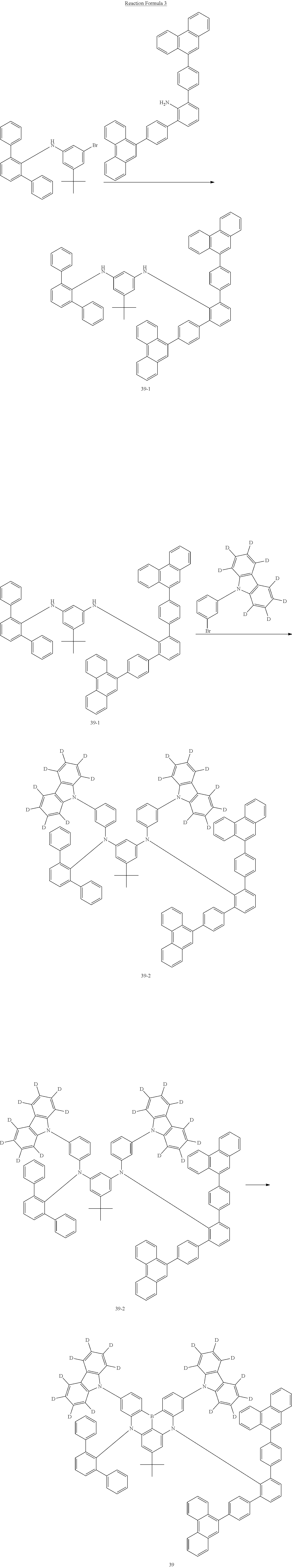

### Synthesis of Intermediate 39-1

N-(3-bromo-5-(tert-butyl)phenyl)-[1,1′:3′,1″-terphenyl]-2′-amine (1 eq), 4,4″-di(phenanthren-9-yl)-[1,1′:3′,1″-terphenyl]-2′-amine (1 eq), Tris(dibenzylideneacetone)dipalladium(0) (0.05 eq), Tri-tert-butyl phosphine (0.1 eq), and Sodium tert-butoxide (3 eq) were dissolved in toluene, and then stirred at 110 degrees Celsius for 12 hours. The reaction solution was cooled, washed three times with ethyl acetate and water, and then separated to obtain an organic layer. The obtained organic layer was dried over MgSO₄ and then dried under reduced pressure. Intermediate 39-1 was obtained by purification by column chromatography utilizing MC and n-Hexane as an eluent. (Yield: 75%)

### Synthesis of Intermediate 39-2

Intermediate 39-1 (1 eq), 9-(3-bromophenyl)-9H-carbazole-1,2,3,4,5,6,7,8-d8 (4 eq), Tris(dibenzylideneacetone)dipalladium(0) (0.25 eq), Tri-tert-butyl phosphine (0.5 eq), and Sodium tert-butoxide (5 eq) were dissolved in o-xylene, and then stirred at 150 degrees Celsius for 48 hours. The reaction solution was cooled, washed three times with ethyl acetate and water, and then separated to obtain an organic layer. The obtained organic layer was dried over MgSO₄ and then dried under reduced pressure. Intermediate 39-2 was obtained by purification by column chromatography utilizing MC and n-Hexane as an eluent. (Yield: 34%)

### Synthesis of Compound 39

Intermediate 39-2 (1 eq) was dissolved in ortho dichlorobenzene in a flask, cooled to 0 degrees Celsius, and BBr₃ (4 eq) was slowly injected thereto in a nitrogen atmosphere. After the completion of the injection, the temperature was raised to 140 degrees Celsius and stirring was performed for 24 hours. After the reaction solution was cooled, triethylamine was slowly dropped into the flask to terminate the reaction. Thereafter, ethyl alcohol was added to the reaction solution to perform precipitation and filtering to obtain solids. The obtained solids were purified by column chromatography utilizing MC and n-Hexane as an eluent, and then recrystallized utilizing toluene and acetone to obtain Compound 39. (Yield: 7%)

### (4) Synthesis of Fused Polycyclic Compound 52

Fused Polycyclic Compound 52 according to one or more embodiments may be synthesized by, for example, steps of Reaction Formula 4.

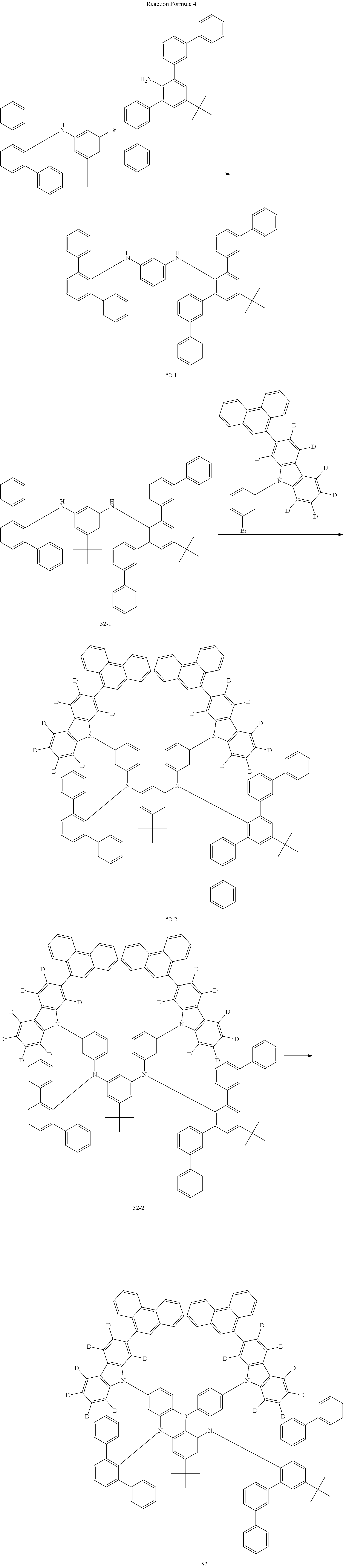

### Synthesis of Intermediate 52-1

N-(3-bromo-5-(tert-butyl)phenyl)-[1,1′:3′,1″-terphenyl]-2′-amine (1 eq), 5″-(tert-butyl)-[1,1′:3′,1″:3″,1′″:3′″,1″″-quinquephenyl]-2″-amine (1 eq), Tris(dibenzylideneacetone)dipalladium(0) (0.05 eq), Tri-tert-butyl phosphine (0.1 eq), and Sodium tert-butoxide (3 eq) were dissolved in toluene, and then stirred at 110 degrees Celsius for 12 hours. The reaction solution was cooled, washed three times with ethyl acetate and water, and then separated to obtain an organic layer. The obtained organic layer was dried over MgSO₄ and then dried under reduced pressure. Intermediate 52-1 was obtained by purification by column chromatography utilizing MC and n-Hexane as an eluent. (Yield: 69%)

### Synthesis of Intermediate 52-2

Intermediate 52-1 (1 eq), 9-(3-bromophenyl)-2-(phenanthren-9-yl)-9H-carbazole-1,3,4,5,6,7,8-d7 (4 eq), Tris(dibenzylideneacetone)dipalladium(0) (0.25 eq), Tri-tert-butyl phosphine (0.5 eq), and Sodium tert-butoxide (5 eq) were dissolved in o-xylene, and then stirred at 150 degrees Celsius for 48 hours. The reaction solution was cooled, washed three times with ethyl acetate and water, and then separated to obtain an organic layer. The obtained organic layer was dried over MgSO₄ and then dried under reduced pressure. Intermediate 52-2 was obtained by purification by column chromatography utilizing MC and n-Hexane as an eluent. (Yield: 29%)

### Synthesis of Compound 52

Intermediate 52-2 (1 eq) was dissolved in ortho dichlorobenzene in a flask, cooled to 0 degrees Celsius, and BBr₃ (4 eq) was slowly injected thereto in a nitrogen atmosphere. After the completion of the injection, the temperature was raised to 140 degrees Celsius and stirring was performed for 24 hours. After the reaction solution was cooled, triethylamine was slowly dropped into the flask to terminate the reaction. Thereafter, ethyl alcohol was added to the reaction solution to perform precipitation and filtering to obtain solids. The obtained solids were purified by column chromatography utilizing MC and n-Hexane as an eluent, and then recrystallized utilizing toluene and acetone to obtain Compound 52. (Yield: 6%)

### (5) Synthesis of Fused Polycyclic Compound 85

Fused Polycyclic Compound 85 according to one or more embodiments may be synthesized by, for example, steps of Reaction Formula 5.

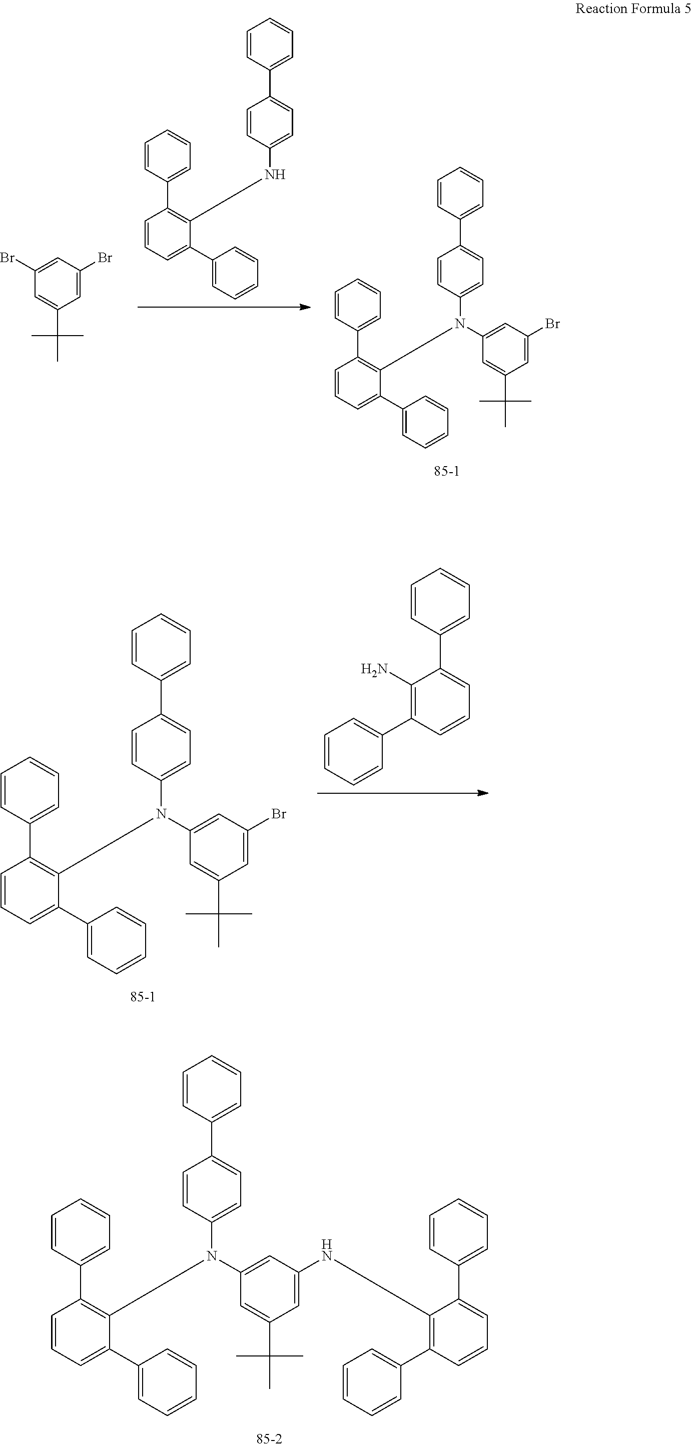

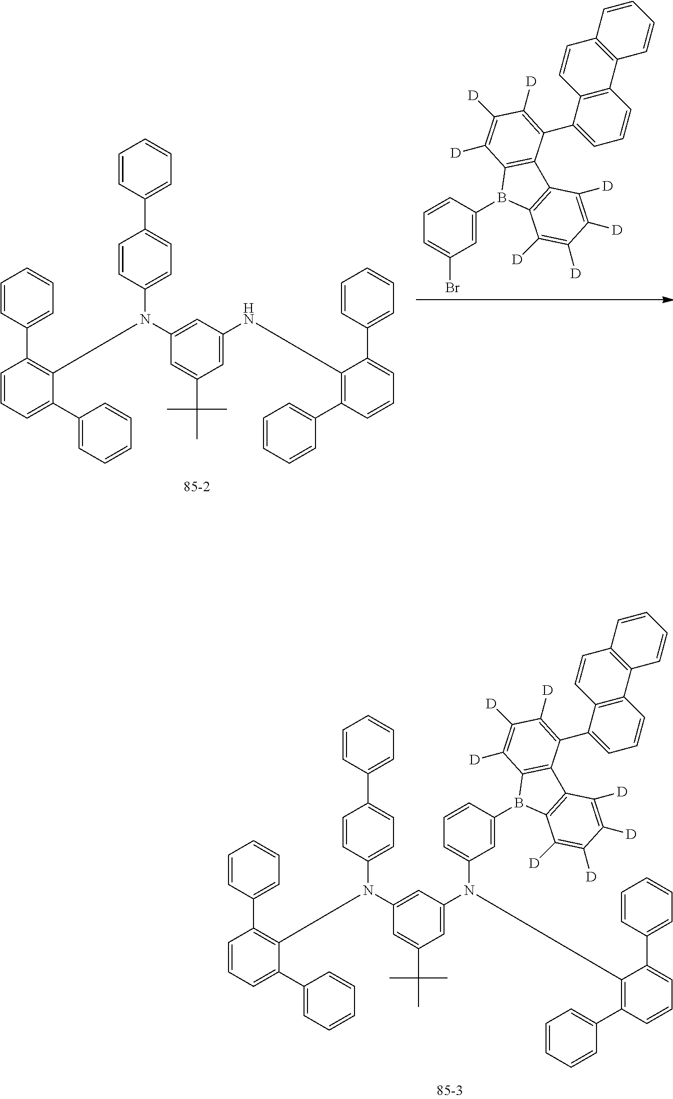 [SMILES: CC(C)(C)c1cc(Nc2c(-c3ccccc3)cccc2-c2ccccc2)cc(N(c2ccc(-c3ccccc3)cc2)c2c(-c3ccccc3)cccc2-c2ccccc2)c1 ; [2H]c1c([2H])c([2H])c2c(c1[2H])B(c1cccc(Br)c1)c1c([2H])c([2H])c([2H])c(-c3cccc4c3ccc3ccccc34)c1-2 ; [2H]c1c([2H])c([2H])c2c(c1[2H])B(c1cccc(N(c3cc(N(c4ccc(-c5ccccc5)cc4)c4c(-c5ccccc5)cccc4-c4ccccc4)cc(C(C)(C)C)c3)c3c(-c4ccccc4)cccc3-c3ccccc3)c1)c1c([2H])c([2H])c([2H])c(-c3cccc4c3ccc3ccccc34)c1-2]

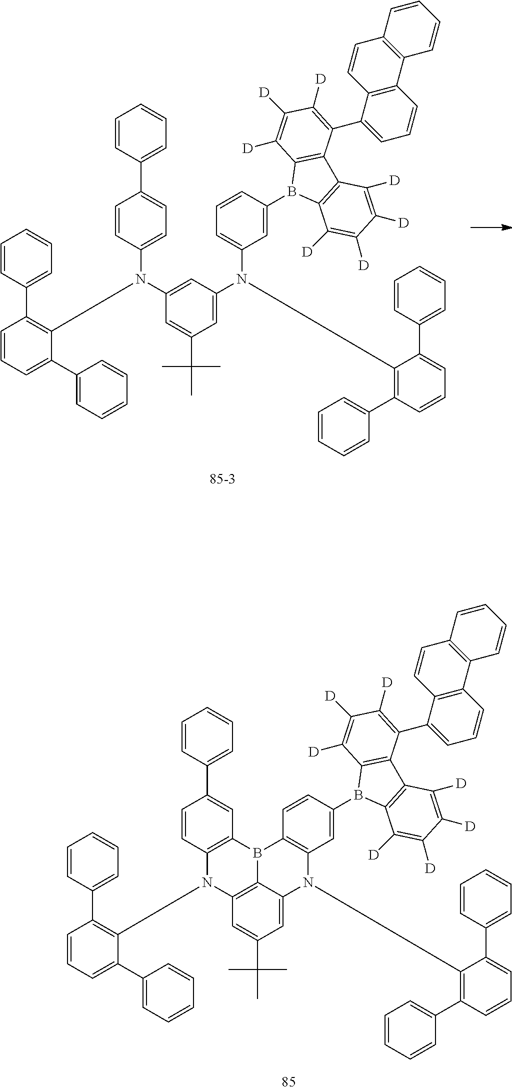 [SMILES: [2H]c1c([2H])c([2H])c2c(c1[2H])B(c1cccc(N(c3cc(N(c4ccc(-c5ccccc5)cc4)c4c(-c5ccccc5)cccc4-c4ccccc4)cc(C(C)(C)C)c3)c3c(-c4ccccc4)cccc3-c3ccccc3)c1)c1c([2H])c([2H])c([2H])c(-c3cccc4c3ccc3ccccc34)c1-2 ; [2H]c1c([2H])c([2H])c2c(c1[2H])B(c1ccc3c(c1)N(c1c(-c4ccccc4)cccc1-c1ccccc1)c1cc(C(C)(C)C)cc4c1B3c1cc(-c3ccccc3)ccc1N4c1c(-c3ccccc3)cccc1-c1ccccc1)c1c([2H])c([2H])c([2H])c(-c3cccc4c3ccc3ccccc34)c1-2]

### Synthesis of Intermediate 85-1

1,3-dibromo-5-(tert-butyl)benzene (1 eq), N-([1,1′-biphenyl]-4-yl)-[1,1′:3′,1″-terphenyl]-2′-amine (0.8 eq), Tris(dibenzylideneacetone)dipalladium(0) (0.05 eq), BINAP(([1,1′-Binaphthalene]-2,2′-diyl)bis(diphenylphosphane), 0.1 eq), and Sodium tert-butoxide (3 eq) were dissolved in toluene, and then stirred at 80 degree Celsius for 12 hours. The reaction solution was cooled, washed three times with ethyl acetone and water, and then separated to obtain an organic layer. The obtained organic layer was dried over MgSO₄ and then dried under reduced pressure. Intermediate 85-1 was obtained by purification by column chromatography utilizing MC and n-Hexane as an eluent. (Yield: 71%)

### Synthesis of Intermediate 85-2

Intermediate-85-1 (1 eq), [1,1′:3′1-terphenyl]-2′-amine (1 eq 0) Tris(dibenzylideneacetone)dipalladium(0) (0.05 eq), Tri-tert-butyl phosphine (0.1 eq) and Sodium tert-butoxide (3 eq) were dissolved in toluene, and then stirred at 110 degrees Celsius for 12 hours. The reaction solution was cooled, washed three times with ethyl acetate and water, and then separated to obtain an organic layer. The obtained organic layer was dried over MgSO₄ and then dried under reduced pressure. Intermediate 85-2 was obtained by purification by column chromatography utilizing MC and n-Hexane as an eluent. (Yield: 87%)

### Synthesis of Intermediate 85-3

Intermediate 85-2 (1 eq), 9-(3-bromophenyl)-4-(phenanthren-1-yl)-9H-carbazole-1,2,3,5,6,7,8-d7 (3 eq), Tris(dibenzylideneacetone)dipalladium(0) (0.25 eq), Tri-tert-butyl phosphine (0.5 eq), and Sodium tert-butoxide (5 eq) were dissolved in o-xylene, and then stirred at 150 degrees Celsius for 48 hours. The reaction solution was cooled, washed three times with ethyl acetate and water, and then separated to obtain an organic layer. The obtained organic layer was dried over MgSO₄ and then dried under reduced pressure. Intermediate 85-3 was obtained by purification by column chromatography utilizing MC and n-Hexane as an eluent. (Yield: 31%)

### Synthesis of Compound 85

Intermediate 85-3 (1 eq) was dissolved in ortho dichlorobenzene in a flask, cooled to 0 degrees Celsius, and BBr₃ (4 eq) was slowly injected thereto in a nitrogen atmosphere. After the completion of the injection, the temperature was raised to 140 degrees Celsius and stirring was performed for 24 hours. After the reaction solution was cooled, triethylamine was slowly dropped into the flask to terminate the reaction. Thereafter, ethyl alcohol was added to the reaction solution to perform precipitation and filtering to obtain solids. The obtained solids were purified by column chromatography utilizing MC and n-Hexane as an eluent, and then recrystallized utilizing toluene and acetone to obtain Compound 85. (Yield: 8%)

### 2. Manufacturing and Evaluation of Light Emitting Element

### (1) Manufacturing of Light Emitting Element

A light emitting element including the fused polycyclic compound of one or more embodiments or including a Comparative Example Compound in a light emitting layer was manufactured in the following manner. Compounds 11, 22, 39, 52, and 85, which are the fused polycyclic compounds of one or more embodiments, were respectively utilized as a dopant material of a light emitting layer to manufacture light emitting elements of Examples 1 to 5. Light emitting elements of Comparative Examples 1 to 8 were each manufactured respectively utilizing Comparative Example Compounds CX2 to CX9 as a dopant material of a light emitting layer.

As a first electrode, a glass substrate (manufactured by Corning Co., Ltd.) having an ITO electrode of 15 Ω/cm² (1200 Å) was cut to a size of 50 mm×50 mm×0.7 mm, ultrasonically cleaned respectively for 5 minutes with isopropyl alcohol and pure water, and then irradiated with ultraviolet rays for 30 minutes and exposed to ozone for further cleaning, and then mounted on a vacuum deposition apparatus.

On the first electrode, NPD was deposited to form a hole injection layer having a thickness of 300 Å. HT-1-1 was deposited on the hole injection layer to form a hole transport layer having a thickness of 200 Å, and then CZSI was deposited on the hole transport layer to form a light emitting auxiliary layer having a thickness of 100 Å.

On the light emitting auxiliary layer, a host mixture, a sensitizer, and a dopant were co-deposited at a weight ratio of 85:14:1 to form a light emitting layer having a thickness of 350 Å, and subsequently, ETH2 was vacuum-deposited to a thickness of 50 Å to form a hole blocking layer. On the hole blocking layer, a mixed layer of CNNPTRZ:LiQ with a weight ratio 4.0:6.0 was deposited to a thickness of 310 Å as an electron transport layer. On the electron transport layer, Yb was deposited to a thickness of 15 Å as an electron injection layer, and Mg was vacuum-deposited to a thickness of 800 Å to form a second electrode, thereby manufacturing a light emitting element.

### Materials Utilized in Manufacturing Light Emitting Elements

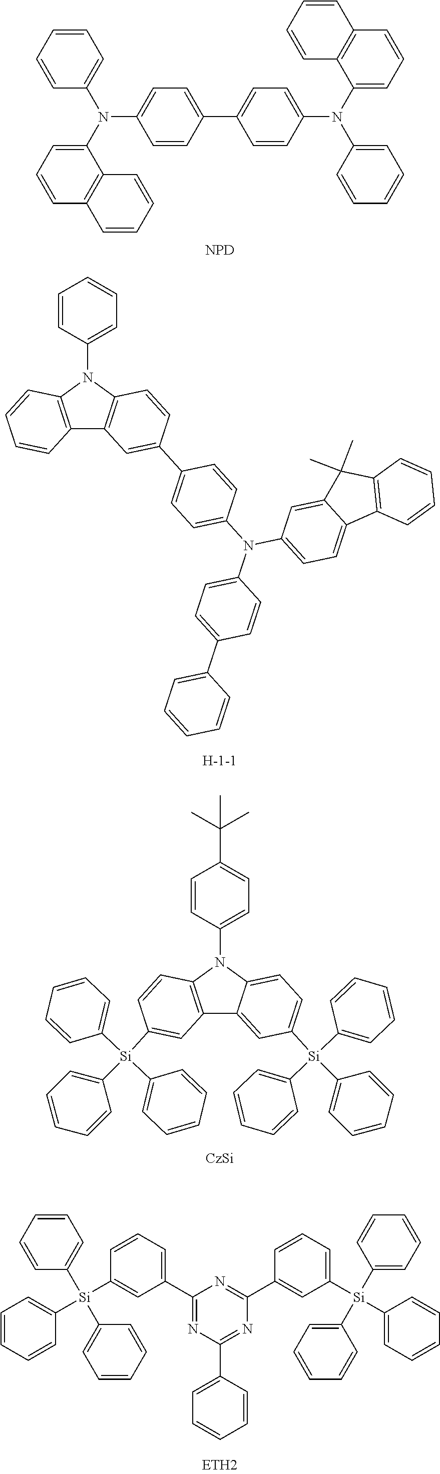 [SMILES: c1ccc(N(c2ccc(-c3ccc(N(c4ccccc4)c4cccc5ccccc45)cc3)cc2)c2cccc3ccccc23)cc1 ; "NPD" ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

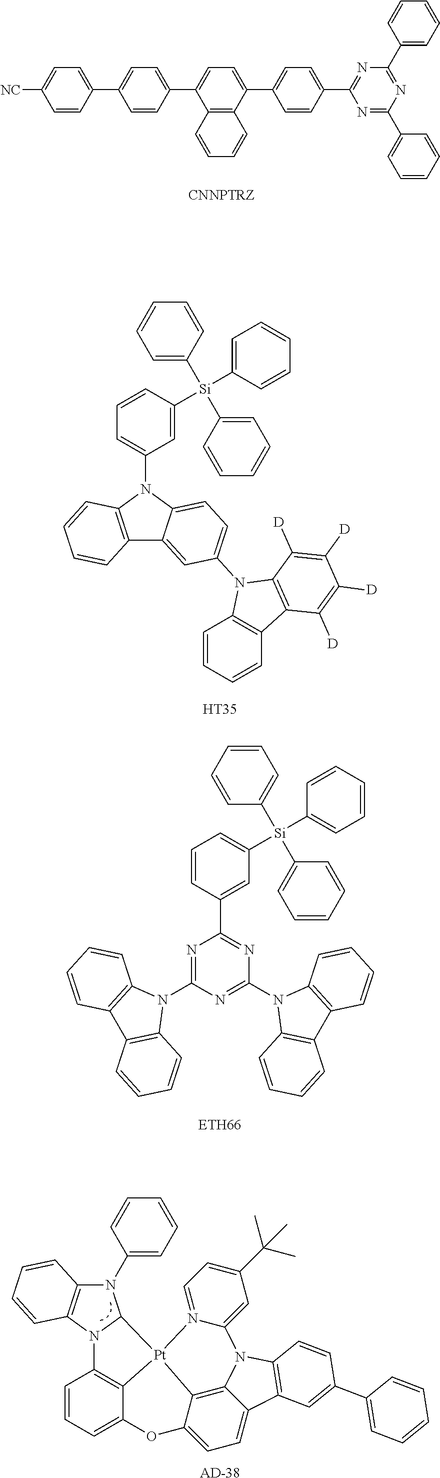

### Example Compounds

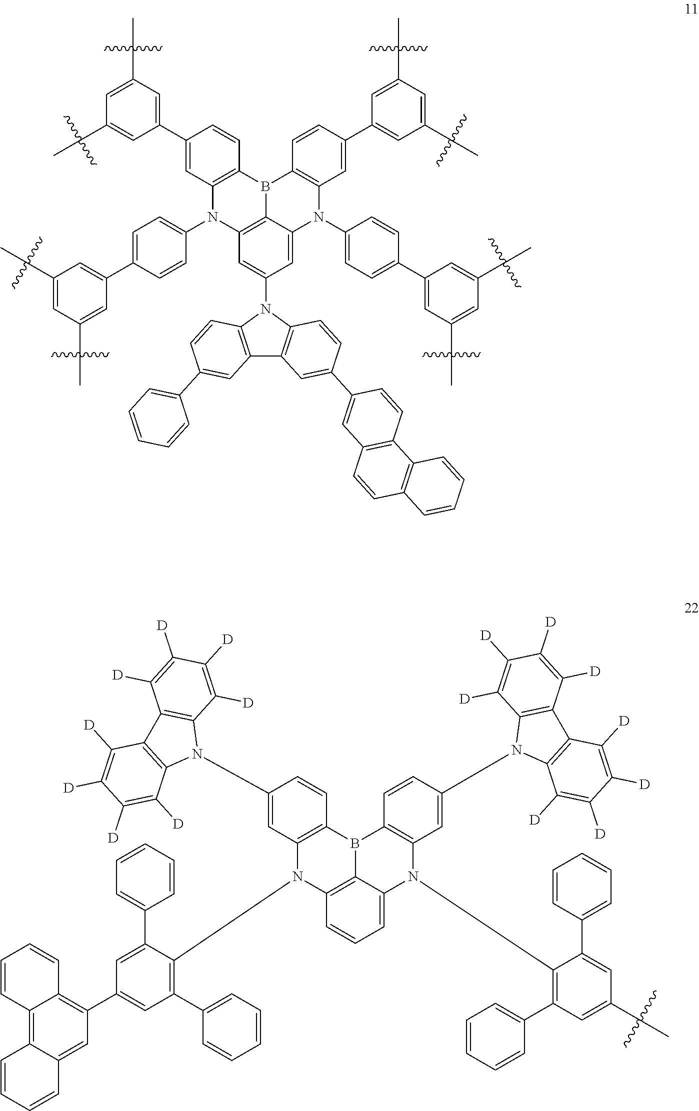 [SMILES: *c1cc(*)cc(-c2ccc(N3c4cc(-c5cc(*)cc(*)c5)ccc4B4c5ccc(-c6cc(*)cc(*)c6)cc5N(c5ccc(-c6cc(*)cc(*)c6)cc5)c5cc(-n6c7ccc(-c8ccccc8)cc7c7cc(-c8ccc9c(ccc%10ccccc%109)c8)ccc76)cc3c54)cc2)c1 ; *c1cc(-c2ccccc2)c(N2c3cc(-n4c5c([2H])c([2H])c([2H])c([2H])c5c5c([2H])c([2H])c([2H])c([2H])c54)ccc3B3c4ccc(-n5c6c([2H])c([2H])c([2H])c([2H])c6c6c([2H])c([2H])c([2H])c([2H])c65)cc4N(c4c(-c5ccccc5)cc(-c5cc6ccccc6c6ccccc56)cc4-c4ccccc4)c4cccc2c43)c(-c2ccccc2)c1]

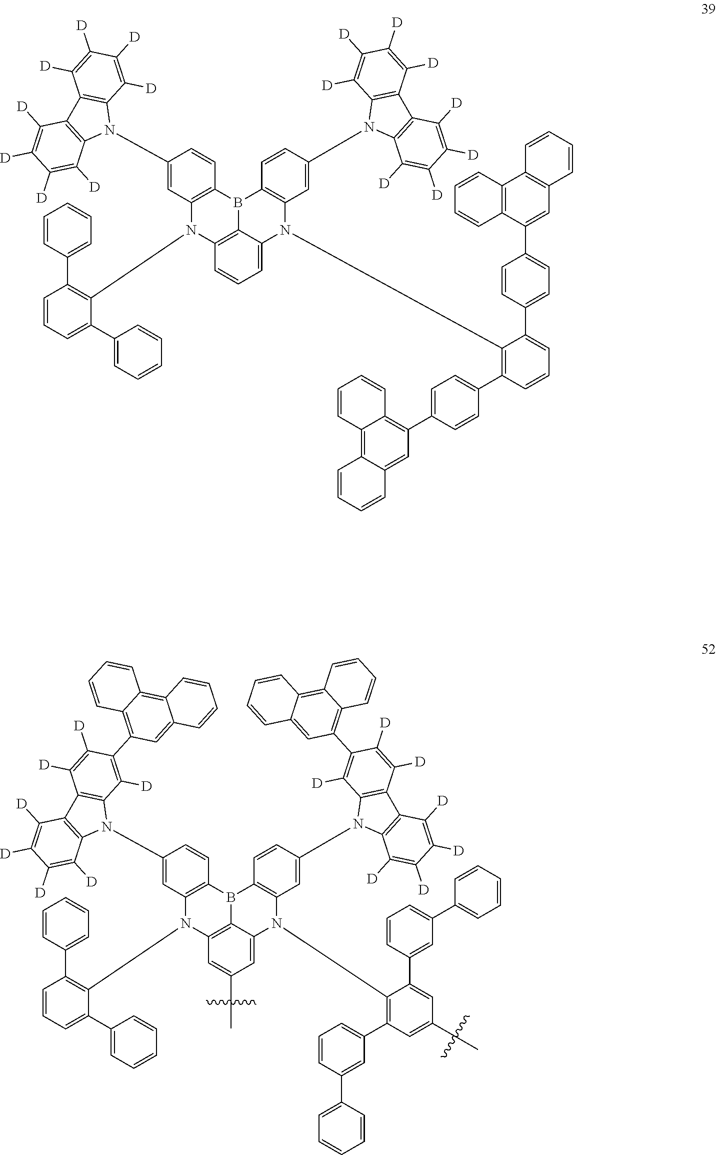

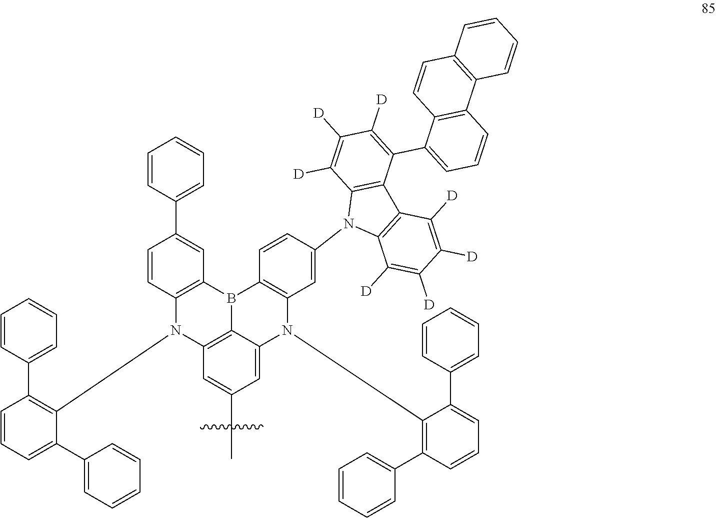 [SMILES: *c1cc2c3c(c1)N(c1c(-c4ccccc4)cccc1-c1ccccc1)c1cc(-n4c5c([2H])c([2H])c([2H])c([2H])c5c5c(-c6cccc7c6ccc6ccccc67)c([2H])c([2H])c([2H])c54)ccc1B3c1cc(-c3ccccc3)ccc1N2c1c(-c2ccccc2)cccc1-c1ccccc1]

### Comparative Example Compounds

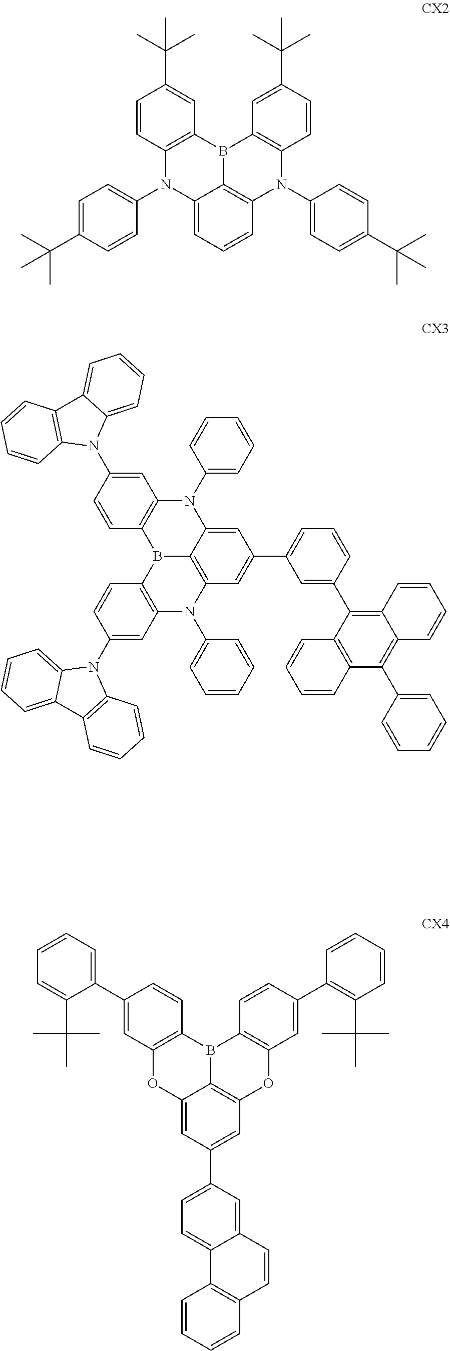

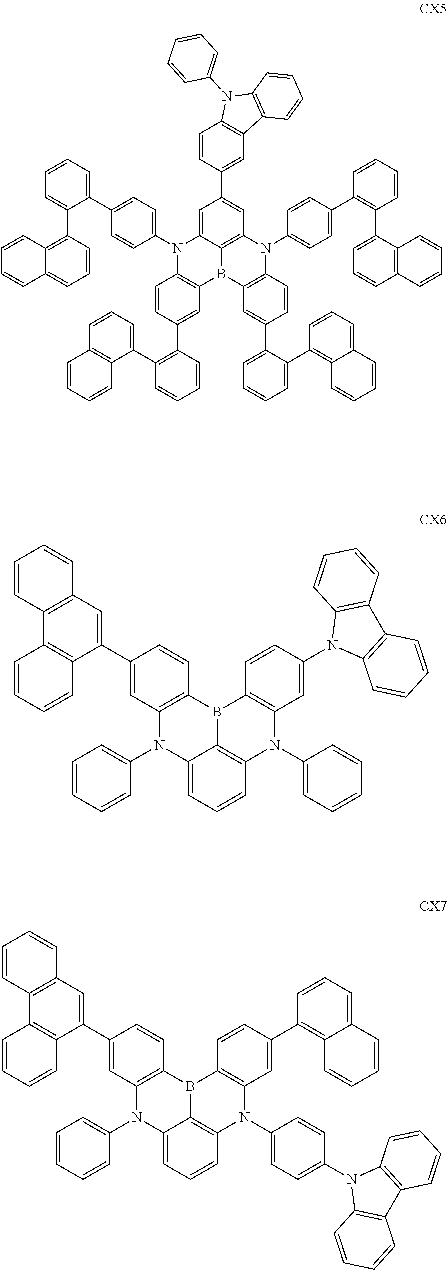 [SMILES: c1ccc(-n2c3ccccc3c3cc(-c4cc5c6c(c4)N(c4ccc(-c7ccccc7-c7cccc8ccccc78)cc4)c4ccc(-c7ccccc7-c7cccc8ccccc78)cc4B6c4cc(-c6ccccc6-c6cccc7ccccc67)ccc4N5c4ccc(-c5ccccc5-c5cccc6ccccc56)cc4)ccc32)cc1 ; c1ccc(N2c3cc(-c4cc5ccccc5c5ccccc45)ccc3B3c4ccc(-n5c6ccccc6c6ccccc65)cc4N(c4ccccc4)c4cccc2c43)cc1 ; c1ccc(N2c3cc(-c4cc5ccccc5c5ccccc45)ccc3B3c4ccc(-c5cccc6ccccc56)cc4N(c4ccc(-n5c6ccccc6c6ccccc65)cc4)c4cccc2c43)cc1]

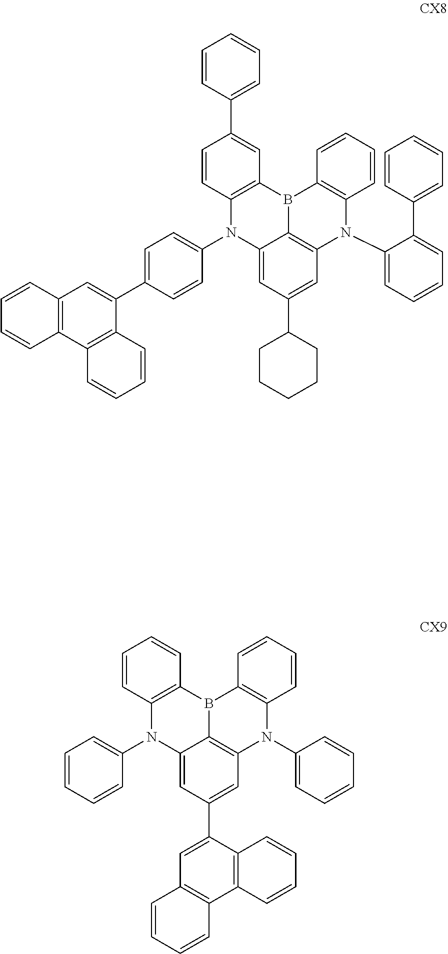 [SMILES: c1ccc(-c2ccc3c(c2)B2c4ccccc4N(c4ccccc4-c4ccccc4)c4cc(C5CCCCC5)cc(c42)N3c2ccc(-c3cc4ccccc4c4ccccc34)cc2)cc1 ; c1ccc(N2c3ccccc3B3c4ccccc4N(c4ccccc4)c4cc(-c5cc6ccccc6c6ccccc56)cc2c43)cc1]

### (2) Evaluation of Light Emitting Elements

Table 2 shows the evaluation of each of light emitting elements of Comparative Examples and Examples. The driving voltage, light emission efficiency, light emission wavelength, and lifespan at a current density of 10 mA/cm² were measured utilizing a Keithley MU 236 and a luminance meter PR650. Lifespan (T95) is the result of measuring the time required for luminance to decrease to 95% of an initial luminance, and then calculating relative lifespan with respect to Comparative Example 1.

TABLE 2

| | | | | | Light | Light | |
|---|---|---|---|---|---|---|---|
| | | | | | emis- | emis- | |
| | Host | | | | sion | sion | |
| | (HT: | | | Driving | effi- | wave- | Life- |
| | ET = | Sensi- | | voltage | ciency | length | span |
| | 5:5) | tizer | Dopant | (V) | (cd/A) | (nm) | (T95) |
| Exam- | HT35/ | AD-38 | Compound | 4.6 | 24.8 | 459 | 4.6 |
| ple 1 | ETH66 | | 11 | | | | |
| Exam- | HT35/ | AD-38 | Compound | 4.4 | 26.1 | 461 | 6.8 |
| ple 2 | ETH66 | | 22 | | | | |
| Exam- | HT35/ | AD-38 | Compound | 4.4 | 26.4 | 460 | 6.6 |
| ple 3 | ETH66 | | 39 | | | | |
| Exam- | HT35/E | AD-38 | Compound | 4.4 | 26.6 | 462 | 7.1 |
| ple 4 | TH66 | | 52 | | | | |
| Exam- | HT35/E | AD-38 | Compound | 4.5 | 25.7 | 463 | 6.9 |
| ple 5 | TH66 | | 85 | | | | |
| Compar- | HT35/ | AD-38 | Compar- | 5.2 | 19.8 | 465 | 1 |
| ative | ETH66 | | ative | | | | |
| Exam- | | | Example | | | | |
| ple 1 | | | Compound | | | | |
| | | | CX2 | | | | |
| Compar- | HT35/ | AD-38 | Compar- | 5.4 | 12.4 | 470 | 1.8 |
| ative | ETH66 | | ative | | | | |
| Exam- | | | Example | | | | |
| ple 2 | | | Compound | | | | |
| | | | CX3 | | | | |
| Compar- | HT35/ | AD-38 | Compar- | 5.6 | 18.6 | 457 | 0.7 |
| ative | ETH66 | | ative | | | | |
| Exam- | | | Example | | | | |
| ple 3 | | | Compound | | | | |
| | | | CX4 | | | | |
| Compar- | HT35/ | AD-38 | Compar- | 5.0 | 22.1 | 464 | 3.7 |
| ative | ETH66 | | ative | | | | |
| Exam- | | | Example | | | | |
| ple 4 | | | Compound | | | | |
| | | | CX5 | | | | |
| Compar- | HT35/ | AD-38 | Compar- | 5.1 | 20.4 | 468 | 1.6 |
| ative | ETH66 | | ative | | | | |
| Exam- | | | Example | | | | |
| ple 5 | | | Compound | | | | |
| | | | CX6 | | | | |
| Compar- | HT35/ | AD-38 | Compar- | 5.2 | 21.6 | 472 | 2.5 |
| ative | ETH66 | | ative | | | | |
| Exam- | | | Example | | | | |
| ple 6 | | | Compound | | | | |
| | | | CX7 | | | | |
| Compar- | HT35/ | AD-38 | Compar- | 5.6 | 17.2 | 463 | 0.9 |
| ative | ETH66 | | ative | | | | |
| Exam- | | | Example | | | | |
| ple 7 | | | Compound | | | | |
| | | | CX8 | | | | |
| Compar | HT35/ | AD-38 | Compar- | 5.7 | 16.2 | 471 | 1.9 |
| ative | ETH66 | | ative | | | | |
| Exam- | | | Example | | | | |
| ple 8 | | | Compound | | | | |
| | | | CX9 | | | | |

Referring to Table 2, it can be seen that compared to the light emitting elements of Comparative Examples 1 to 8, the light emitting elements of Examples 1 to 5 each have a relatively low driving voltage, a relatively high light emission efficiency, and a relatively long lifespan. The light emitting elements of Examples 1 to 5 respectively include Compounds 11, 22, 39, 52, and 85, wherein Compounds 11, 22, 39, 52, and 85 are the fused polycyclic compounds of one or more embodiments. Compounds 11, 22, 39, 52, and 85 each include a phenanthryl moiety and a carbazole moiety bonded directly or indirectly to a 5-ring fused ring system. Accordingly, it can be seen that a light emitting element including the fused polycyclic compound of one or more embodiments will exhibit relatively low-driving voltage, relatively high-efficiency, and relatively long-lifespan properties.

The light emitting element of Comparative Example 1 includes Comparative Example Compound CX2, wherein Comparative Example Compound CX2 does not include a phenanthryl moiety and a carbazole moiety. Accordingly, the light emitting element of Comparative Example 1 exhibits a relatively high driving voltage, a relatively low efficiency, and a short lifespan.

The light emitting element of Comparative Example 2 includes Comparative Example Compound CX3, wherein Comparative Example Compound CX3 does not include a phenanthryl moiety but includes an anthracene moiety. Due to a low T1 energy level of the anthracene moiety, Comparative Example Compound CX3 has a ΔE_{ST} close to about 1 eV, and thus, is not suitable as a TADF material. In addition, Comparative Example Compound CX3 acts as a quencher of a T1 exciton, causing a decrease in light emission efficiency of the light emitting element. Accordingly, the light emitting element of Comparative Example 2 exhibits a relatively high driving voltage, a relatively low efficiency, and a relatively short lifespan.

The light emitting element of Comparative Example 3 includes Comparative Example Compound CX4, wherein Comparative Example Compound CX4 does not include a carbazole moiety, but includes an oxygen atom, rather than a nitrogen atom, as a ring-forming atom of the central structure. The oxygen atom has weak donor properties compared to the nitrogen atom, so that Comparative Example Compound CX4 has weak multiple resonance, resulting in poor RISC. In addition, Comparative Example Compound CX4 has weak multiple resonance, and thus, has a large Stokes shift and/or the like, which is disadvantageous to a Fluorescence Resonance Energy Transfer (FRET) from the sensitizer. Accordingly, the light emitting element of Comparative Example 3 exhibits a relatively high driving voltage, a relatively low efficiency, and a relatively short lifespan.

In addition, the light emitting element of Comparative Example 2 has a relatively long light emission wavelength. The light emitting element of Comparative Example 3 has a relatively short light emission wavelength, and Comparative Example Compound CX4 has a structure that does not allow energy transfer.

The light emitting element of Comparative Example 4 includes Comparative Example Compound CX5, wherein Comparative Example Compound CX5 does not include a phenanthryl moiety. Accordingly, the light emitting element of Comparative Example 4 exhibits a relatively high driving voltage, a relatively low efficiency, and a relatively short lifespan.

The light emitting element of Comparative Example 5 includes Comparative Example Compound CX6, wherein Comparative Example Compound CX6 includes a phenanthryl moiety directly linked to the core structure. Comparative Example Compound CX6 corresponds to a case in which L_{d} of Formula 2 does not include a carbazole moiety. Comparative Example Compound CX6 differs from the fused polycyclic compound of one or more embodiments in that at least one selected from among the rest of Rₐ₁ to R^{a5} of Formula 1 not represented by Formula 2 does not include a carbazole moiety substituted with a substituent other than a phenanthryl group. Comparative Example Compound CX6 differs from the fused polycyclic compound of one or more embodiments in that only one of Rₐ₂ and Rₐ₃ of Formula 1 includes an unsubstituted carbazole moiety. Comparative Example Compound CX6 does not have a substituent that protects a 5-ring fused ring system, which is the central structure, so that the suppression of Dexter energy transfer is insignificant. Accordingly, the light emitting element of Comparative Example 5 exhibits a relatively high driving voltage, a relatively low efficiency, and a relatively short lifespan.

The light emitting element of Comparative Example 6 includes Comparative Example Compound CX7, wherein Comparative Example Compound CX7 corresponds to a case in which L_{d} of Formula 2 does not include a carbazole moiety. Comparative Example Compound CX7 differs from the fused polycyclic compound of one or more embodiments in that at least one selected from among the rest of Rₐ₁ to R^{a5} of Formula 1 not represented by Formula 2 does not include carbazole substituted with a substituent other than a phenanthryl group. Comparative Example Compound CX7 includes a carbazole group in which Rₐ₄ or R^{a5} is not substituted. Comparative Example Compound CX7 differs from the fused polycyclic compound of one or more embodiments in that Rₐ₂ and Rₐ₃ of Formula 1 do not include a substituted or unsubstituted carbazole moiety. Comparative Example Compound CX7 does not have a substituent that protects a 5-ring fused ring system, which is the central structure, so that the suppression of Dexter energy transfer is insignificant. Accordingly, the light emitting element of Comparative Example 6 exhibits a relatively high driving voltage, a relatively low efficiency, and a relatively short lifespan.

The light emitting element of Comparative Example 7 includes Comparative Example Compound CX8, wherein Comparative Example Compound CX8 does not include a carbazole moiety. Comparative Example Compound CX8 does not have sufficient bulkiness, and has a weak (e.g., less stable) cyclohexyl group, which causes the degradation in lifespan of the light emitting element. In addition, Comparative Example Compound CX8 has a high HOMO energy level, thereby generating a shallow hole trap, which increases the driving voltage. Because Comparative Example Compound CX8, which is a dopant, participates in the generation of excitons, the concentration of triplet excitons is increased, resulting in the degradation in efficiency and lifetime of the light emitting element. Accordingly, the light emitting element of Comparative Example 7 exhibits a relatively high driving voltage, a relatively low efficiency, and a relatively short lifespan.

The light emitting element of Comparative Example 8 includes Comparative Example Compound CX9, wherein Comparative Example Compound CX9 does not include a carbazole moiety. Comparative Example Compound CX9 does not have sufficient bulkiness by a substituent protecting the central structure. In addition, Comparative Example Compound CX9 has a high HOMO energy level, thereby generating a shallow hole trap, which increases the driving voltage. Because Comparative Example Compound CX9, which is a dopant, participates in the generation of excitons, the concentration of triplet excitons is increased, resulting in the degradation in efficiency and lifetime of the light emitting element. Accordingly, the light emitting element of Comparative Example 8 exhibits a relatively high driving voltage, a relatively low efficiency, and a relatively short lifespan.

A display device of one or more embodiments may include the light emitting element of one or more embodiments. The light emitting element of one or more embodiments may include the fused polycyclic compound of one or more embodiments. The fused polycyclic compound of one or more embodiments includes, as a central structure, a 5-ring fused ring system containing two nitrogen atoms and one boron atom as ring-forming atoms, and a phenanthryl moiety and a carbazole moiety may be bonded to the central structure. The fused polycyclic compound of one or more embodiments including a phenanthryl group may accelerate RISC. The fused polycyclic compound of one or more embodiments including a carbazole group may exhibit properties that facilitate the matching of a host material and a HOMO energy level of the fused polycyclic compound. Accordingly, the fused polycyclic compound of one or more embodiments may contribute to improving the efficiency and lifespan of the light emitting element. A light emitting element including the fused polycyclic compound of one or more embodiments may exhibit relatively high-efficiency and relatively long-lifespan properties. A display device including the fused polycyclic compound of one or more embodiments may exhibit excellent or suitable display efficiency and display lifespan.

A light emitting element of one or more embodiments and a display device including the light emitting element include a fused polycyclic compound of one or more embodiments, and thus, may exhibit relatively high-efficiency and relatively long-lifespan properties.

The fused polycyclic compound of one or more embodiments may contribute to the relatively high efficiency and the relatively long lifespan of the light emitting element.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In present disclosure, “not include a or any ‘component’” “exclude a or any ‘component’”, “‘component’-free”, and/or the like refers to that the “component” not being added, selected, or utilized as a component in a compound/composition, but the “component” of less than a suitable amount may still be included due to other impurities and/or external factors in a composition.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when particles are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The light-emitting element, the display device, the electronic apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to example embodiments of the present disclosure, it will be understood by those skilled in the art that one or more suitable modifications and changes in form and details may be made therein without departing from the spirit and scope of the present disclosure as set forth in the appended claims and equivalents thereof.

Accordingly, the technical scope of the present disclosure is not intended to be limited to the contents set forth in the detailed description of the disclosure, but is intended to be defined by the appended claims and equivalents thereof.

What is claimed is:

1. A light emitting element comprising:
a first electrode;
a second electrode on the first electrode; and
a light emitting layer between the first electrode and the second electrode and comprising a first compound represented by Formula 1: 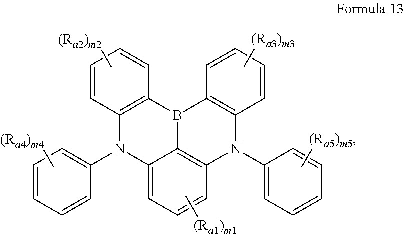
wherein, in Formula 1,
m1 is an integer of 0 to 3,
m2 and m3 are each independently an integer of 0 to 4,
m4 and m5 are each independently an integer of 0 to 5,
at least one selected from among Rₐ₁ to R^{a5} comprises a first carbazole substituted or unsubstituted, and
at least one selected from among Rₐ₁ to R^{a5} is a group represented by Formula 2, and the rest thereof are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms: 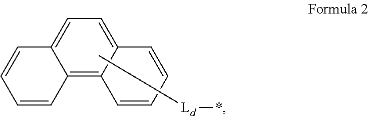
and
wherein, in Formula 2,
L_{d} is a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 30 ring-forming carbon atoms,
and
when L_{d} does not include the first carbazole:
at least one selected from among Rₐ₁ to R^{a5} not represented by Formula 2 comprises the first carbazole substituted with a substituent other than a phenanthryl group; or
Rₐ₂ and Rₐ₃ are each independently include the first carbazole not substituted or the first carbazole substituted with a substituent other than a phenanthryl group.

2. The light emitting element of claim 1, wherein the light emitting layer further comprises at least one of a second compound represented by Formula HT-1, a third compound represented by Formula ET-1, or a fourth compound represented by Formula D-1: 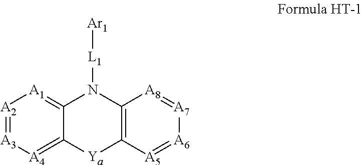
in Formula HT-1,
A₁ to A₈ being each independently N or CR₅₁,
L₁ being a direct linkage, a substituted or unsubstituted arylene group having 6 to 30 ring-forming carbon atoms, or a substituted or unsubstituted heteroarylene group having 2 to 30 ring-forming carbon atoms,
Yₐ being a direct linkage, CR₅₂R₅₃, or SiR₅₄R₅₅,
Ar₁ being a substituted or unsubstituted aryl group having 6 to 30 ring-forming carbon atoms or a substituted or unsubstituted heteroaryl group having 2 to 30 ring-forming carbon atoms, and
R₅₁ to R₅₅ being each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or form a ring by being bonded to an adjacent group; 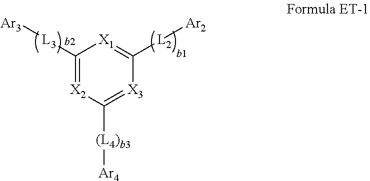
in Formula ET-1,
at least one selected from among X₁ to X₃ being N, and the rest thereof being CR₅₆,
R₅₆ being a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 being each independently an integer of 0 to 10,
Ar₂ to Ar₄ being each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ being each independently a direct linkage, a substituted or unsubstituted arylene group having 6 to 30 ring-forming carbon atoms, or a substituted or unsubstituted heteroarylene group having 2 to 30 ring-forming carbon atoms; and 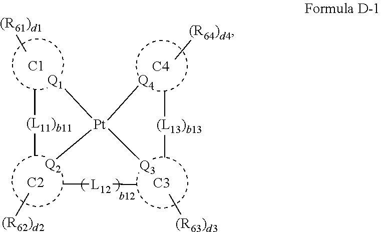
in Formula D-1,
Q₁ to Q₄ being each independently C or N,
C1 to C4 being each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle ring having 2 to 30 ring-forming carbon atoms,
L₁₁ to L₁₃ being each independently a direct linkage, *—O—*, *—S—*, 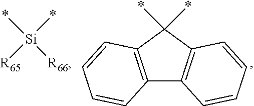
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 being each independently 0 or 1,
R₆₁ to R₆₆ being each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 being each independently an integer of 0 to 4.

3. The light emitting element of claim 1, wherein the first compound represented by Formula 1 is represented by any one selected from among Formula 1-1 to Formula 1-3: 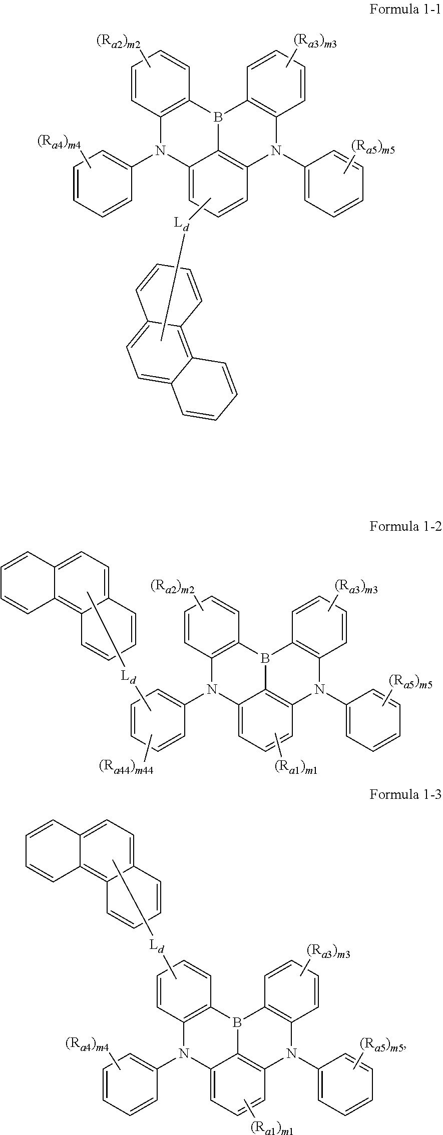
in Formula 1-2,
m44 being an integer of 0 to 4, and
Rₐ₄₄ being a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
in Formula 1-1 to Formula 1-3,
m1 to m5, Rₐ₁ to R^{a5}, and L_{d} being each the same as defined in Formula 1 and Formula 2.

4. The light emitting element of claim 3, wherein the first compound represented by Formula 1-1 is represented by Formula 1-1A: 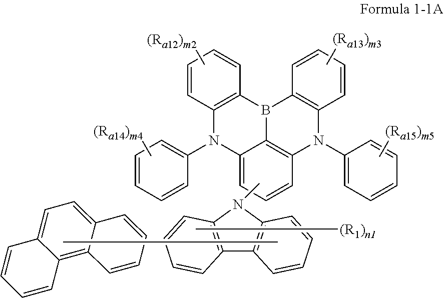
and
wherein, in Formula 1-1A,
n1 is an integer of 0 to 7,
R₁ and Rₐ₁₂ to Rₐ₁₅ are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m2 to m5 are each the same as defined in Formula 1-1.

5. The light emitting element of claim 3, wherein the first compound represented by Formula 1-2 is represented by Formula 1-2A: 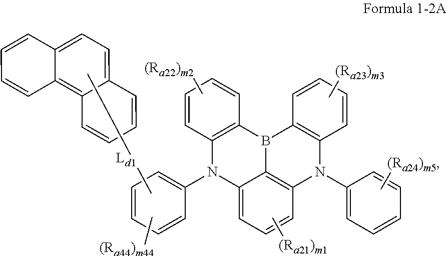
wherein, in Formula 1-2A,
L_{d1} is a direct linkage or a substituted or unsubstituted arylene group having 6 to 30 ring-forming carbon atoms,
wherein:
at least one selected from among Rₐ₂₁ to Rₐ₂₄ is the first carbazole substituted with a substituent other than a phenanthryl group, and the rest thereof are each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; or
Rₐ₂₂ and Rₐ₂₃ each are independently the first carbazole not substituted or the first carbazole substituted with a substituent other than a phenanthryl group, and Rₐ₂₁ and Rₐ₂₄ are each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
wherein m1 to m3, m5, m44, and Rₐ₄₄ are each the same as defined in Formula 1-2.

6. The light emitting element of claim 3, wherein the first compound represented by Formula 1-3 is represented by Formula 1-3A: 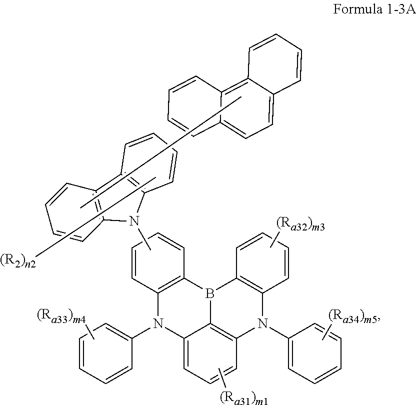
and
wherein, in Formula 1-3A,
n2 is an integer of 0 to 7,
R₂ and Rₐ₃₁ to Rₐ₃₄ are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m1 and m3 to m5 are each the same as defined in Formula 1-3.

7. The light emitting element of claim 6, wherein the first compound represented by Formula 1-3A is represented by Formula 1-3AA: 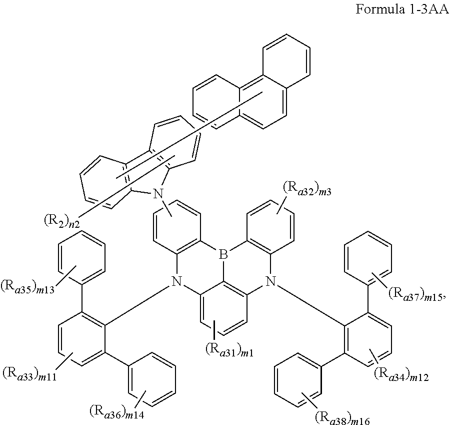
and
wherein, in Formula 1-3AA,
m11 and m12 are each independently an integer of 0 to 3,
m13 to m16 are each independently an integer of 0 to 5,
Rₐ₃₅ to Rₐ₃₈ are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m1, m3, n2, R₂, and Rₐ₃₁ to Rₐ₃₄ are each the same as defined in Formula 1-3A.

8. The light emitting element of claim 1, wherein the group represented by Formula 2 is represented by any one selected from among Formula 2-1 to Formula 2-31: 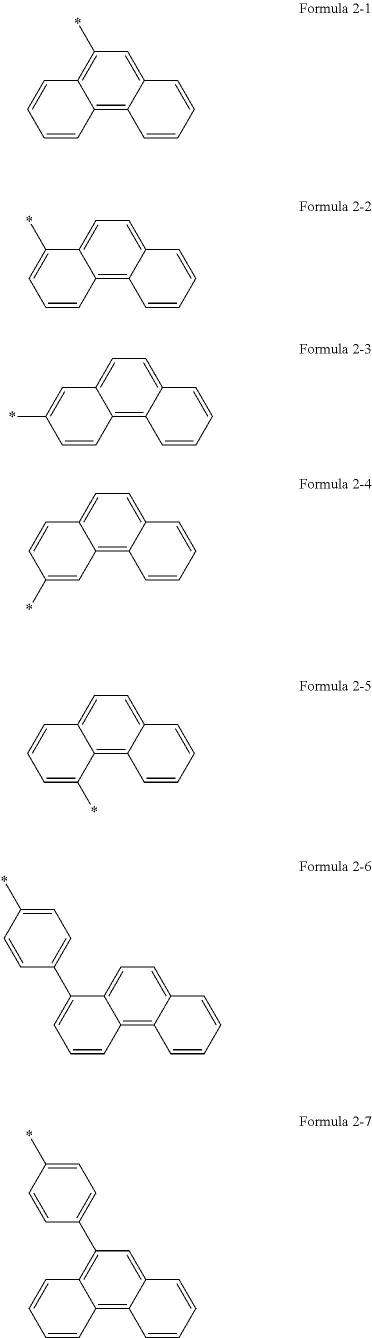 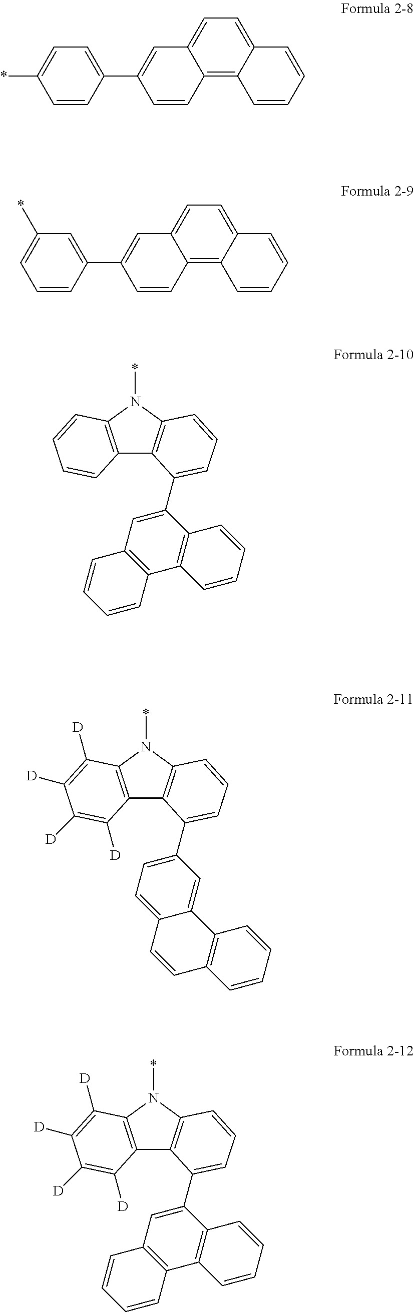 [SMILES: *c1ccc(-c2ccc3c(ccc4ccccc43)c2)cc1 ; *c1cccc(-c2ccc3c(ccc4ccccc43)c2)c1 ; *n1c2ccccc2c2c(-c3cc4ccccc4c4ccccc34)cccc21 ; *n1c2cccc(-c3ccc4ccc5ccccc5c4c3)c2c2c([2H])c([2H])c([2H])c([2H])c21 ; *n1c2cccc(-c3cc4ccccc4c4ccccc34)c2c2c([2H])c([2H])c([2H])c([2H])c21] 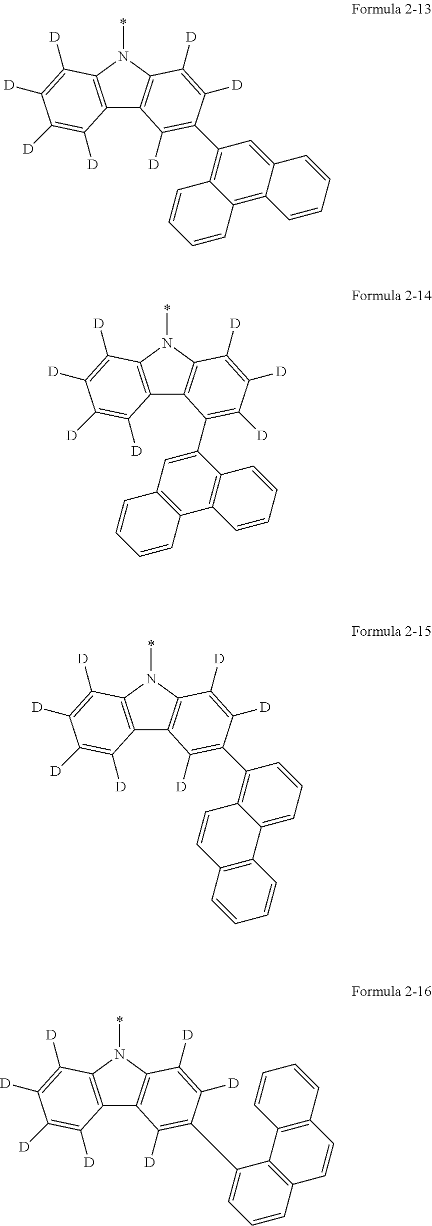 [SMILES: *n1c2c([2H])c([2H])c([2H])c([2H])c2c2c([2H])c(-c3cc4ccccc4c4ccccc34)c([2H])c([2H])c21 ; *n1c2c([2H])c([2H])c([2H])c([2H])c2c2c(-c3cc4ccccc4c4ccccc34)c([2H])c([2H])c([2H])c21 ; *n1c2c([2H])c([2H])c([2H])c([2H])c2c2c([2H])c(-c3cccc4c3ccc3ccccc34)c([2H])c([2H])c21 ; *n1c2c([2H])c([2H])c([2H])c([2H])c2c2c([2H])c(-c3cccc4ccc5ccccc5c34)c([2H])c([2H])c21] 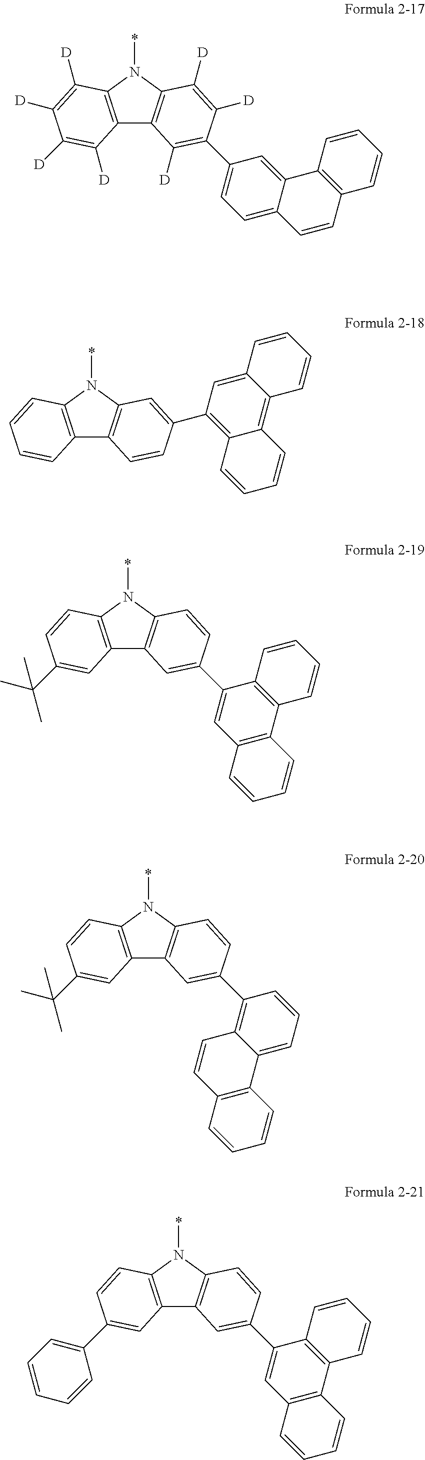 [SMILES: *n1c2c([2H])c([2H])c([2H])c([2H])c2c2c([2H])c(-c3ccc4ccc5ccccc5c4c3)c([2H])c([2H])c21 ; *n1c2ccccc2c2ccc(-c3cc4ccccc4c4ccccc34)cc21 ; *n1c2ccc(-c3cc4ccccc4c4ccccc34)cc2c2cc(C(C)(C)C)ccc21 ; *n1c2ccc(-c3cccc4c3ccc3ccccc34)cc2c2cc(C(C)(C)C)ccc21 ; *n1c2ccc(-c3ccccc3)cc2c2cc(-c3cc4ccccc4c4ccccc34)ccc21] 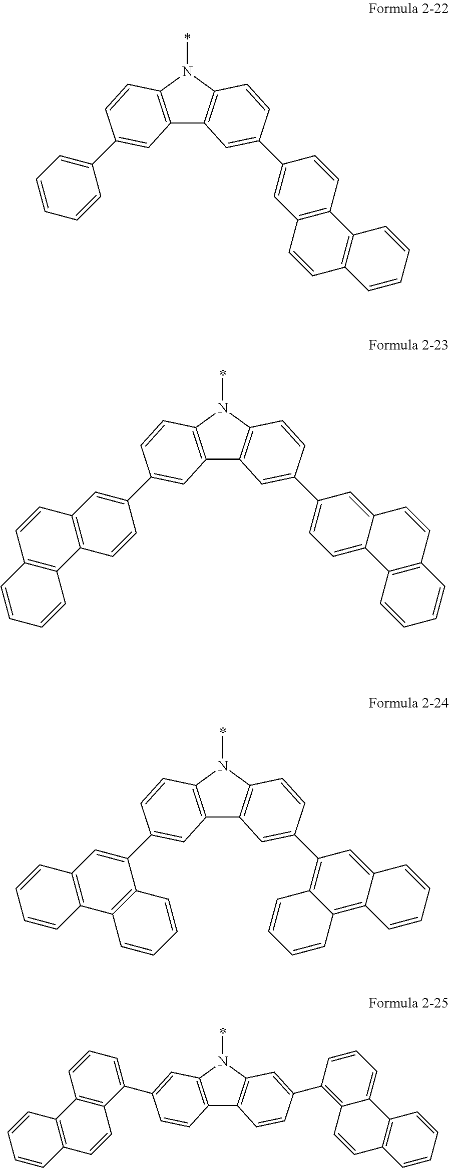 [SMILES: *n1c2ccc(-c3ccccc3)cc2c2cc(-c3ccc4c(ccc5ccccc54)c3)ccc21 ; *n1c2ccc(-c3ccc4c(ccc5ccccc54)c3)cc2c2cc(-c3ccc4c(ccc5ccccc54)c3)ccc21 ; *n1c2ccc(-c3cc4ccccc4c4ccccc34)cc2c2cc(-c3cc4ccccc4c4ccccc34)ccc21 ; *n1c2cc(-c3cccc4c3ccc3ccccc34)ccc2c2ccc(-c3cccc4c3ccc3ccccc34)cc21] 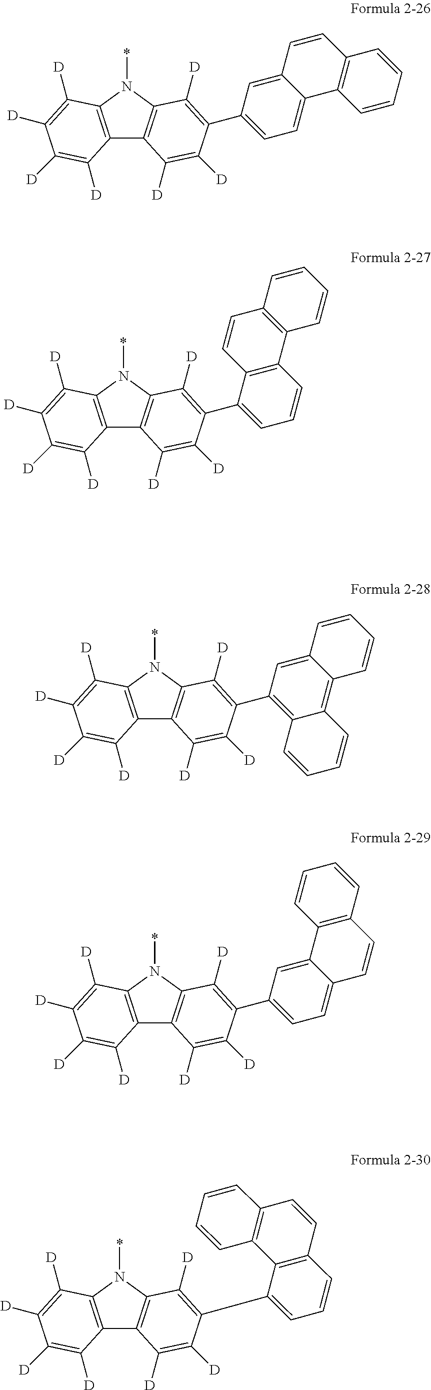 [SMILES: *n1c2c([2H])c([2H])c([2H])c([2H])c2c2c([2H])c([2H])c(-c3ccc4c(ccc5ccccc54)c3)c([2H])c21 ; *n1c2c([2H])c([2H])c([2H])c([2H])c2c2c([2H])c([2H])c(-c3cccc4c3ccc3ccccc34)c([2H])c21 ; *n1c2c([2H])c([2H])c([2H])c([2H])c2c2c([2H])c([2H])c(-c3cc4ccccc4c4ccccc34)c([2H])c21 ; *n1c2c([2H])c([2H])c([2H])c([2H])c2c2c([2H])c([2H])c(-c3ccc4ccc5ccccc5c4c3)c([2H])c21 ; *n1c2c([2H])c([2H])c([2H])c([2H])c2c2c([2H])c([2H])c(-c3cccc4ccc5ccccc5c34)c([2H])c21] 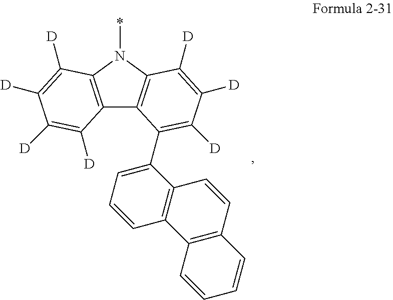 [SMILES: *n1c2c([2H])c([2H])c([2H])c([2H])c2c2c(-c3cccc4c3ccc3ccccc34)c([2H])c([2H])c([2H])c21]
in Formula 2-11 to Formula 2-17 and Formula 2-26 to Formula 2-31, D being a deuterium atom.

9. The light emitting element of claim 1, wherein the first compound comprises at least one selected from among compounds of Compound Group 1:
Compound Group 1 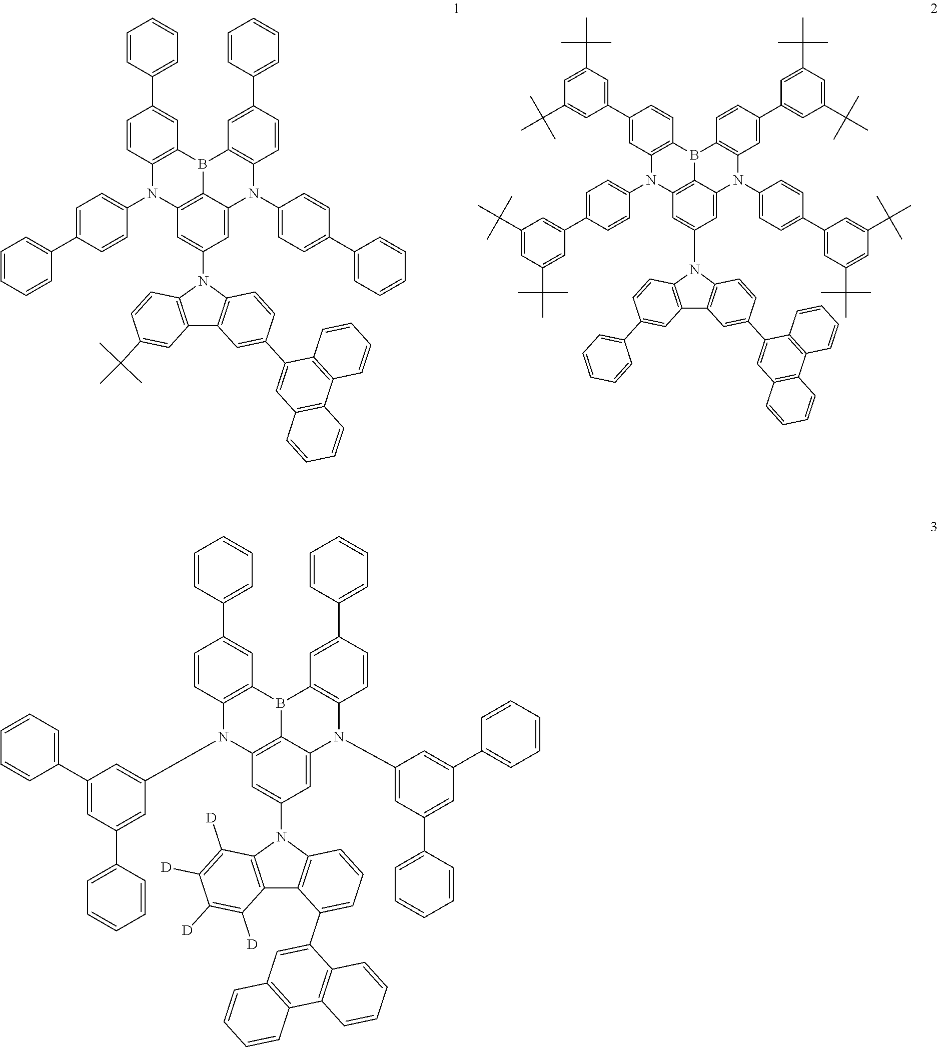 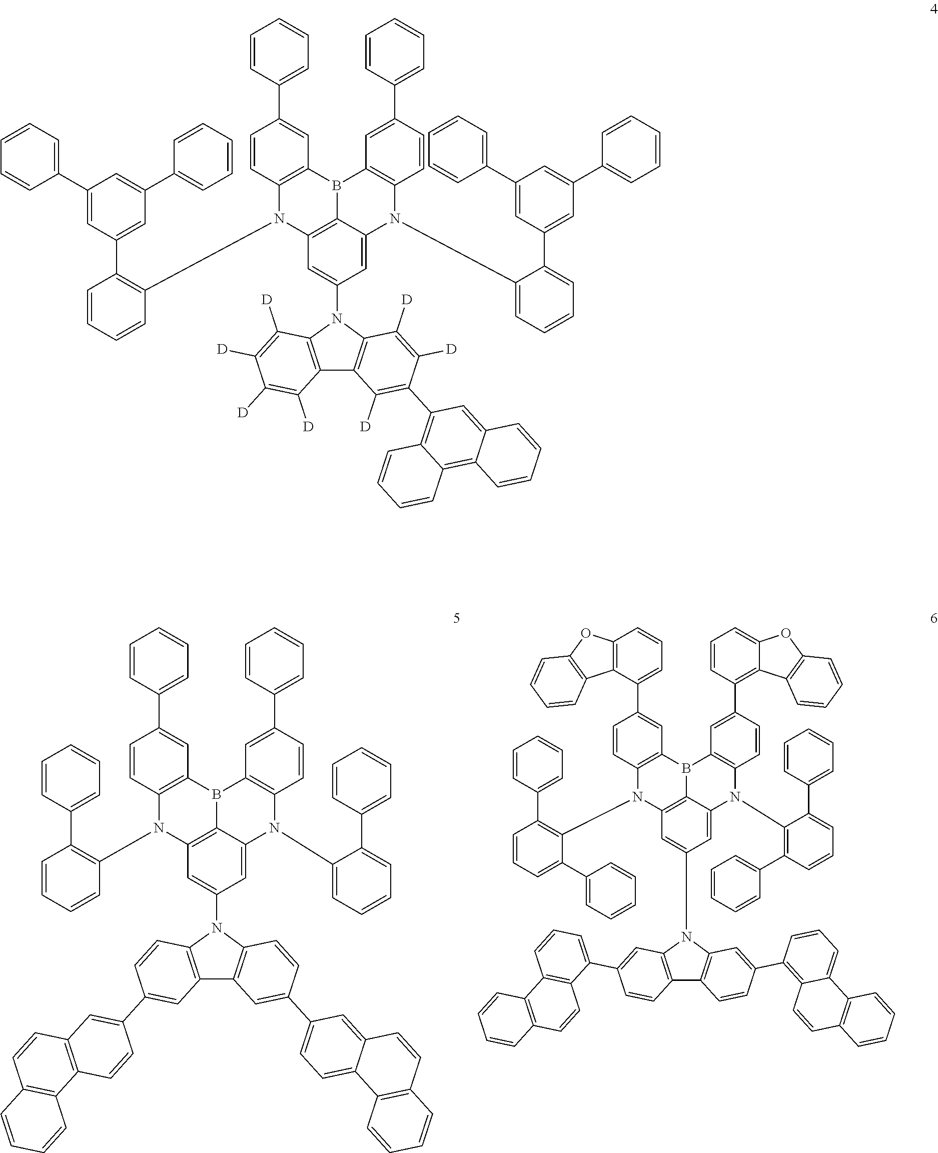 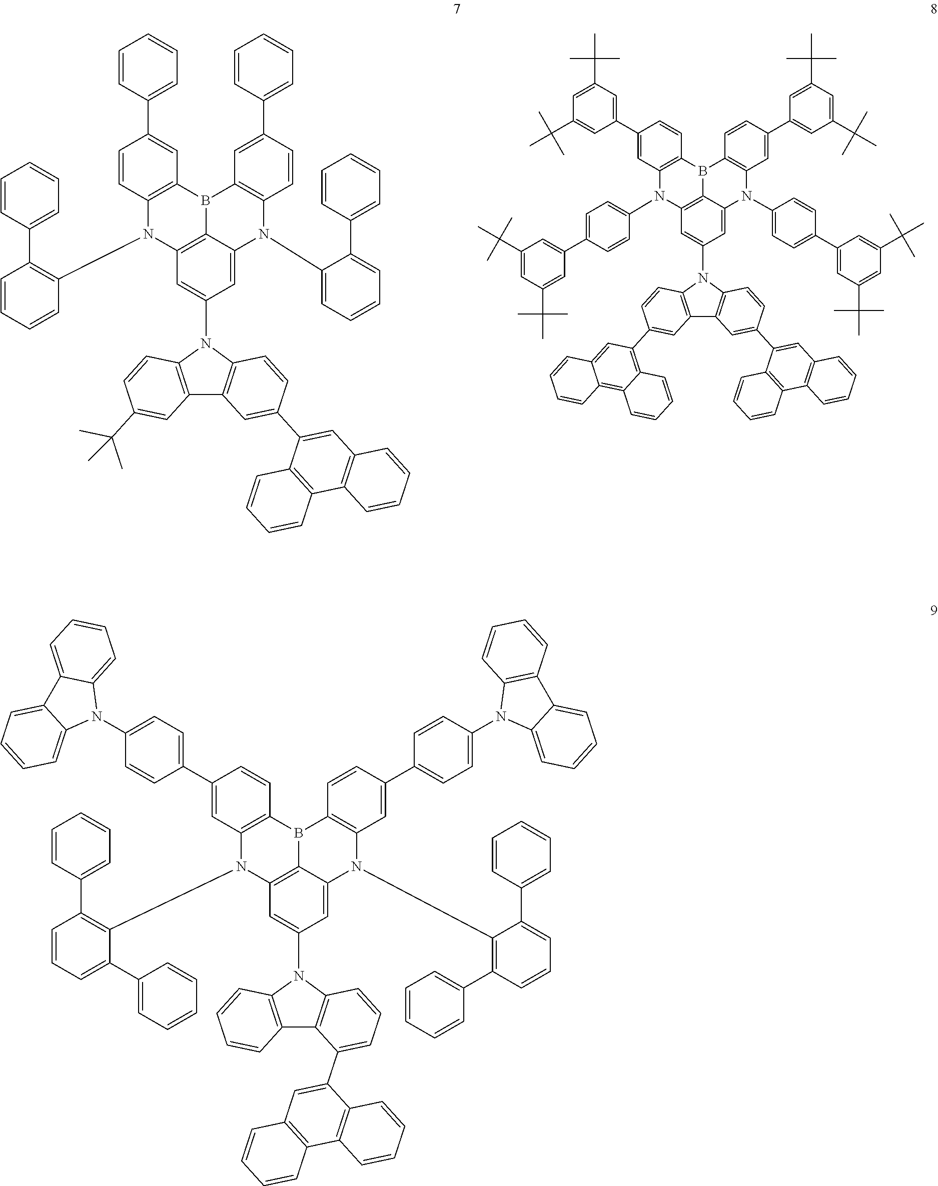 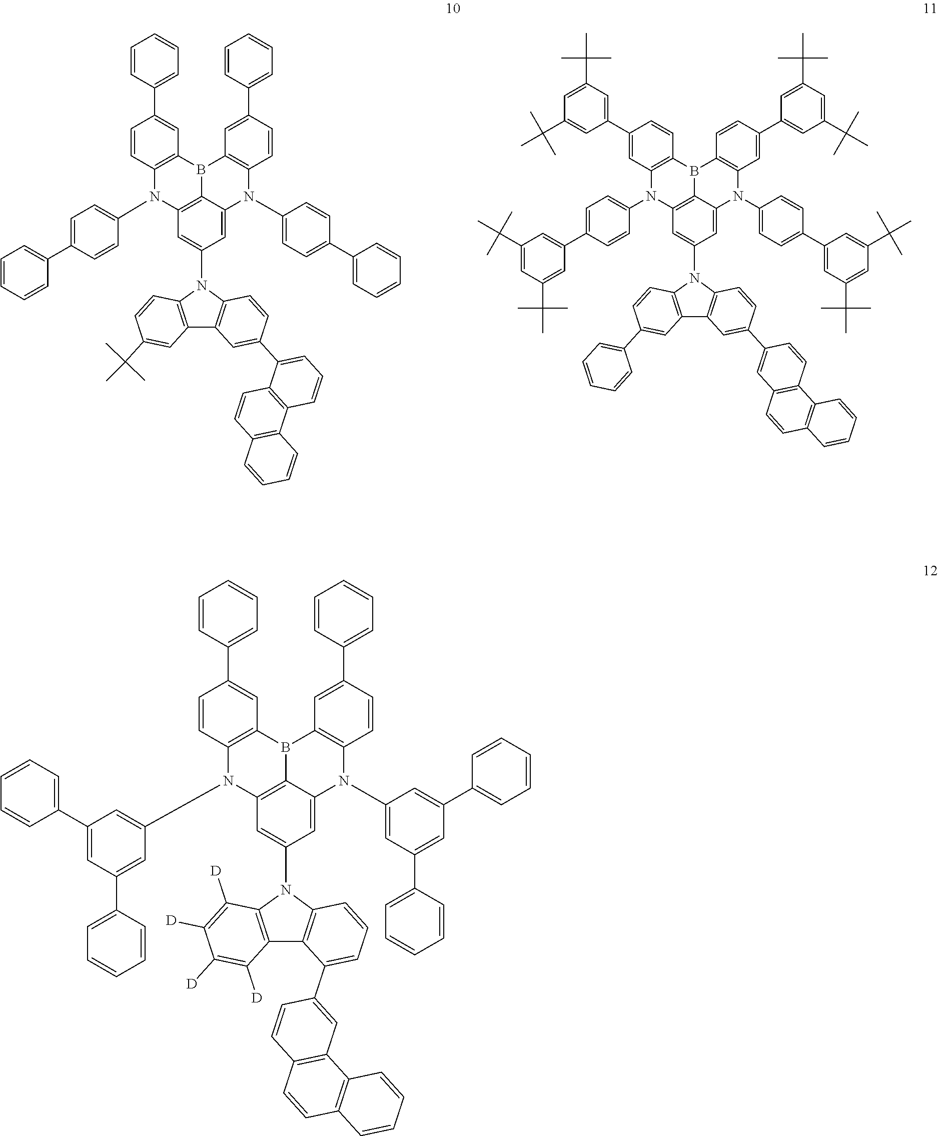 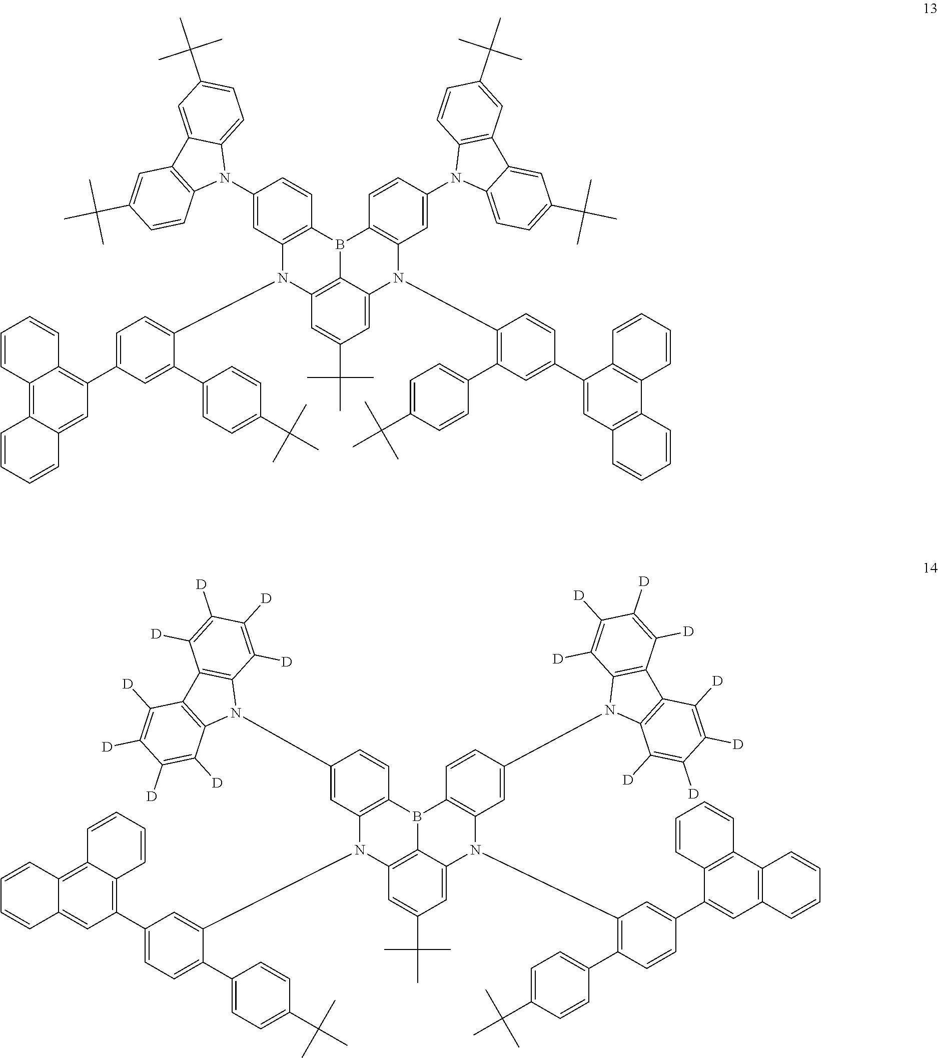 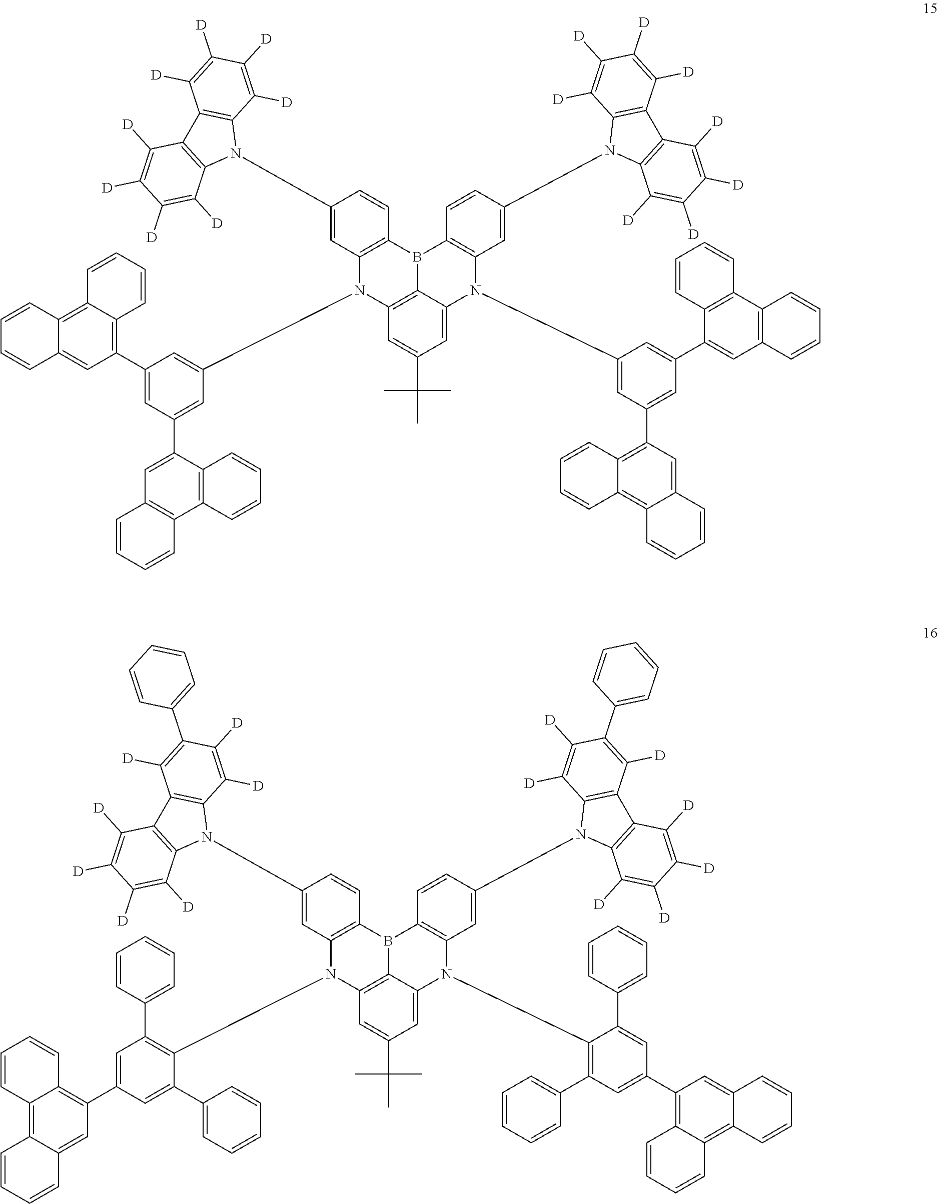 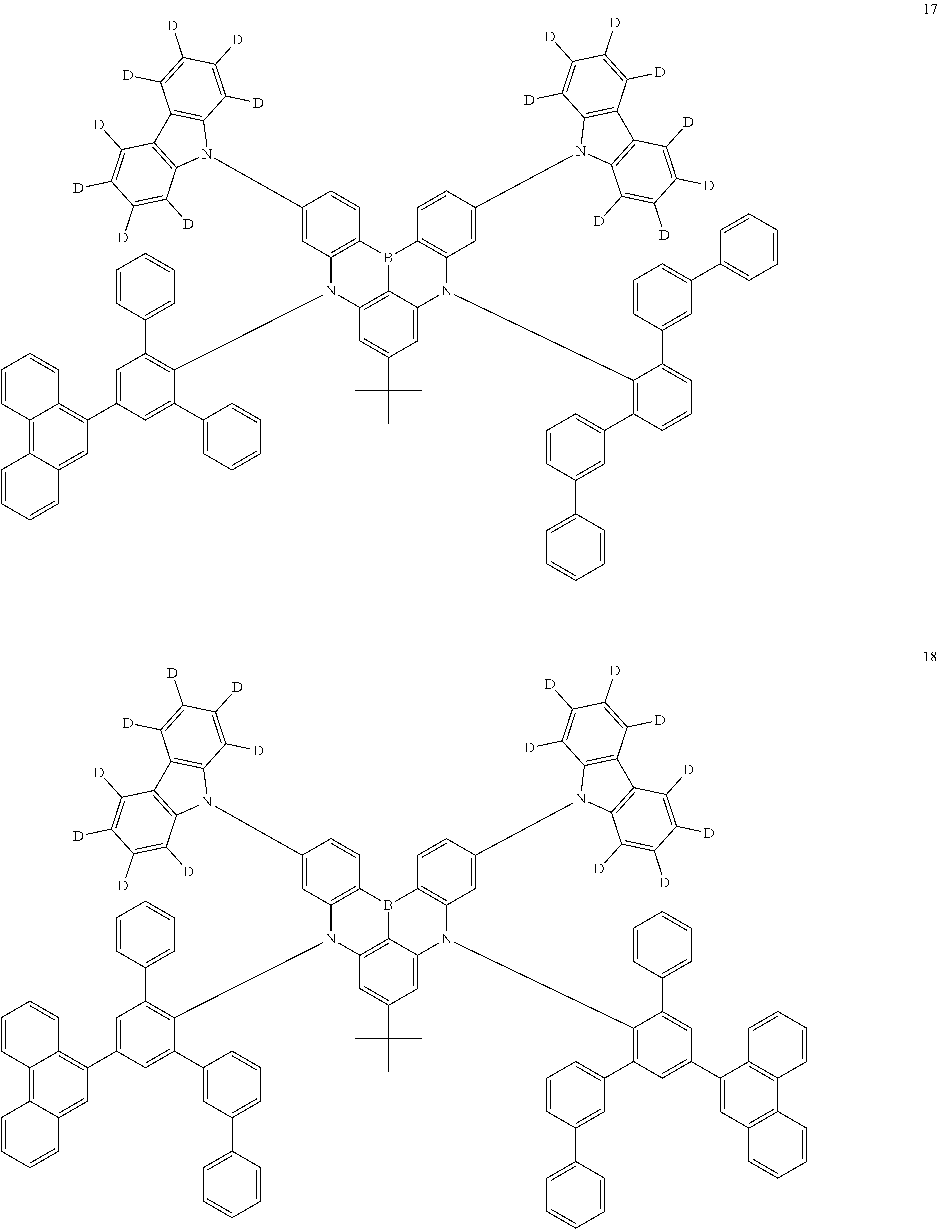 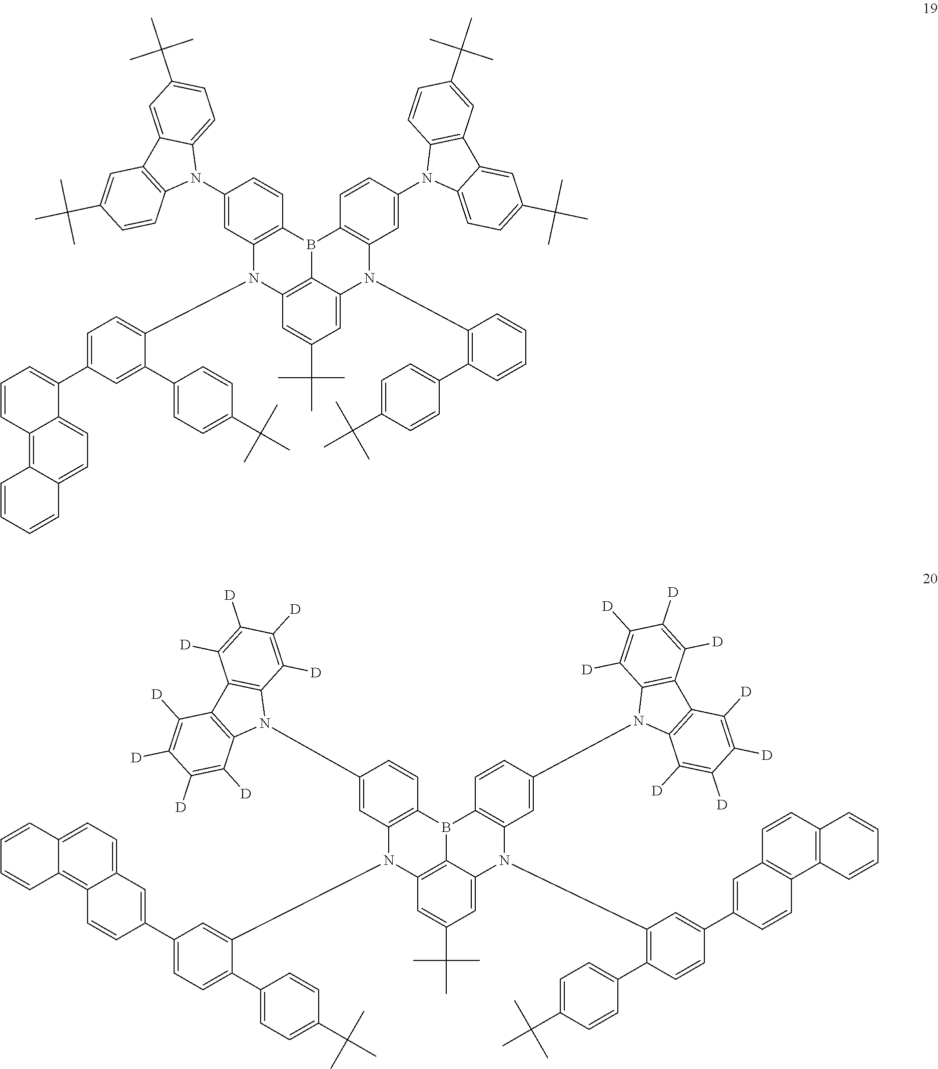 [SMILES: CC(C)(C)c1ccc(-c2ccccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5cccc6c5ccc5ccccc56)cc4-c4ccc(C(C)(C)C)cc4)c4cc(C(C)(C)C)cc2c43)cc1 ; [2H]c1c([2H])c([2H])c2c(c1[2H])c1c([2H])c([2H])c([2H])c([2H])c1n2-c1ccc2c(c1)N(c1cc(-c3ccc4c(ccc5ccccc54)c3)ccc1-c1ccc(C(C)(C)C)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1cc(-c2ccc3c(ccc4ccccc43)c2)ccc1-c1ccc(C(C)(C)C)cc1] 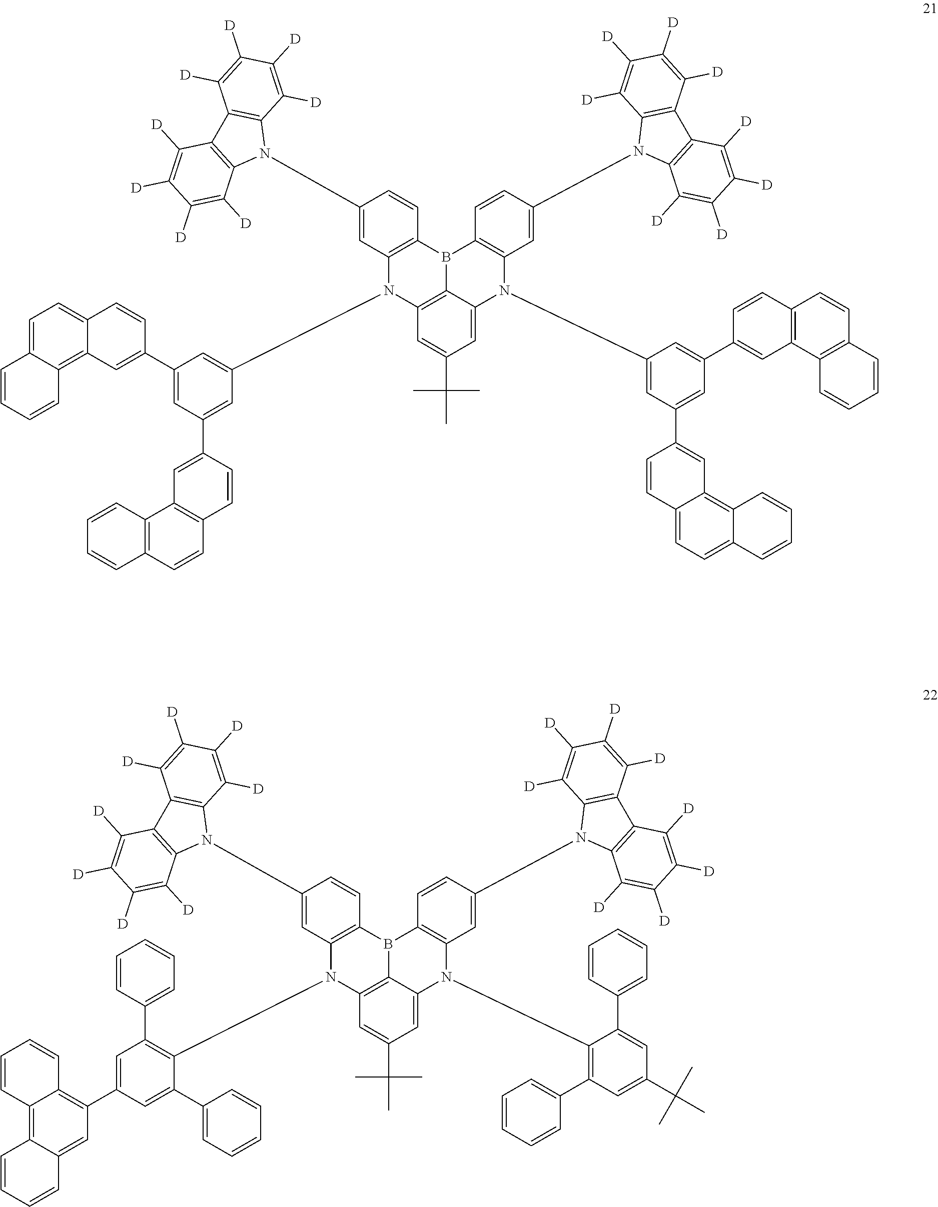 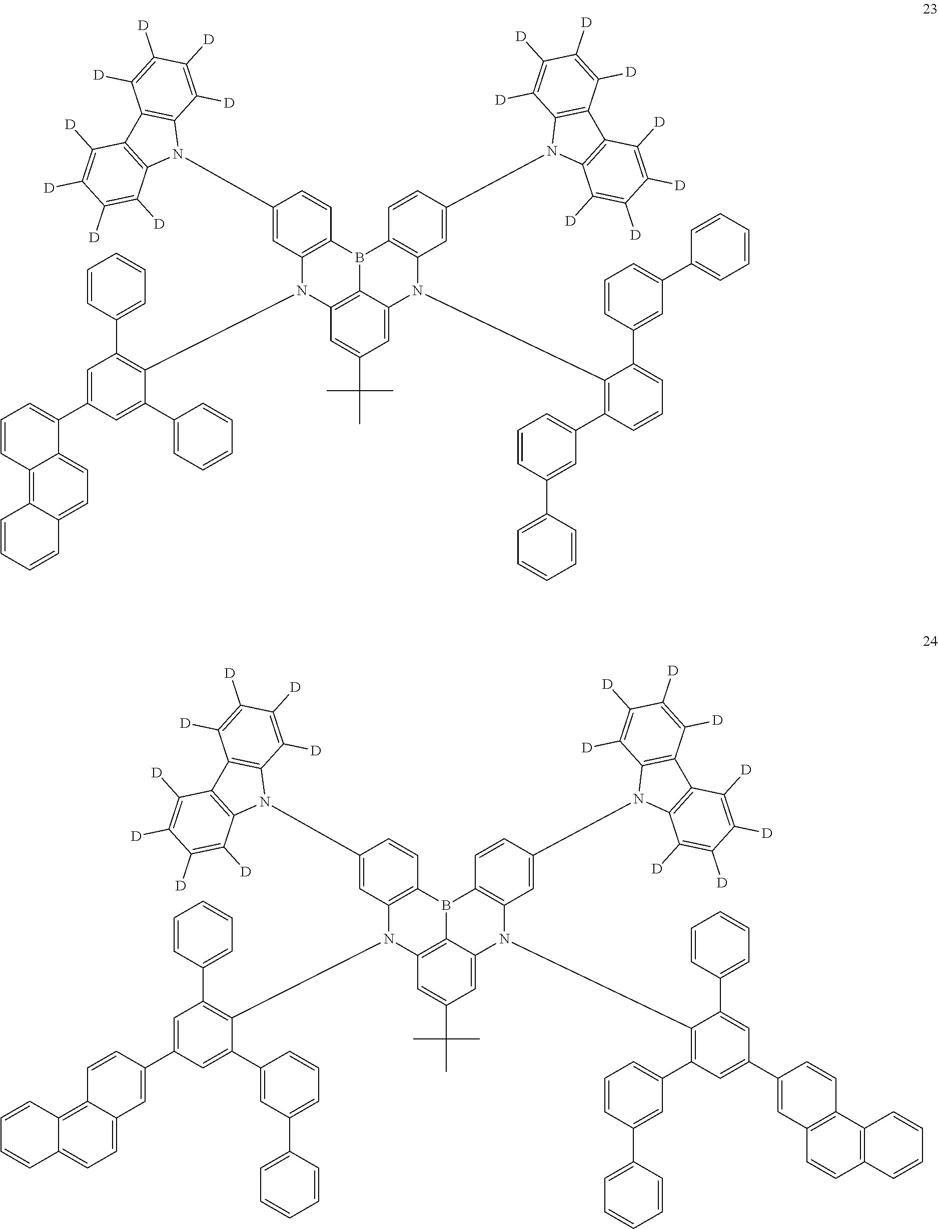 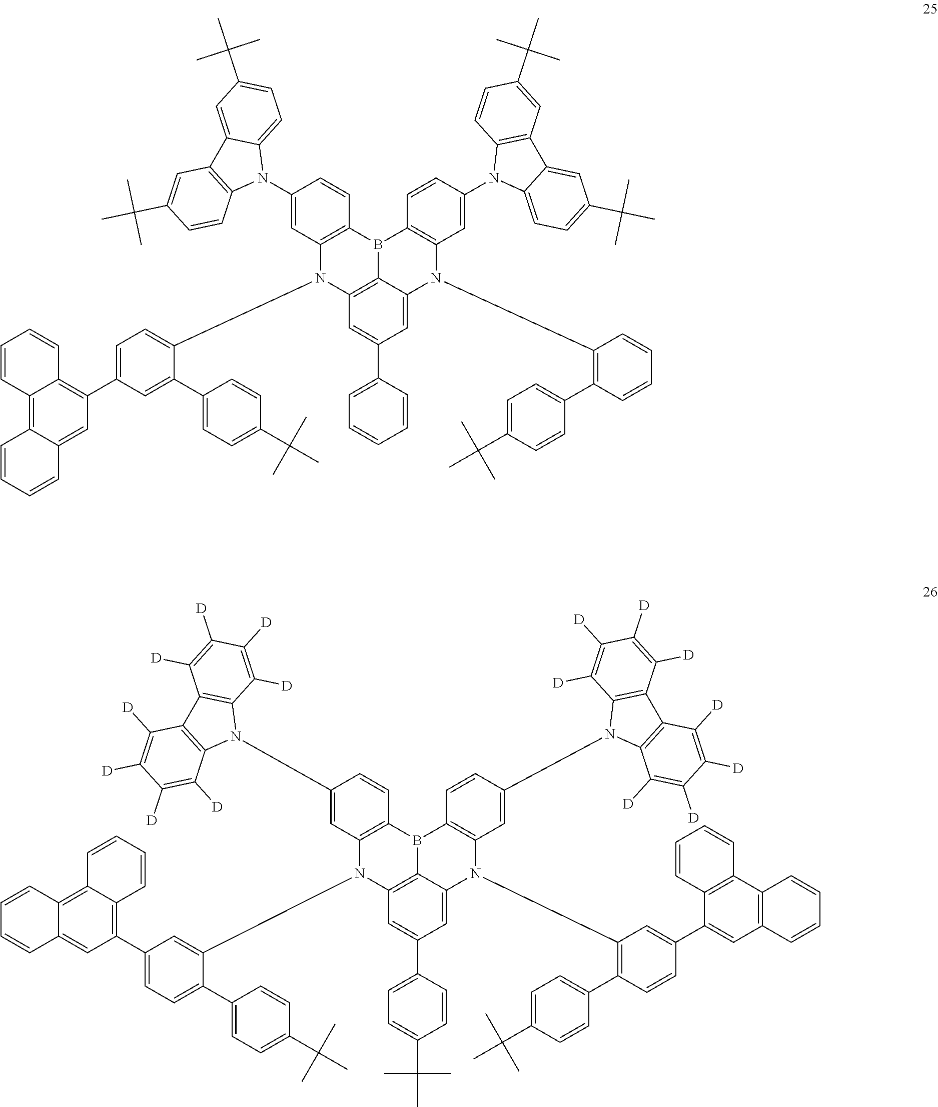 [SMILES: CC(C)(C)c1ccc(-c2ccccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5cc6ccccc6c6ccccc56)cc4-c4ccc(C(C)(C)C)cc4)c4cc(-c5ccccc5)cc2c43)cc1 ; [2H]c1c([2H])c([2H])c2c(c1[2H])c1c([2H])c([2H])c([2H])c([2H])c1n2-c1ccc2c(c1)N(c1cc(-c3cc4ccccc4c4ccccc34)ccc1-c1ccc(C(C)(C)C)cc1)c1cc(-c3ccc(C(C)(C)C)cc3)cc3c1B2c1ccc(-n2c4c([2H])c([2H])c([2H])c([2H])c4c4c([2H])c([2H])c([2H])c([2H])c42)cc1N3c1cc(-c2cc3ccccc3c3ccccc23)ccc1-c1ccc(C(C)(C)C)cc1] 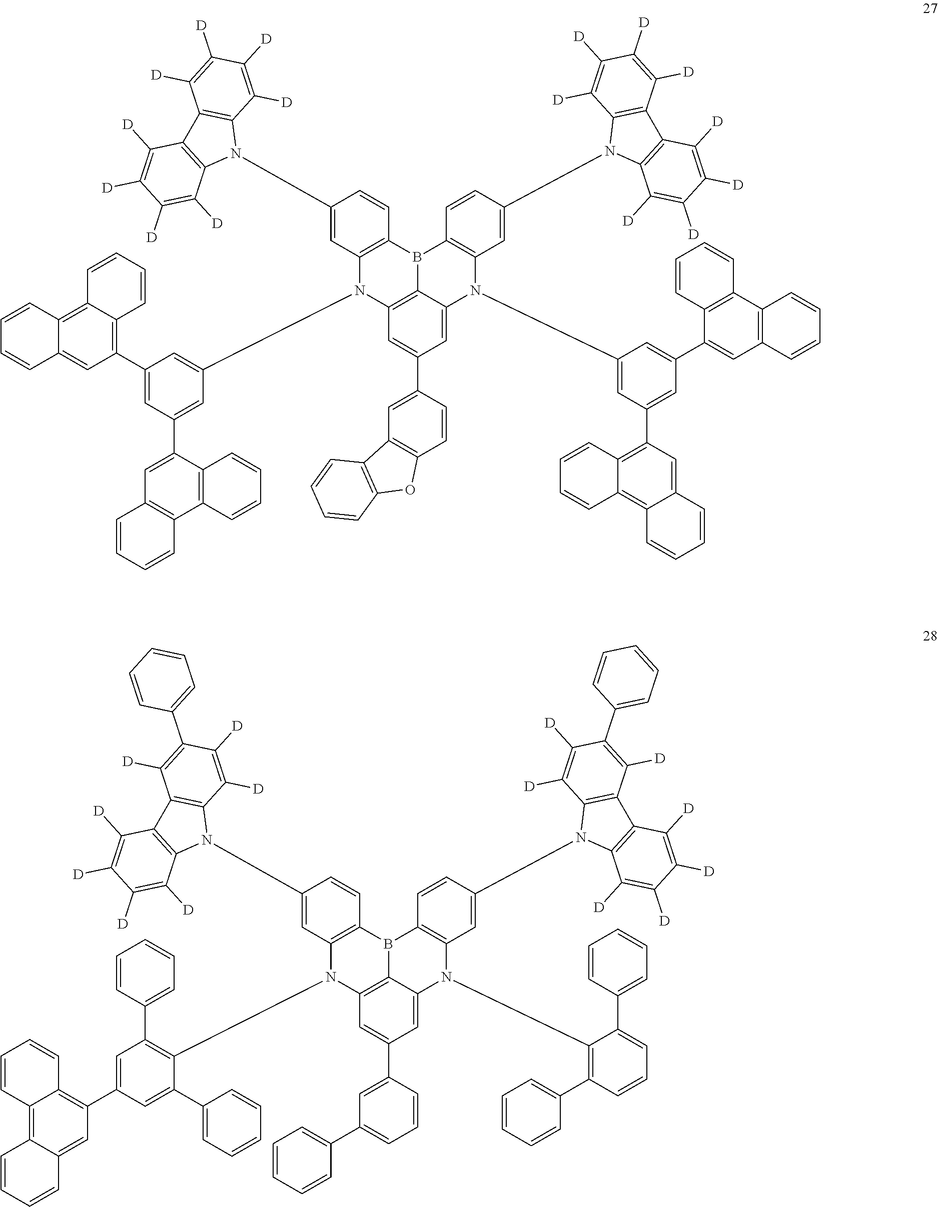 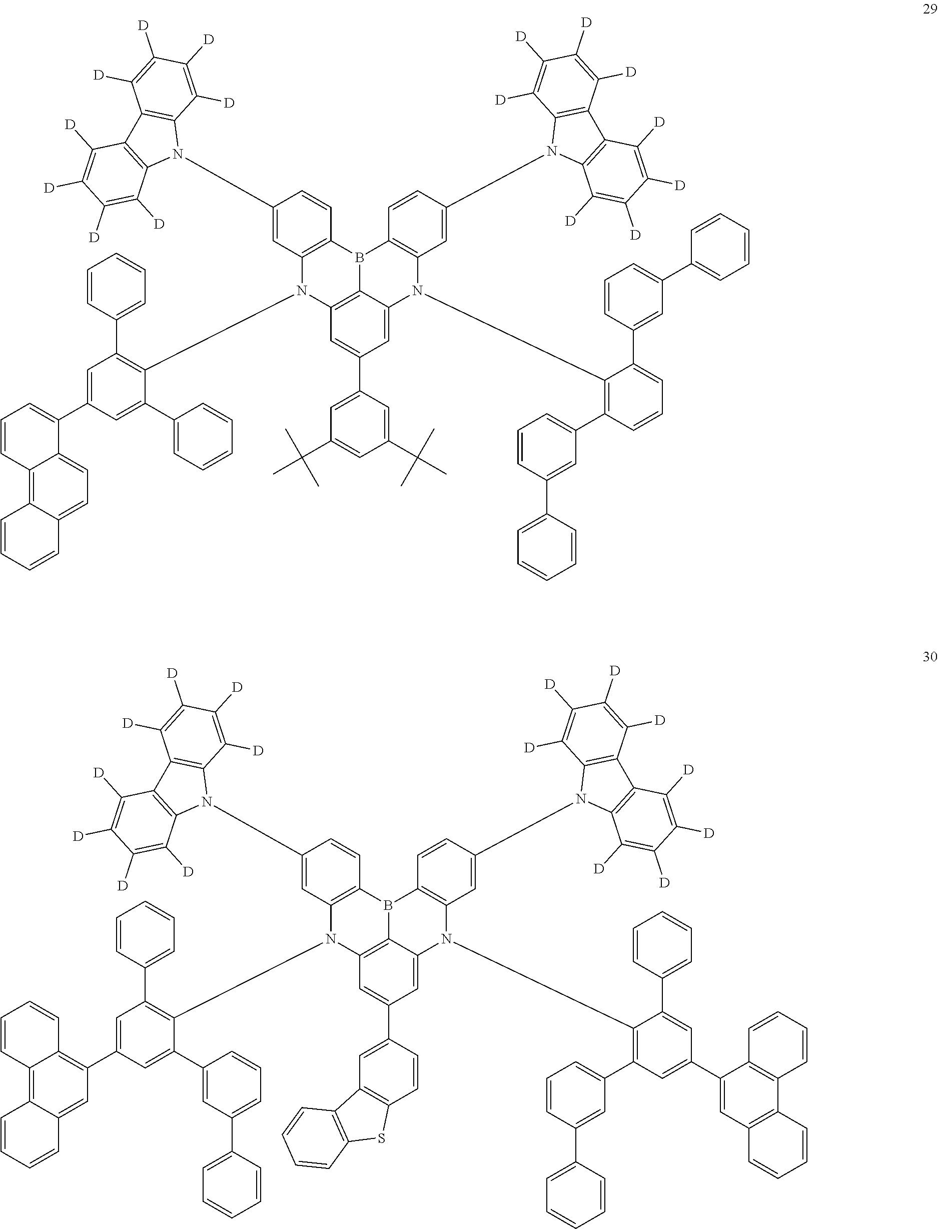 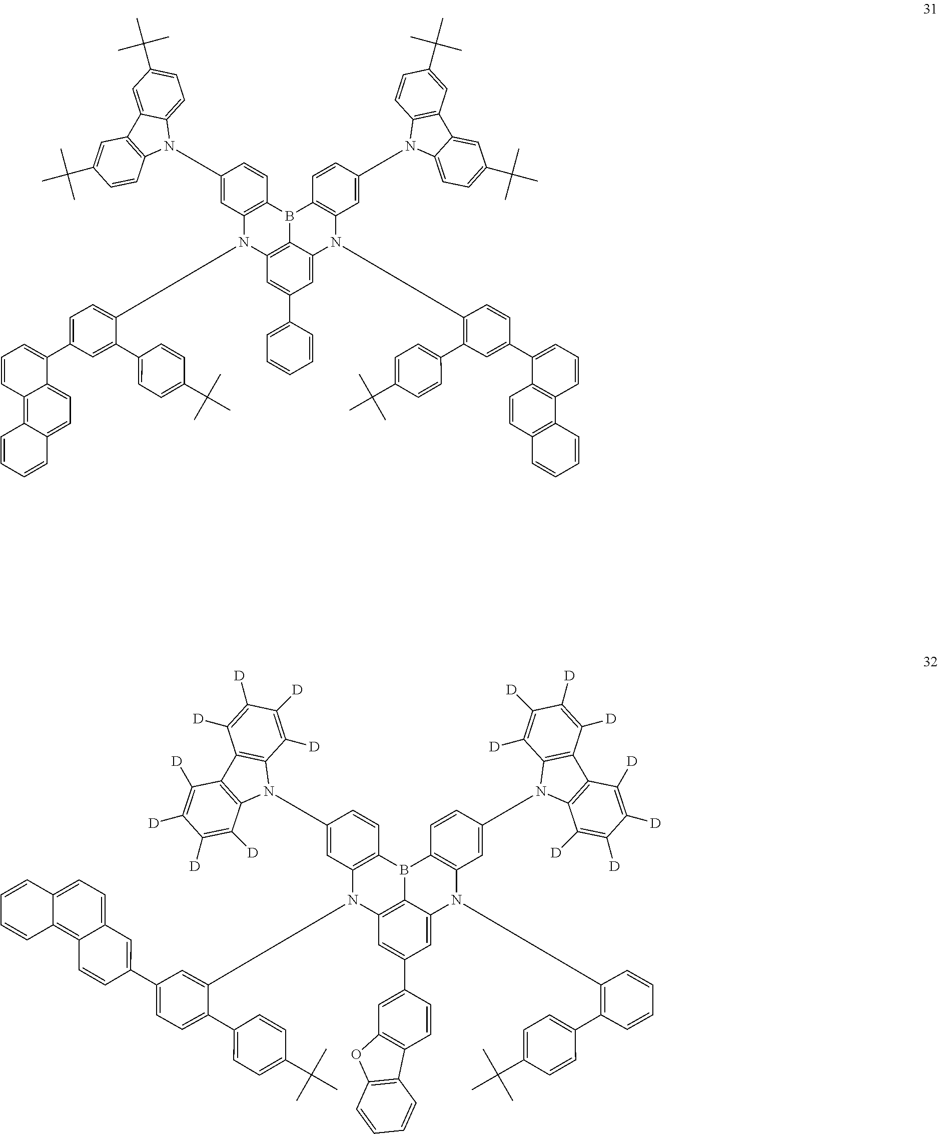 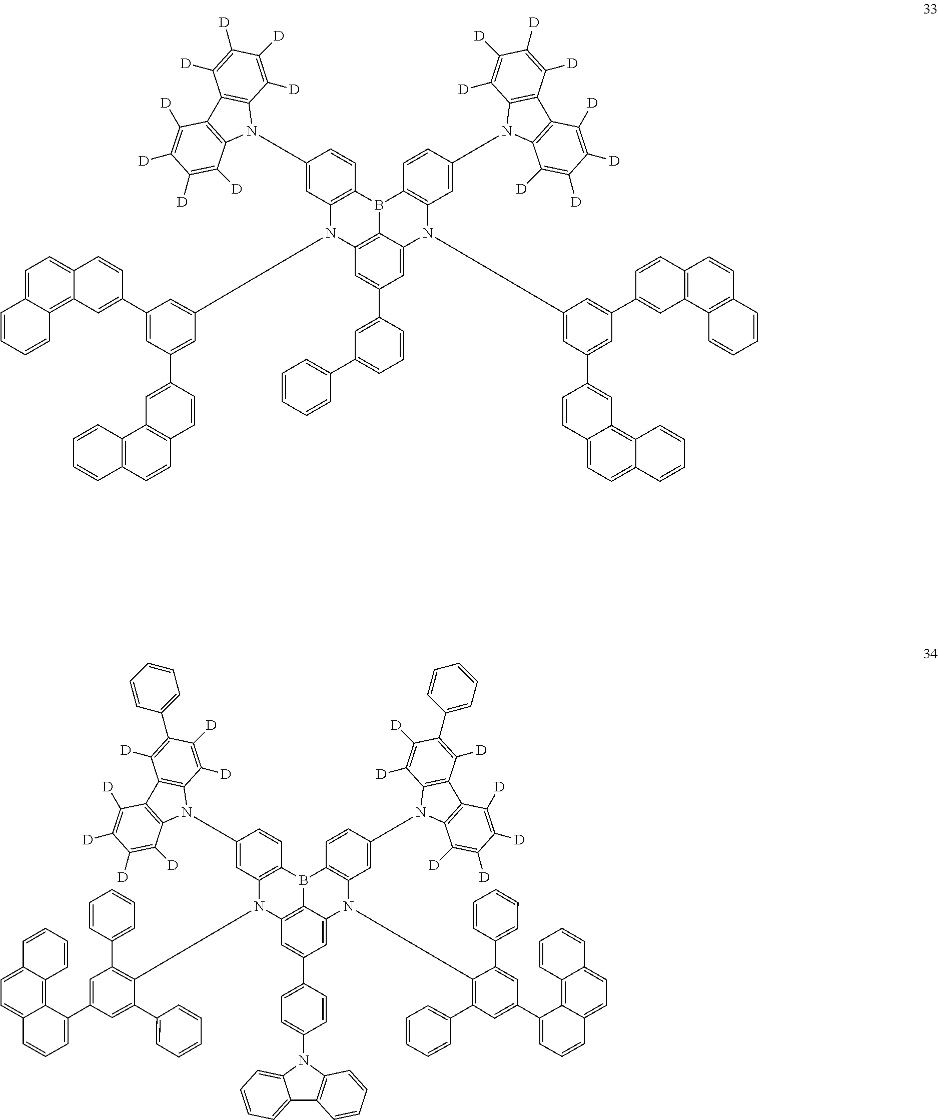 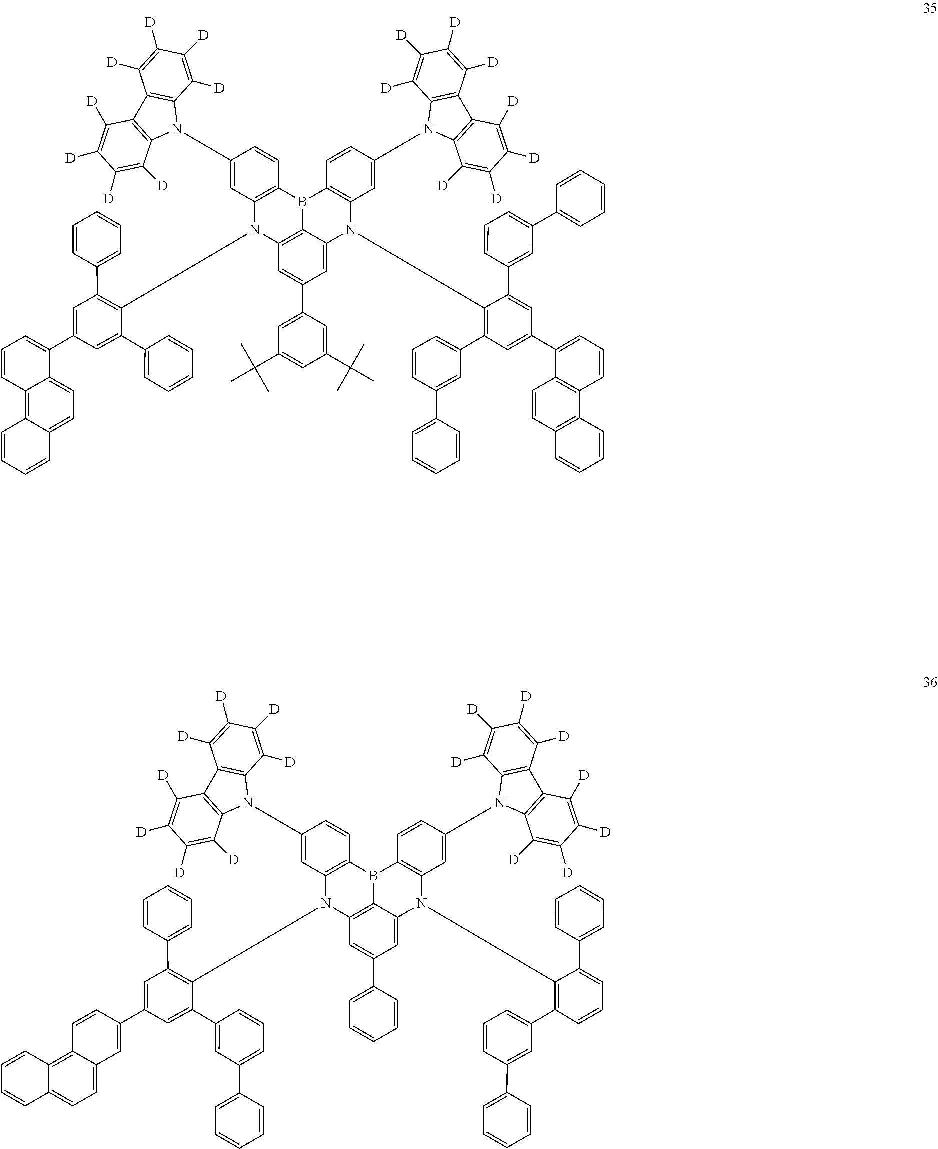 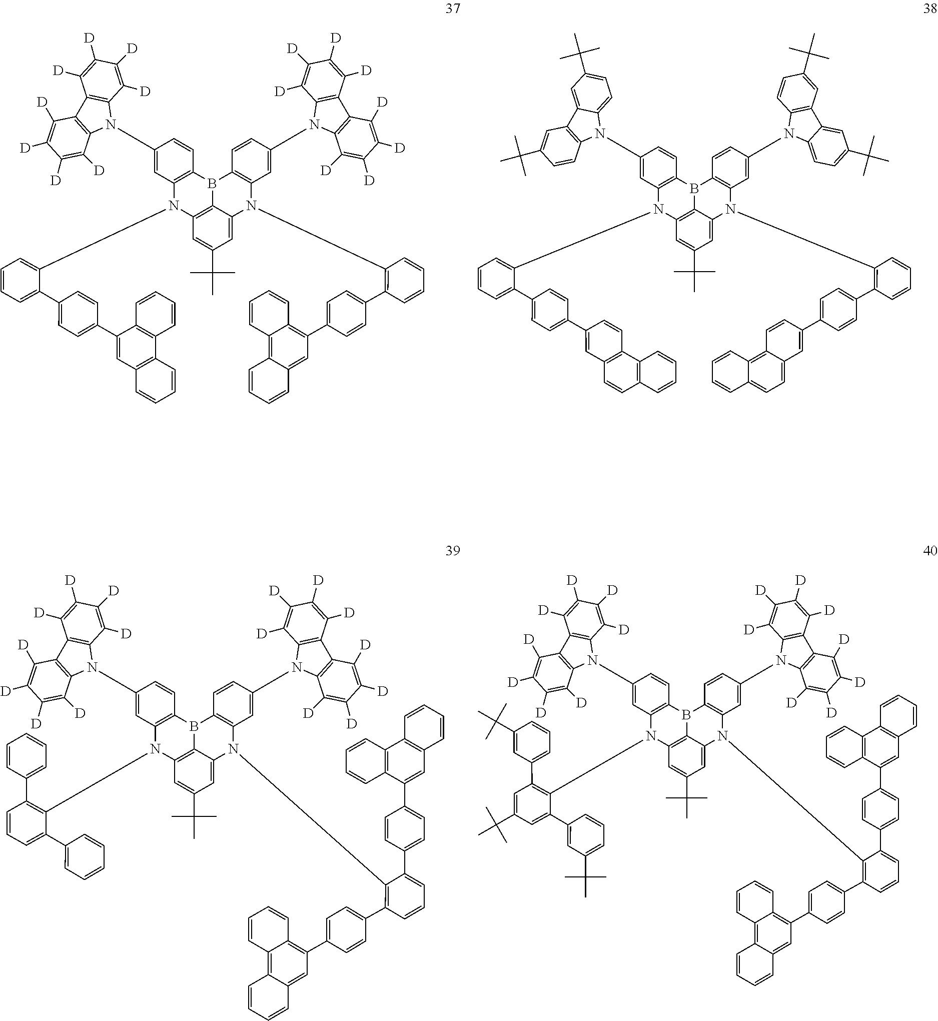 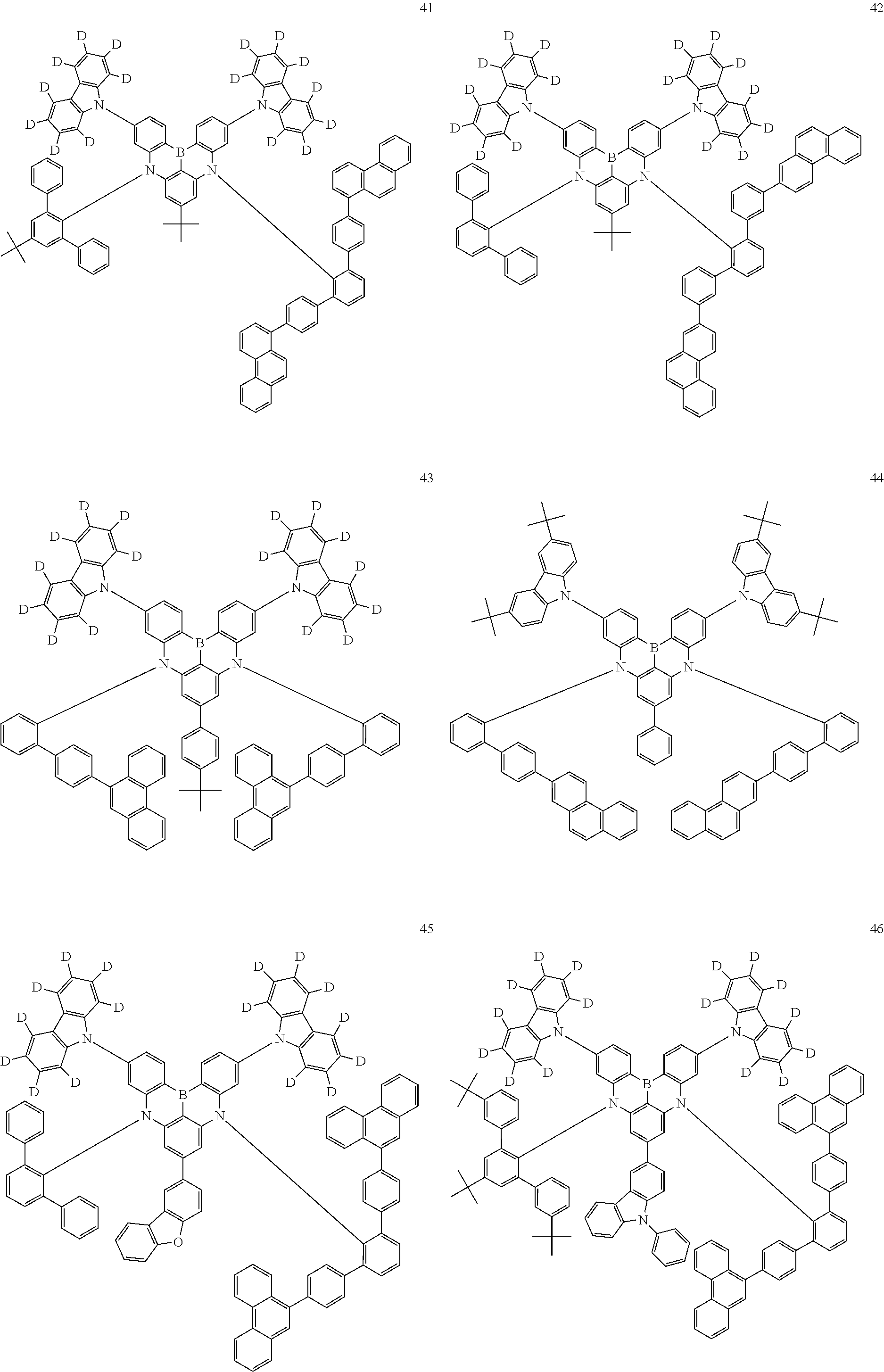 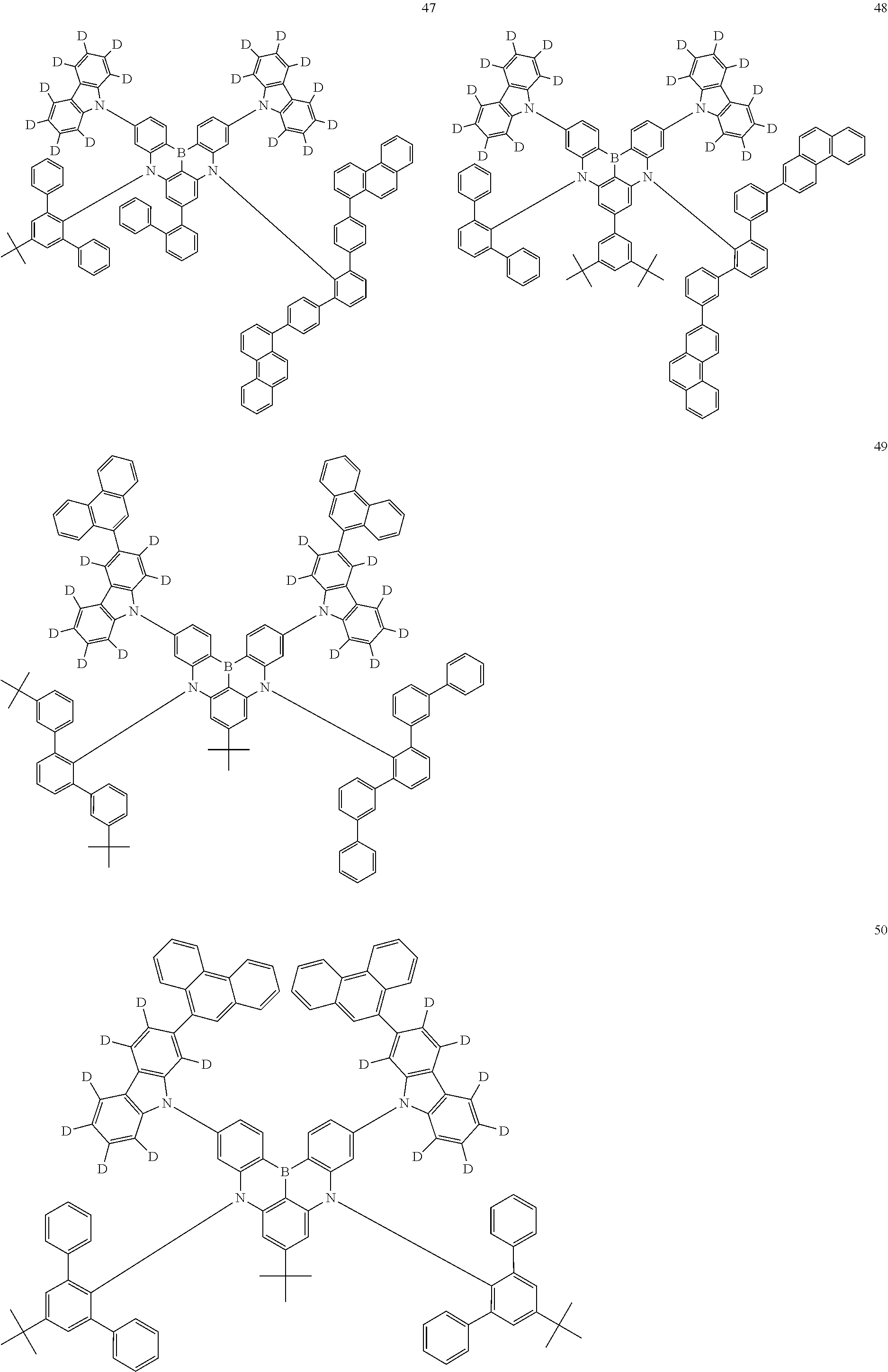 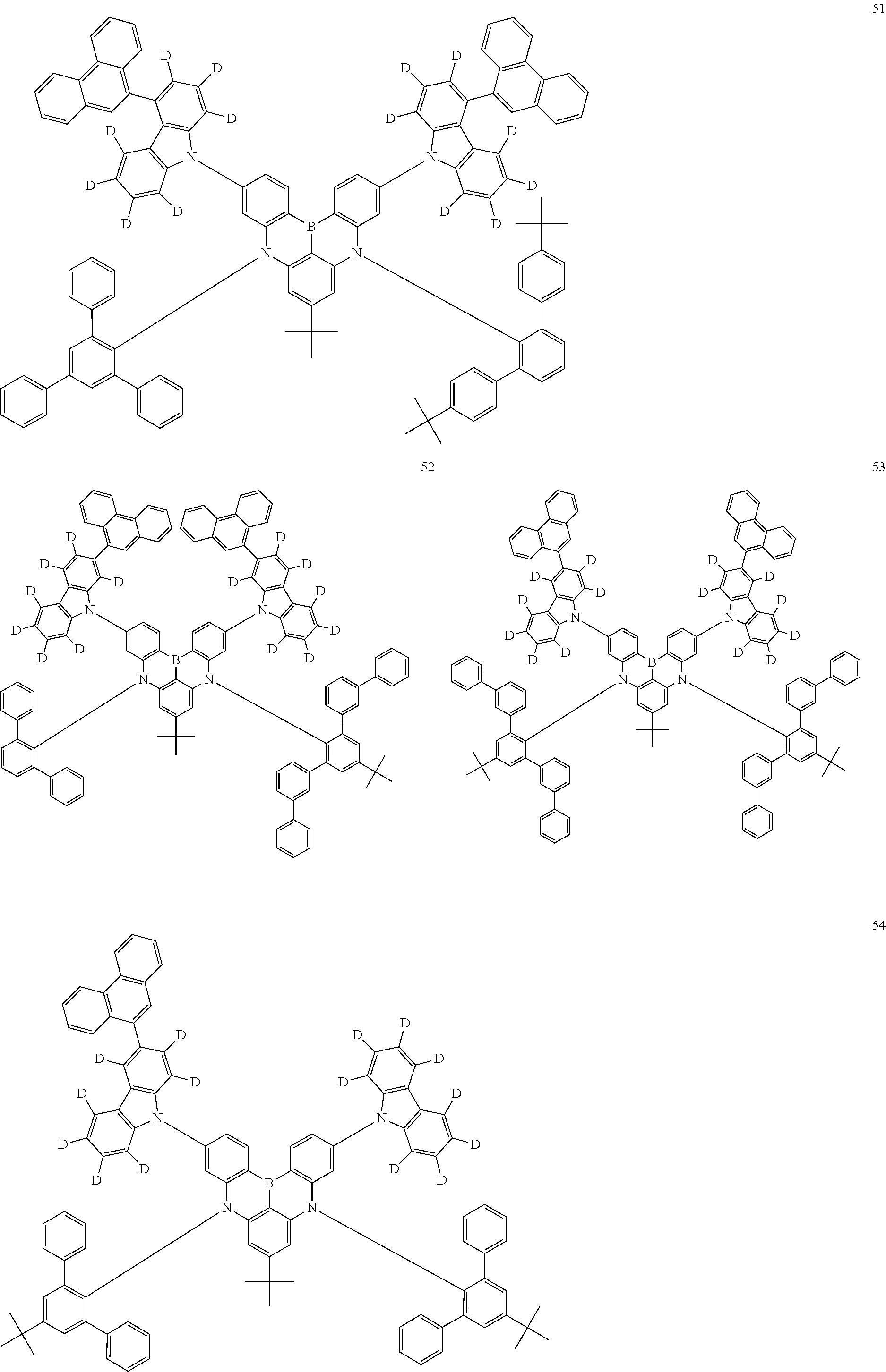 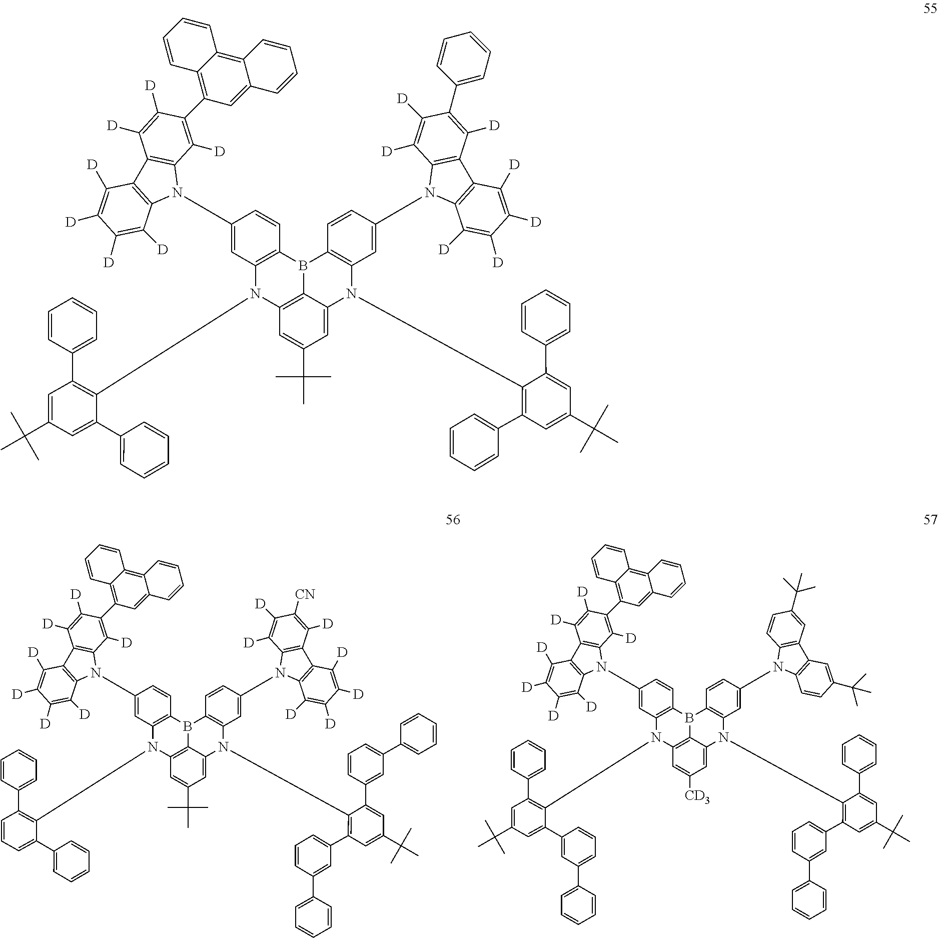 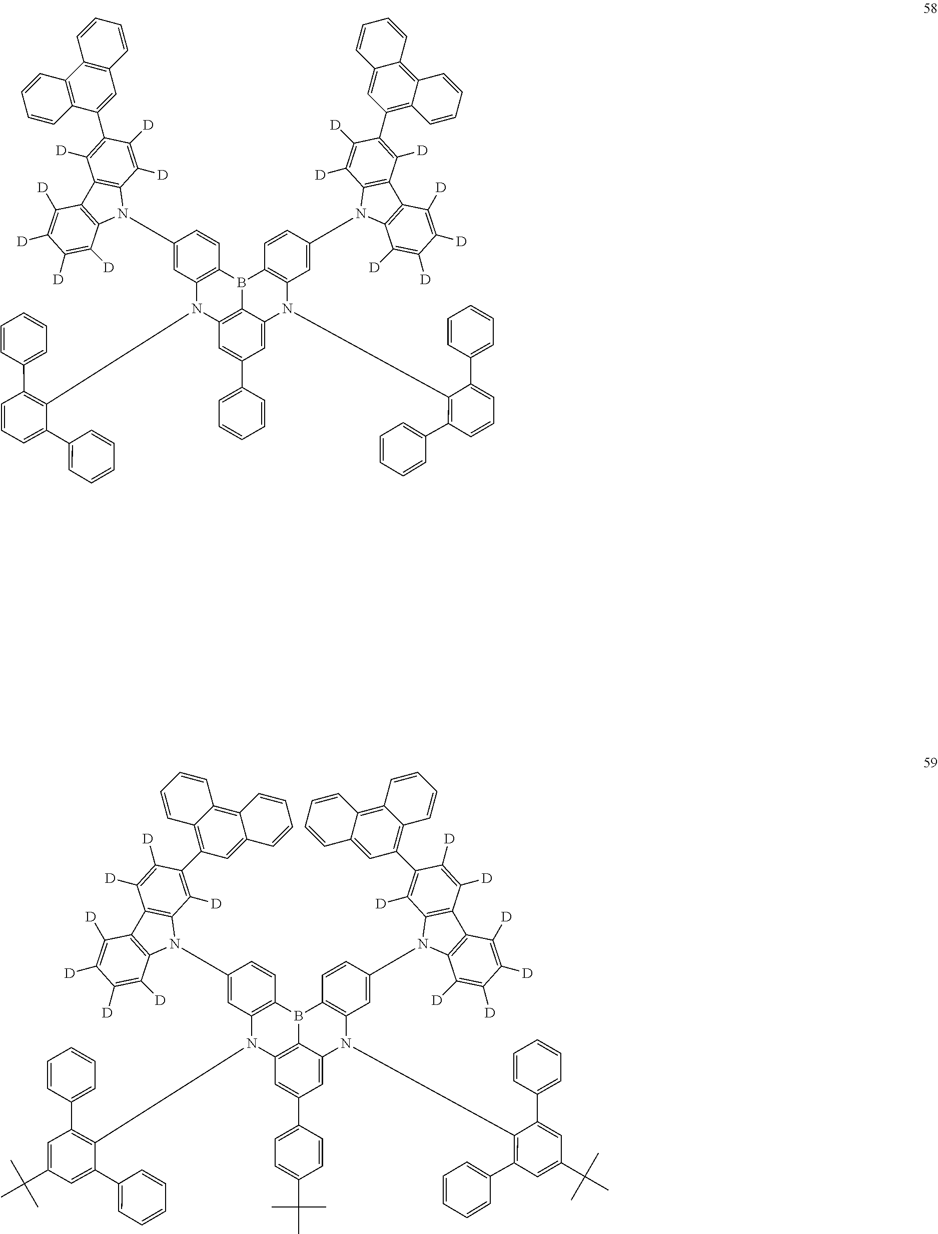 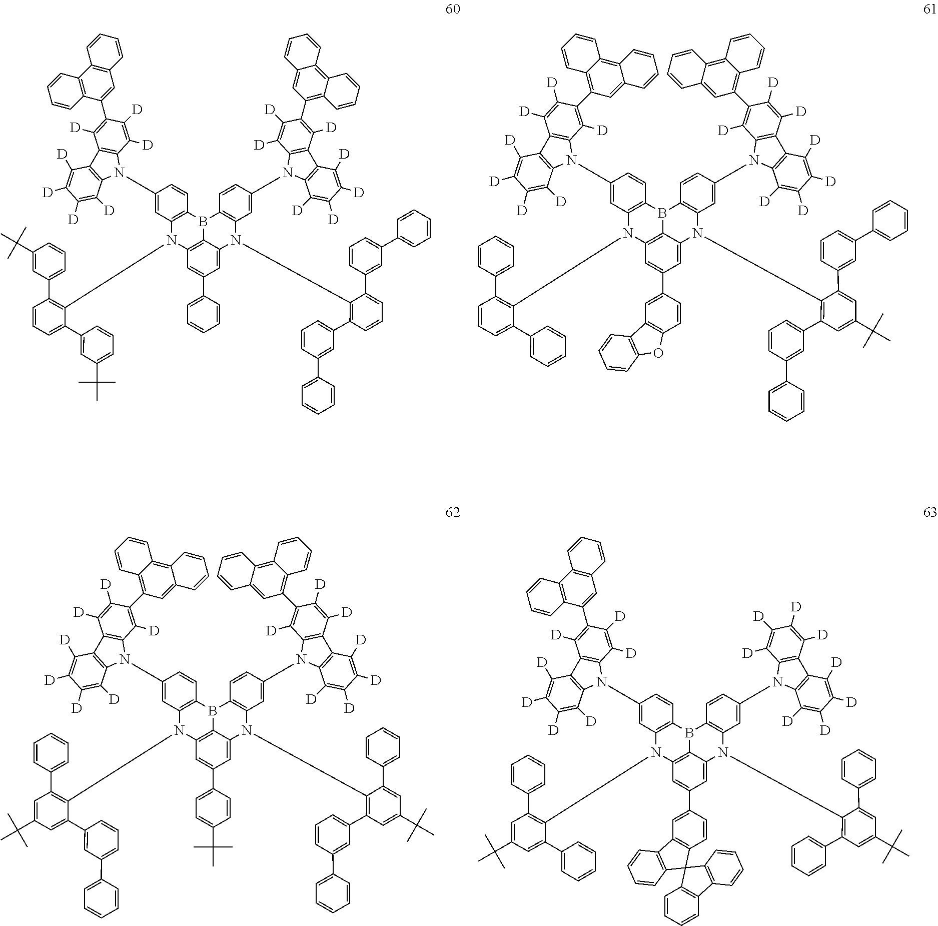 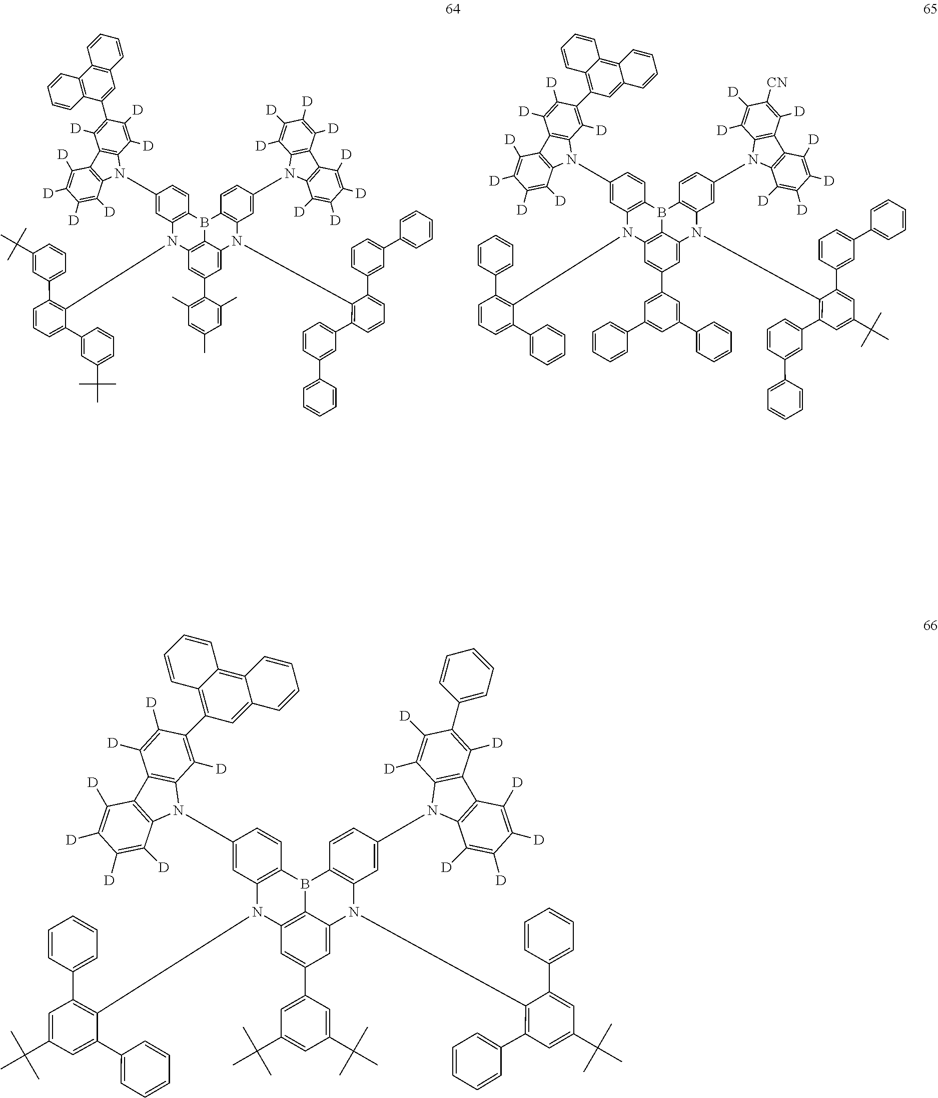 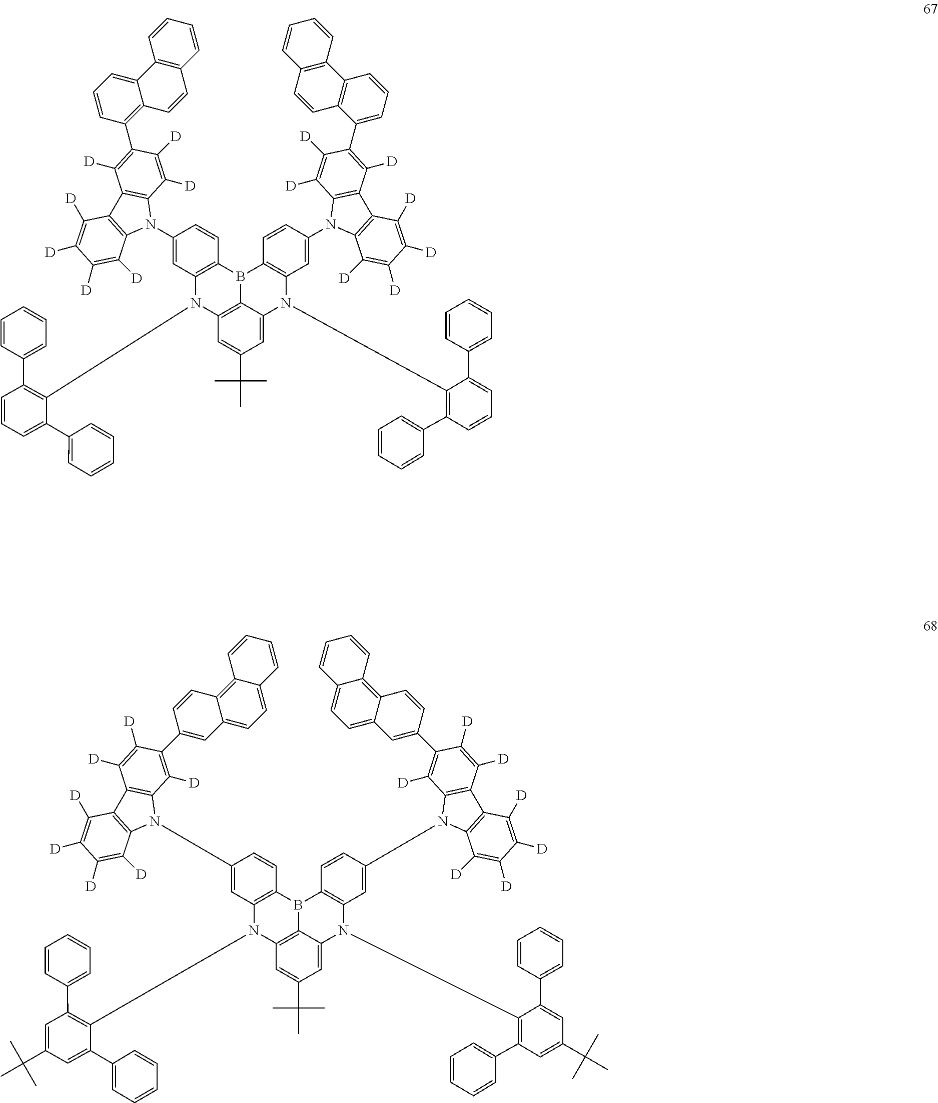 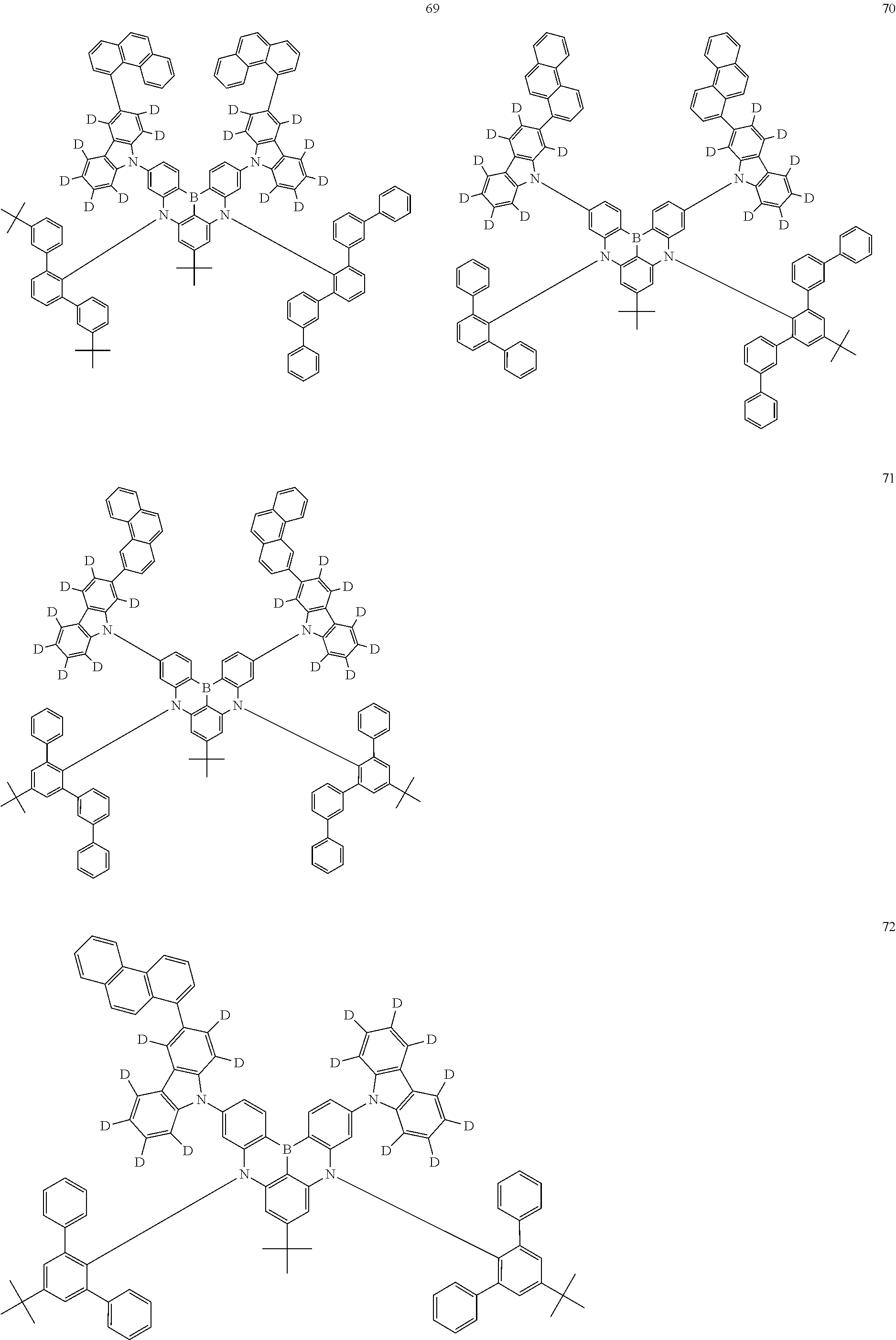 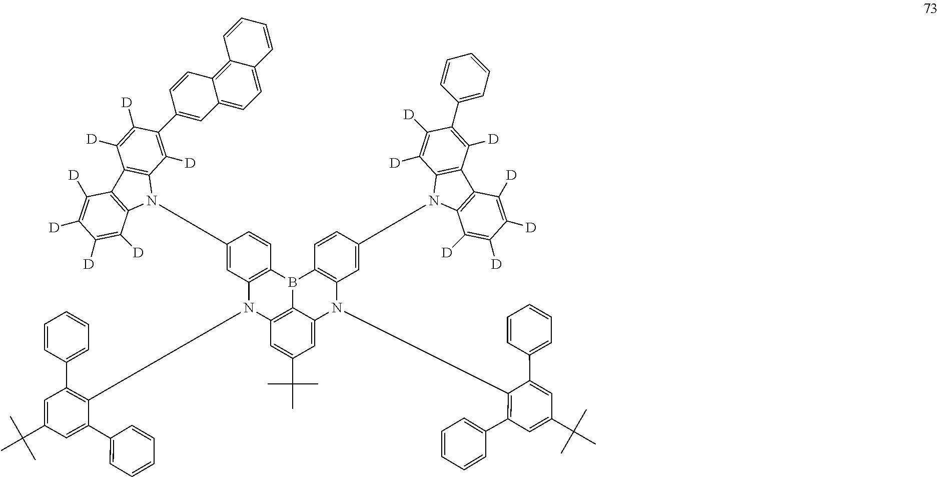 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4c([2H])c([2H])c([2H])c([2H])c4c4c([2H])c([2H])c(-c5ccc6c(ccc7ccccc76)c5)c([2H])c42)cc1N3c1c(-c2ccccc2)cc(C(C)(C)C)cc1-c1ccccc1] 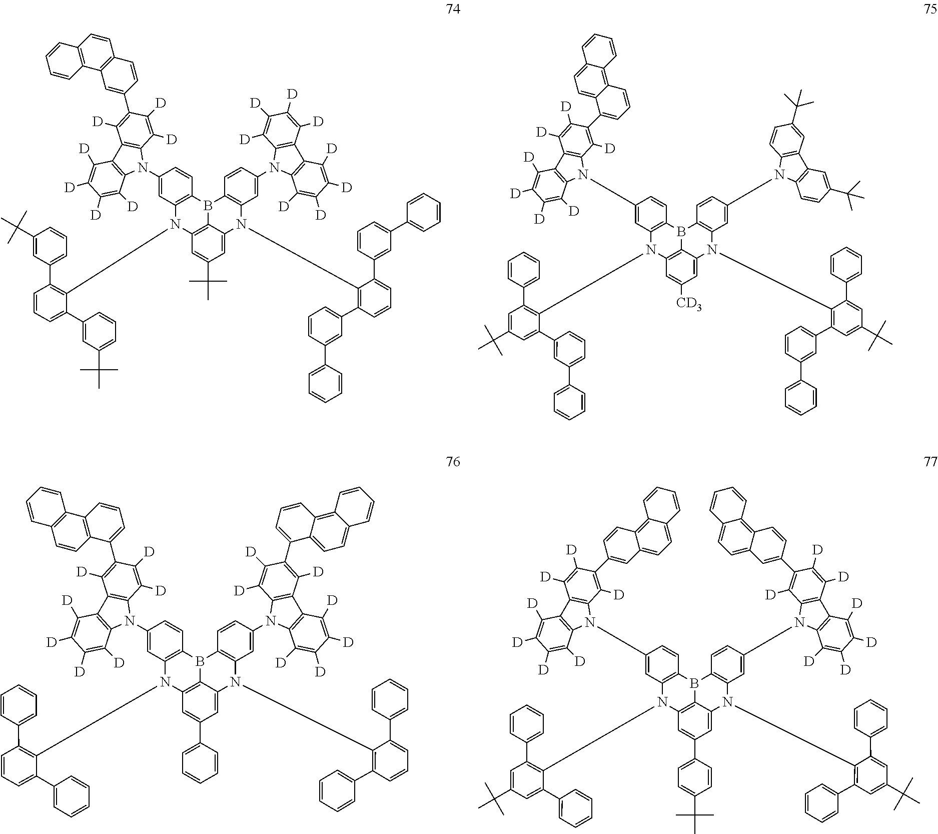 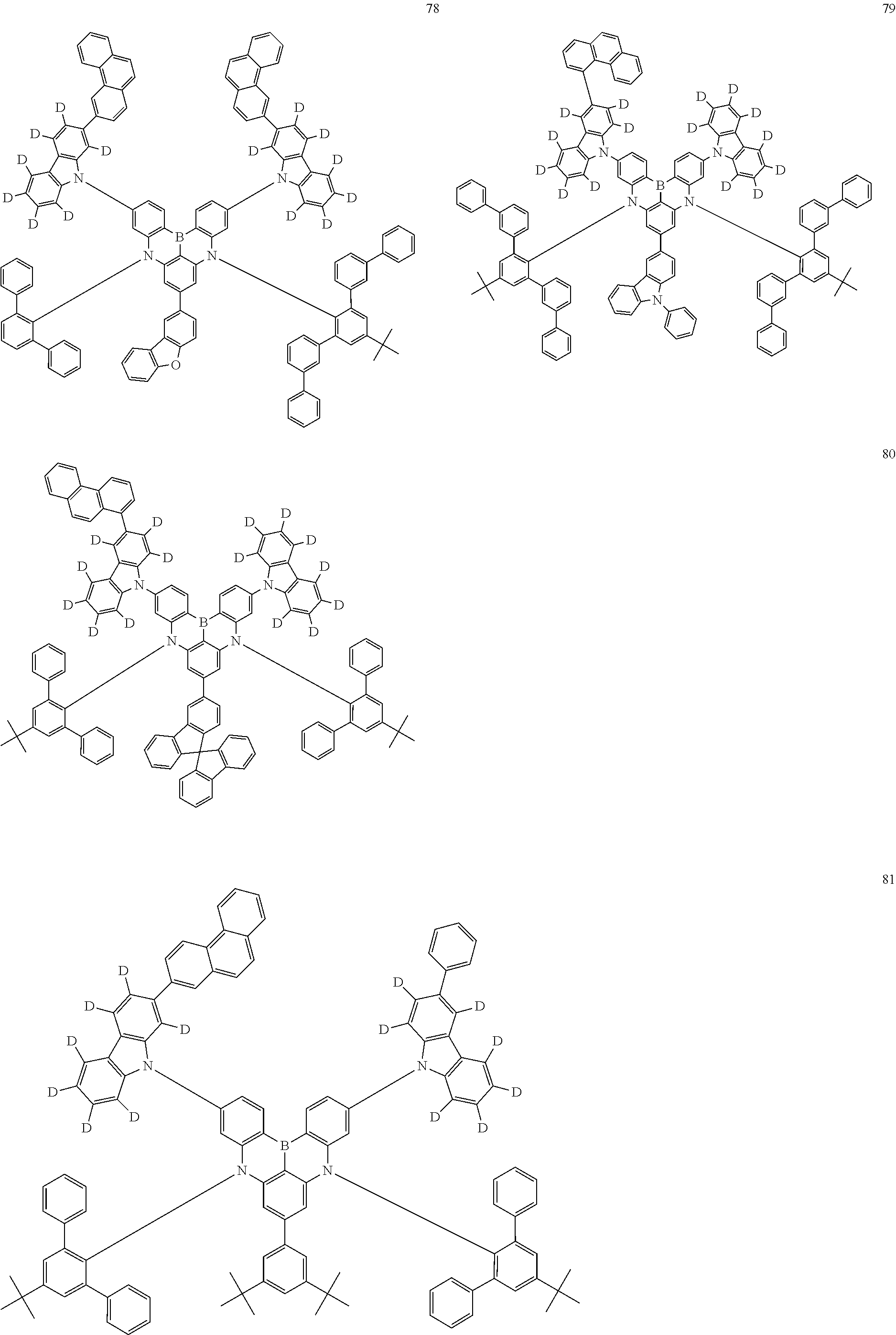 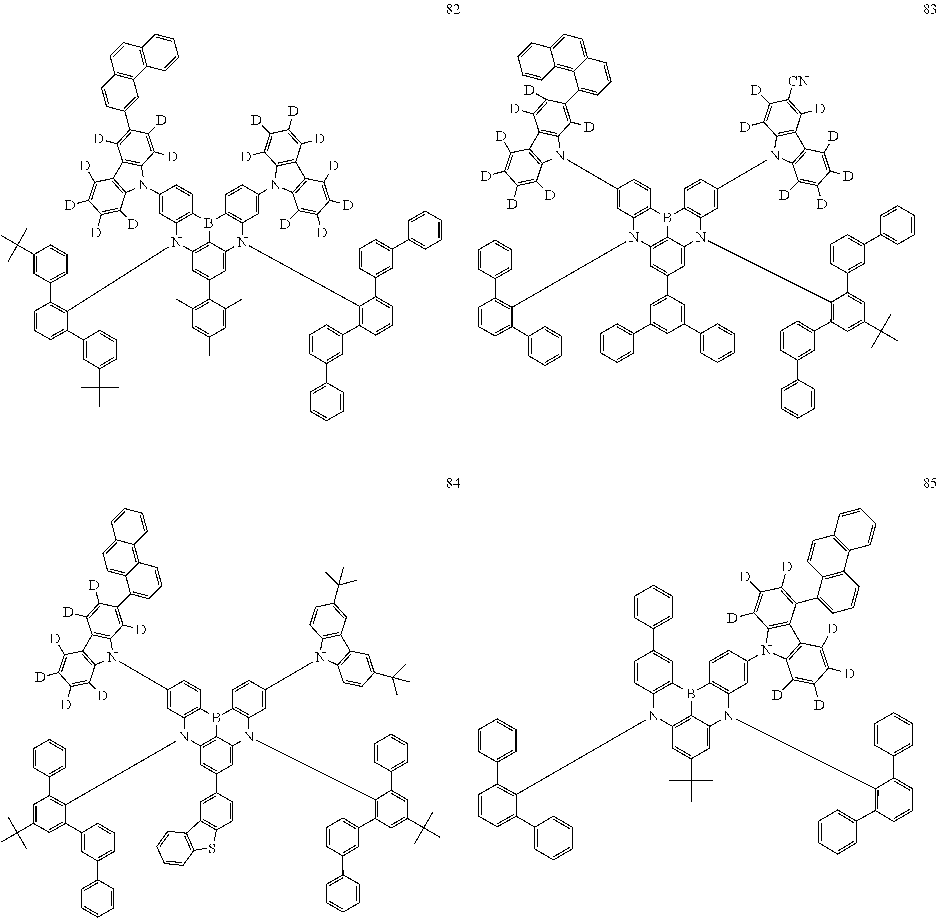 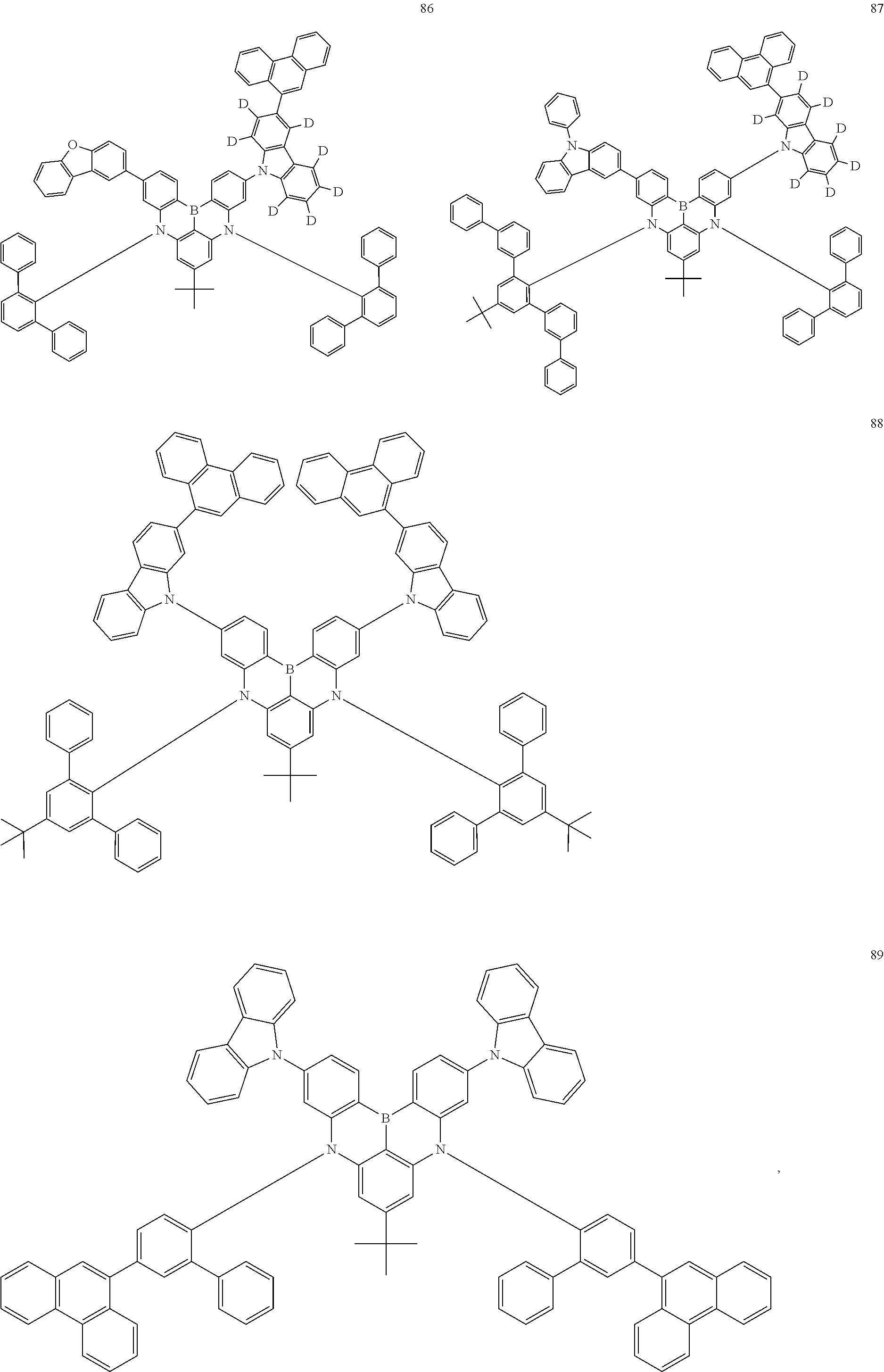
in Compound Group 1, D being a deuterium atom.

10. A fused polycyclic compound represented by Formula 1: 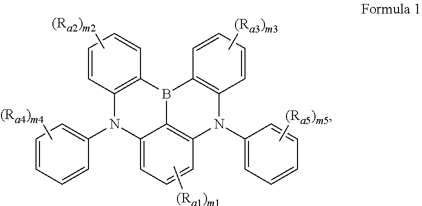
wherein, in Formula 1,
m1 is an integer of 0 to 3,
m2 and m3 are each independently an integer of 0 to 4,
m4 and m5 are each independently an integer of 0 to 5,
at least one selected from among Rₐ₁ to R^{a5} comprises a first carbazole substituted or unsubstituted, and
at least one selected from among Rₐ₁ to R^{a5} is a group represented by Formula 2, and the rest thereof are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms: 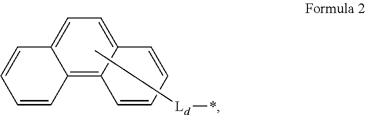
and
wherein, in Formula 2,
L_{d} is a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 30 ring-forming carbon atoms,
and
when L_{d} does not include the first carbazole:
at least one selected from among Rₐ₁ to R^{a5} not represented by Formula 2 comprises the first carbazole substituted with a substituent other than a phenanthryl group; or
Rₐ₂ and Rₐ₃ are each independently include the first carbazole not substituted or the first carbazole substituted with a substituent other than a phenanthryl group.

11. The fused polycyclic compound of claim 10, wherein the fused polycyclic compound represented by Formula 1 is represented by any one selected from among Formula 1-1 to Formula 1-3: 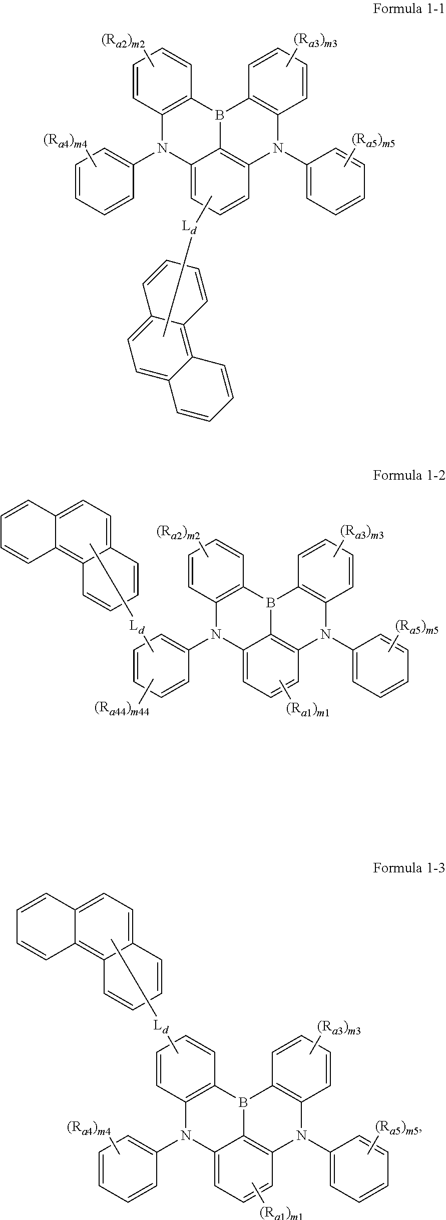
in Formula 1-2,
m44 being an integer of 0 to 4,
Rₐ₄₄ being a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
in Formula 1-1 to Formula 1-3,
m1 to m5, Rₐ₁ to R^{a5}, and L_{d} being each the same as defined in Formula 1 and in Formula 2.

12. The fused polycyclic compound of claim 11, wherein the fused polycyclic compound represented by Formula 1-1 is represented by Formula 1-1A: 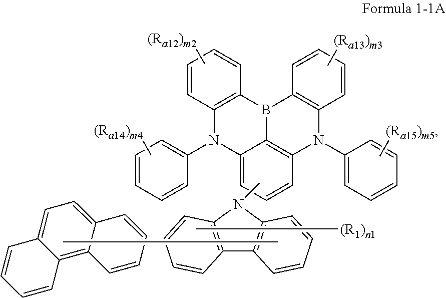
and
wherein, in Formula 1-1A,
n1 is an integer of 0 to 7,
R₁ and Rₐ₁₂ to Rₐ₁₅ are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m2 to m5 are each the same as defined in Formula 1-1.

13. The fused polycyclic compound of claim 11, wherein the fused polycyclic compound represented by Formula 1-2 is represented by Formula 1-2A: 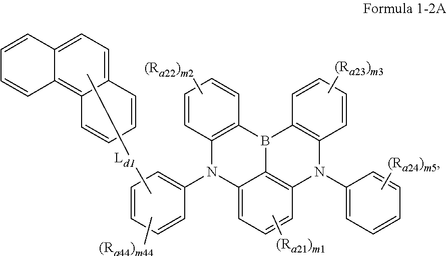
and
wherein, in Formula 1-2A,
L_{d1} is a direct linkage or a substituted or unsubstituted arylene group having 6 to 30 ring-forming carbon atoms,
at least one selected from among Rₐ₂₁ to Rₐ₂₄ is the first carbazole substituted with a substituent other than a phenanthryl group, and the rest thereof are each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or
Rₐ₂₂ and Rₐ₂₃ are each independently the first carbazole not substituted or the first carbazole substituted with a substituent other than a phenanthryl group, and Rₐ₂₁ and Rₐ₂₄ are each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m1 to m3, m5, m44, and Rₐ₄₄ are each the same as defined in Formula 1-2.

14. The fused polycyclic compound of claim 11, wherein the fused polycyclic compound represented by Formula 1-3 is represented by Formula 1-3A: 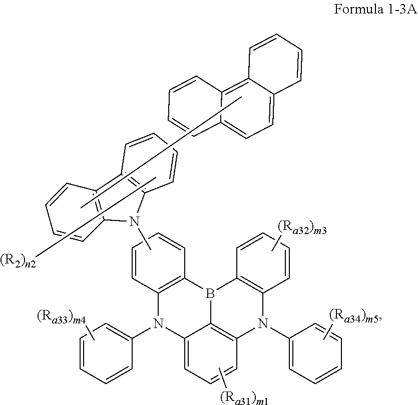
and
wherein, in Formula 1-3A,
n2 is an integer of 0 to 7,
R₂ and Rₐ₃₁ to Rₐ₃₄ are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m1 and m3 to m5 are each the same as defined in Formula 1-3.

15. The fused polycyclic compound of claim 14, wherein the fused polycyclic compound represented by Formula 1-3A is represented by Formula 1-3AA: 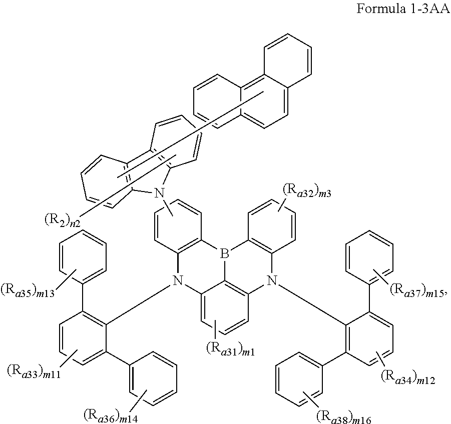
and
wherein, in Formula 1-3AA,
m11 and m12 are each independently an integer of 0 to 3,
m13 to m16 are each independently an integer of 0 to 5,
Rₐ₃₅ to Rₐ₃s are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
m1, m3, n2, R₂, and Rₐ₃₁ to Rₐ₃₄ are each the same as defined in Formula 1-3A.

16. The fused polycyclic compound of claim 10, wherein the group represented by Formula 2 is represented by any one selected from among Formula 2-1 to Formula 2-31: 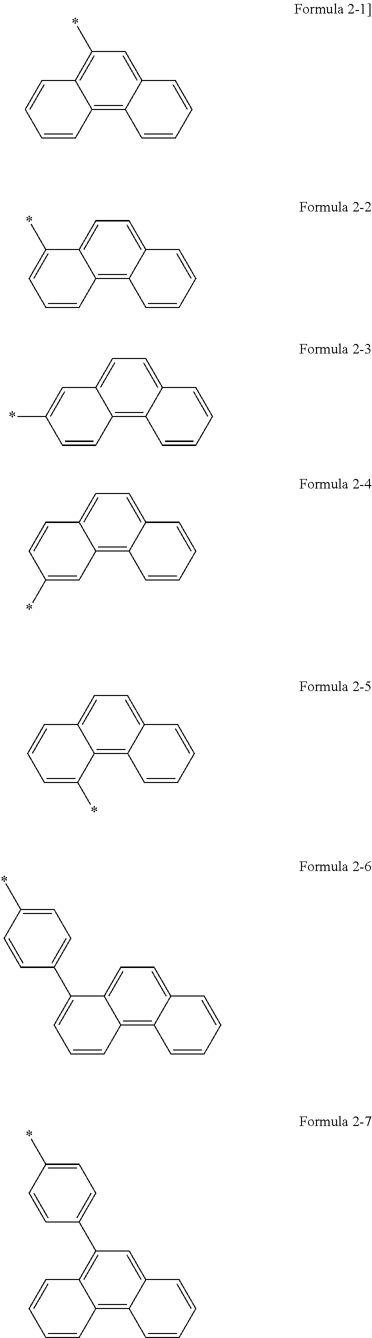 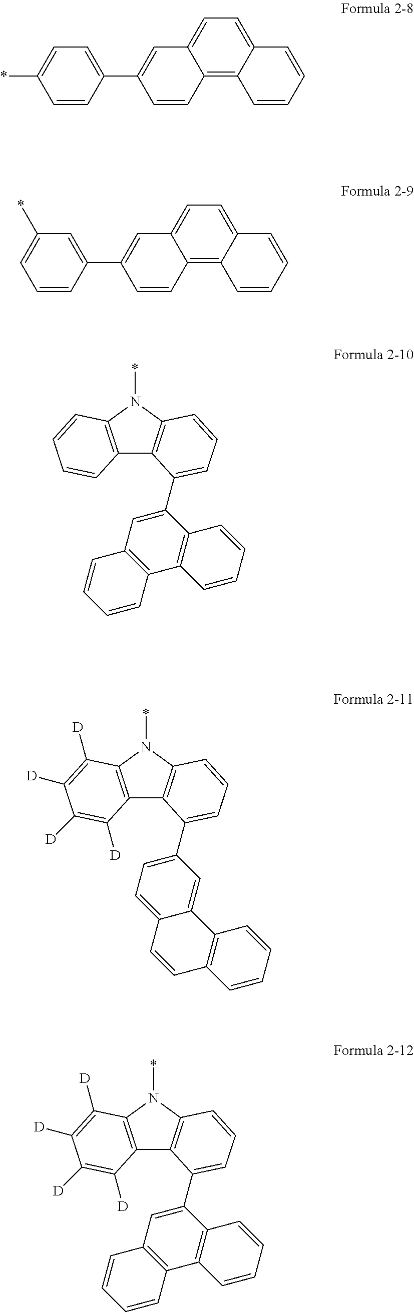 [SMILES: *c1ccc(-c2ccc3c(ccc4ccccc43)c2)cc1 ; *c1cccc(-c2ccc3c(ccc4ccccc43)c2)c1 ; *n1c2ccccc2c2c(-c3cc4ccccc4c4ccccc34)cccc21 ; *n1c2cccc(-c3ccc4ccc5ccccc5c4c3)c2c2c([2H])c([2H])c([2H])c([2H])c21 ; *n1c2cccc(-c3cc4ccccc4c4ccccc34)c2c2c([2H])c([2H])c([2H])c([2H])c21] 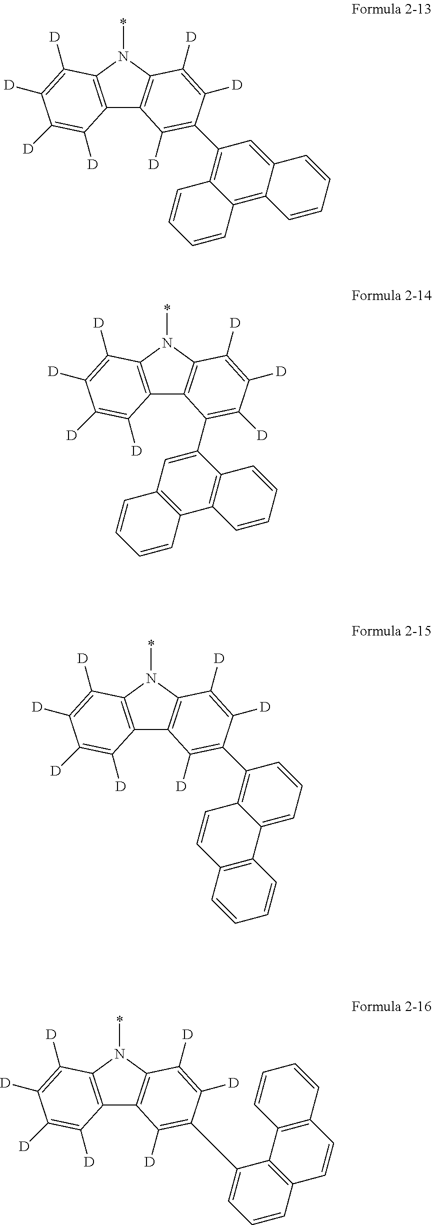 [SMILES: *n1c2c([2H])c([2H])c([2H])c([2H])c2c2c([2H])c(-c3cc4ccccc4c4ccccc34)c([2H])c([2H])c21 ; *n1c2c([2H])c([2H])c([2H])c([2H])c2c2c(-c3cc4ccccc4c4ccccc34)c([2H])c([2H])c([2H])c21 ; *n1c2c([2H])c([2H])c([2H])c([2H])c2c2c([2H])c(-c3cccc4c3ccc3ccccc34)c([2H])c([2H])c21 ; *n1c2c([2H])c([2H])c([2H])c([2H])c2c2c([2H])c(-c3cccc4ccc5ccccc5c34)c([2H])c([2H])c21] 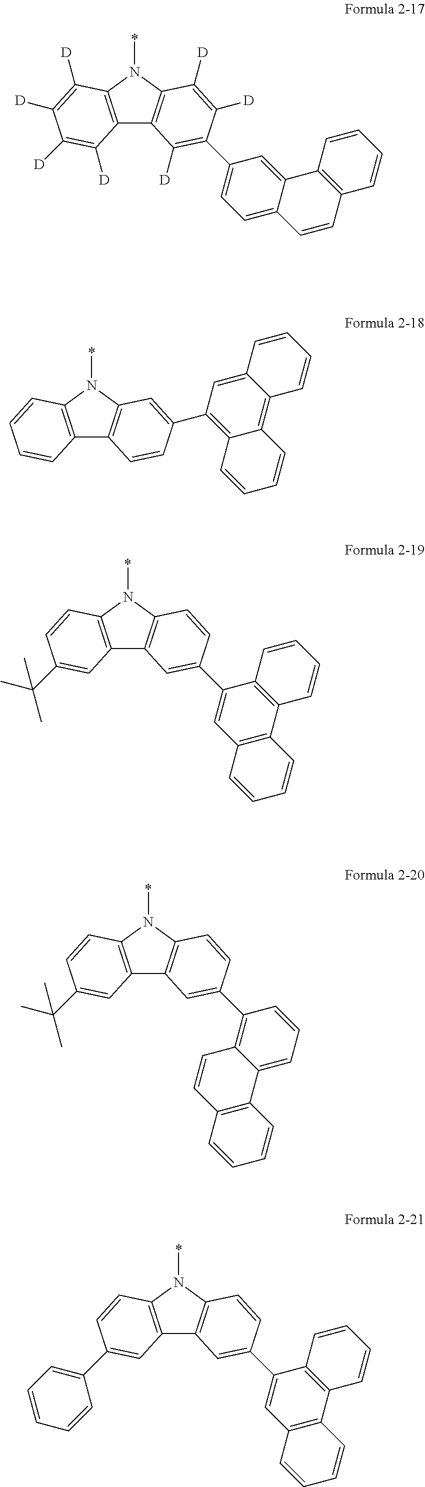 [SMILES: *n1c2c([2H])c([2H])c([2H])c([2H])c2c2c([2H])c(-c3ccc4ccc5ccccc5c4c3)c([2H])c([2H])c21 ; *n1c2ccccc2c2ccc(-c3cc4ccccc4c4ccccc34)cc21 ; *n1c2ccc(-c3cc4ccccc4c4ccccc34)cc2c2cc(C(C)(C)C)ccc21 ; *n1c2ccc(-c3cccc4c3ccc3ccccc34)cc2c2cc(C(C)(C)C)ccc21 ; *n1c2ccc(-c3ccccc3)cc2c2cc(-c3cc4ccccc4c4ccccc34)ccc21] 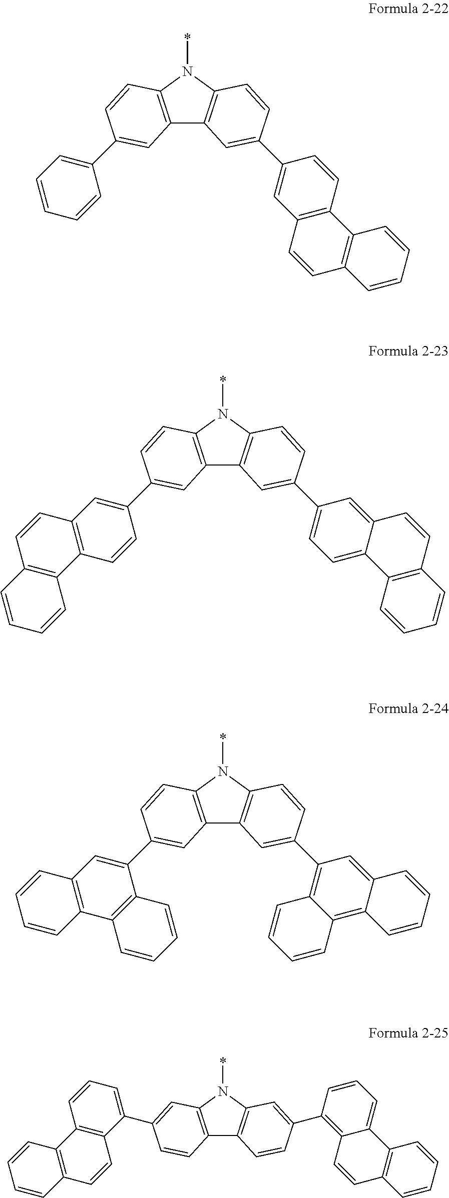 [SMILES: *n1c2ccc(-c3ccccc3)cc2c2cc(-c3ccc4c(ccc5ccccc54)c3)ccc21 ; *n1c2ccc(-c3ccc4c(ccc5ccccc54)c3)cc2c2cc(-c3ccc4c(ccc5ccccc54)c3)ccc21 ; *n1c2ccc(-c3cc4ccccc4c4ccccc34)cc2c2cc(-c3cc4ccccc4c4ccccc34)ccc21 ; *n1c2cc(-c3cccc4c3ccc3ccccc34)ccc2c2ccc(-c3cccc4c3ccc3ccccc34)cc21] 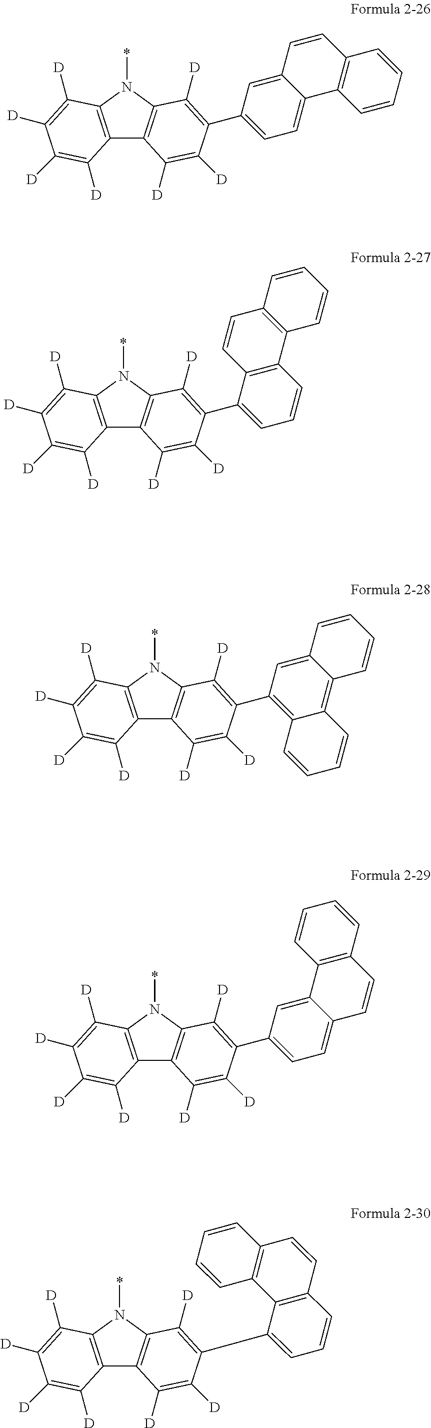 [SMILES: *n1c2c([2H])c([2H])c([2H])c([2H])c2c2c([2H])c([2H])c(-c3ccc4c(ccc5ccccc54)c3)c([2H])c21 ; *n1c2c([2H])c([2H])c([2H])c([2H])c2c2c([2H])c([2H])c(-c3cccc4c3ccc3ccccc34)c([2H])c21 ; *n1c2c([2H])c([2H])c([2H])c([2H])c2c2c([2H])c([2H])c(-c3cc4ccccc4c4ccccc34)c([2H])c21 ; *n1c2c([2H])c([2H])c([2H])c([2H])c2c2c([2H])c([2H])c(-c3ccc4ccc5ccccc5c4c3)c([2H])c21 ; *n1c2c([2H])c([2H])c([2H])c([2H])c2c2c([2H])c([2H])c(-c3cccc4ccc5ccccc5c34)c([2H])c21] 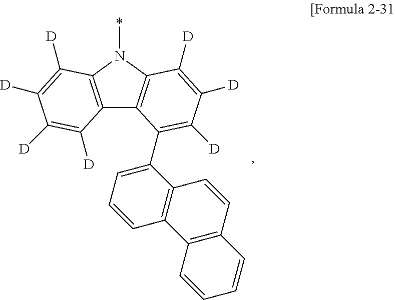 [SMILES: *n1c2c([2H])c([2H])c([2H])c([2H])c2c2c(-c3cccc4c3ccc3ccccc34)c([2H])c([2H])c([2H])c21]
in Formula 2-11 Formula 2-17 and Formula 2-26 to Formula 2-31, D being a deuterium atom.

17. The fused polycyclic compound of claim 10, wherein the fused polycyclic compound represented by Formula 1 is any one selected from among compounds of Compound Group 1:
Compound Group 1 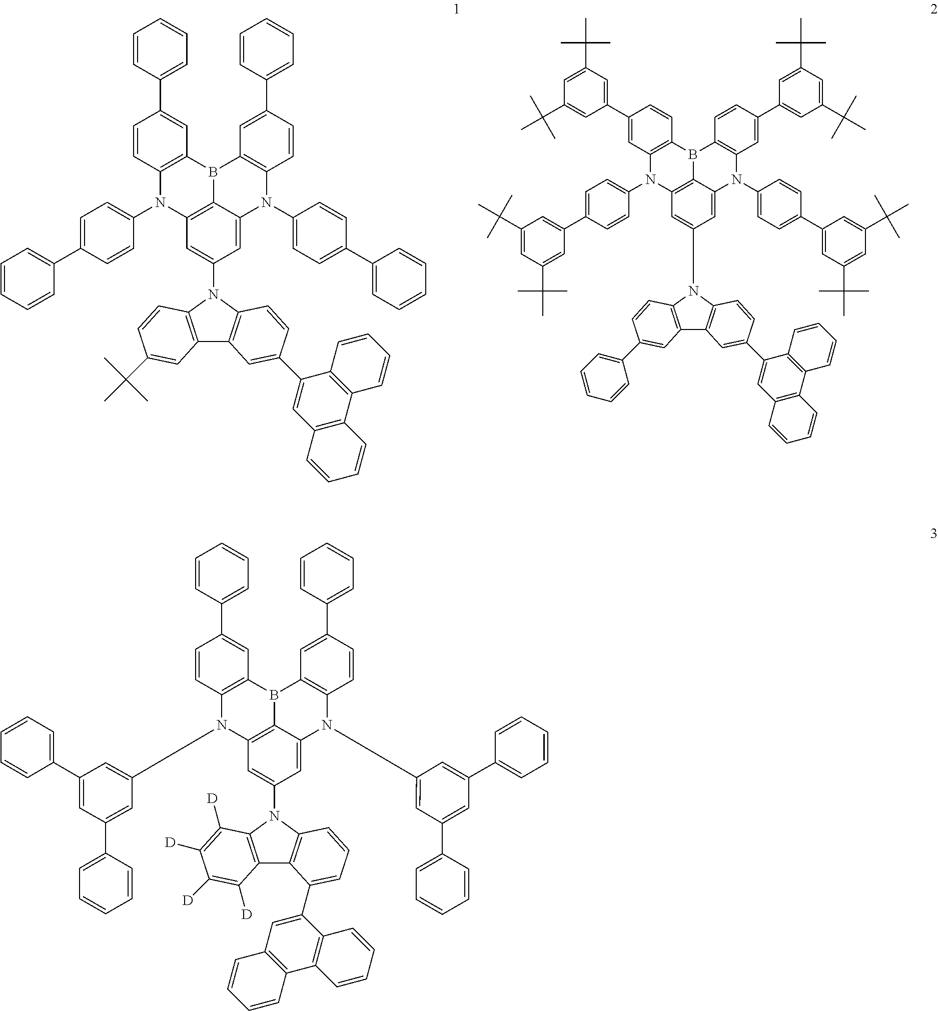 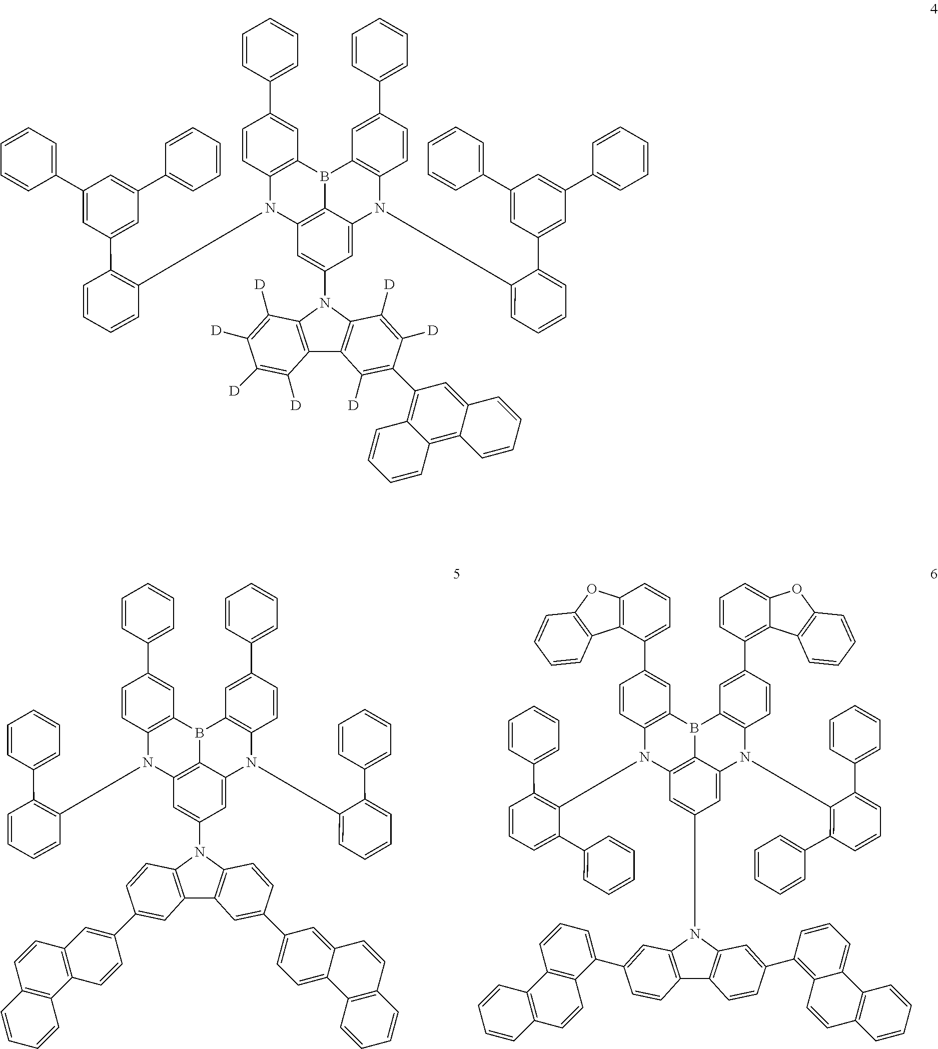 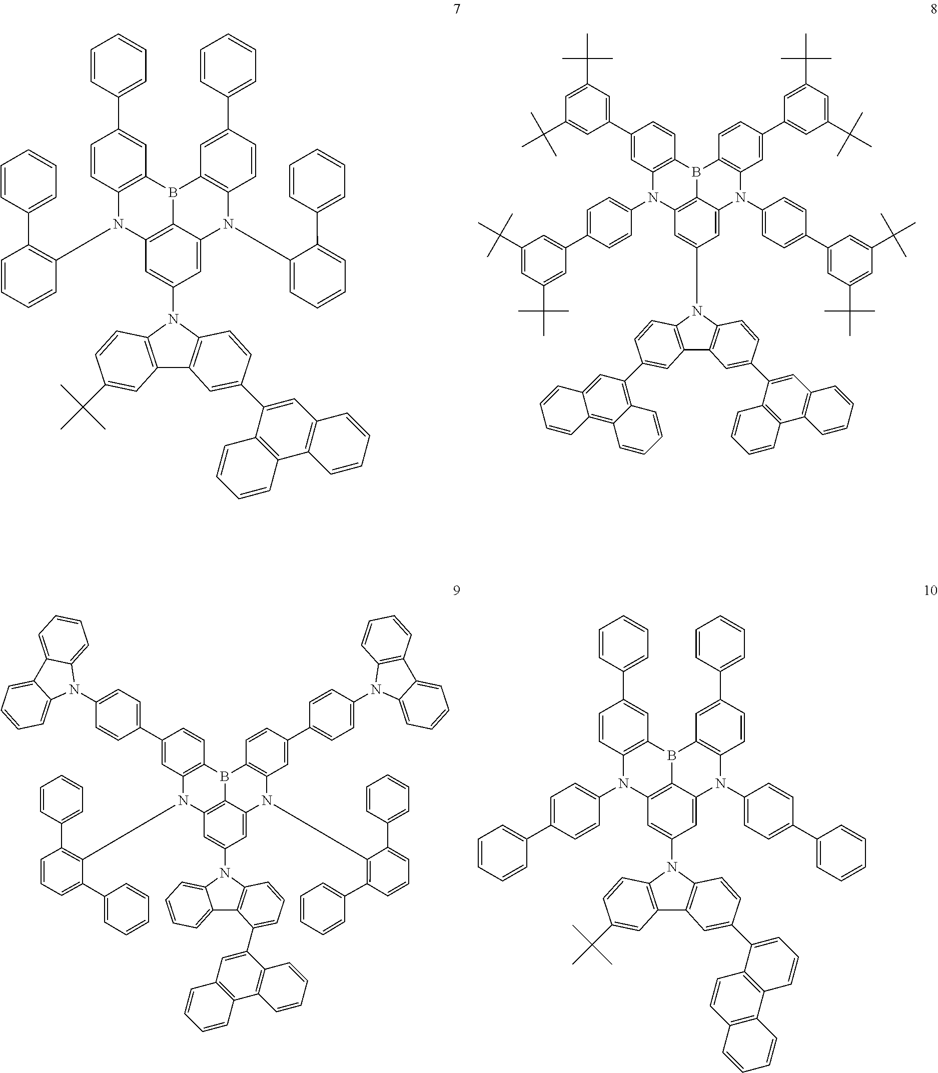 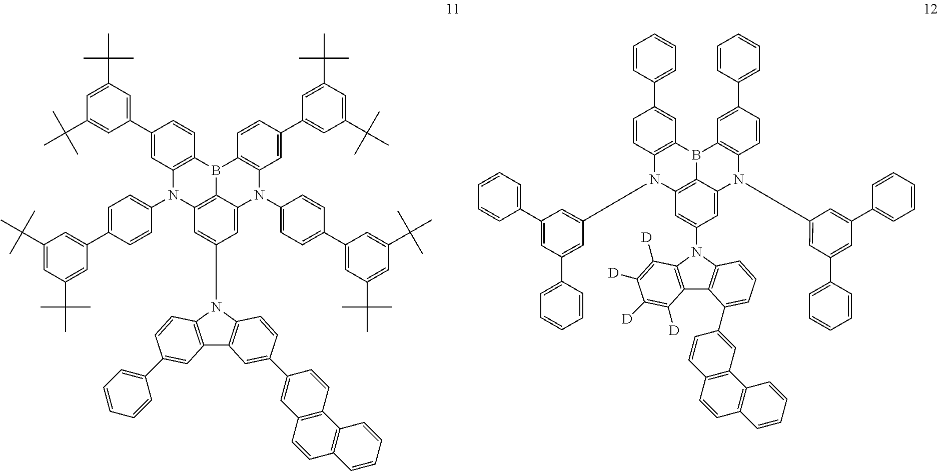 [SMILES: CC(C)(C)c1cc(-c2ccc(N3c4cc(-c5cc(C(C)(C)C)cc(C(C)(C)C)c5)ccc4B4c5ccc(-c6cc(C(C)(C)C)cc(C(C)(C)C)c6)cc5N(c5ccc(-c6cc(C(C)(C)C)cc(C(C)(C)C)c6)cc5)c5cc(-n6c7ccc(-c8ccccc8)cc7c7cc(-c8ccc9c(ccc%10ccccc%109)c8)ccc76)cc3c54)cc2)cc(C(C)(C)C)c1 ; [2H]c1c([2H])c([2H])c2c(c1[2H])c1c(-c3ccc4ccc5ccccc5c4c3)cccc1n2-c1cc2c3c(c1)N(c1cc(-c4ccccc4)cc(-c4ccccc4)c1)c1ccc(-c4ccccc4)cc1B3c1cc(-c3ccccc3)ccc1N2c1cc(-c2ccccc2)cc(-c2ccccc2)c1] 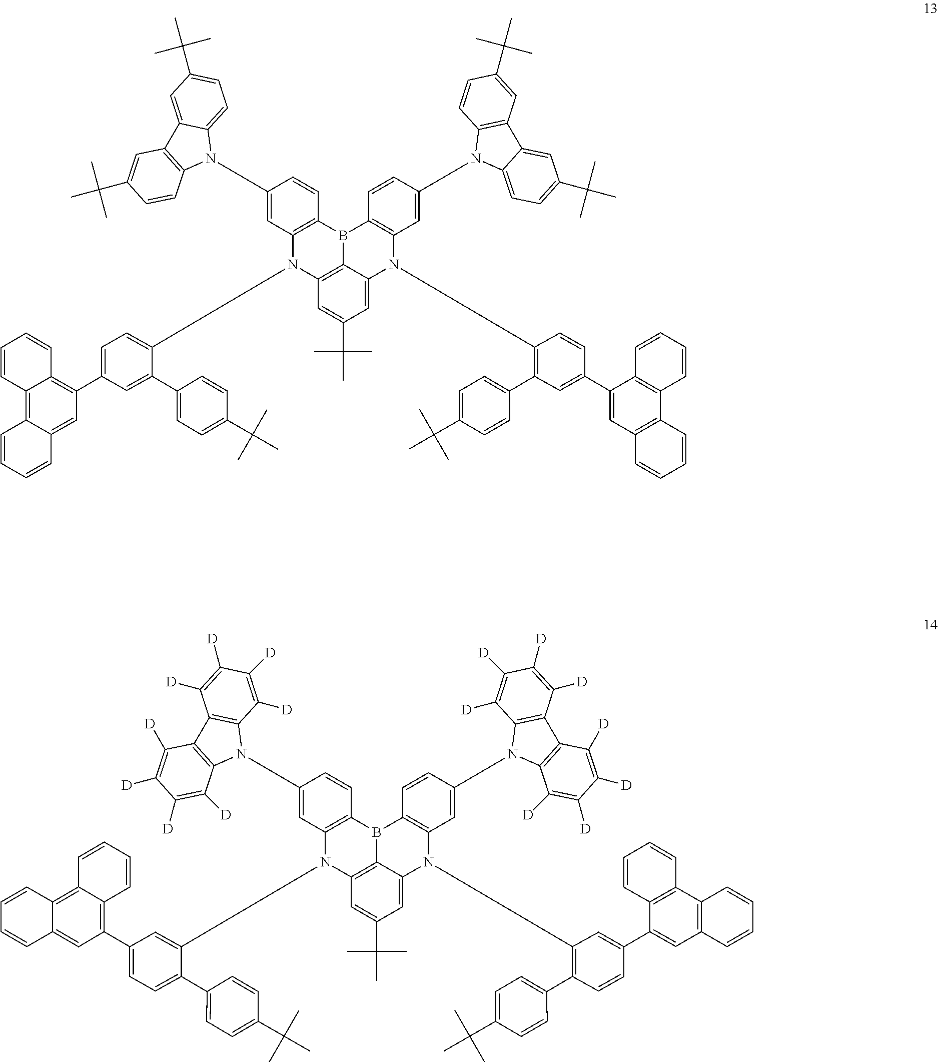 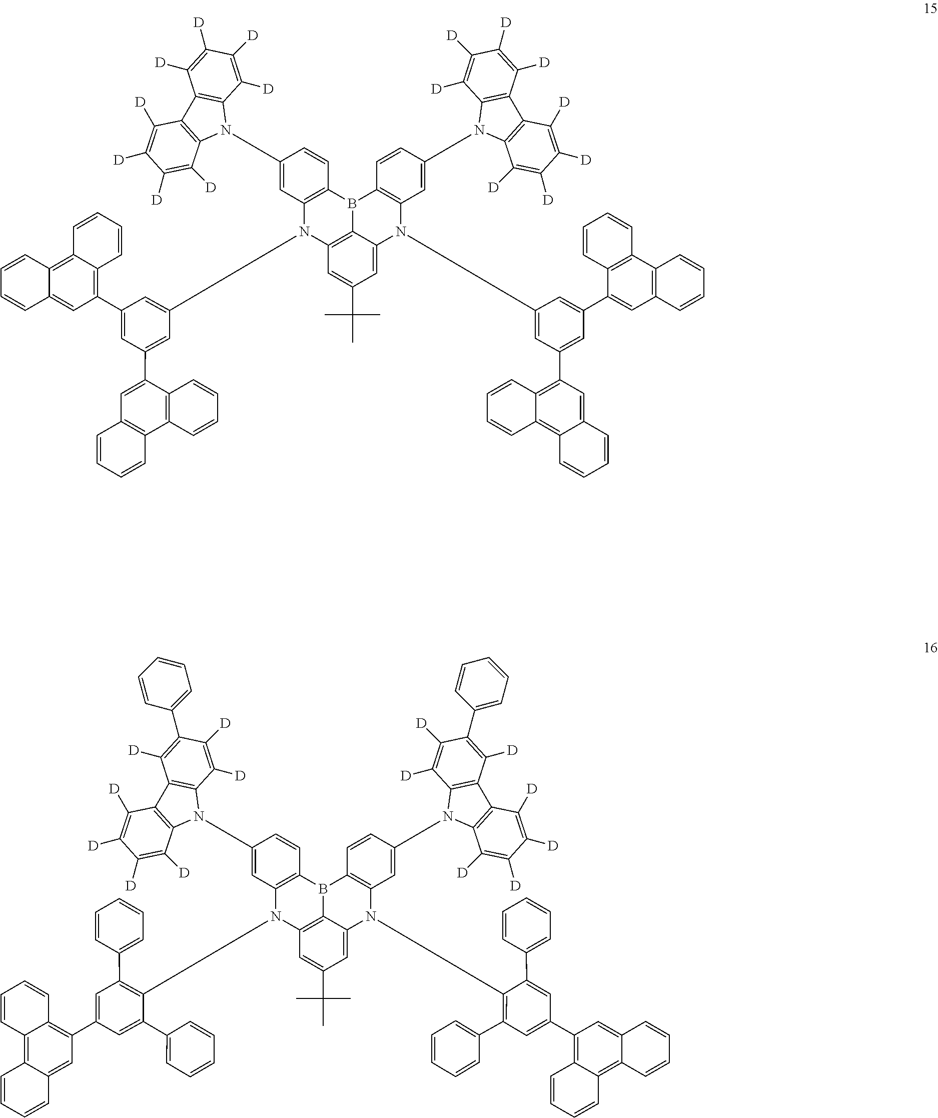 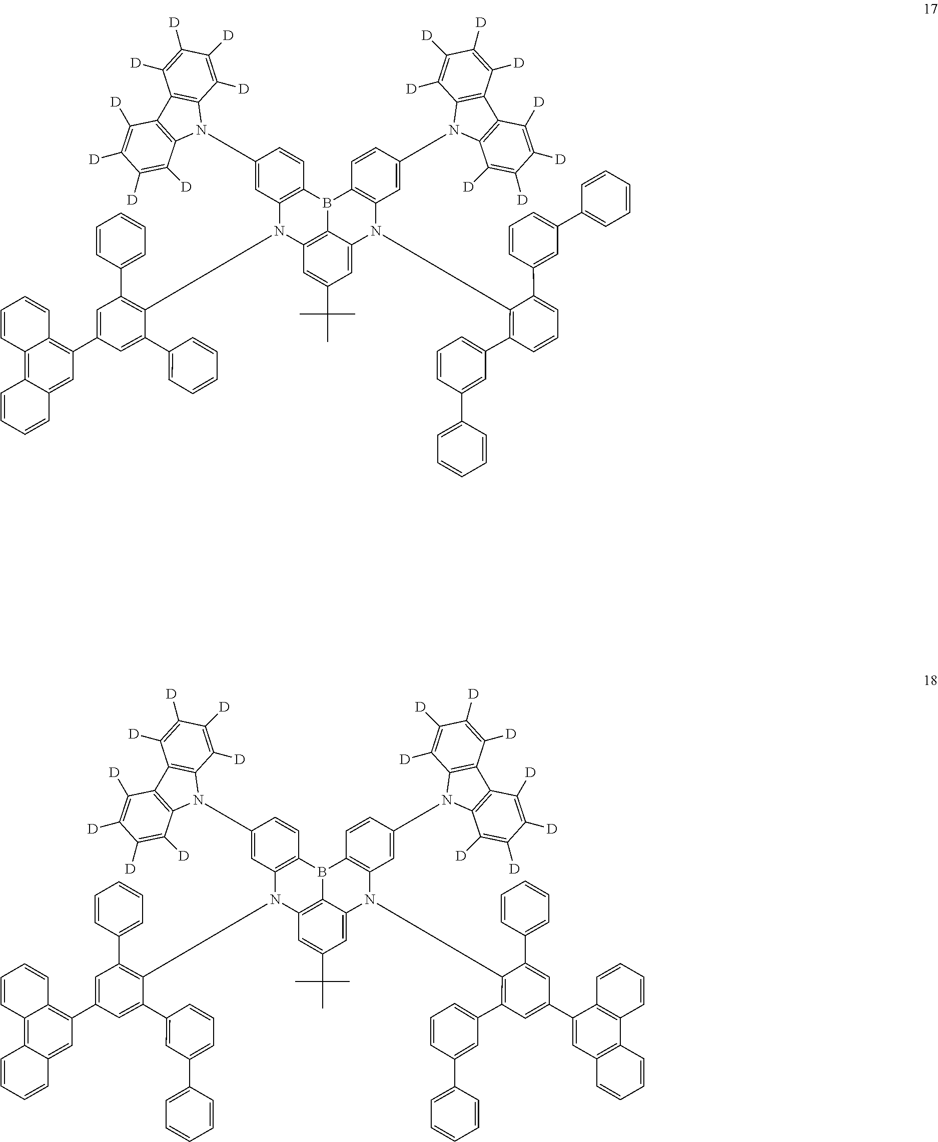 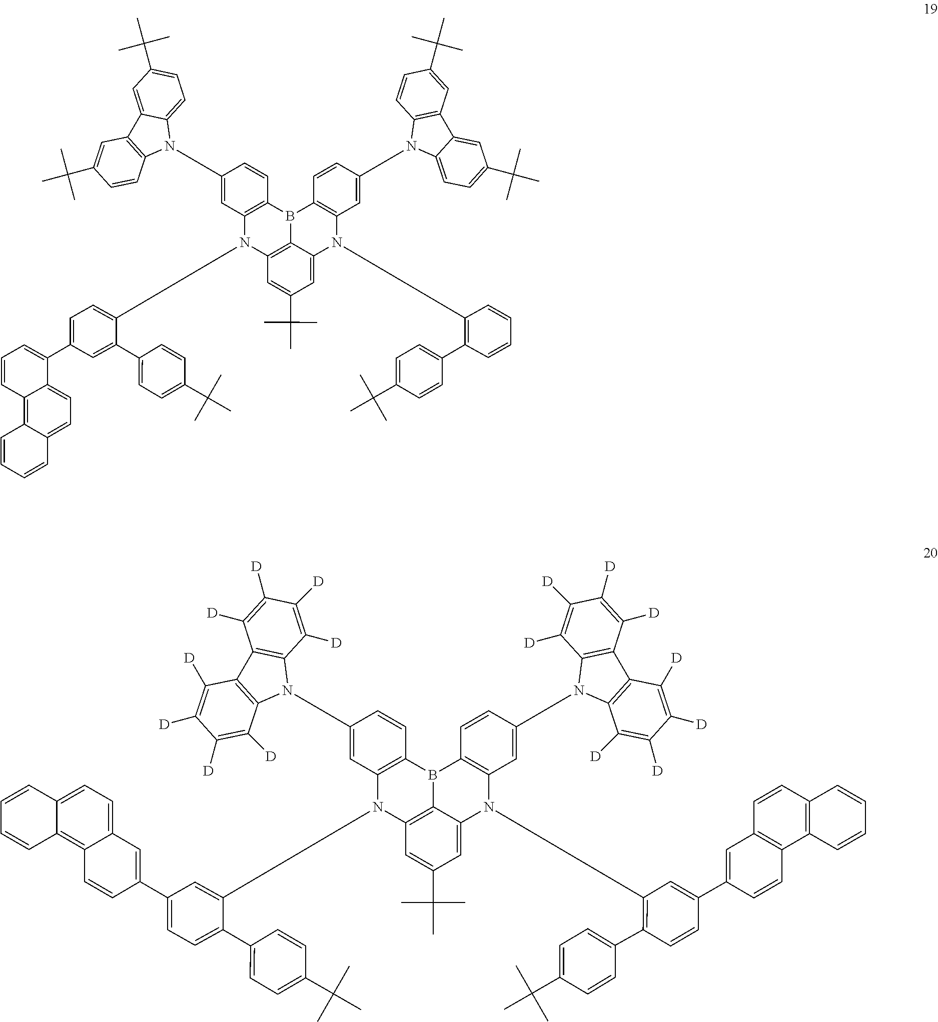 [SMILES: CC(C)(C)c1ccc(-c2ccccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5cccc6c5ccc5ccccc56)cc4-c4ccc(C(C)(C)C)cc4)c4cc(C(C)(C)C)cc2c43)cc1 ; [2H]c1c([2H])c([2H])c2c(c1[2H])c1c([2H])c([2H])c([2H])c([2H])c1n2-c1ccc2c(c1)N(c1cc(-c3ccc4c(ccc5ccccc54)c3)ccc1-c1ccc(C(C)(C)C)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1cc(-c2ccc3c(ccc4ccccc43)c2)ccc1-c1ccc(C(C)(C)C)cc1] 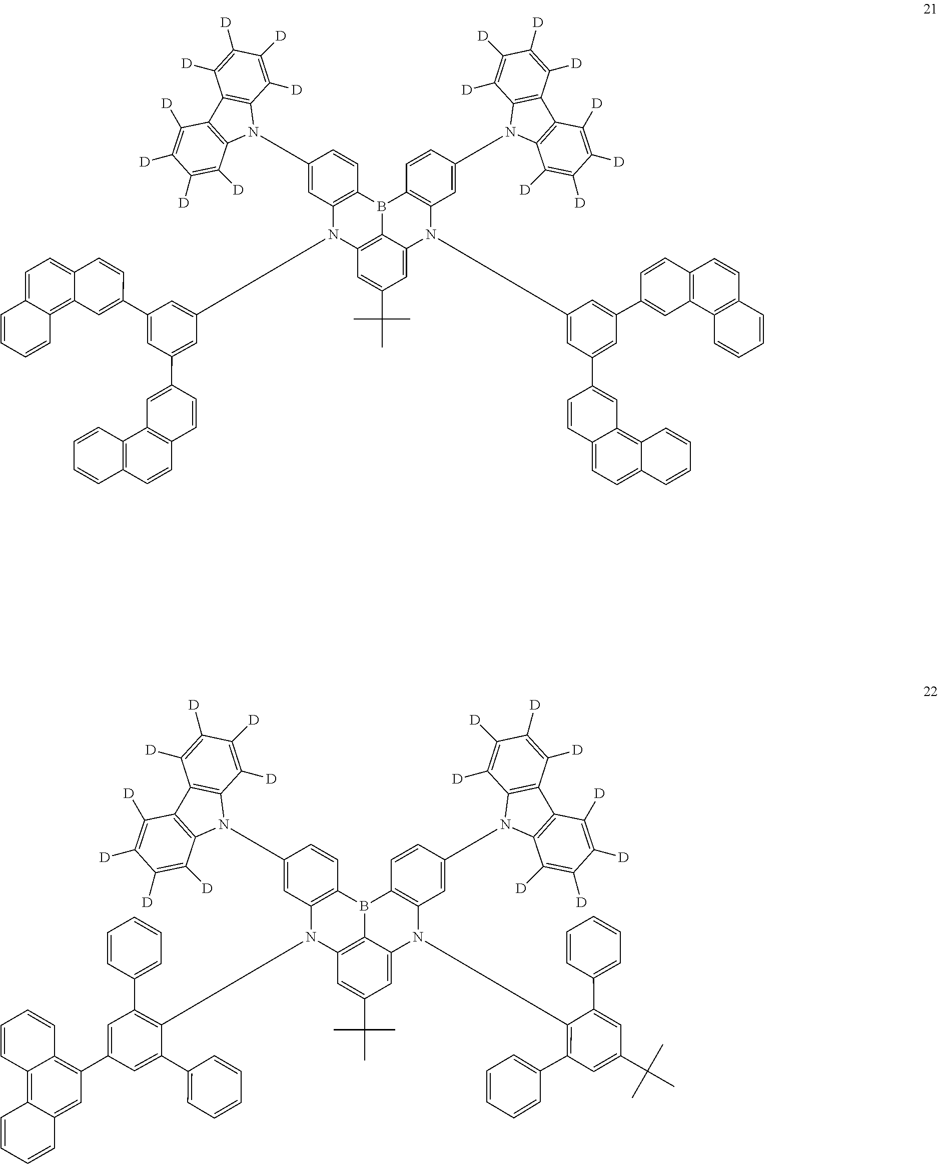 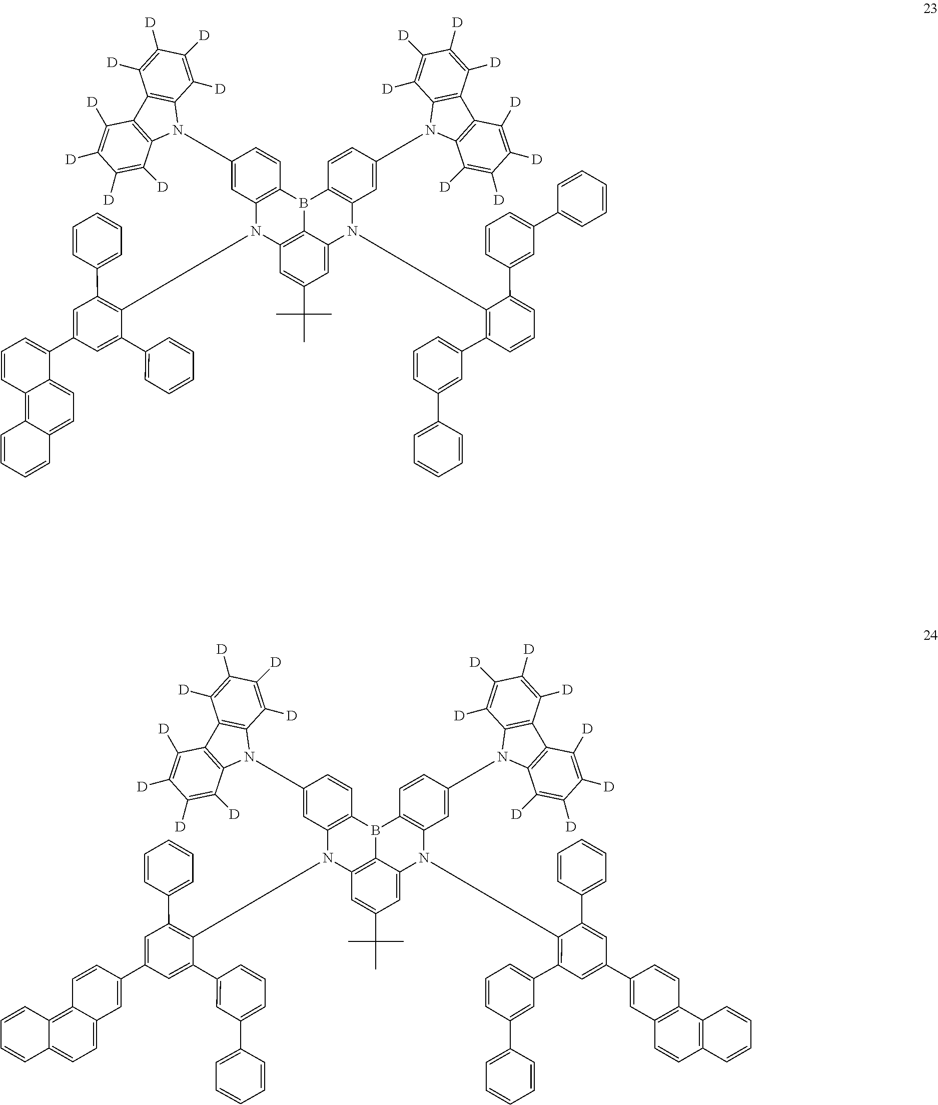 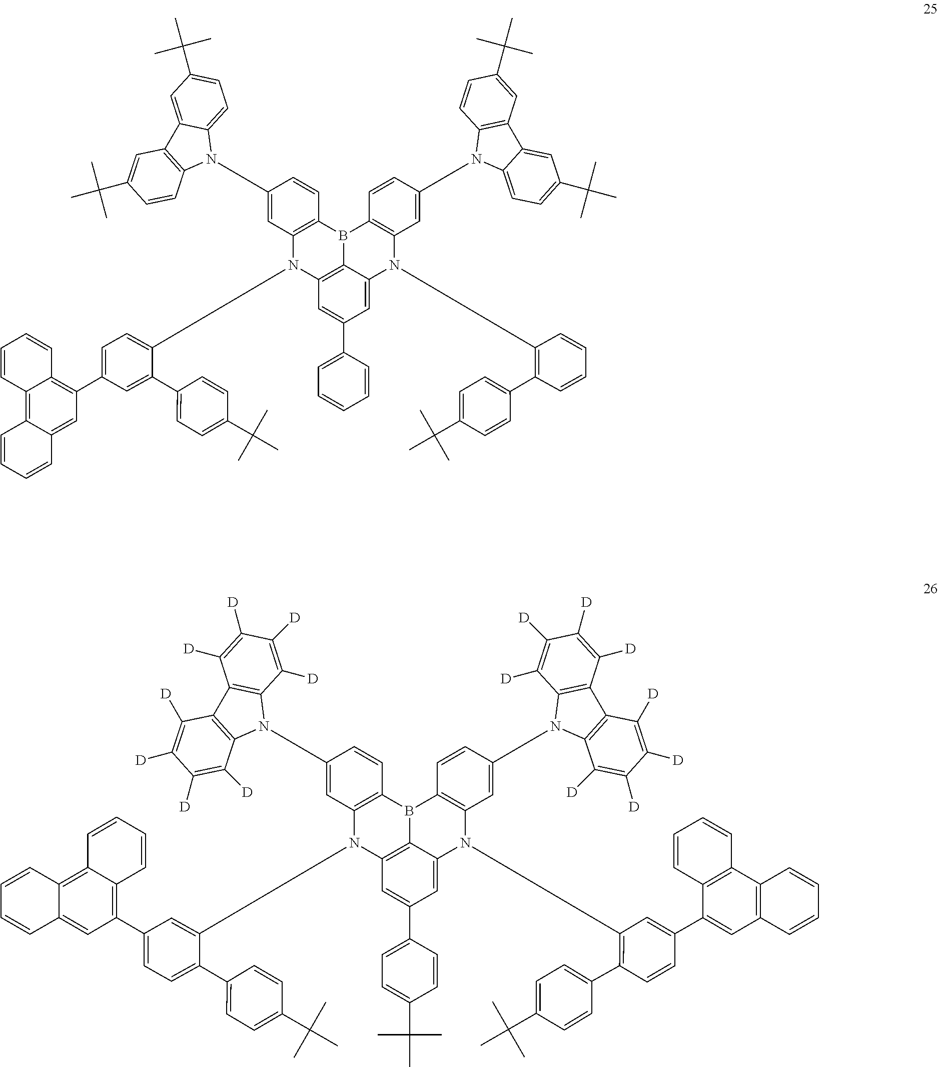 [SMILES: CC(C)(C)c1ccc(-c2ccccc2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-c5cc6ccccc6c6ccccc56)cc4-c4ccc(C(C)(C)C)cc4)c4cc(-c5ccccc5)cc2c43)cc1 ; [2H]c1c([2H])c([2H])c2c(c1[2H])c1c([2H])c([2H])c([2H])c([2H])c1n2-c1ccc2c(c1)N(c1cc(-c3cc4ccccc4c4ccccc34)ccc1-c1ccc(C(C)(C)C)cc1)c1cc(-c3ccc(C(C)(C)C)cc3)cc3c1B2c1ccc(-n2c4c([2H])c([2H])c([2H])c([2H])c4c4c([2H])c([2H])c([2H])c([2H])c42)cc1N3c1cc(-c2cc3ccccc3c3ccccc23)ccc1-c1ccc(C(C)(C)C)cc1] 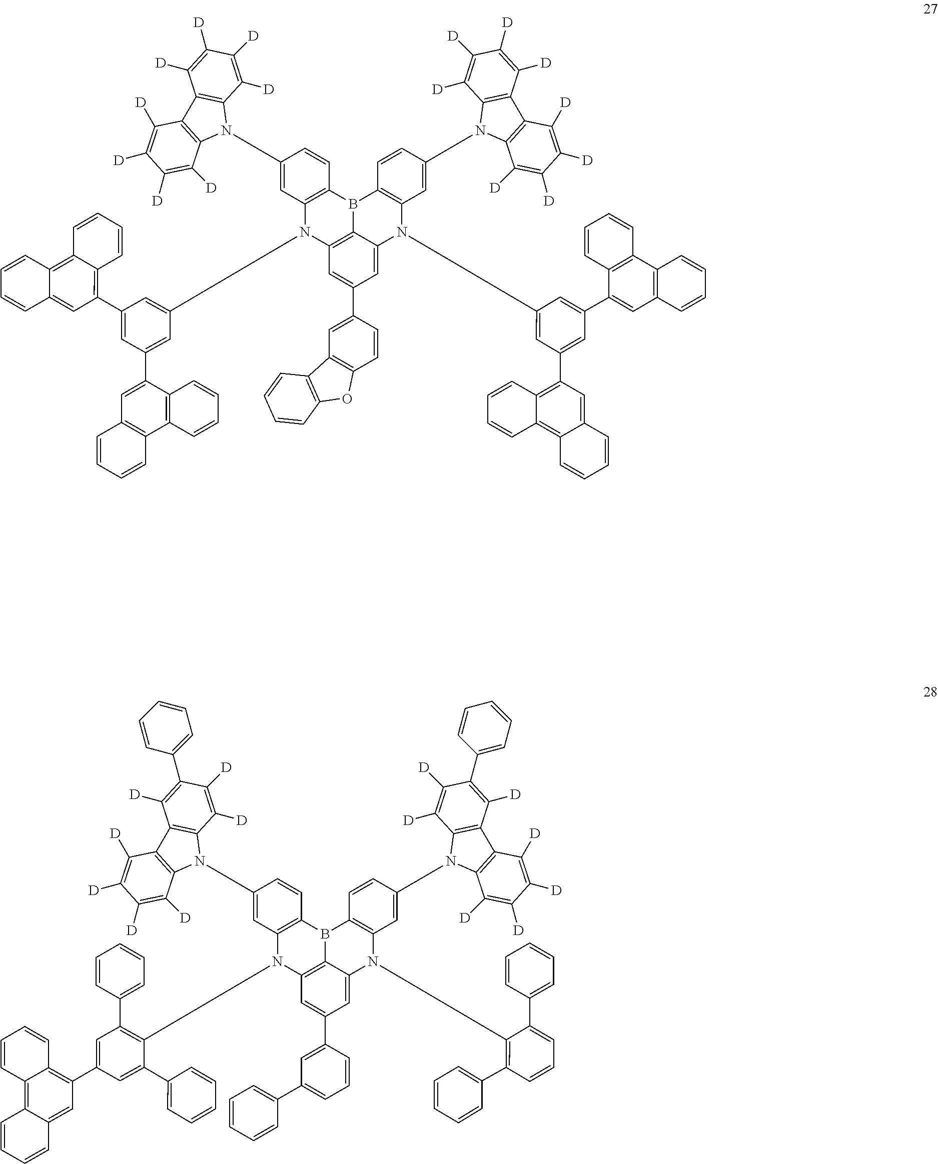 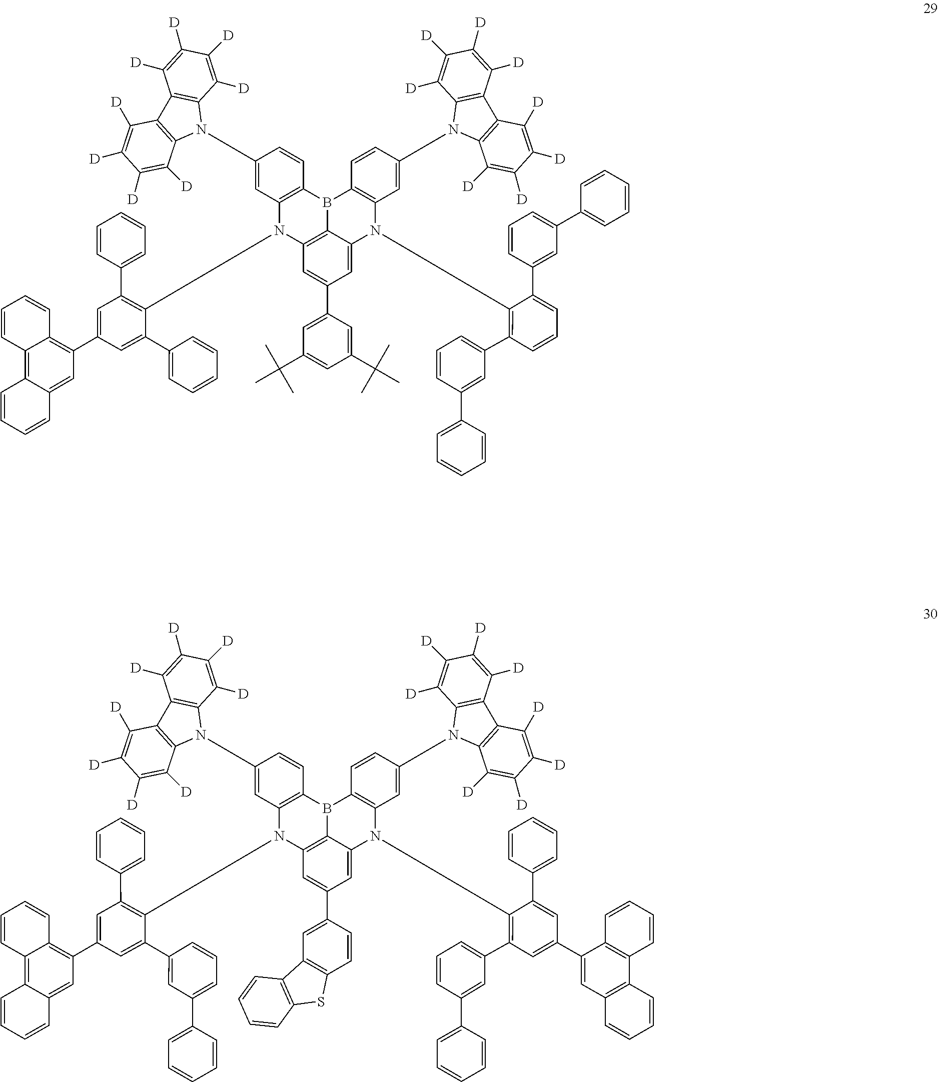 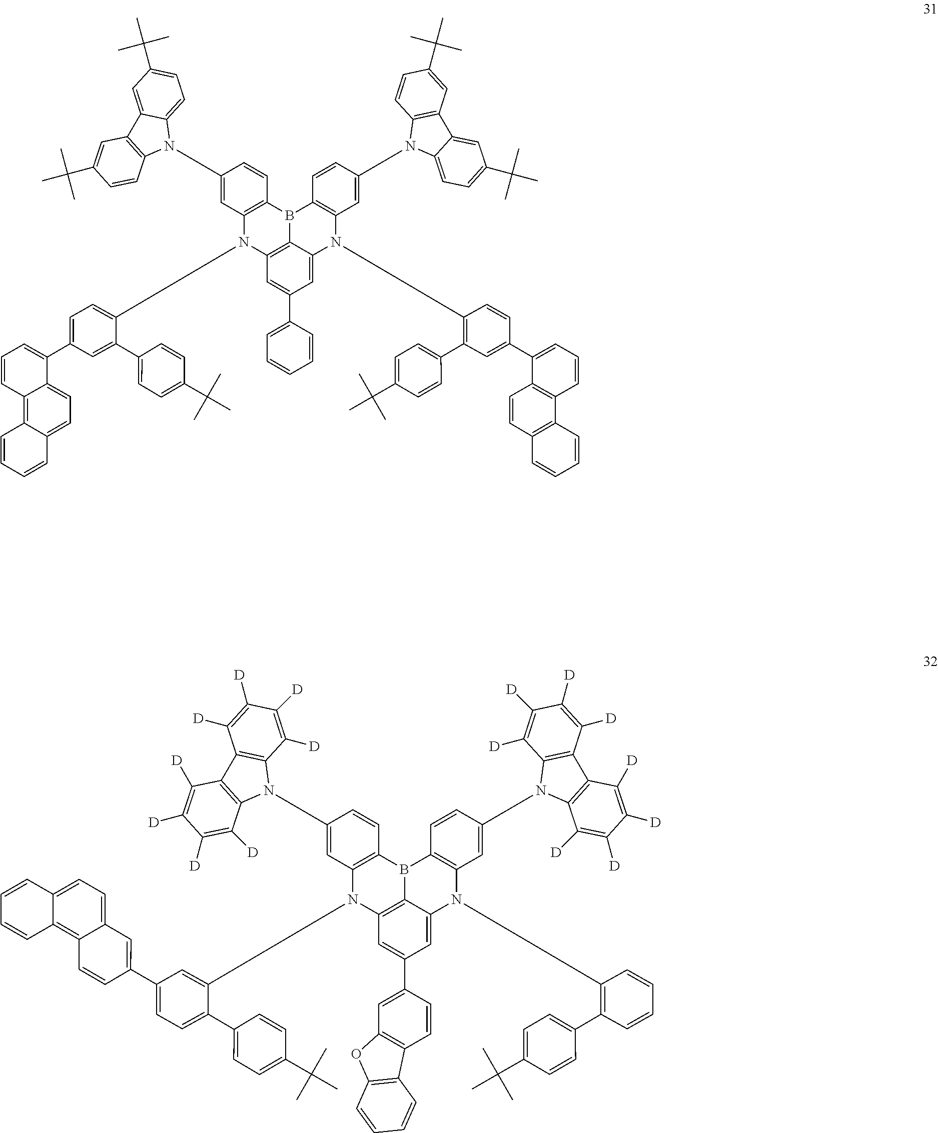 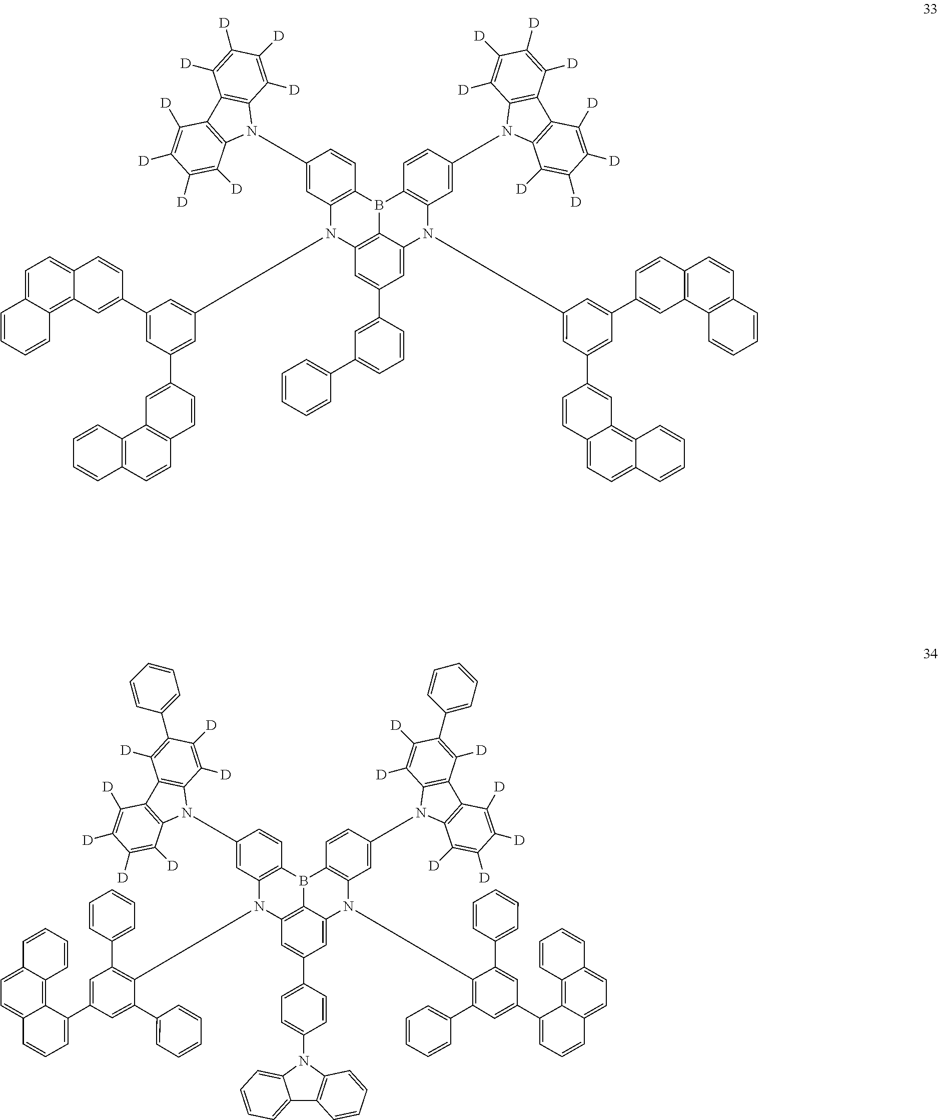 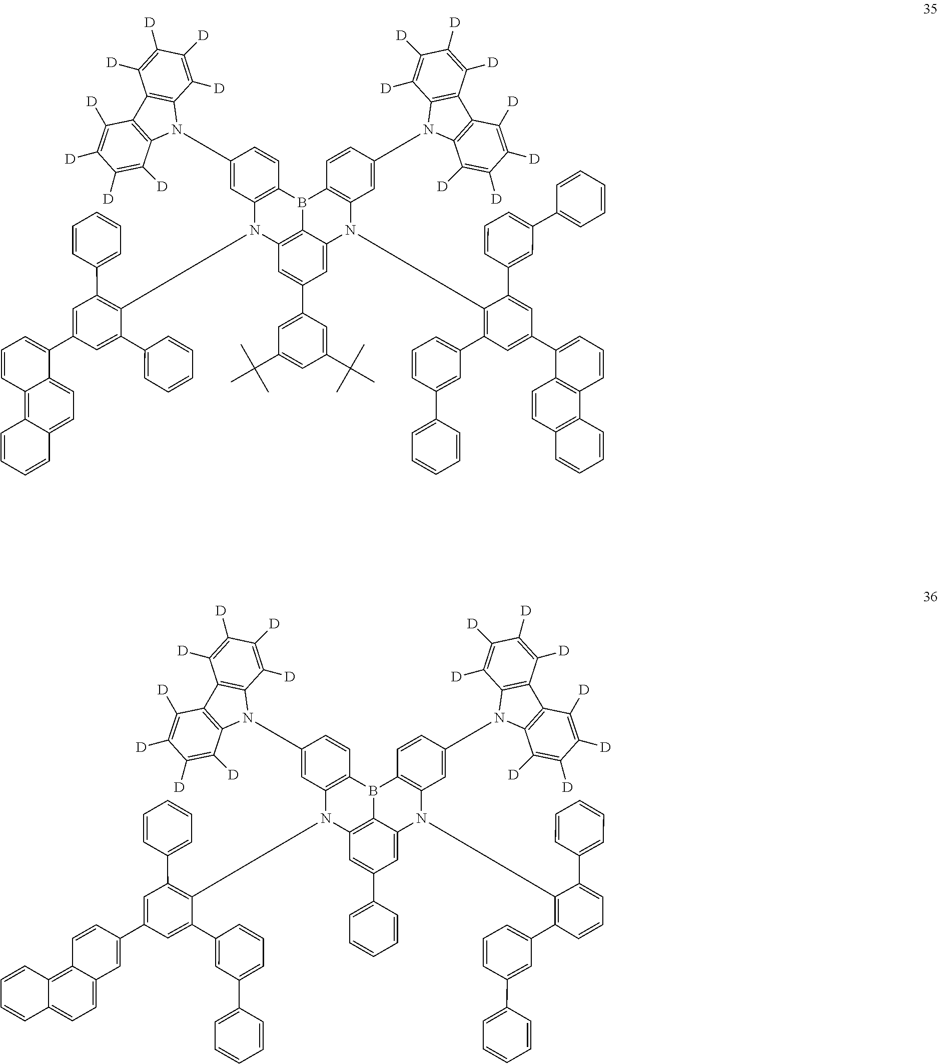 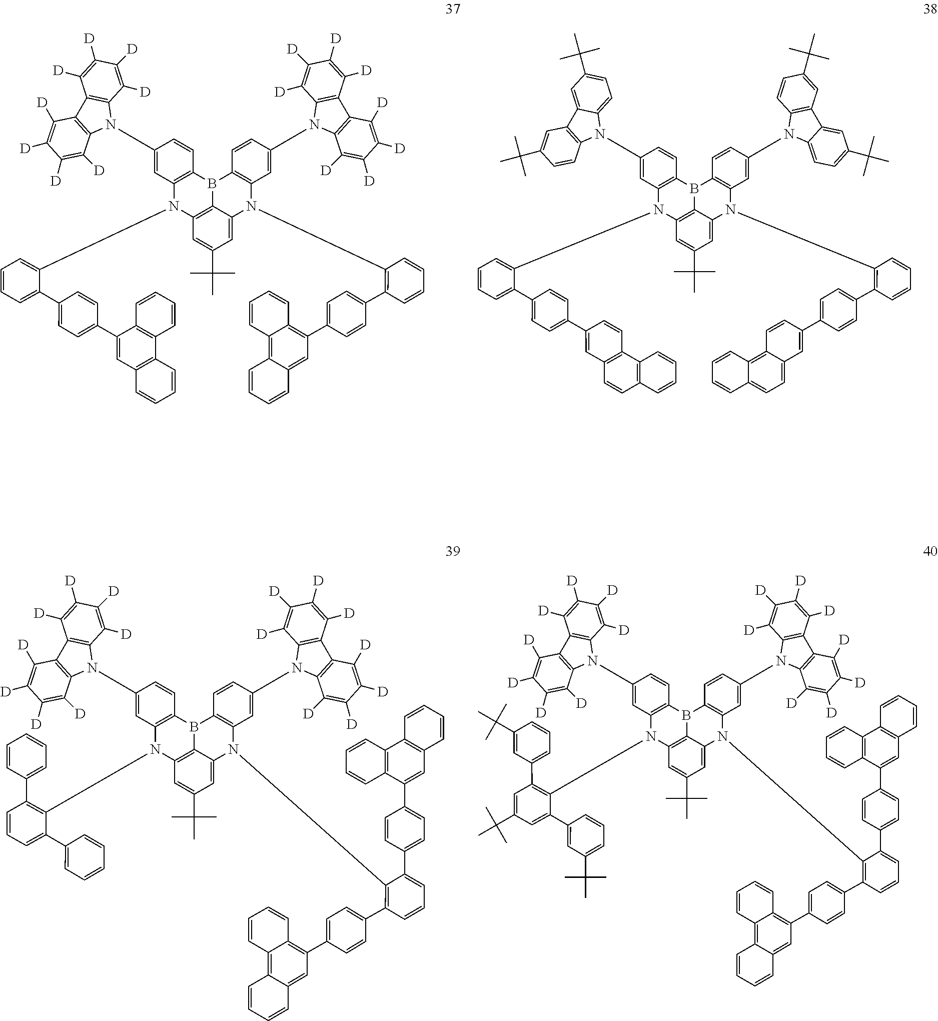 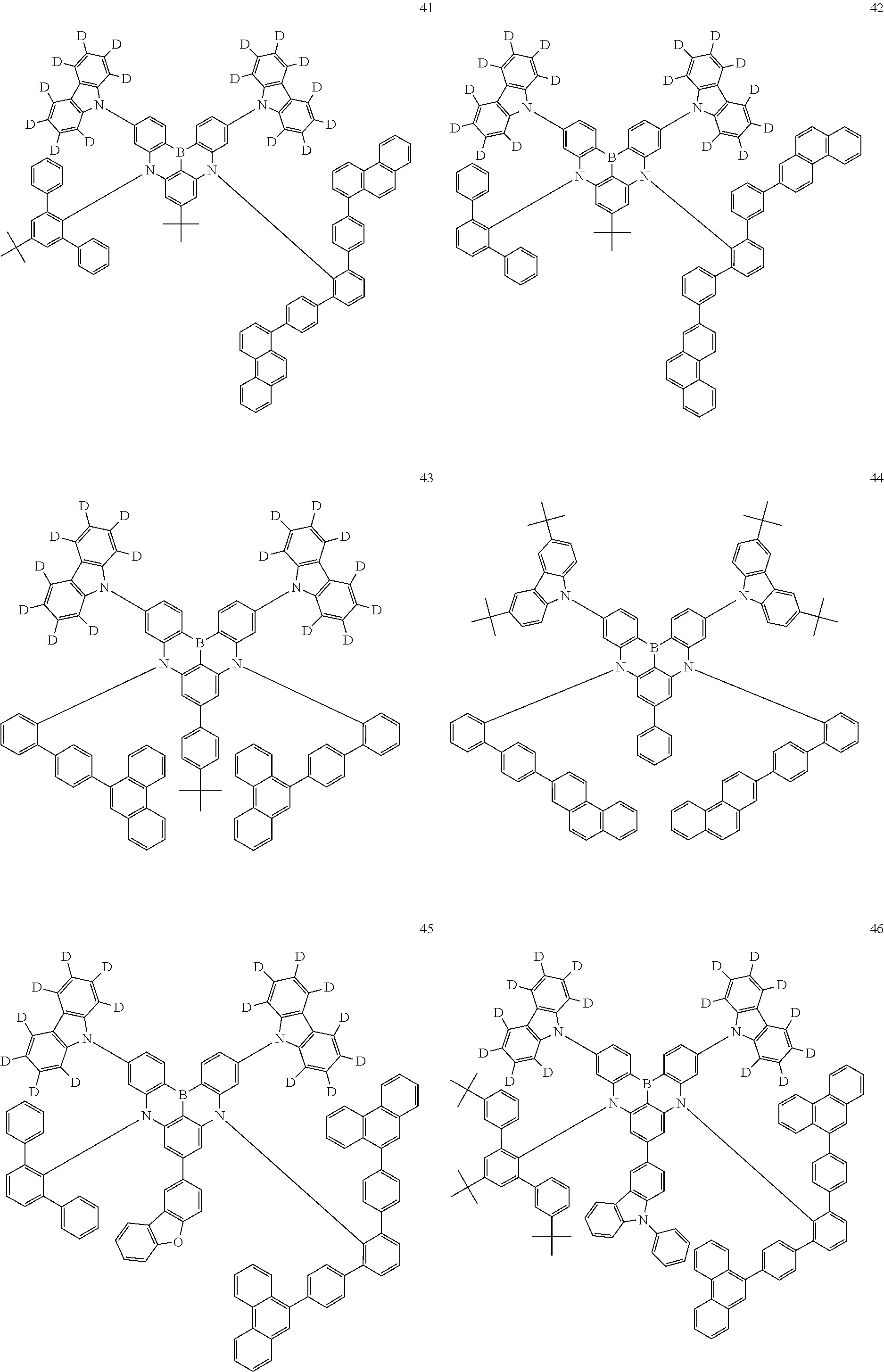 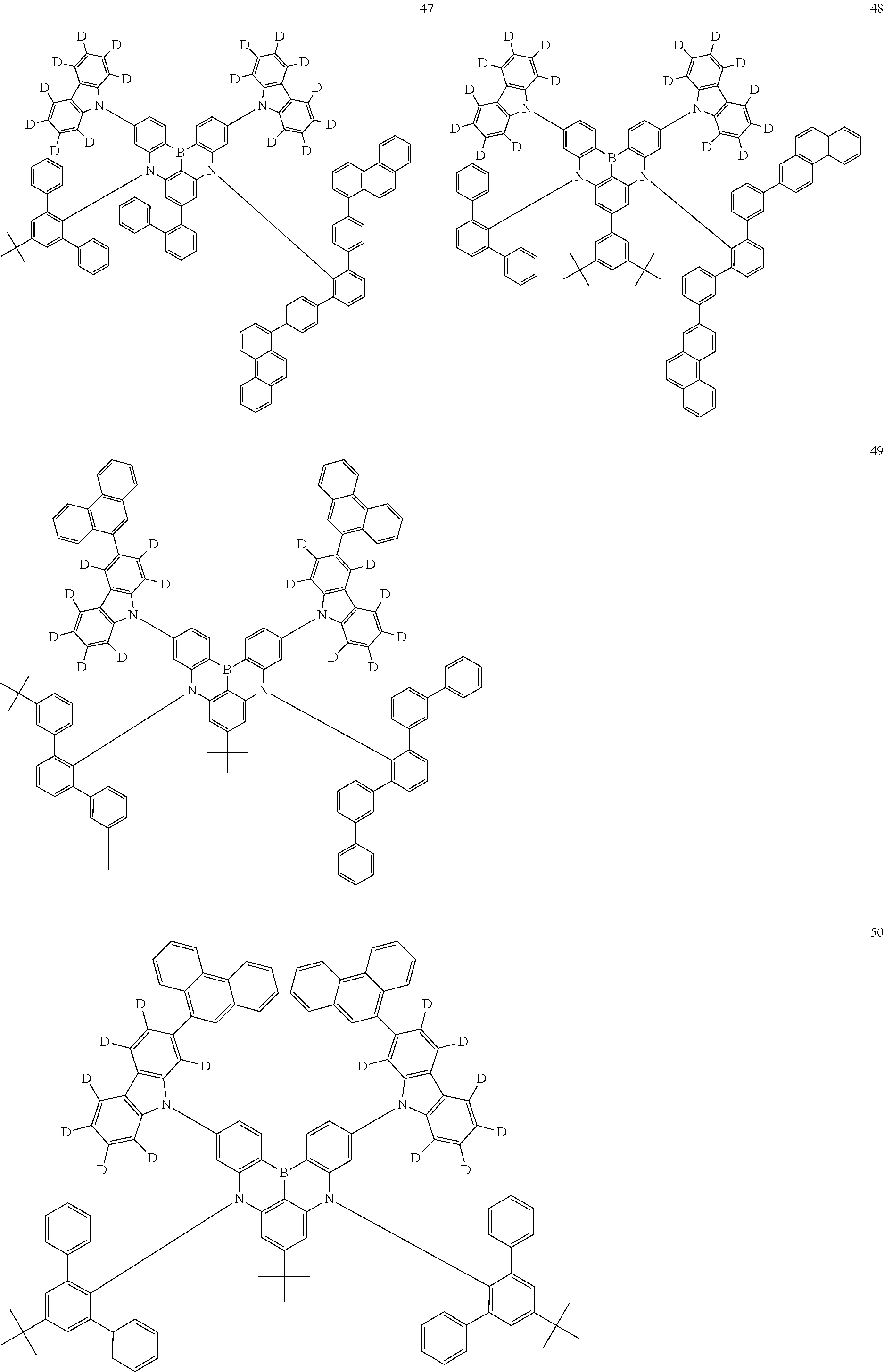 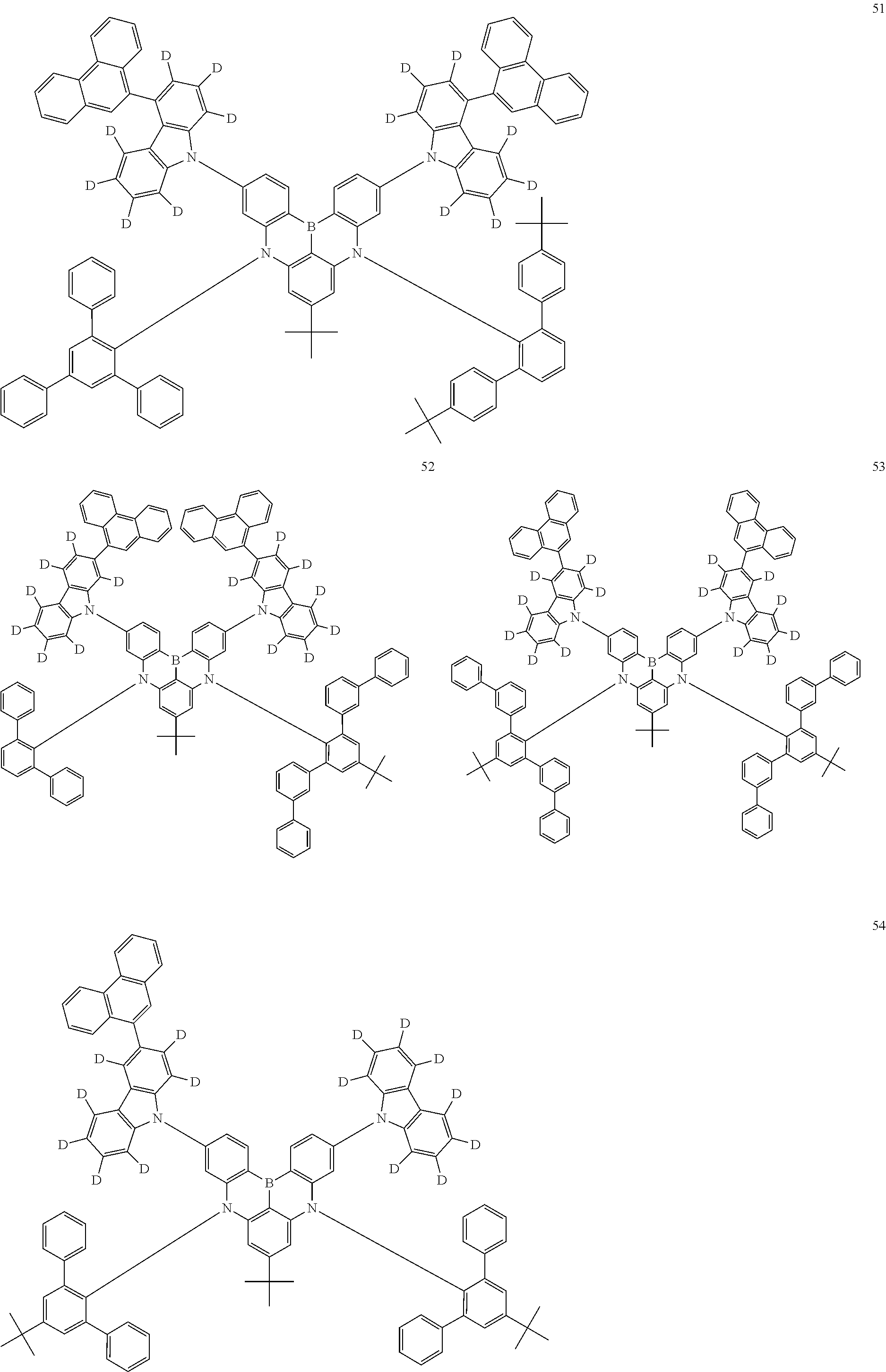 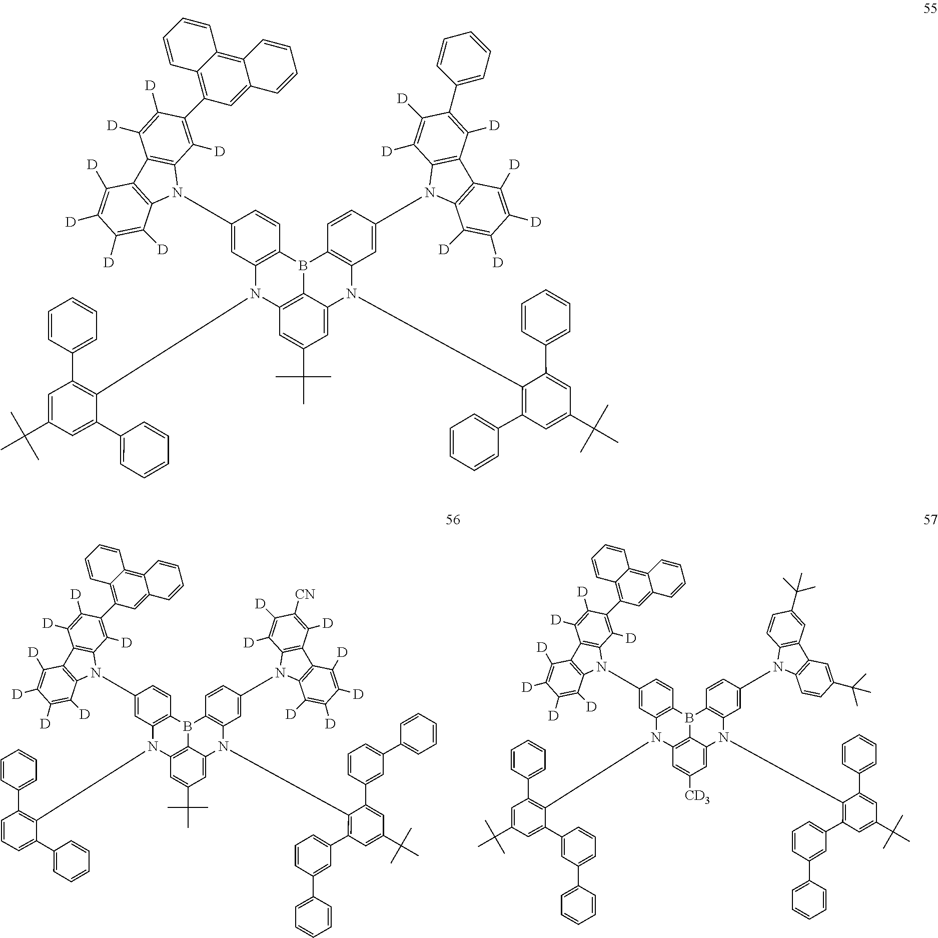 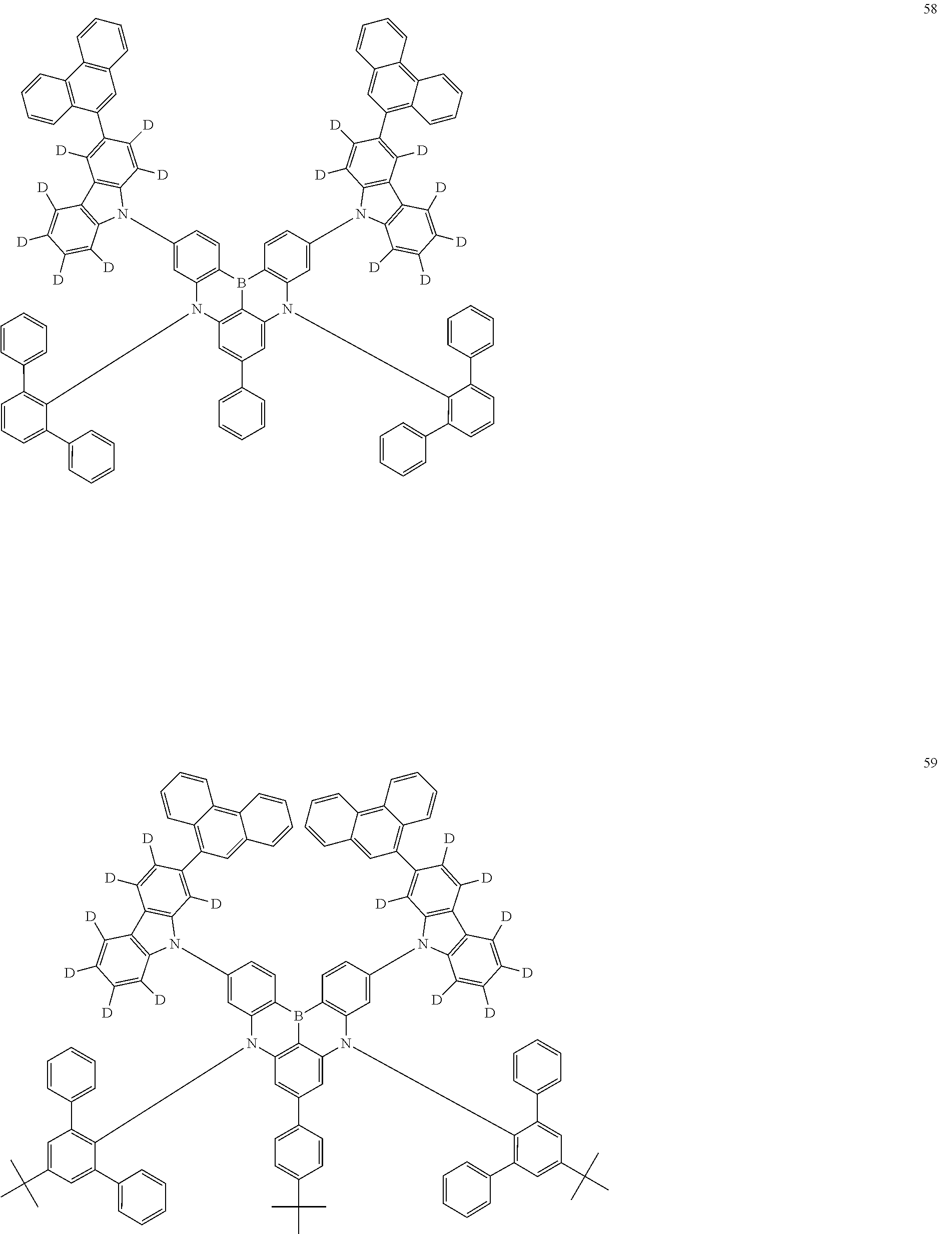 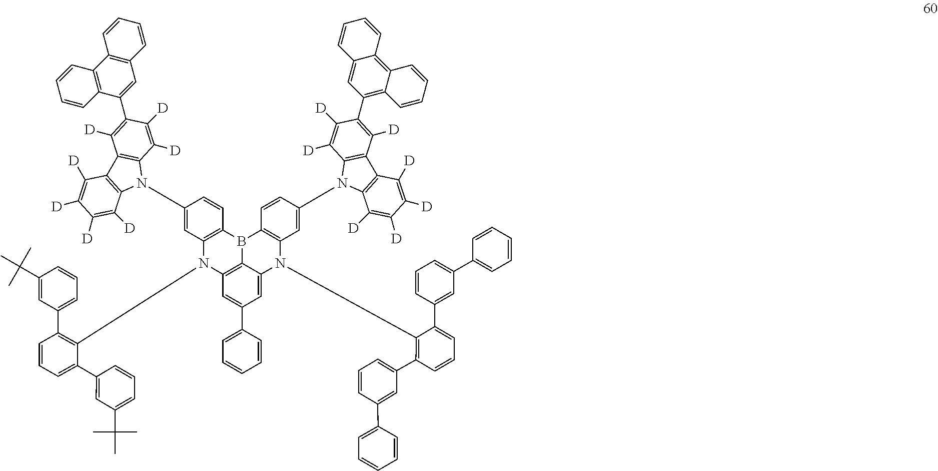 [SMILES: [2H]c1c([2H])c([2H])c2c(c1[2H])c1c([2H])c(-c3cc4ccccc4c4ccccc34)c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc(-n2c4c([2H])c([2H])c([2H])c([2H])c4c4c([2H])c(-c5cc6ccccc6c6ccccc56)c([2H])c([2H])c42)cc1N3c1c(-c2cccc(C(C)(C)C)c2)cccc1-c1cccc(C(C)(C)C)c1] 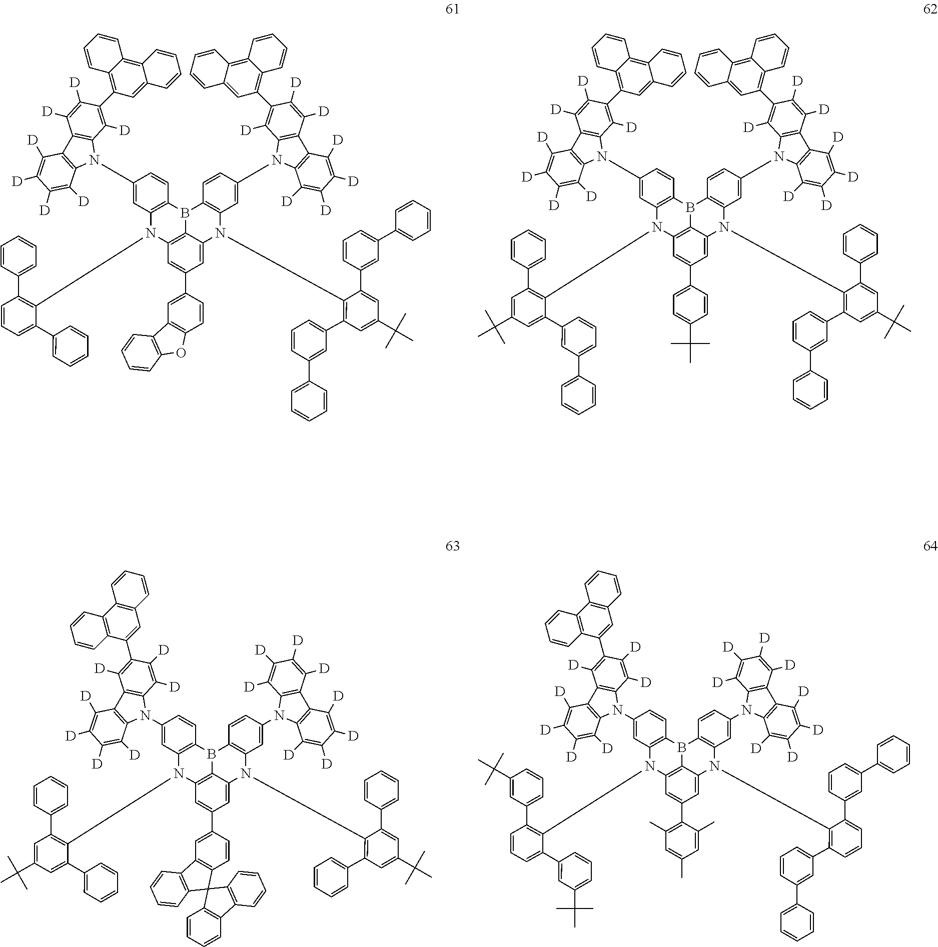 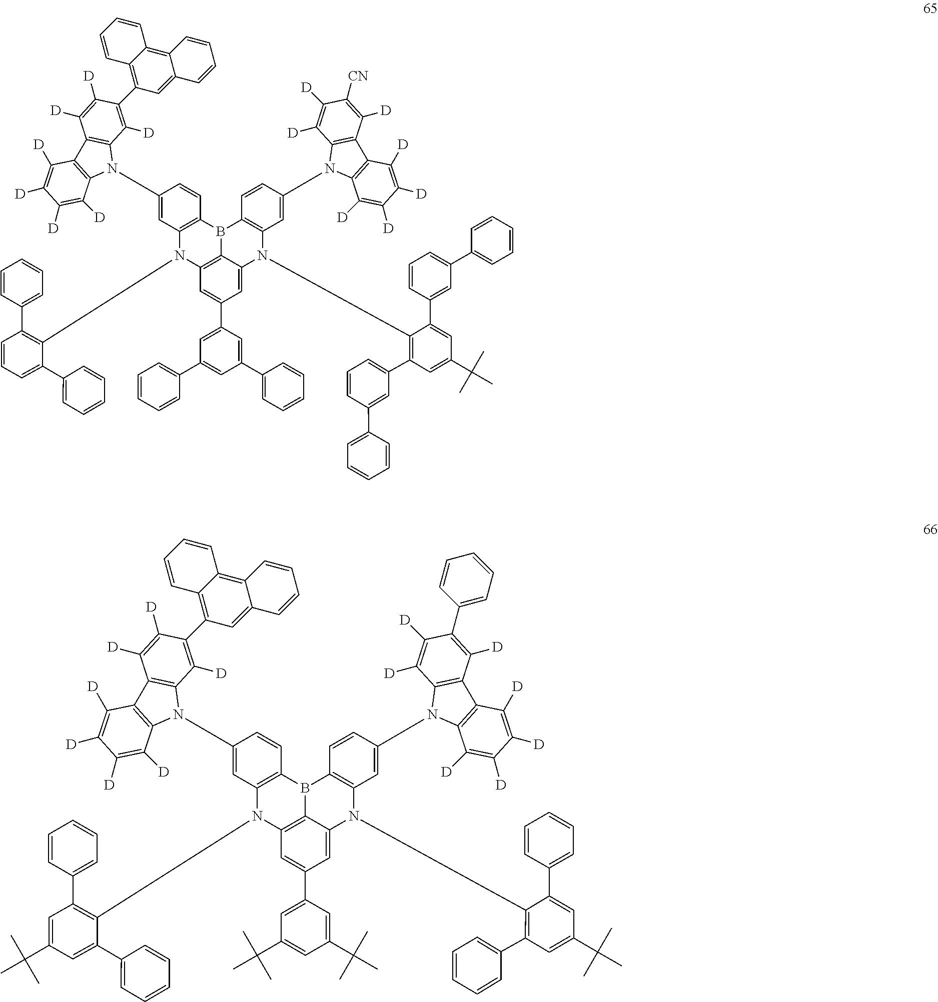 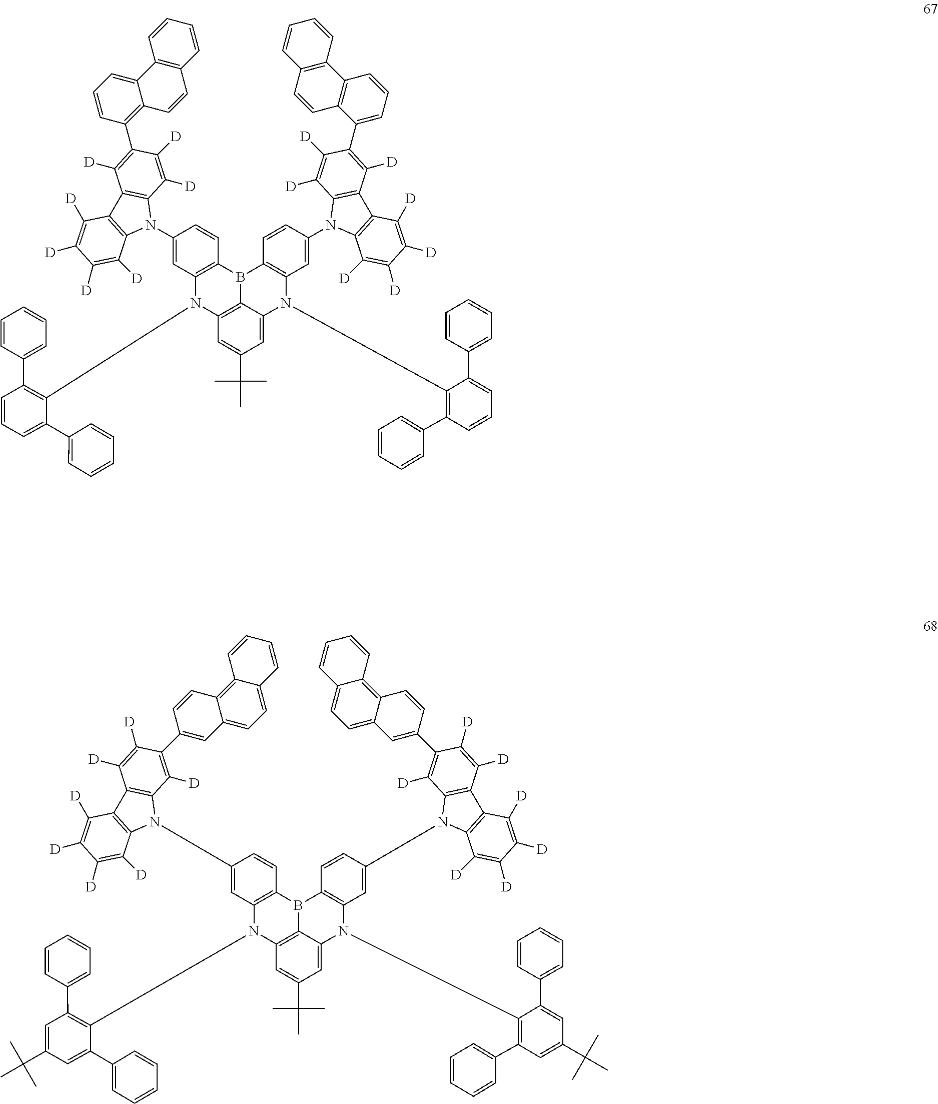 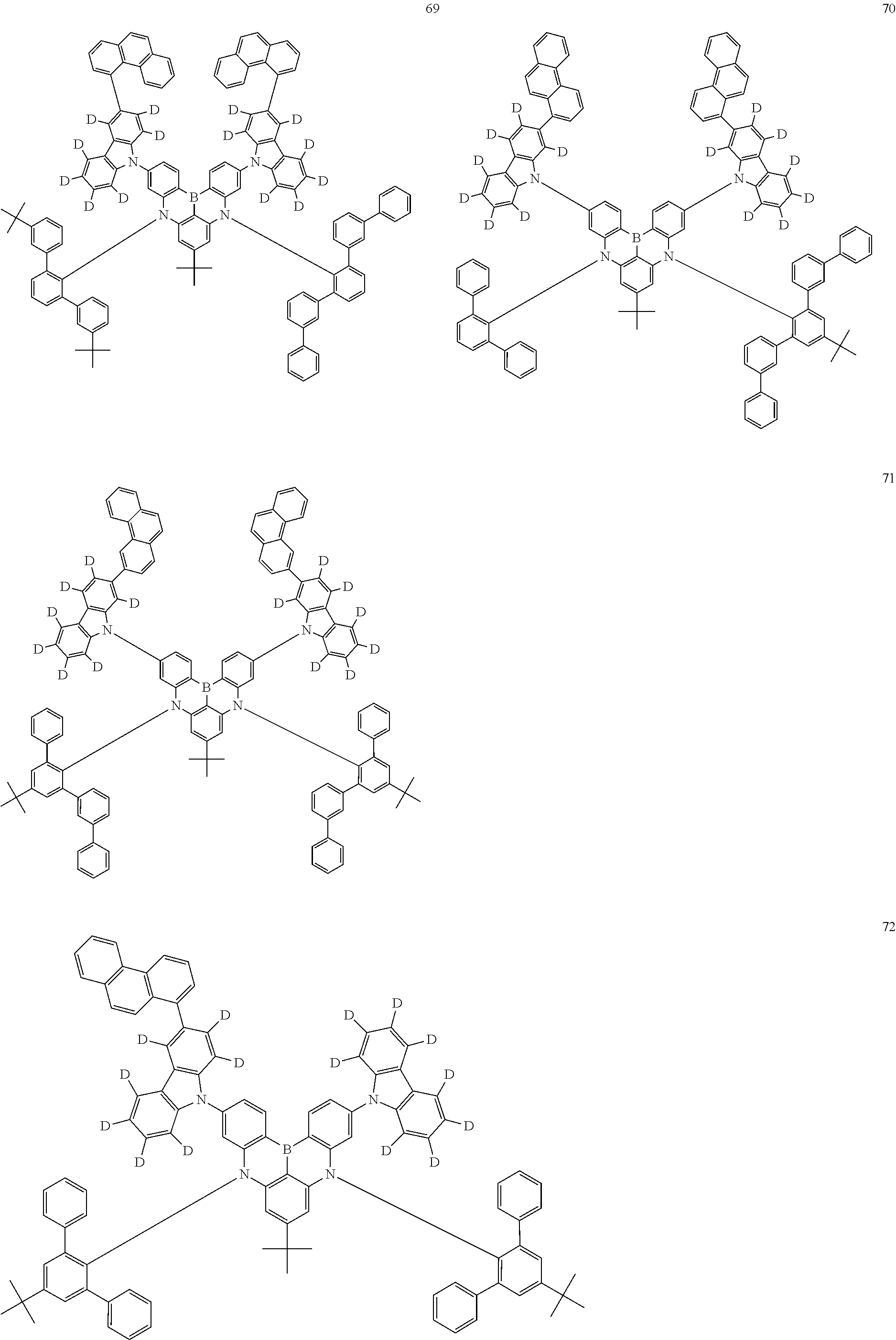 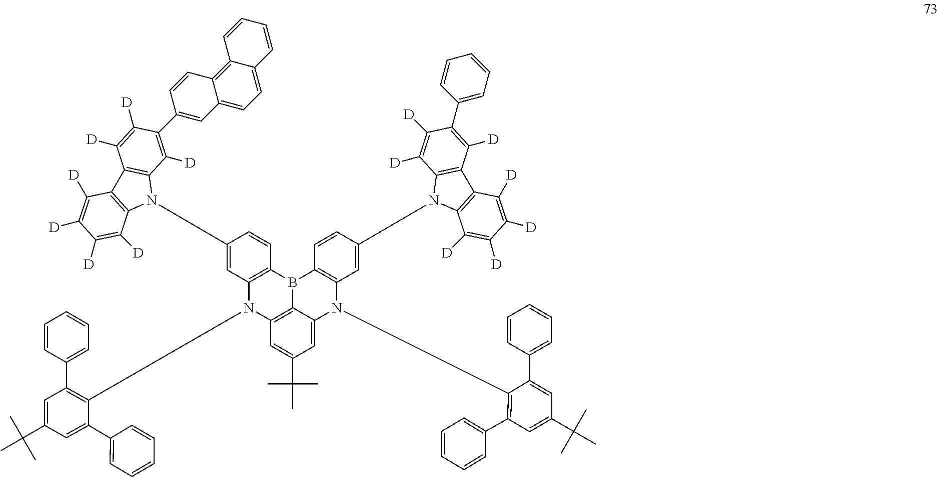 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4c([2H])c([2H])c([2H])c([2H])c4c4c([2H])c([2H])c(-c5ccc6c(ccc7ccccc76)c5)c([2H])c42)cc1N3c1c(-c2ccccc2)cc(C(C)(C)C)cc1-c1ccccc1] 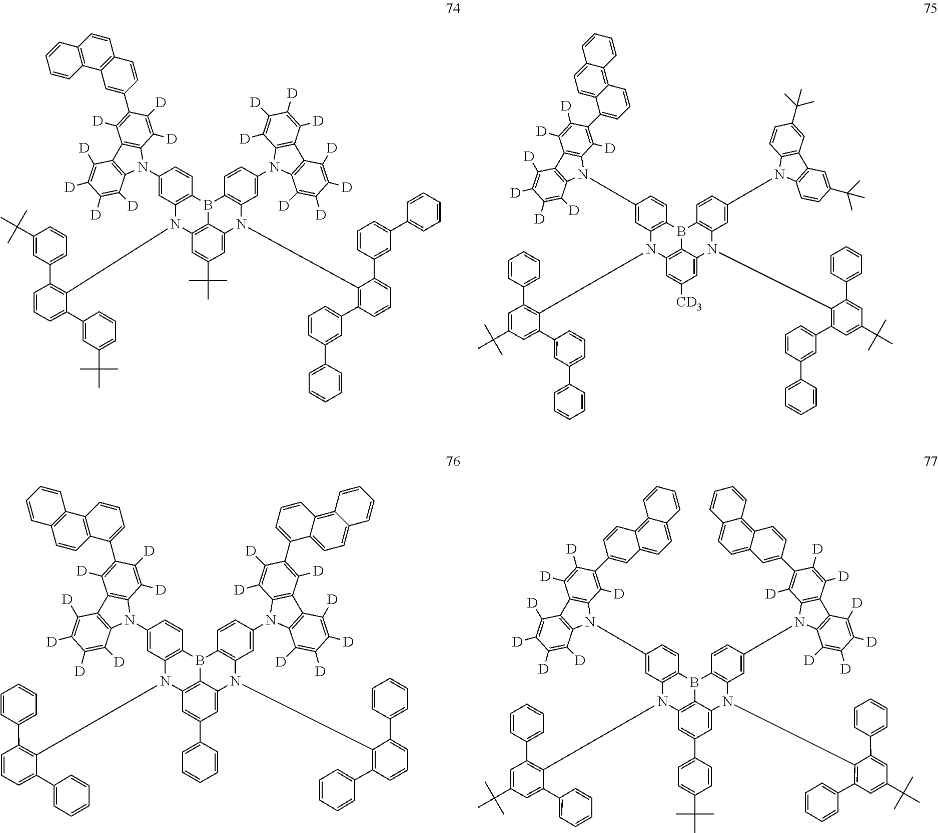 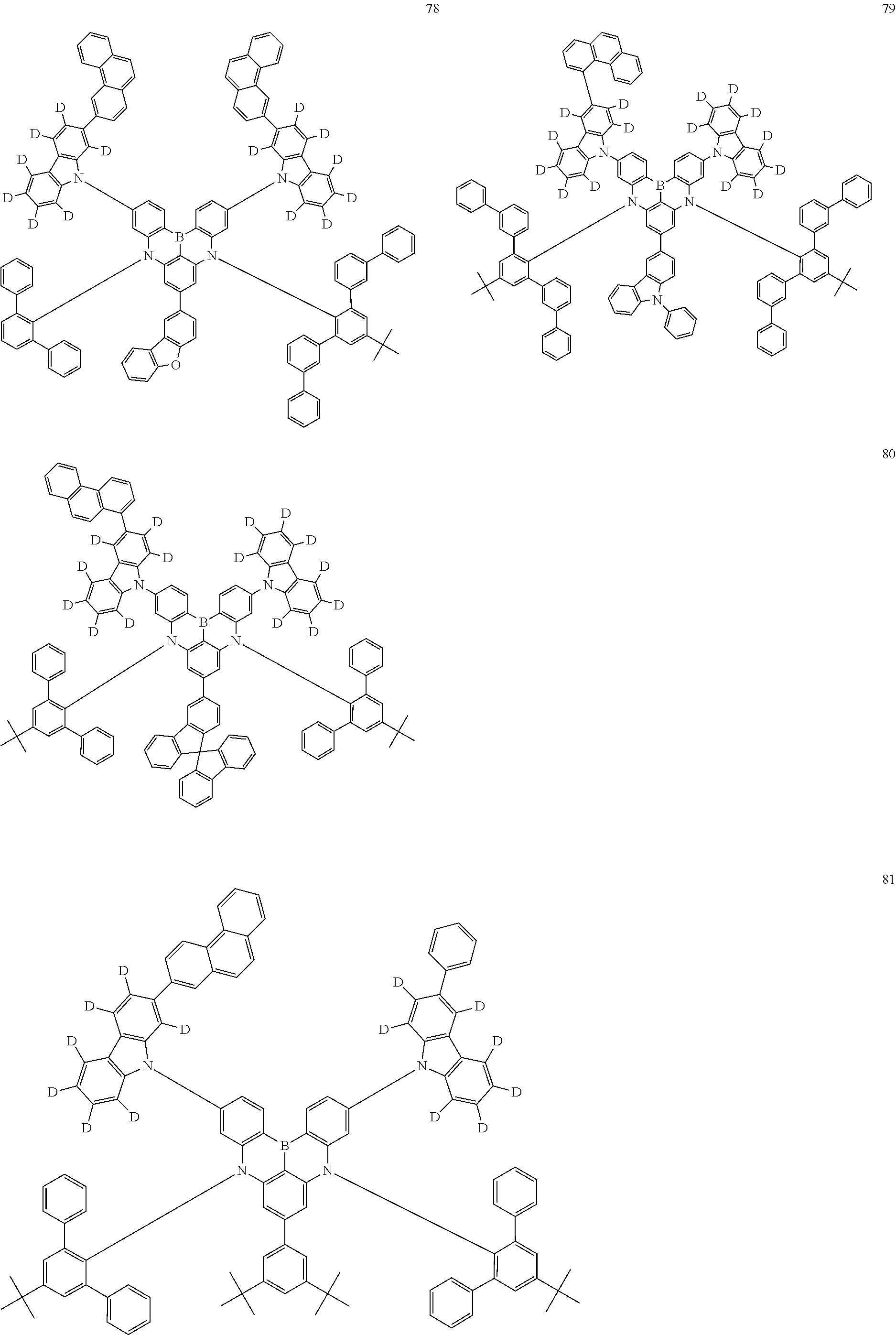 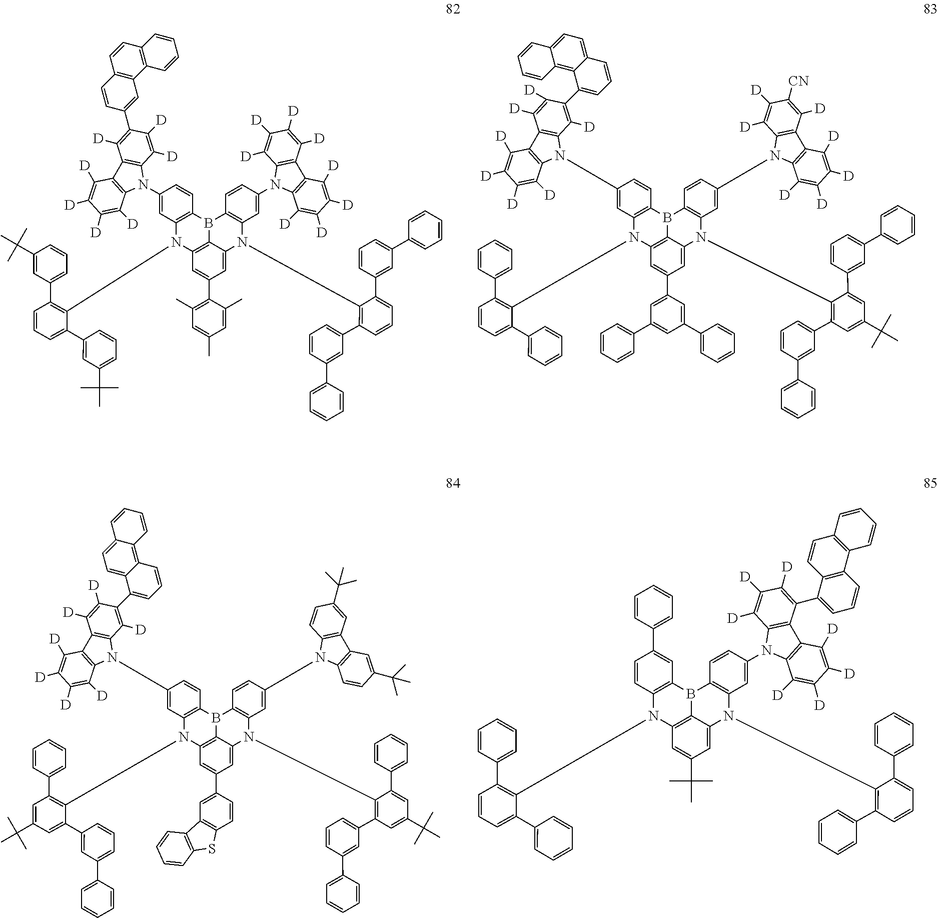 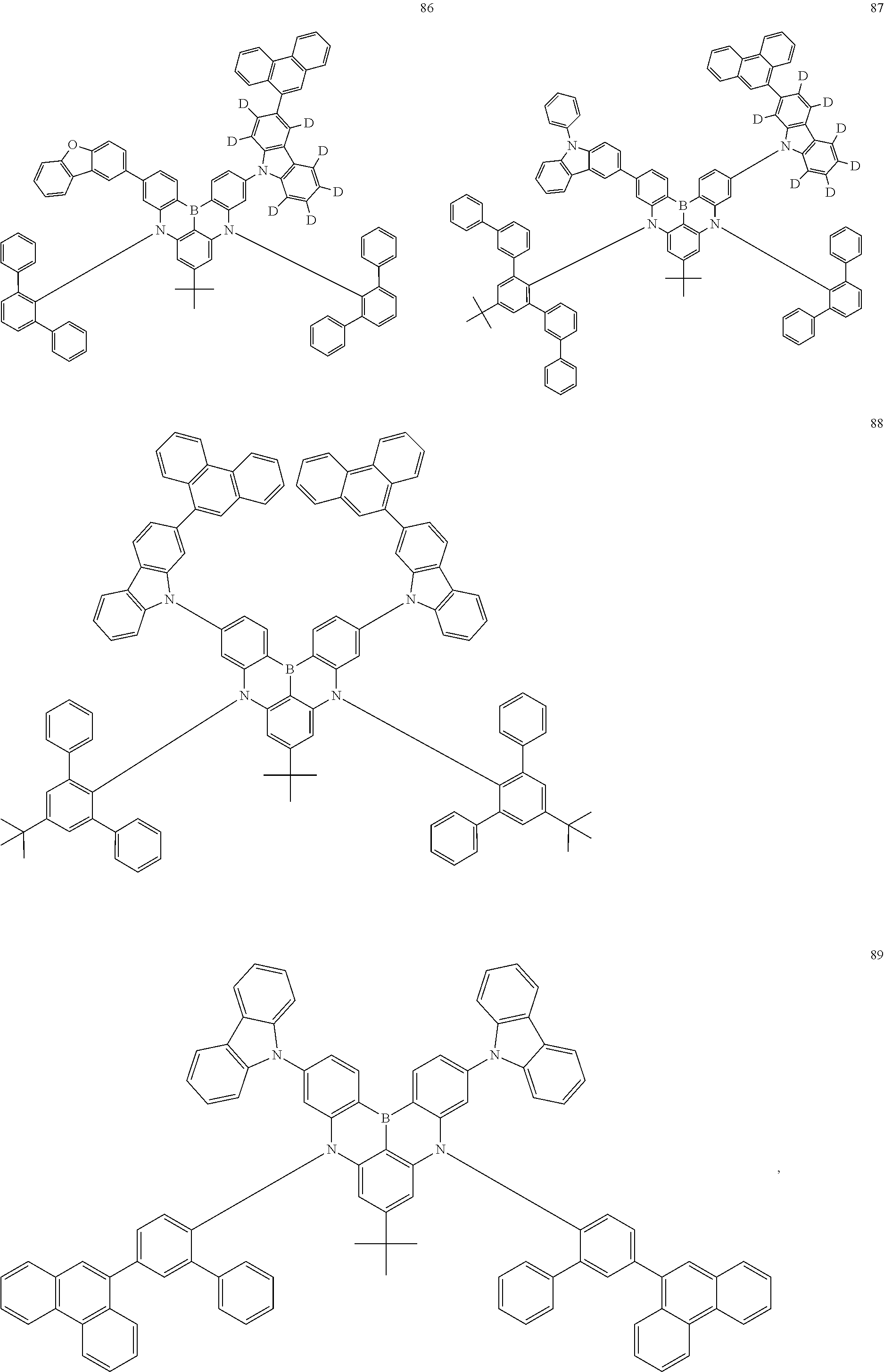
in Compound Group 1, D being a deuterium atom.

18. A display device comprising:
a base layer;
a circuit layer on the base layer; and
a display element layer on the circuit layer and comprising a light emitting element, the light emitting element comprising a first electrode, a second electrode on the first electrode, and a light emitting layer between the first electrode and the second electrode and comprising a fused polycyclic compound represented by Formula 1: 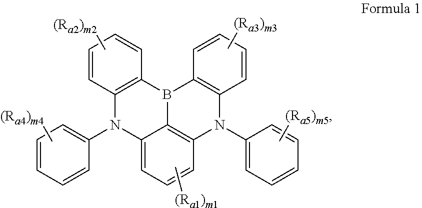
wherein, in Formula 1,
m1 is an integer of 0 to 3,
m2 and m3 are each independently an integer of 0 to 4,
m4 and m5 are each independently an integer of 0 to 5,
at least one selected from among Rₐ₁ to R^{a5} comprises a first carbazole substituted or unsubstituted, and
at least one selected from among Rₐ₁ to R^{a5} is a group represented by Formula 2, and the rest thereof are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms: 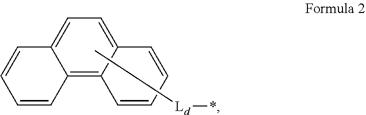
wherein, in Formula 2,
L_{d} is a direct linkage, a substituted or unsubstituted alkylene group having 1 to 30 carbon atoms, a substituted or unsubstituted arylene group having 6 to 30 ring-forming carbon atoms, or a substituted or unsubstituted heteroarylene group having 2 to 30 ring-forming carbon atoms,
and
when L_{d} does not include the first carbazole:
at least one selected from among Rₐ₁ to R^{a5} not represented by Formula 2 comprises the first carbazole substituted with a substituent other than a phenanthryl group; or
Rₐ₂ and Rₐ₃ are each independently include the first carbazole not substituted or the first carbazole substituted with a substituent other than a phenanthryl group.

19. The display device of claim 18, wherein the light emitting element comprises a first light emitting element configured to emit red light, a second light emitting element configured to emit green light, and a third light emitting element configured to emit blue light, wherein the fused polycyclic compound is in the third light emitting element.

20. The display device of claim 18, further comprising a light control layer on the display element layer and comprising a quantum dot.
